(19) United States
(12) Patent Application Publication
(10) Pub. No.: US 2026/0182246 A1
(43) Pub. Date: Jun. 25, 2026

(54) CONDENSED CYCLIC COMPOUND, LIGHT-EMITTING DEVICE INCLUDING THE CONDENSED CYCLIC COMPOUND, AND ELECTRONIC APPARATUS INCLUDING THE LIGHT-EMITTING DEVICE

(71) Applicant: Samsung Electronics Co., Ltd., Suwon-si (KR)

(72) Inventors: Joonghee Won, Suwon-si (KR); Sangmo Kim, Suwon-si (KR); Jong Soo Kim, Suwon-si (KR); Jiwhan Kim, Suwon-si (KR); Sungho Nam, Suwon-si (KR); Jun Chwae, Suwon-si (KR); Raesung Kim, Suwon-si (KR); Eunkyung Lee, Suwon-si (KR); Halim Lee, Suwon-si (KR); Daun Jeong, Suwon-si (KR); Hwayoung Cho, Suwon-si (KR); Kyeongsik Ju, Suwon-si (KR)

(21) Appl. No.: 19/417,922

(22) Filed: Dec. 12, 2025

(30) Foreign Application Priority Data
Dec. 24, 2024 (KR) 10-2024-0196204

(51) Int. Cl. H10K 85/60; C07F 5/02; C09K 11/06; H10K 50/12; H10K 85/30

(52) U.S. Cl. CPC H10K 85/658; C07F 5/027; C09K 11/06; H10K 85/346; C09K 2211/1007; C09K 2211/1018; H10K 50/121

(57) ABSTRACT

Provided are a condensed cyclic compound, a light-emitting device including the same, and an electronic apparatus including the light-emitting device, the condensed cyclic compound including a first boron, a second boron, ring A1, ring A2, ring A3, ring A4, and ring A5, and having a percent volume buried (% Vbur) of 65% or more with respect to the center of highest occupied natural transition orbital (HONTO).

### CROSS-REFERENCE TO RELATED APPLICATION

This application claims priority to and the benefit of Korean Patent Application No. 10-2024-0196204, filed on Dec. 24, 2024, in the Korean Intellectual Property Office, and all the benefits accruing therefrom under 35 U.S.C. § 119, the content of which is incorporated by reference herein in its entirety.

### BACKGROUND

### 1. Field

The subject matter relates to a condensed cyclic compound, a light-emitting device including the condensed cyclic compound, and an electronic apparatus including the light-emitting device.

### 2. Description of the Related Art

From among light-emitting devices, organic light-emitting devices (OLEDs) are self-emissive devices that, as compared with devices of the related art, have wide viewing angles, high contrast ratios, short response times, and excellent characteristics in terms of luminance, driving voltage, and response speed, and produce full-color images.

An organic light-emitting device includes an anode, a cathode, and an interlayer including an emission layer and arranged between the anode and the cathode. A hole transport region may be provided between the anode and the emission layer, and an electron transport region may be provided between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. When the excitons transition from an excited state to a ground state, light is emitted.

### SUMMARY

Provided are a condensed cyclic compound having excellent electrical stability and a light-emitting device employing the condensed cyclic compound having high luminescence efficiency and a long lifespan. Provided is a high-quality electronic apparatus including the light-emitting device.

Additional aspects will be set forth in part in the description which follows and, in part, will be apparent from the description, or may be learned by practice of the presented embodiments of the disclosure.

According to an aspect, provided is a condensed cyclic compound including a first boron, a second boron, ring A1, ring A2, ring A3, ring A4, and ring A5, wherein
each of ring A1 and ring A2 is a monocyclic 6-membered ring including the first boron, four carbons, and one nitrogen, wherein the nitrogen is located at a para-position to the first boron,
ring A1 and ring A2 are condensed (or, fused) with each other while sharing one of the carbons and the first boron,
each of ring A3 and ring A4 is a monocyclic 5-membered ring including the second boron as a ring-forming atom, or a monocyclic 6-membered ring including the second boron as a ring-forming atom,
ring A3 and ring A4 are condensed with each other while sharing the second boron,
ring A5 is a C₅-C₆₀ carbocyclic group or a C₃-C₆₀ heterocyclic group,
i) at least one of ring A1 or ring A2 and ii) at least one of ring A3 or ring A4 are each condensed to ring A5,
a percent volume buried (also referred to as percent buried volume, % Vbur) for a center of highest occupied natural transition orbital (HONTO) of the condensed cyclic compound is greater than or equal to 65%,
the center of HONTO of the condensed cyclic compound is evaluated from the natural transition orbital (NTO) contribution by each atom of the condensed cyclic compound in the triplet (T₁) state of the condensed cyclic compound, which is obtained using time dependent-density functional theory (TD-DFT) calculation at the B3LYP/6-31G(d,p) level, after obtaining an optimized structure of the condensed cyclic compound in a singlet state using DFT calculation at the B3LYP/6-31G(d,p) level,
% Vbur is V2/V1,
V1 is a volume of a virtual sphere S1, a center of the virtual sphere S1 is the center of HONTO of the condensed cyclic compound, and a radius of the virtual sphere S1 is 5 Å,
V2 is a total volume of atoms occupying the interior of the virtual sphere S1 among the atoms of the condensed cyclic compound arranged together with the virtual sphere S1 such that the center of HONTO of the condensed cyclic compound coincides with the center of the virtual sphere S1,
V2 is evaluated based on the geometric structure obtained through DFT calculations.

According to another aspect, a light-emitting device includes
a first electrode,
a second electrode facing the first electrode, and
an interlayer arranged between the first electrode and the second electrode,
wherein the interlayer includes an emission layer, and
wherein the interlayer further includes at least one of the condensed cyclic compounds.

According to another aspect, an electronic apparatus includes the light-emitting device.

### BRIEF DESCRIPTION OF THE DRAWINGS

These and other aspects, features, and advantages of certain exemplary embodiments will be more apparent from the following detailed description taken in conjunction with the accompanying drawings, in which:

FIG. 1 shows a schematic diagram of compound 2 arranged together with a virtual sphere S1 such that the center of HONTO of compound 2 coincides with the center of the virtual sphere S1; and

FIG. 2 shows a cross-sectional diagram schematically illustrating a light-emitting device according to one or more embodiments.

### DETAILED DESCRIPTION

Reference will now be made in further detail to exemplary embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

### Condensed Cyclic Compound

A condensed cyclic compound according to an aspect includes a first boron, a second boron, ring A1, ring A2, ring A3, ring A4, and ring A5.

Each of ring A1 and ring A2 in the condensed cyclic compound is a monocyclic 6-membered ring including, as ring-forming atoms, the first boron, four carbons, and one nitrogen, wherein the nitrogen is located at a para-position to the first boron.

Ring A1 and ring A2 are condensed with each other while sharing one of the carbons and the first boron.

Each of ring A3 and ring A4 is independently a monocyclic 5-membered ring including the second boron as a ring-forming atom, or a monocyclic 6-membered ring including the second boron as a ring-forming atom.

According to one or more embodiments, each of ring A3 and ring A4 may further include at least one carbon as a ring-forming atom, in addition to the second boron as described above.

In some embodiments, each of ring A3 and ring A4 may be a monocyclic 6-membered ring including the second boron as a ring-forming atom.

In some embodiments, each of ring A3 and ring A4 may be a monocyclic 6-membered ring including oxygen (O), sulfur (S), nitrogen (N), or silicon (Si), as a ring-forming atom, at the para-position with respect to the second boron.

Ring A3 and ring A4 are condensed with each other while sharing the second boron.

Each of ring A3 and ring A4 may be a monocyclic 6-membered ring including the second boron and at least one carbon as ring-forming atoms, and ring A3 and ring A4 may be condensed to each other while sharing the second boron and one of the at least one carbon.

Ring A5 is a C₅-C₆₀ carbocyclic group or a C₃-C₆₀ heterocyclic group.

According to one or more embodiments, ring A5 may be a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

In some embodiments, ring A5 in the condensed cyclic compound may be a benzene group.

In the condensed cyclic compound, i) at least one of ring A1 or ring A2, and ii) at least one of ring A3 or ring A4 are each condensed to ring A5.

At least one of the nitrogen included in ring A1 or the nitrogen included in ring A2 (for example, both the nitrogen included in ring A1 and the nitrogen included in ring A2) may each independently be bonded to a terphenyl monovalent group, a quaterphenyl monovalent group, or a quinquephenyl monovalent group. In this regard, at least one hydrogen of each of the terphenyl monovalent group, the quaterphenyl monovalent group, and the quinquephenyl monovalent group may optionally be substituted with:
deuterium, —F, or a cyano group; or
a C₁-C₆₀ alkyl group (e.g., a C₁-C₂₀ alkyl group or the like) unsubstituted or substituted with deuterium, —F, a cyano group, or a combination thereof.

In some embodiments, the nitrogen included in ring A1, the nitrogen included in ring A2, or a combination thereof (for example, both the nitrogen included in ring A1 and the nitrogen included in ring A2) may each independently be bonded to a group represented by Formula 2A, a group represented by Formula 2B, or a group represented by Formula 2C:

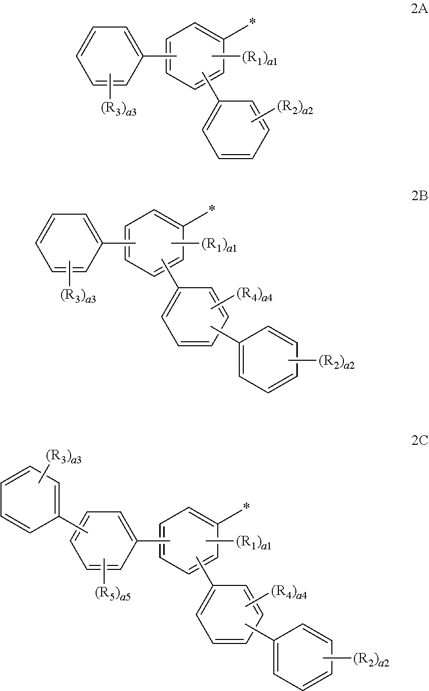

wherein, in Formulae 2A to 2C,
R₁ to R₅ are each independently:
hydrogen, deuterium, —F, or a cyano group; or
a C₁-C₆₀ alkyl group (e.g., a C₁-C₂₀ alkyl group or the like) unsubstituted or substituted with deuterium, —F, a cyano group, or a combination thereof,
a1 is an integer from 0 to 3,
a4 and a5 may each independently be an integer from 0 to 4,
a2 and a3 may each independently be an integer from 0 to 5, and
* indicates a binding site with a neighboring nitrogen.

R₁ to R₅ in Formulae 2A to 2C may each independently be hydrogen, deuterium, or a deuterated C₁-C₁₀ alkyl group.

In some embodiments, R₁ to R₅ in Formulae 2A to 2C may each independently be hydrogen, deuterium, or a deuterated tert-butyl group.

In some embodiments, the nitrogen included in ring A1, the nitrogen included in ring A2, or combination thereof (for example, both the nitrogen included in ring A1 and the nitrogen included in ring A2) may each independently be bonded to a group represented by Formula 2A(1) or a group represented by Formula 2A(2):

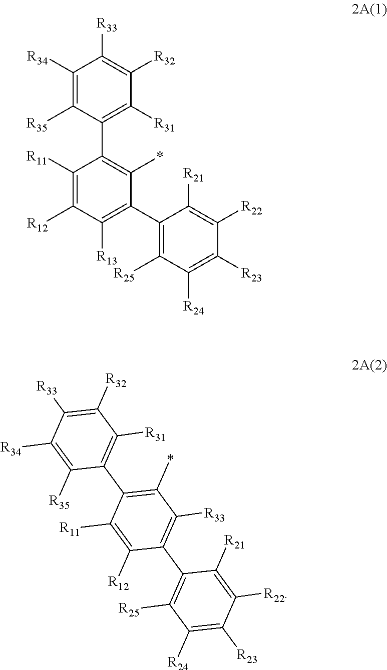

R₁₁ to R₁₃, R₂₁ to R₂₅, and R₃₁ to R₃₅ in Formulae 2A(1) and 2A(2) may be as described in connection with R₁, and * indicates a bonding site with a neighboring nitrogen.

In some embodiments, the nitrogen included in ring A1, the nitrogen included in ring A2, or a combination thereof may each independently be bonded to one of the groups represented by Formulae 21(1) to 21(8) or one of the groups represented by Formulae 22(1) to 22(8):

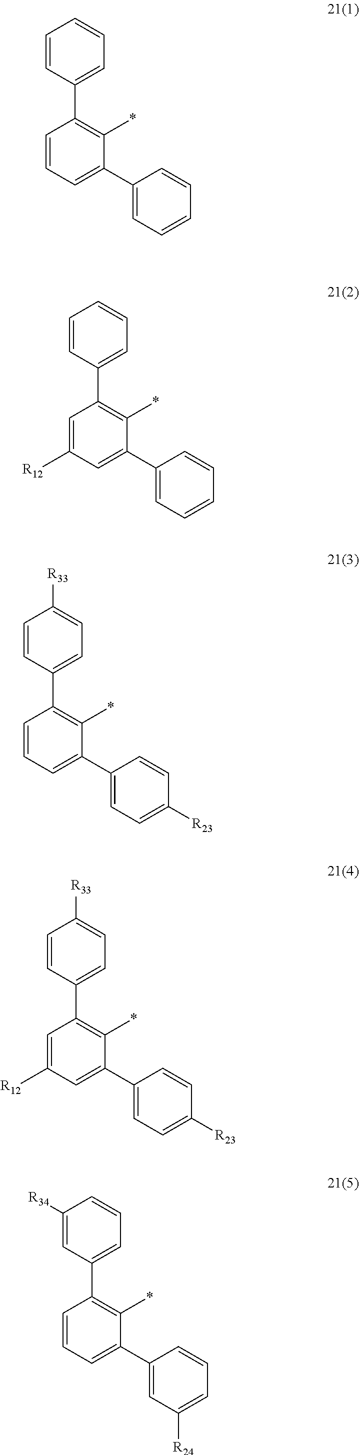

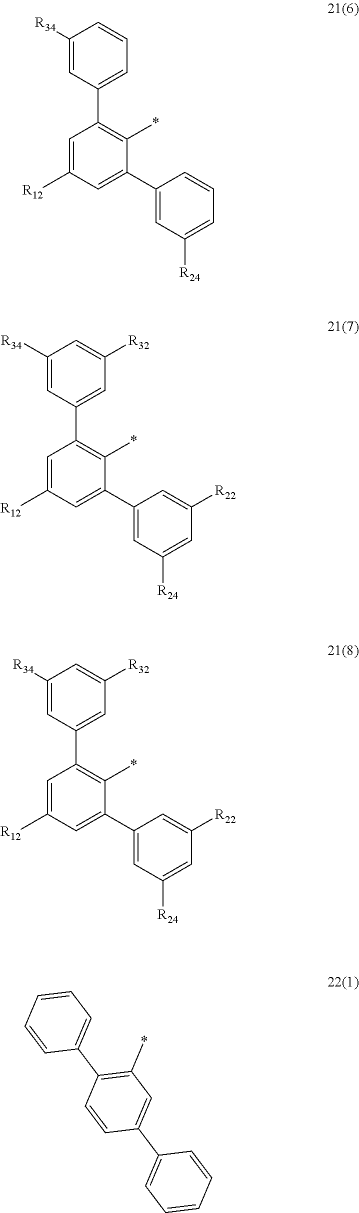

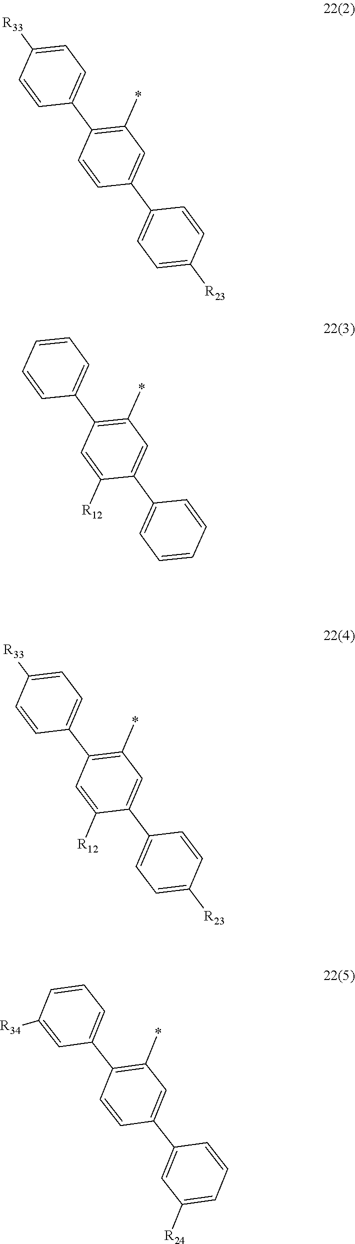

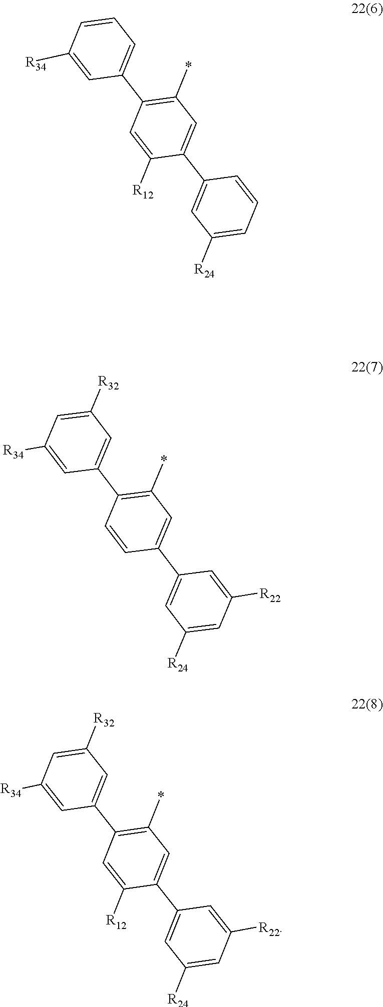

In Formulae 21(1) to 21(8) and 22(1) to 22(8),
R₁₂, R₂₂ to R₂₄ and R₃₂ to R₃₄ may each independently be a C₁-C₂₀ alkyl group unsubstituted or substituted with deuterium, and
* indicates a binding site with a neighboring nitrogen.

A percent volume buried (% Vbur) for the center of highest occupied natural transition orbital (HONTO) of the condensed cyclic compound may be about 65% or more, and for example, about 65% to 100%, about 65% to about 95%, about 65% to about 90%, about 65% to about 85%, about 65% to about 80%, about 65% to about 76%, about 65% to about 75.7%, about 66% to about 100%, about 66% to about 95%, about 66% to about 90%, about 66% to about 85%, about 66% to about 80%, about 66% to about 76%, about 66% to about 75.7%, about 66.6% to about 100%, about 66.6% to about 95%, about 66.6% to about 90%, about 66.6% to about 85%, about 66.6% to about 80%, about 66.6% to about 76%, or about 66.6% to about 75.7%.

The center of HONTO of the condensed cyclic compound is evaluated from the natural transition orbital (NTO) contribution by each atom of the condensed cyclic compound in the T₁ state of the condensed cyclic compound, which is obtained using a time dependent-density functional theory (TD-DFT) calculation at the B3LYP/6-31G(d,p) level, after obtaining an optimized structure of the condensed cyclic compound in the singlet state using DFT calculation at the B3LYP/6-31 G(d,p) level.

The DFT calculations may be performed using various known programs. For example, the DFT calculation may be performed using a Guassian program, or the like.

The % Vbur for the center of HONTO is calculated as “V2/V1”, i.e. V2 divided by V1.

V1 is a volume of a virtual sphere S1, a center of the virtual sphere S1 is the center of HONTO of the condensed cyclic compound, and a radius of the virtual sphere S1 is 5 Å.

V2 is a total volume of atoms occupying the interior of the virtual sphere S1 among the atoms of the condensed cyclic compound arranged together with the virtual sphere S1 such that the center of HONTO of the condensed cyclic compound coincides with the center of the virtual sphere S1.

V1 is a volume of a virtual sphere S1 having a radius of 5 Å. V2 is evaluated based on the geometric structure obtained through DFT calculations. For example, V2 is evaluated based on the geometric structure obtained through DFT calculations at the B3LYP/6-31G(d, p) level.

For example, % Vbur for the center of HONTO may be calculated by utilizing the Morfeus module, SambVca calculation, or the like based on the geometric structure obtained through DFT calculation for the condensed cyclic compound.

The position of the “center of HONTO” of the condensed cyclic compound may be changed depending on the structure of the condensed cyclic compound.

According to one or more embodiments, the distance between the center of HONTO and the first boron may be smaller than the distance between the center of HONTO and the second boron.

In some embodiments, the condensed cyclic compound may include a core represented by Formula 1:

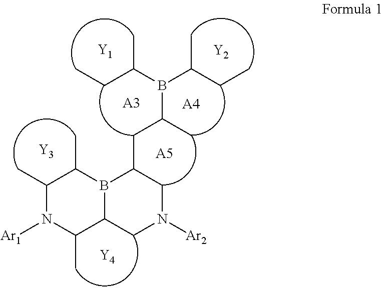

wherein, in Formula 1,
each of ring A3 and ring A4 is as described herein,
ring Y₁, ring Y₂, ring Y₃, ring Y₄ and ring A5 may each independently be a C₅-C₆₀ carbocyclic group or a C₃-C₆₀ heterocyclic group,
Ar₁ and Ar₂ may each independently be a terphenyl monovalent group, a quaterphenyl monovalent group, or a quinquephenyl monovalent group,
at least one hydrogen of each of the terphenyl monovalent group, the quaterphenyl monovalent group, and the quinquephenyl monovalent group may optionally be substituted with:
deuterium, —F, or a cyano group; or
a C₁-C₆₀ alkyl group (e.g., a C₁-C₂₀ alkyl group or the like) unsubstituted or substituted with deuterium, —F, a cyano group, or a combination thereof.

In Formula 1, the first boron, the second boron, ring A1, ring A2, ring A3, ring A4, and ring A5 may respectively correspond to “Boron 1”, “Boron 2”, “A1”, “A2”, “A3”, “A4” and “A5” shown in Formula 1′:

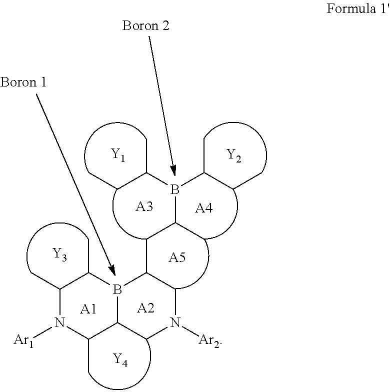

According to one or more embodiments, ring Y₁, ring Y₂, ring Y₃, ring Y₄, and ring A5 in Formula 1 may each independently be a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

In some embodiments, each of ring A3 and ring A4 in Formula 1 may be a monocyclic 6-membered ring including oxygen (O), sulfur (S), nitrogen (N), or silicon (Si) as a ring-forming atom at the para-position with respect to boron.

In some embodiments, Ar₁ and Ar₂ in the formula 1 may each independently be one of the groups represented by Formulae 2A, 2B, 2C, 2A(1), 2A(2), 21(1) to 21(8) and 22(1) to 22(8) described herein.

In some embodiments, at least one hydrogen of each of ring A3, ring A4, ring Y₁, ring Y₂, ring Y₃, ring Y₄, and ring A5 in Formula 1 may optionally be substituted with:
deuterium, —F, or a cyano group;
a C₁-C₆₀ alkyl group unsubstituted or substituted with deuterium, —F, a cyano group, or a combination thereof;
a C₆-C₆₀ aryl group, a C₁-C₆₀ heteroaryl group, a dibenzofuranyl group, a dibenzothiophenyl group, a carbazolyl group (e.g., an N-carbazolyl group), a fluorenyl group, or a dibenzosilolyl group, each unsubstituted or substituted with a deuterium, —F, a cyano group, a C₁-C₆₀ alkyl group, a C₆-C₆₀ aryl group, a C₁-C₆₀ heteroaryl group, a dibenzofuranyl group, a dibenzothiophenyl group, a carbazolyl group (e.g., an N-carbazolyl group), a fluorenyl group, a dibenzosilolyl group, —N(Q₃₁)(Q₃₂), —Si(Q₃₃)(Q₃₄)(Q₃₅), —Ge(Q₃₃)(Q₃₄)(Q₃₅), or a combination thereof; or
—N(Q₁)(Q₂), —Si(Q₃)(Q₄)(Q₅), or —Ge(Q₃)(Q₄)(Q₅).

In this regard, Q₁ to Q₅ and Q₃₁ to Q₃₅ may each independently be:
a C₁-C₆₀ alkyl group unsubstituted or substituted with deuterium, —F, a cyano group, or a combination thereof; or
a C₆-C₆₀ aryl group (a phenyl group, a biphenyl group, a terphenyl group, or the like), a C₁-C₆₀ heteroaryl group, a dibenzofuranyl group, a dibenzothiophenyl group, a carbazolyl group, a fluorenyl group, or a dibenzosilolyl group, each unsubstituted or substituted with deuterium, —F, a cyano group, a C₁-C₆₀ alkyl group, a C₆-C₆₀ aryl group (a phenyl group, a biphenyl group, a terphenyl group, or the like), a C₁-C₆₀ heteroaryl group, a dibenzofuranyl group, a dibenzothiophenyl group, a carbazolyl group, a fluorenyl group, a dibenzosilolyl group, or a combination thereof.

In some embodiments, at least one hydrogen of each of ring A3, ring A4, ring Y₁, ring Y₂, ring Y₃, ring Y₄, and ring A5 in Formula 1 may optionally be substituted with:
deuterium, —F, or a cyano group;
a C₁-C₂₀ alkyl group unsubstituted or substituted with deuterium, —F, a cyano group, or a combination thereof;
a phenyl group, a biphenyl group, a terphenyl group, a dibenzofuranyl group, a dibenzothiophenyl group, a carbazolyl group (e.g., an N-carbazolyl group), a fluorenyl group, or a dibenzosilolyl group, unsubstituted or substituted with deuterium, —F, a cyano group, a C₁-C₂₀ alkyl group, a phenyl group, a biphenyl group, a terphenyl group, a dibenzofuranyl group, a dibenzothiophenyl group, a carbazolyl group (e.g., an N-carbazolyl group), a fluorenyl group, a dibenzosilolyl group, —N(Q₃₁)(Q₃₂), —Si(Q₃₃)(Q₃₄)(Q₃₅), —Ge(Q₃₃)(Q₃₄)(Q₃₅), or a combination thereof; or
—N(Q₁)(Q₂), —Si(Q₃)(Q₄)(Q₅), or —Ge(Q₃)(Q₄)(Q₅).

In some embodiments, at least one hydrogen of each of ring A3, ring A4, ring Y₁, ring Y₂, ring Y₃, ring Y₄ or ring A5 in Formula 1 may optionally be substituted with deuterium, a C₁-C₁₀ alkyl group (e.g., a tert-butyl group or the like), a deuterated C₁-C₁₀ alkyl group (e.g., a deuterated tert-butyl group or the like), a phenyl group, a deuterated phenyl group, a deuterated phenyl group substituted with at least one C₁-C₁₀ alkyl group, or a combination thereof.

In some embodiments, the condensed cyclic compound may include a core represented by Formula 1(1):

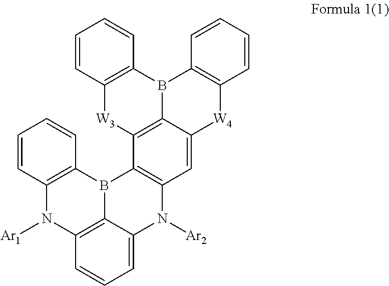

The description of each of Ar₁ and Ar₂ in Formula 1(1) is as described herein, and each of W₃ and W₄ may be O or S.

In some embodiments, the condensed cyclic compound may be represented by Formula 11 or 12:

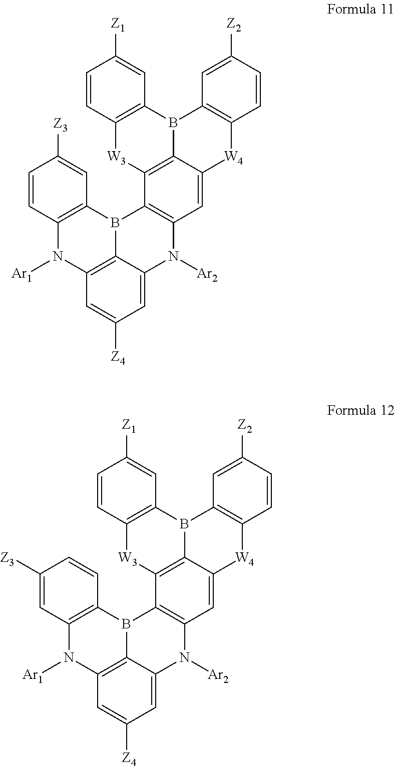

In Formulae 11 and 12,
W₃ and W₄ may each independently be O or S,
Ar₁ and Ar₂ may each be as described herein,
Z₁ to Z₄ may each independently be:
hydrogen, deuterium, —F, or a cyano group;
a C₁-C₂₀ alkyl group unsubstituted or substituted with deuterium, —F, a cyano group, or a combination thereof;
a phenyl group, a biphenyl group, a terphenyl group, a dibenzofuranyl group, a dibenzothiophenyl group, a carbazolyl group (e.g., an N-carbazolyl group), a fluorenyl group, or a dibenzosilolyl group, each unsubstituted or substituted with deuterium, —F, a cyano group, a C₁-C₂₀ alkyl group, a phenyl group, a biphenyl group, a terphenyl group, a dibenzofuranyl group, a dibenzothiophenyl group, a carbazolyl group (e.g., an N-carbazolyl group), a fluorenyl group, a dibenzosilolyl group, —N(Q₃₁)(Q₃₂), —Si(Q₃₃)(Q₃₄)(Q₃₅), —Ge(Q₃₃)(Q₃₄)(Q₃₅), or a combination thereof; or
—N(Q₁)(Q₂), —Si(Q₃)(Q₄)(Q₅), or —Ge(Q₃)(Q₄)(Q₅),
Q₁ to Q₅ and Q₃₁ to Q₃₅ may each independently be:
a C₁-C₂₀ alkyl group unsubstituted or substituted with deuterium, —F, a cyano group, or a combination thereof; or
a phenyl group, a biphenyl group, a terphenyl group, a dibenzofuranyl group, a dibenzothiophenyl group, a carbazolyl group (e.g., an N-carbazolyl group), a fluorenyl group, or a dibenzosilolyl group, each unsubstituted or substituted with deuterium, —F, a cyano group, a C₁-C₂₀ alkyl group, a phenyl group, a biphenyl group, a terphenyl group, a dibenzofuranyl group, a dibenzothiophenyl group, a carbazolyl group (e.g., an N-carbazolyl group), a fluorenyl group, a dibenzosilolyl group, or a combination thereof; and
at least one of Z₁ to Z₄ is not hydrogen.

One aspect provides a condensed cyclic compound including a first boron, a second boron, ring A1, ring A2, ring A3, ring A4, and ring A5, wherein
each of ring A1 and ring A2 may be a monocyclic 6-membered ring including the first boron, four carbon atoms and one nitrogen located at a para-position to the first boron as ring-forming atoms,
ring A1 and ring A2 may be condensed with each other while sharing one of the carbon atoms and the first boron,
each of ring A3 and ring A4 may be a monocyclic 5-membered ring including the second boron as a ring-forming atom, or a monocyclic 6-membered ring including the second boron as a ring-forming atom,
ring A3 and ring A4 may be condensed with each other while sharing the second boron,
ring A5 may be a C₅-C₆₀ carbocyclic group or a C₃-C₆₀ heterocyclic group,
i) at least one of ring A1 or ring A2, and ii) at least one of ring A3 or ring A4 may each be condensed to ring A5,
the nitrogen included in ring A1, the nitrogen included in ring A2, or a combination thereof (for example, both the nitrogen included in ring A1 and the nitrogen included in ring A2) may each independently be bonded to a terphenyl monovalent group, a quaterphenyl monovalent group, or a quinquephenyl monovalent group, and
at least one hydrogen of each of the terphenyl monovalent group, the quaterphenyl monovalent group, and the quinquephenyl monovalent group may optionally be substituted with:
deuterium, —F, or a cyano group; or
a C₁-C₆₀ alkyl group (e.g., a C₁-C₂₀ alkyl group) unsubstituted or substituted with deuterium, —F, a cyano group, or a combination thereof.

For example, the nitrogen included in ring A1, the nitrogen included in ring A2, or a combination thereof (for example, both the nitrogen included in ring A1 and the nitrogen included in ring A2) may each independently be bonded to one of the groups represented by Formulae 2A, 2B, 2C, 2A(1), 2A(2), 21(1) to 21(8), or 22(1) to 22(8).

In some embodiments, the condensed cyclic compound may comprise a core represented by Formula 1 as mentioned above, wherein at least one hydrogen of each of ring A3, ring A4, ring Y₁, ring Y₂, ring Y₃, ring Y₄, and ring A5 may optionally be substituted with:
deuterium, —F, or a cyano group;
a C₁-C₆₀ alkyl group (e.g., a C₁-C₂₀ alkyl group) unsubstituted or substituted with deuterium, —F, a cyano group, or a combination thereof;
a C₆-C₆₀ aryl group, a C₁-C₆₀ heteroaryl group, a dibenzofuranyl group, a dibenzothiophenyl group, a carbazolyl group, a fluorenyl group, or a dibenzosilolyl group, each unsubstituted or substituted with a deuterium, —F, a cyano group, a C₁-C₆₀ alkyl group (e.g., a C₁-C₂₀ alkyl group), a C₆-C₆₀ aryl group, a C₁-C₆₀ heteroaryl group, a dibenzofuranyl group, a dibenzothiophenyl group, a carbazolyl group, a fluorenyl group, a dibenzosilolyl group, —N(Q₃₁)(Q₃₂), —Si(Q₃₃)(Q₃₄)(Q₃₅), —Ge(Q₃₃)(Q₃₄)(Q₃₅), or a combination thereof; or
—N(Q₁)(Q₂), —Si(Q₃)(Q₄)(Q₅), or —Ge(Q₃)(Q₄)(Q₅), and
Q₁ to Q₅ and Q₃₁ to Q₃₅ may each independently be:
a C₁-C₆₀ alkyl group unsubstituted or substituted with deuterium, —F, a cyano group, or a combination thereof; or
a C₆-C₆₀ aryl group, a C₁-C₆₀ heteroaryl group, a dibenzofuranyl group, a dibenzothiophenyl group, a carbazolyl group, a fluorenyl group, or a dibenzosilolyl group, each unsubstituted or substituted with deuterium, —F, a cyano group, a C₁-C₆₀ alkyl group, a C₆-C₆₀ aryl group, a C₁-C₆₀ heteroaryl group, a dibenzofuranyl group, a dibenzothiophenyl group, a carbazolyl group, a fluorenyl group, a dibenzosilolyl group, or a combination thereof.

In some embodiments, the condensed cyclic compound may comprise the core represented by Formula 1(1) as previously described. Alternatively, the condensed cyclic compound may be represented by Formula 11 or 12 as described above. Alternatively or additionally, at least one hydrogen of the various rings of the condensed cyclic compound may be substituted with the various substituents as described above.

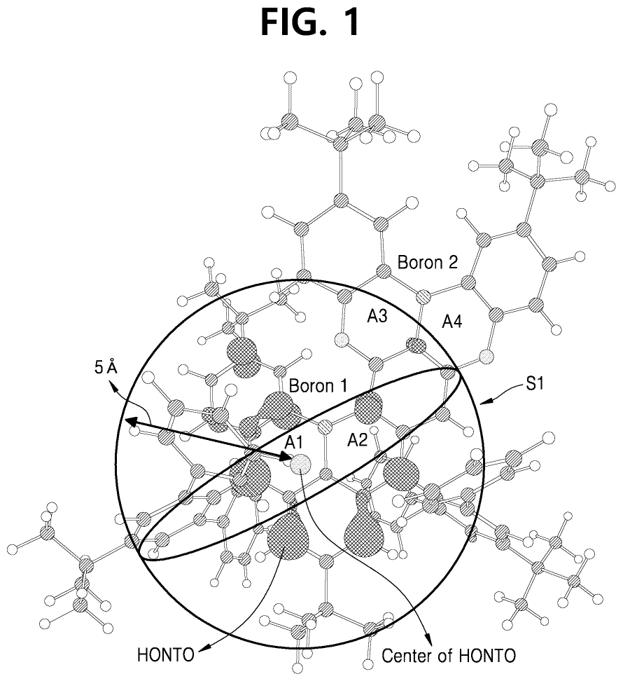

FIG. 1 shows a schematic diagram of compound 2 arranged together with a virtual sphere S1 such that the center of HONTO of compound 2 coincides with the center of the virtual sphere S1. For convenience, the first boron, the second boron, ring A1, ring A2, ring A3, ring A4, and ring A5 of compound 2 are respectively denoted as “Boron 1”, “Boron 2”, “A1”, “A2”, “A3”, “A4” and “A5”. Hereinafter, with reference to compound 2 and FIG. 1, the first boron, the second boron, ring A1, ring A2, ring A3, ring A4, and ring A5 of compound 2 and the % Vbur with respect to the center of HONTO of compound 2 will be described in further detail.

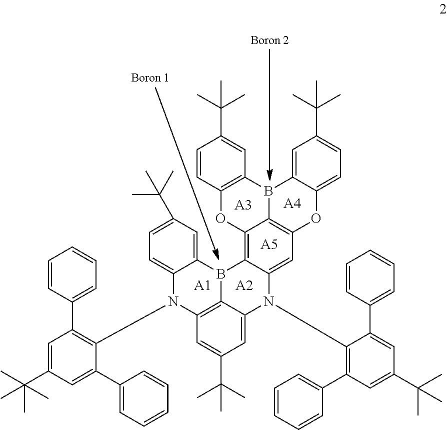

Each of ring A1 and ring A2 of compound 2 is a monocyclic 6-membered ring including a first boron, four carbons, and one nitrogen located at the para-position to the first boron as ring-forming atoms, and each of ring A3 and ring A4 is a monocyclic 6-membered ring including a second boron as a ring-forming atom. Ring A1 and ring A2 are condensed with each other while sharing one of the carbon atoms and the first boron, and ring A3 and ring A4 are condensed with each other while sharing the second boron.

Ring A5 of compound 2 is a benzene group, and ring A2, ring A3, and ring A4 of compound 2 are condensed to ring A5.

FIG. 1 illustrates the “HONTO” of compound 2 in a T₁ state of compound 2, which is obtained using a time dependent-density functional theory (TD-DFT) calculation at a B3LYP/6-31G(d,p) level, after obtaining an optimized structure of compound 2 in a singlet state by using DFT calculation at the B3LYP/6-31 G(d,p) level, and the “center of HONTO” of compound 2, which is evaluated from natural transition orbital (NTO) contribution by each atom of compound 2 in a T₁ state of compound 2 based on the HONTO of compound 2.

In FIG. 1, the distance between the center of HONTO of compound 2 and the first boron may be smaller than the distance between the center of HONTO of compound 2 and the second boron.

The center of the virtual sphere S1 illustrated in FIG. 1 is the center of HONTO of compound 2, the radius of the virtual sphere S1 illustrated in FIG. 1 is 5 Å, and the volume of the virtual sphere S1 simulated in this way becomes V1 of compound 2.

Meanwhile, as shown in FIG. 1, among the atoms of compound 2 arranged together with the virtual sphere S1 to coincide the center of HONTO of compound 2 with the center of the virtual sphere S1, the total volume of the atoms occupying the interior of the virtual sphere S1 is V2 of compound 2. V2 may be evaluated based on the geometric structure obtained through the density functional theory (DFT) calculation for compound 2 as described above, and the result of the calculation of “V2/V1” is the % Vbur for the center of HONTO of compound 2.

As described above, when the % Vbur for the “center of HONTO” of the condensed cyclic compound is about 65% or more, the “center of HONTO,” which is the most electrically vulnerable point in the excited state of the condensed cyclic compound, is effectively protected by the remaining atoms, such that the Dexter energy transfer to other compounds used together with the condensed cyclic compound, for example, the Dexter energy transfer between a host and/or a sensitizer and the condensed cyclic compound may be effectively reduced. As a result, a light-emitting device including at least one of the condensed cyclic compound may have high luminescence efficiency and/or long life characteristics.

The singlet (Si) energy of the condensed cyclic compound may be about 2.700 eV to about 3.050 eV, about 2.800 eV to about 3.050 eV, about 2.900 eV to about 3.050 eV, about 3.000 eV to about 3.050 eV, about 2.700 eV to about 3.035 eV, about 2.800 eV to about 3.035 eV, about 2.900 eV to about 3.035 eV, about 3.000 eV to about 3.035 eV, or about 3.016 eV to about 3.035 eV. In some embodiments, the absolute value of the difference between the singlet (Si) energy and the triplet (T₁) energy of the condensed cyclic compound may be about 0 eV to about 1 eV, about 0 eV to about 0.8 eV, about 0 eV to about 0.6 eV, about 0 eV to about 0.415 eV, about 0 eV to about 0.410 eV, about 0 eV to about 0.404 eV, about 0.1 eV to about 1 eV, about 0.1 eV to about 0.8 eV, about 0.1 eV to about 0.6 eV, about 0.1 eV to about 0.415 eV, about 0.1 eV to about 0.410 eV, about 0.1 eV to about 0.404 eV, about 0.2 eV to about 1 eV, about 0.2 eV to about 0.8 eV, about 0.2 eV to about 0.6 eV, about 0.2 eV to about 0.415 eV, about 0.2 eV to about 0.410 eV, about 0.2 eV to about 0.404 eV, about 0.3 eV to about 1 eV, about 0.3 eV to about 0.8 eV, about 0.3 eV to about 0.6 eV, about 0.3 eV to about 0.415 eV, about 0.3 eV to about 0.410 eV, or about 0.3 eV to about 0.404 eV. Thereby, the reverse inter-system crossing in the condensed cyclic compound may be easily achieved, and the internal quantum efficiency of a light-emitting device including the same may be improved.

According to one or more embodiments, the condensed cyclic compound may satisfy at least one of condition A and condition B:

### Condition A

The singlet (Si) energy of the condensed cyclic compound may be about 2.700 eV to about 3.050 eV.

### Condition B

The absolute value of the difference between the singlet (Si) energy and the triplet (T₁) energy of the condensed cyclic compound may be about 0 eV to about 0.415 eV.

The full width at half maximum (FWHM) of the emission spectrum of the condensed cyclic compound may be about 5 nm to about 30 nm, about 10 nm to about 30 nm, or about 20 nm to about 30 nm.

The emission peak wavelength (also referred to as peak emission wavelength or maximum emission peak wavelength) of the emission spectrum of the condensed cyclic compound may be about 400 nm to about 500 nm, about 440 nm to about 470 nm, about 445 nm to about 470 nm, about 450 nm to about 470 nm, about 440 nm to about 465 nm, about 445 nm to about 465 nm, about 450 nm to about 465 nm, about 440 nm to about 460 nm, about 445 nm to about 460 nm, or about 450 nm to about 460 nm.

The FWHM and the maximum emission peak wavelength of the emission spectrum of the condensed cyclic compound may be evaluated for a film including the condensed cyclic compound. The “film including a condensed cyclic compound” may be produced using various methods, such as a vacuum deposition method, a coating method, and a heating method. The “film including a condensed cyclic compound” may further include other compounds in addition to the condensed cyclic compound, for example, a host as described herein.

The absolute value of the HOMO energy level of the condensed cyclic compound may be about 4.0 eV to about 6.5 eV.

The term “N-carbazolyl group” as used herein refers to a monovalent group

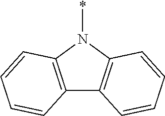 [SMILES: *n1c2ccccc2c2ccccc21]

in which hydrogen is separated from N of a carbazole group, allowing bonding to another group through N. (where * represents a bonding site with a neighboring atom).

In some embodiments, the condensed cyclic compound may be a multiple resonance thermally activated delayed fluorescent material.

In some embodiments, the condensed cyclic compound may be one of compounds 1 to 384 or one of compounds 1 to 384 wherein at least one hydrogen is replaced with deuterium:

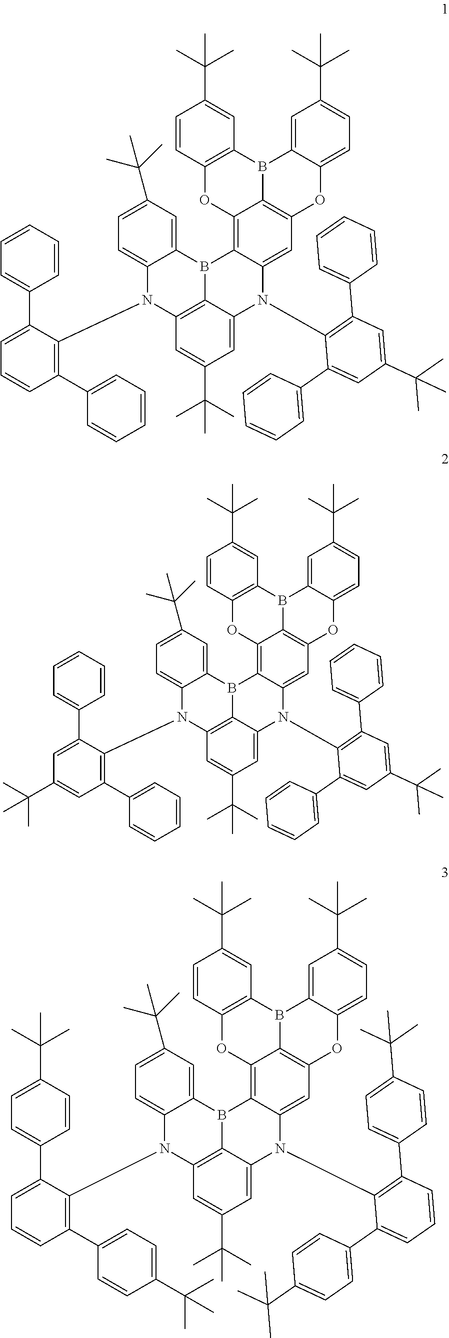

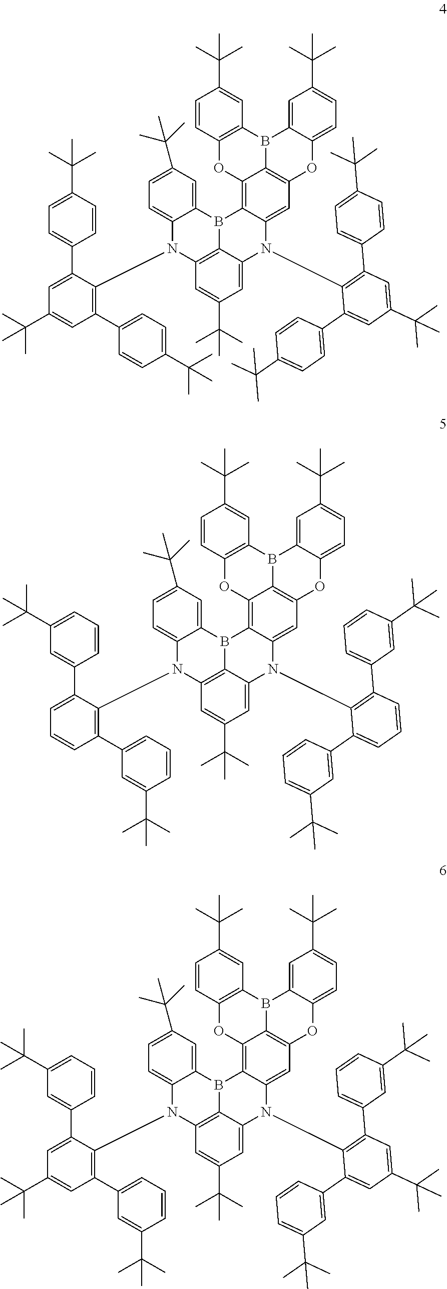

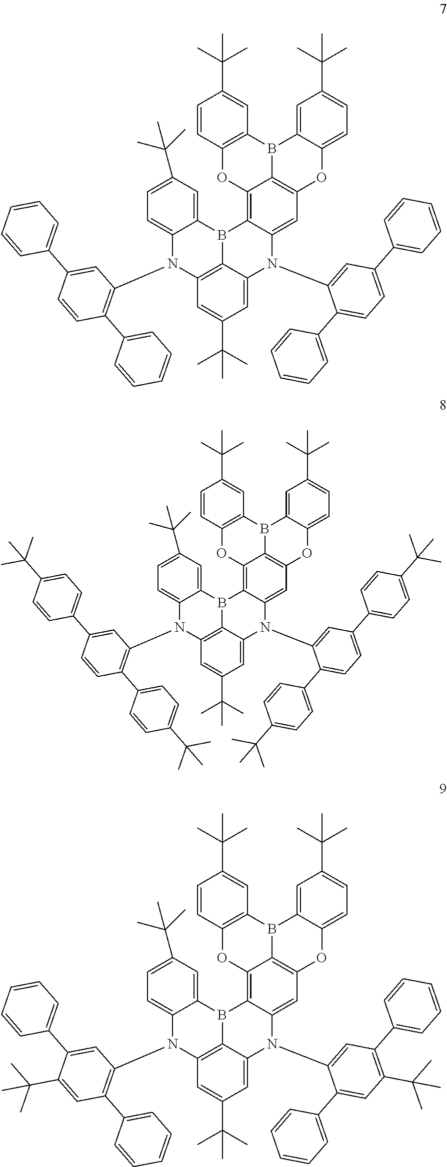

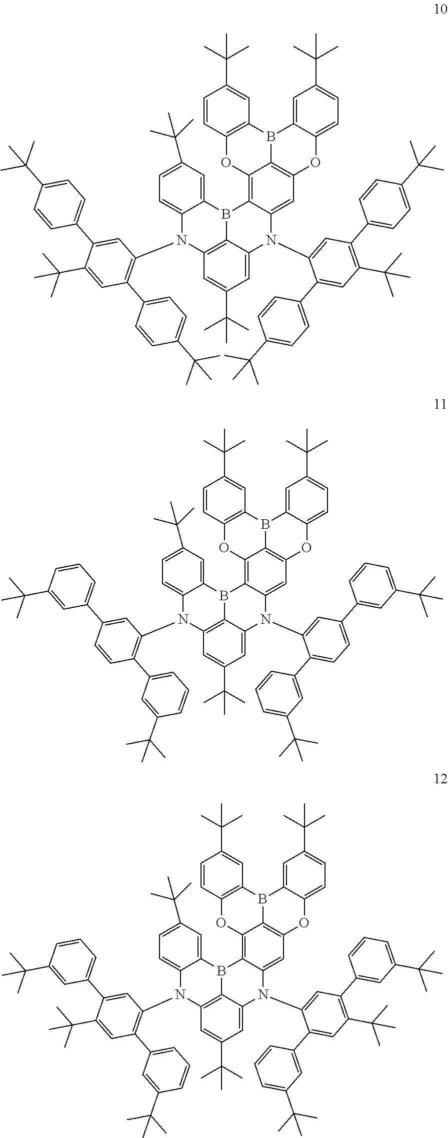

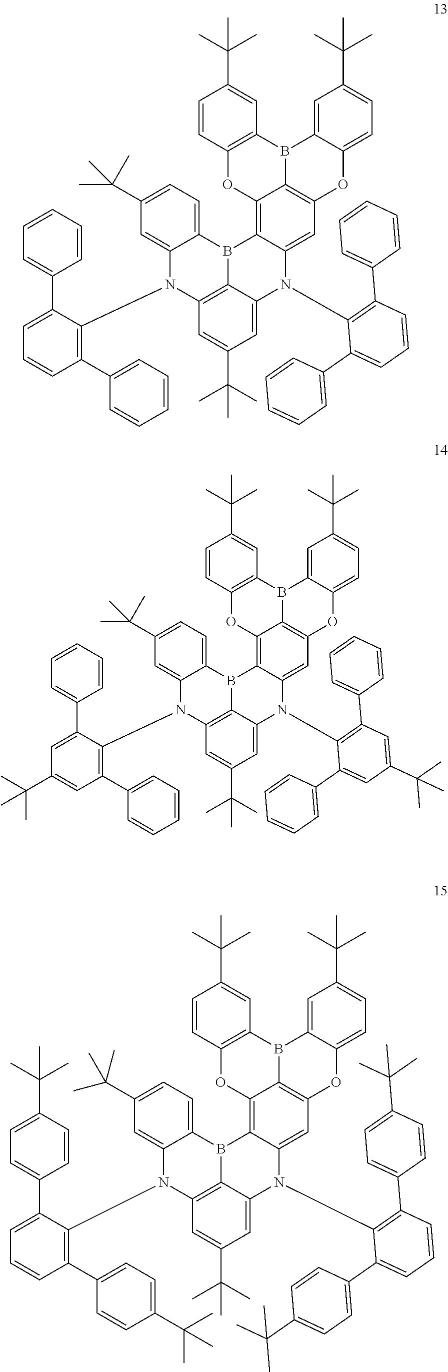

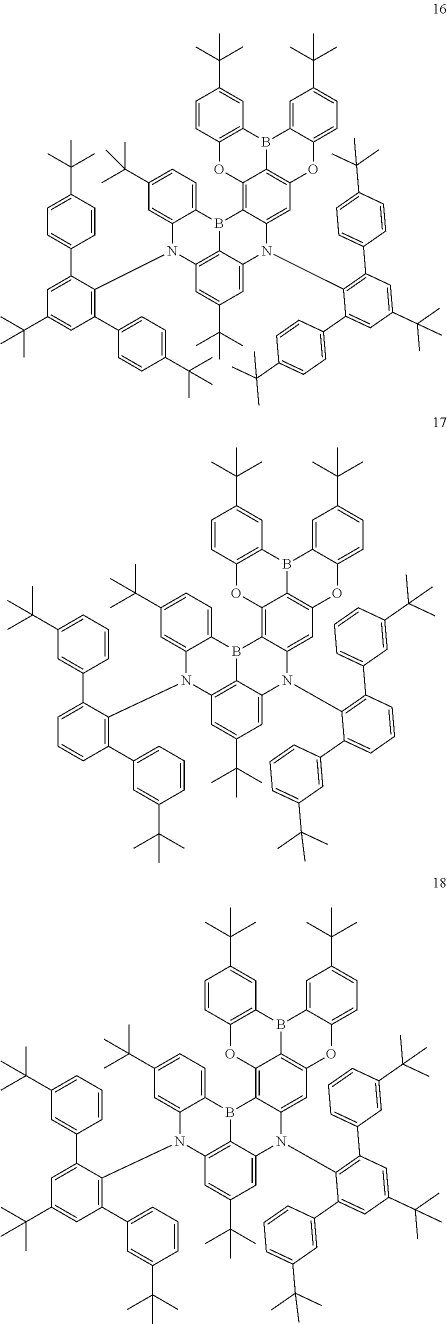

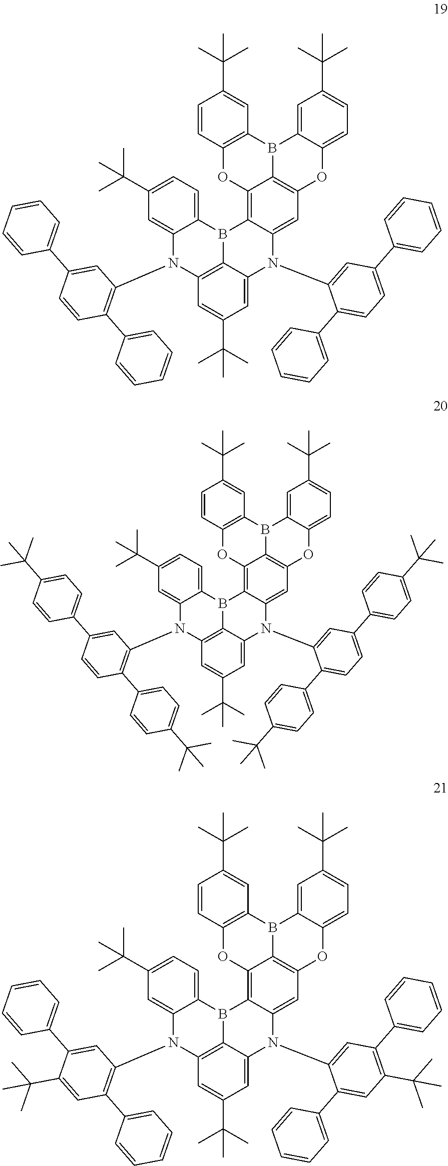

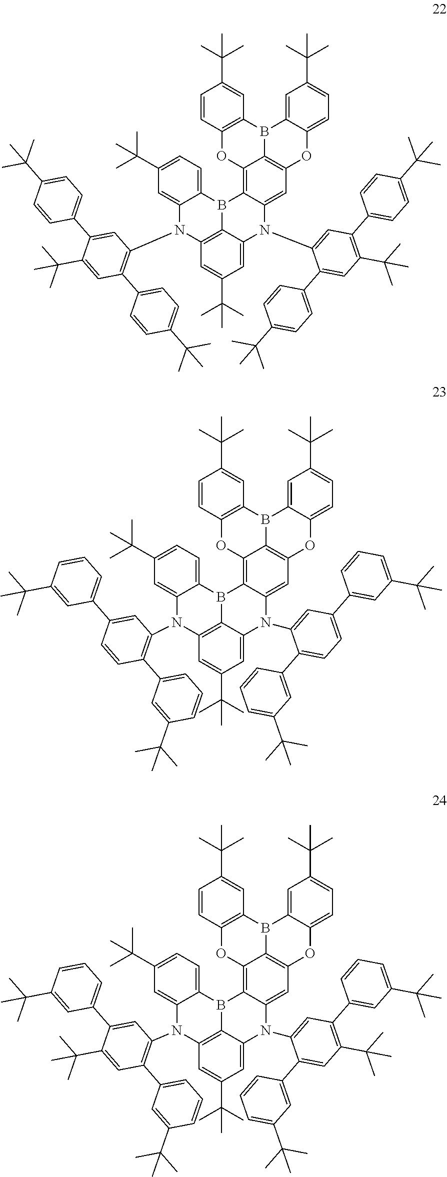

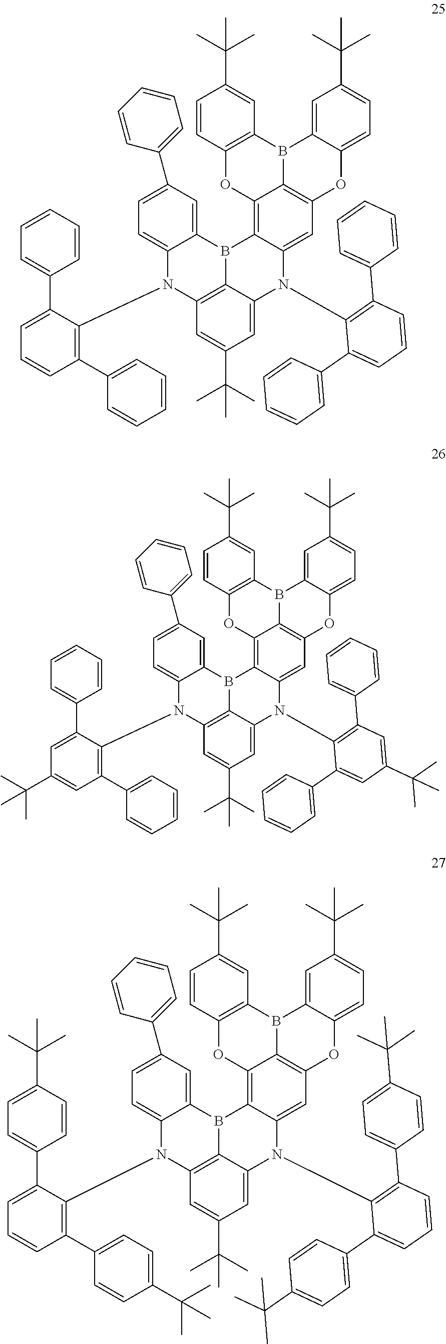

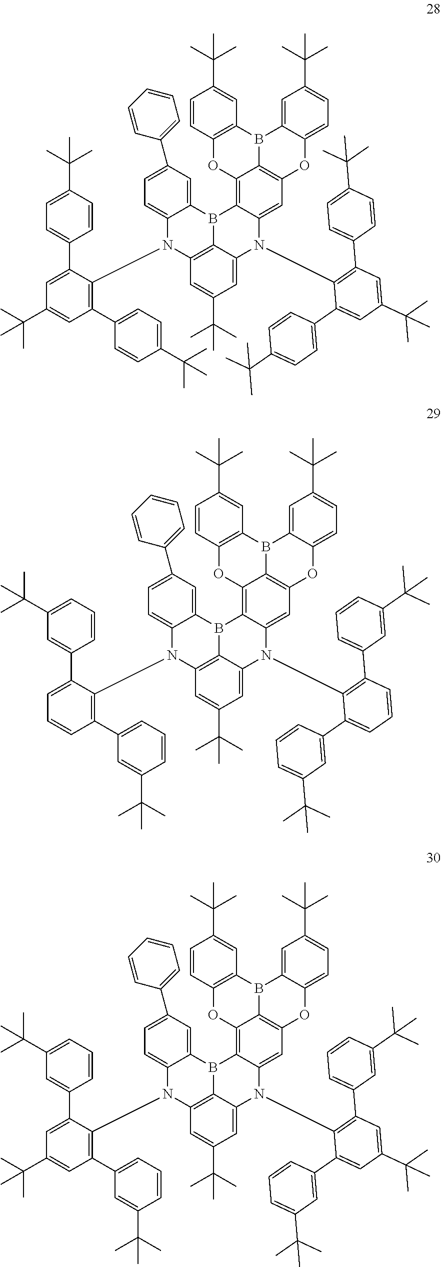

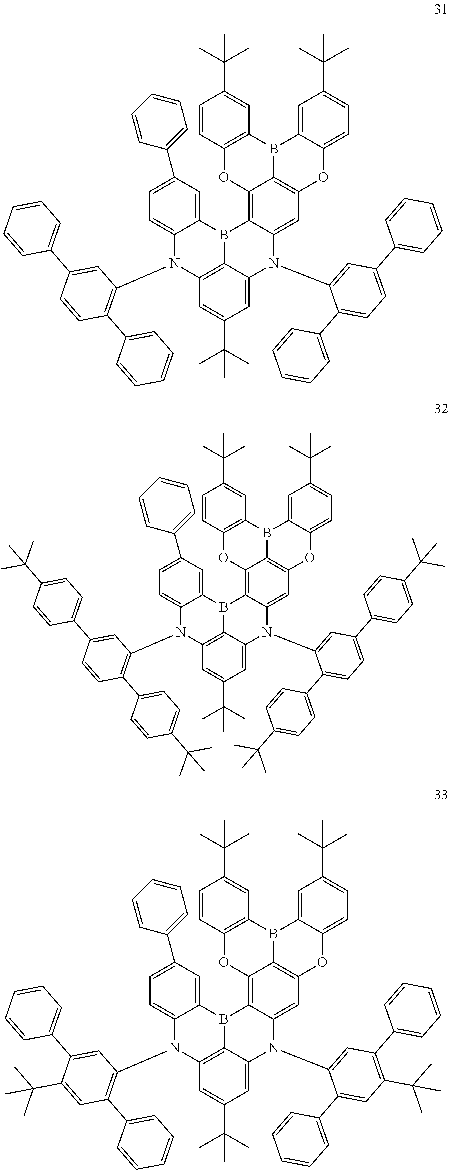

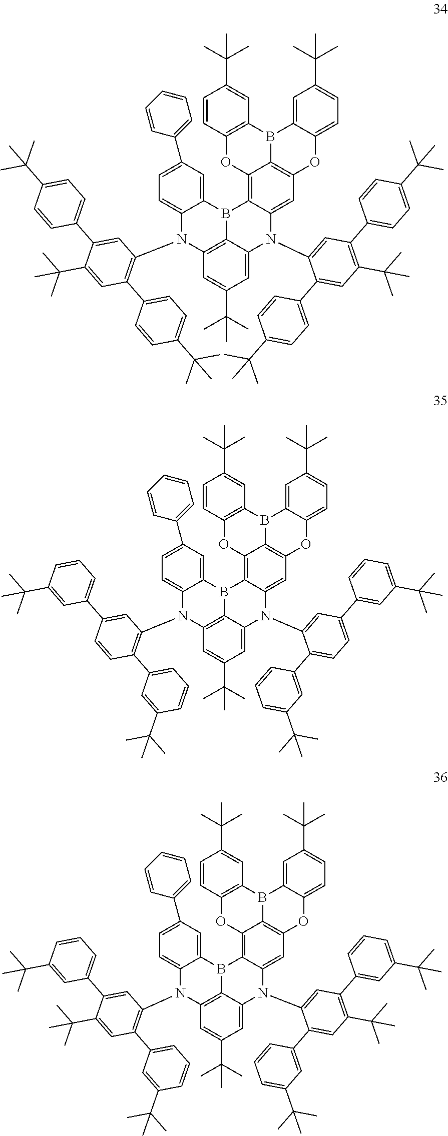

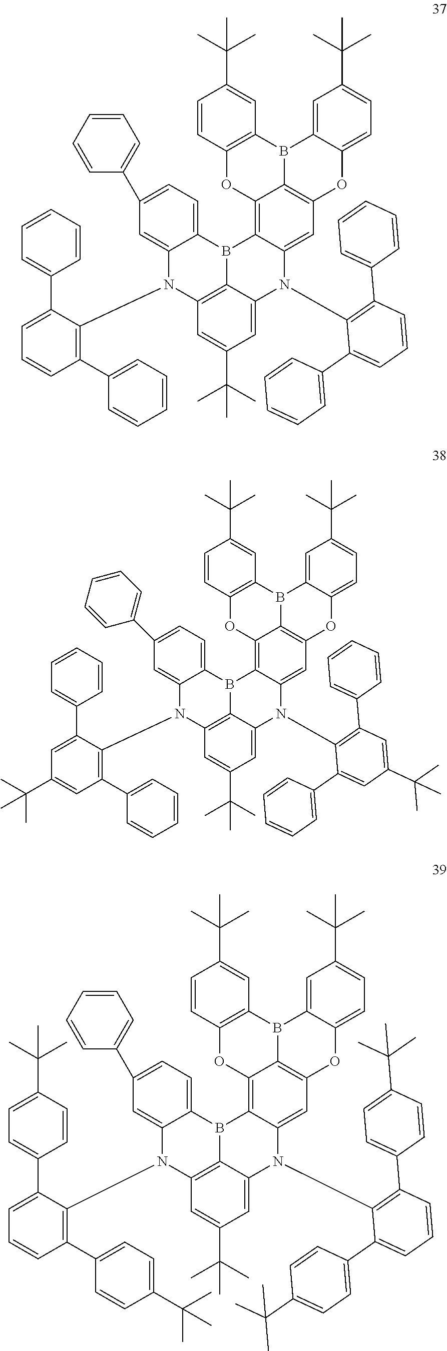

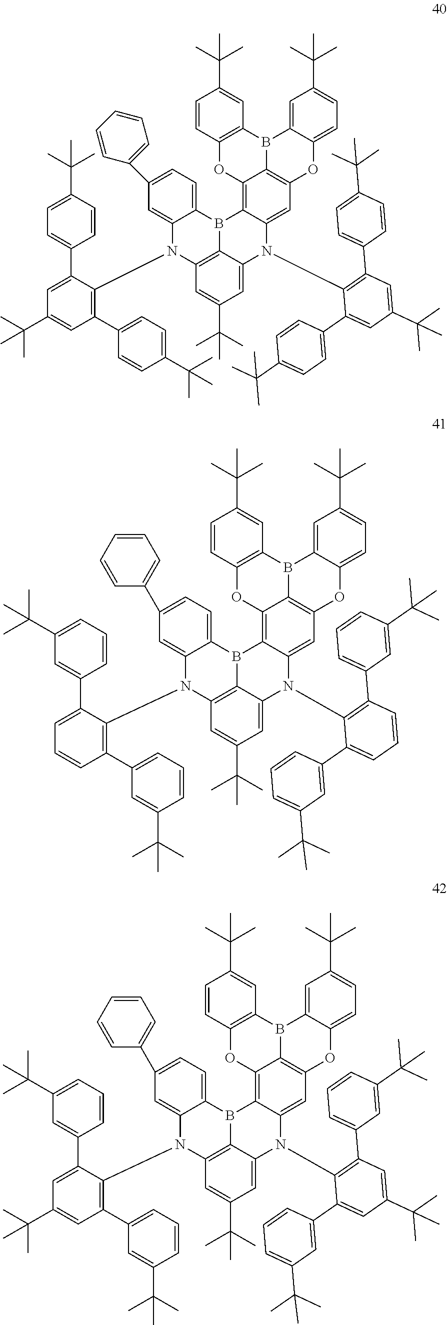

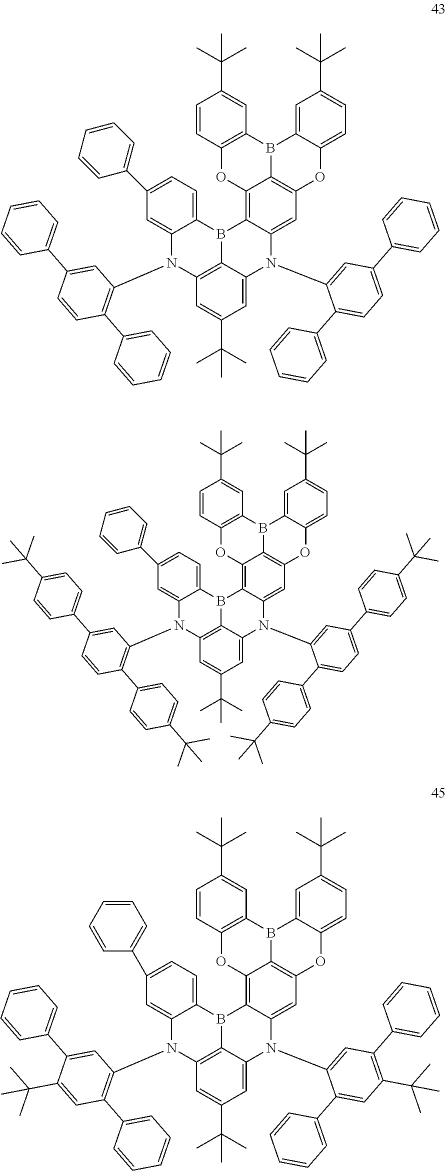

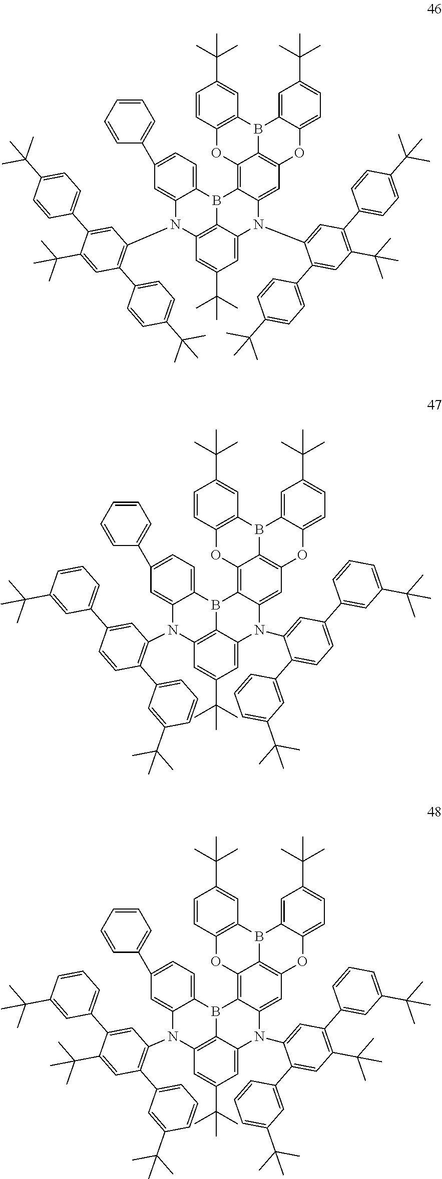

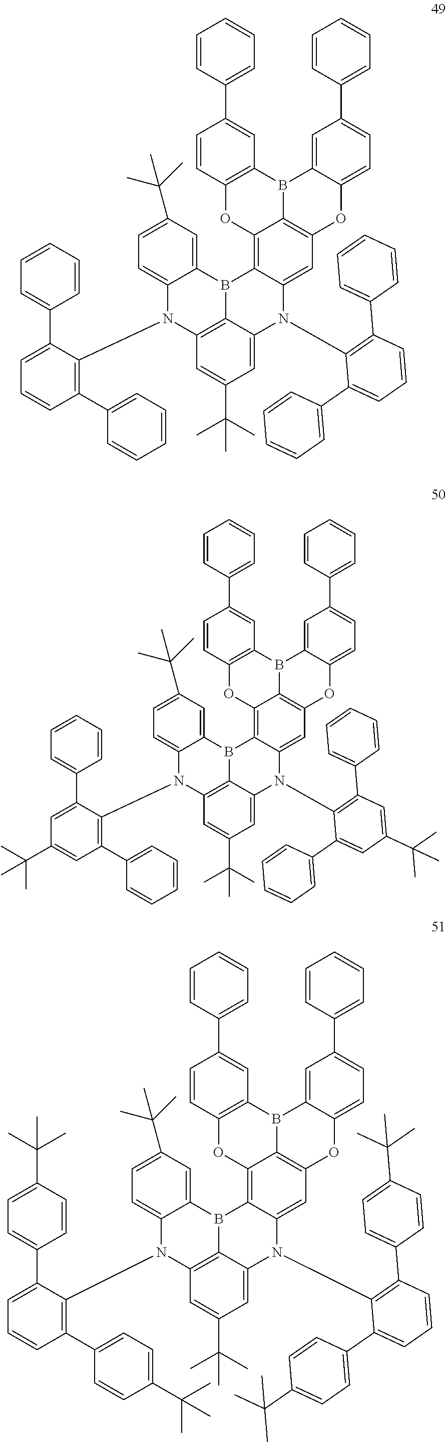

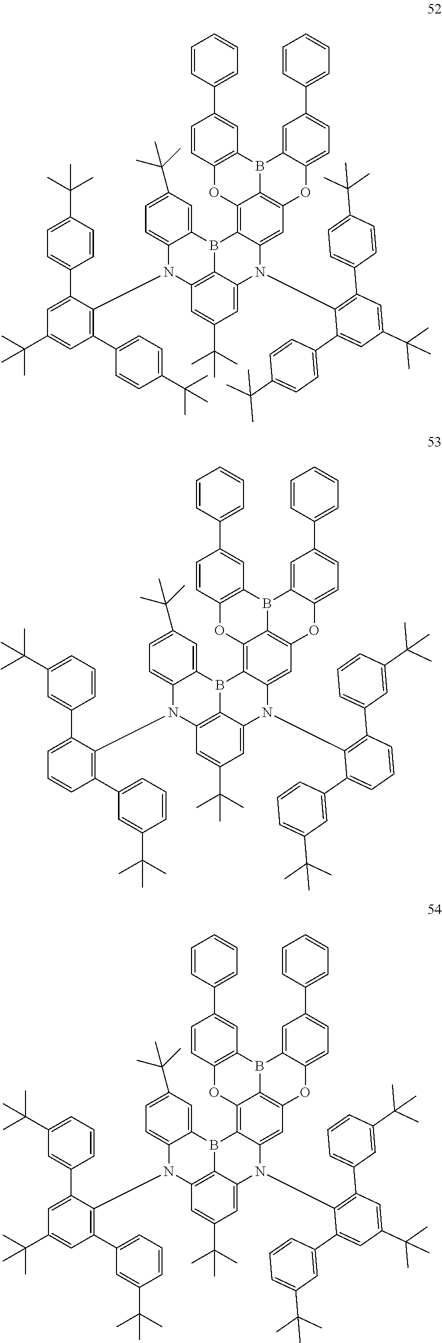

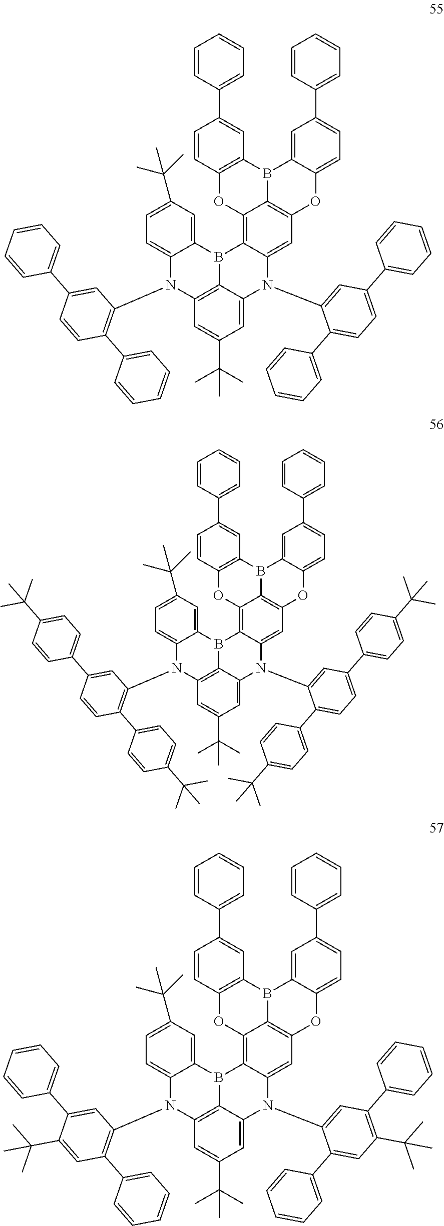

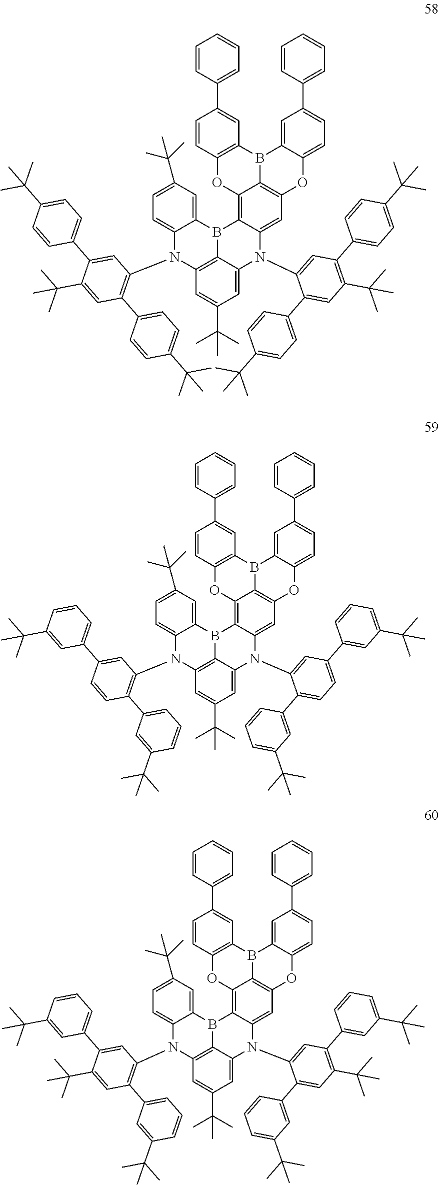

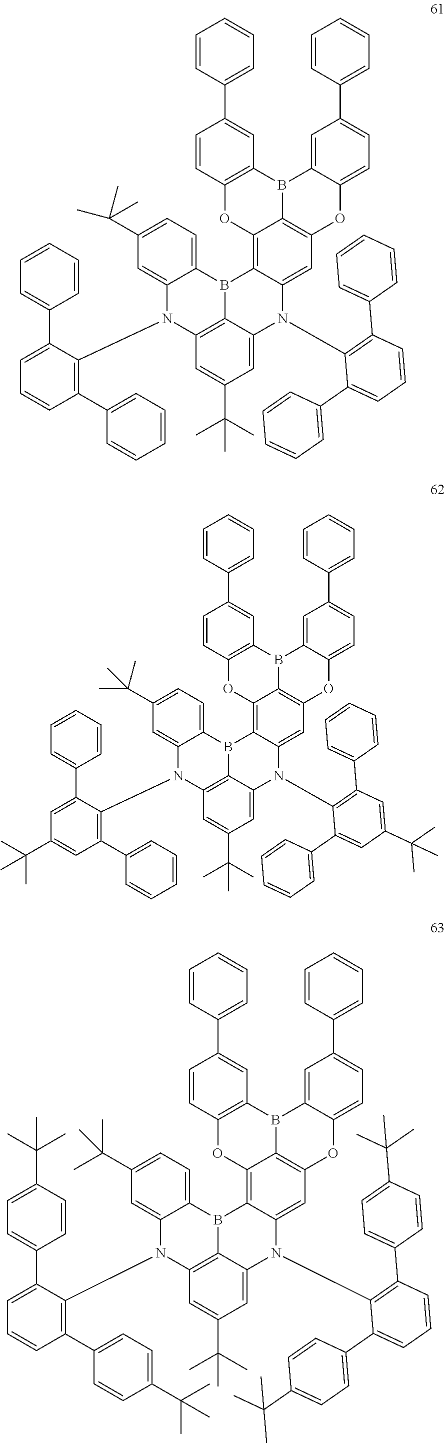

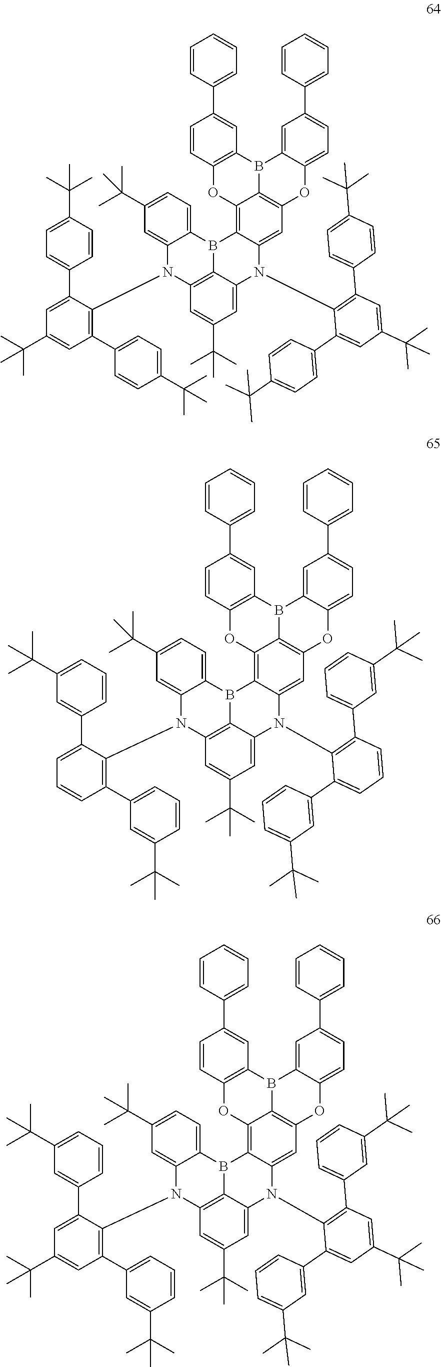

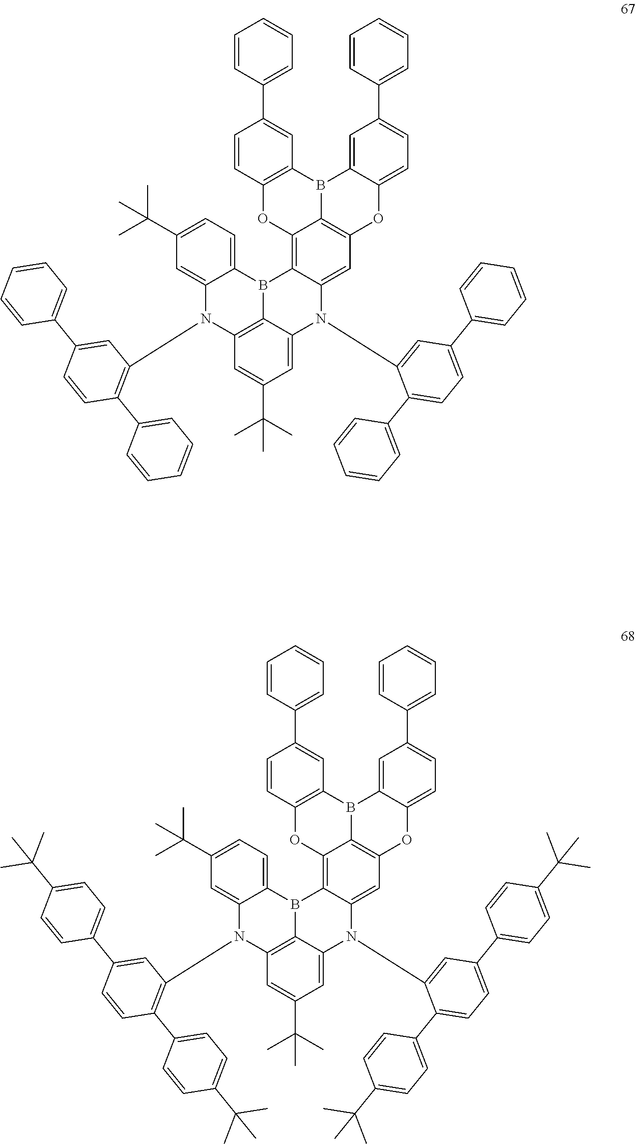 [SMILES: CC(C)(C)c1ccc2c(c1)N(c1cc(-c3ccccc3)ccc1-c1ccccc1)c1cc(C(C)(C)C)cc3c1B2c1c(cc2c4c1Oc1ccc(-c5ccccc5)cc1B4c1cc(-c4ccccc4)ccc1O2)N3c1cc(-c2ccccc2)ccc1-c1ccccc1 ; CC(C)(C)c1ccc(-c2ccc(-c3ccc(C(C)(C)C)cc3)c(N3c4cc(C(C)(C)C)ccc4B4c5c3cc(C(C)(C)C)cc5N(c3cc(-c5ccc(C(C)(C)C)cc5)ccc3-c3ccc(C(C)(C)C)cc3)c3cc5c6c(c34)Oc3ccc(-c4ccccc4)cc3B6c3cc(-c4ccccc4)ccc3O5)c2)cc1]

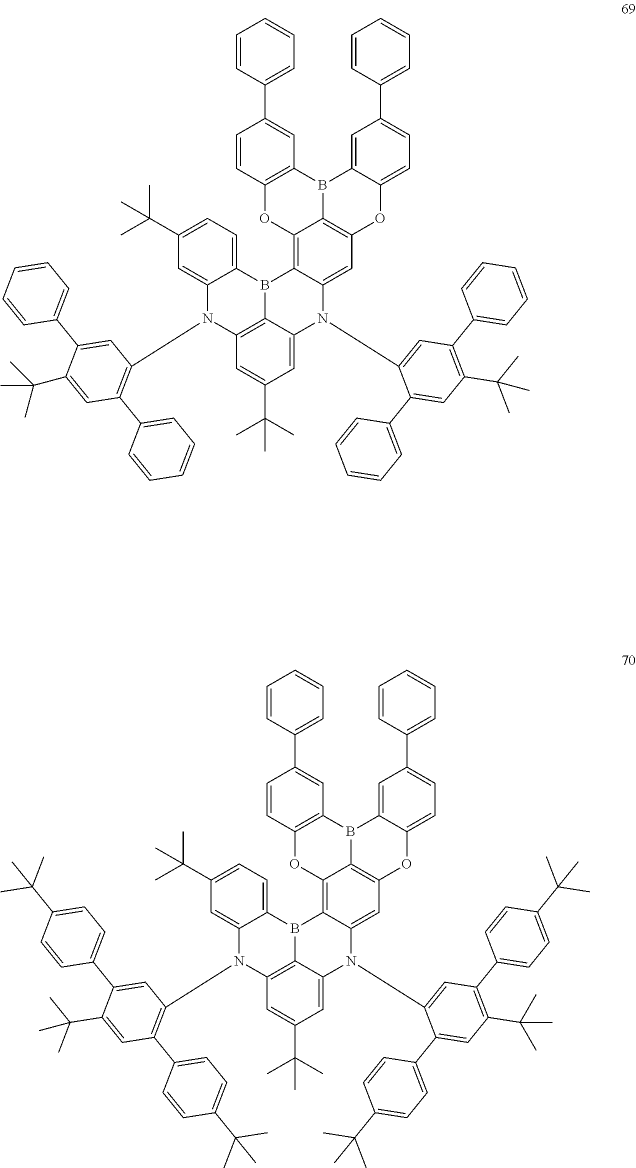

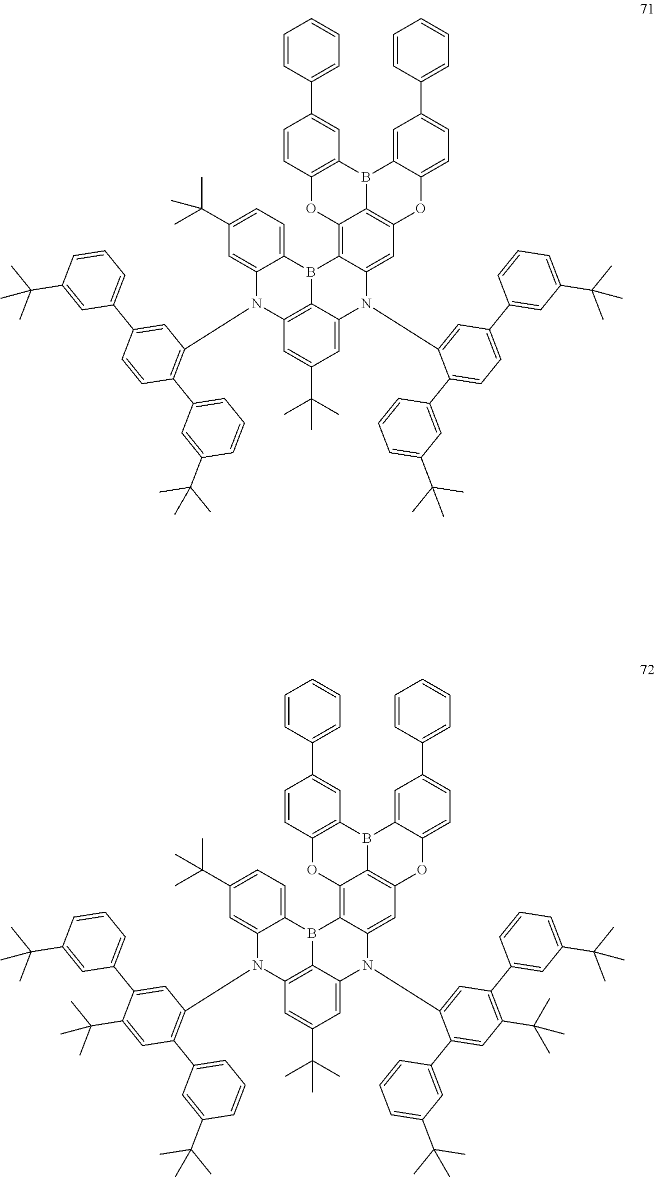

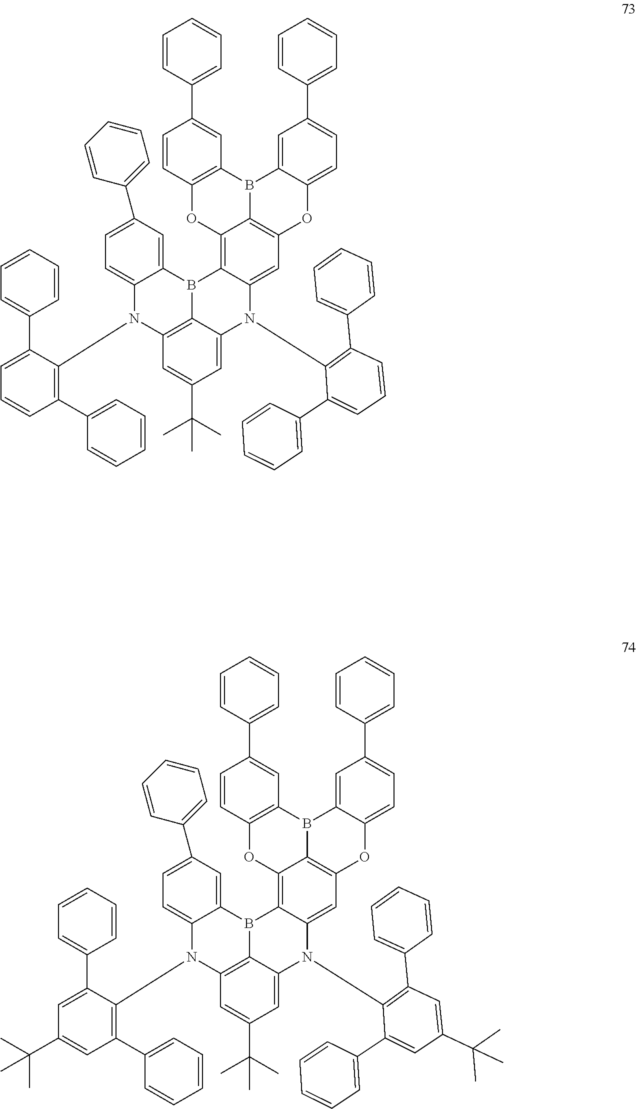 [SMILES: CC(C)(C)c1cc2c3c(c1)N(c1c(-c4ccccc4)cccc1-c1ccccc1)c1cc4c5c(c1B3c1cc(-c3ccccc3)ccc1N2c1c(-c2ccccc2)cccc1-c1ccccc1)Oc1ccc(-c2ccccc2)cc1B5c1cc(-c2ccccc2)ccc1O4 ; CC(C)(C)c1cc(-c2ccccc2)c(N2c3ccc(-c4ccccc4)cc3B3c4c2cc(C(C)(C)C)cc4N(c2c(-c4ccccc4)cc(C(C)(C)C)cc2-c2ccccc2)c2cc4c5c(c23)Oc2ccc(-c3ccccc3)cc2B5c2cc(-c3ccccc3)ccc2O4)c(-c2ccccc2)c1]

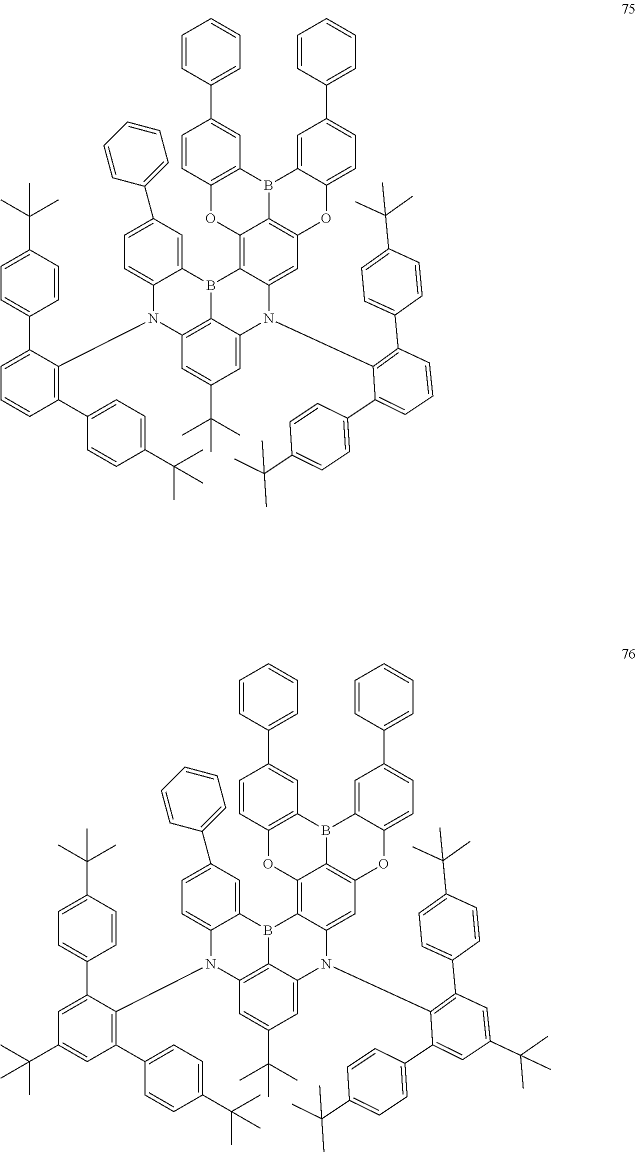 [SMILES: CC(C)(C)c1ccc(-c2cccc(-c3ccc(C(C)(C)C)cc3)c2N2c3ccc(-c4ccccc4)cc3B3c4c2cc(C(C)(C)C)cc4N(c2c(-c4ccc(C(C)(C)C)cc4)cccc2-c2ccc(C(C)(C)C)cc2)c2cc4c5c(c23)Oc2ccc(-c3ccccc3)cc2B5c2cc(-c3ccccc3)ccc2O4)cc1 ; CC(C)(C)c1ccc(-c2cc(C(C)(C)C)cc(-c3ccc(C(C)(C)C)cc3)c2N2c3ccc(-c4ccccc4)cc3B3c4c2cc(C(C)(C)C)cc4N(c2c(-c4ccc(C(C)(C)C)cc4)cc(C(C)(C)C)cc2-c2ccc(C(C)(C)C)cc2)c2cc4c5c(c23)Oc2ccc(-c3ccccc3)cc2B5c2cc(-c3ccccc3)ccc2O4)cc1]

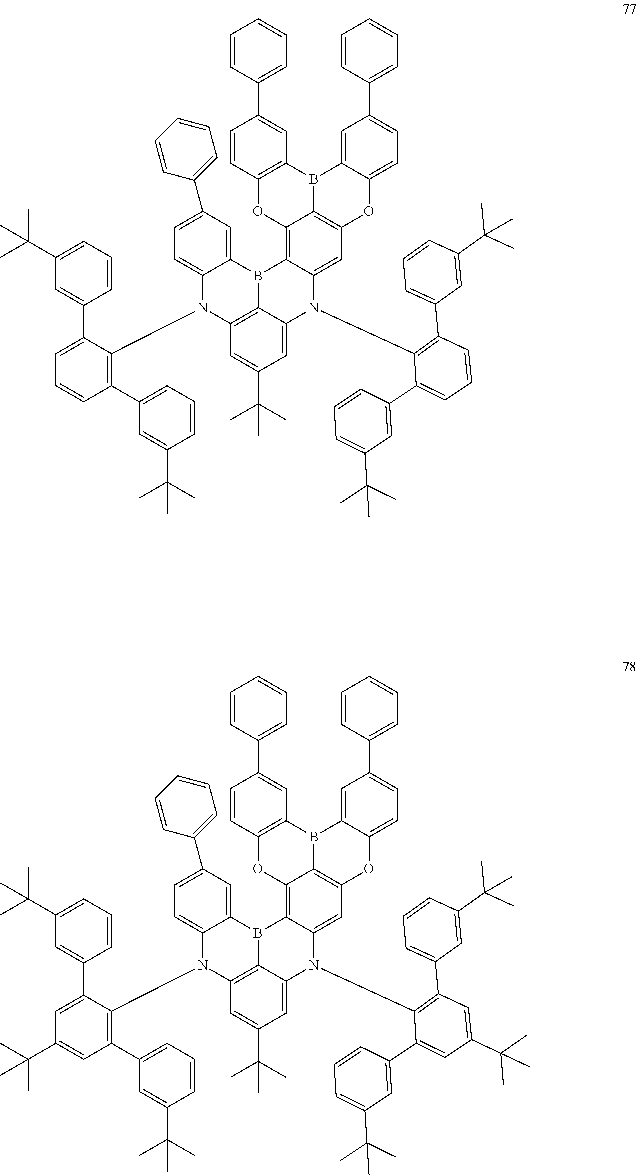

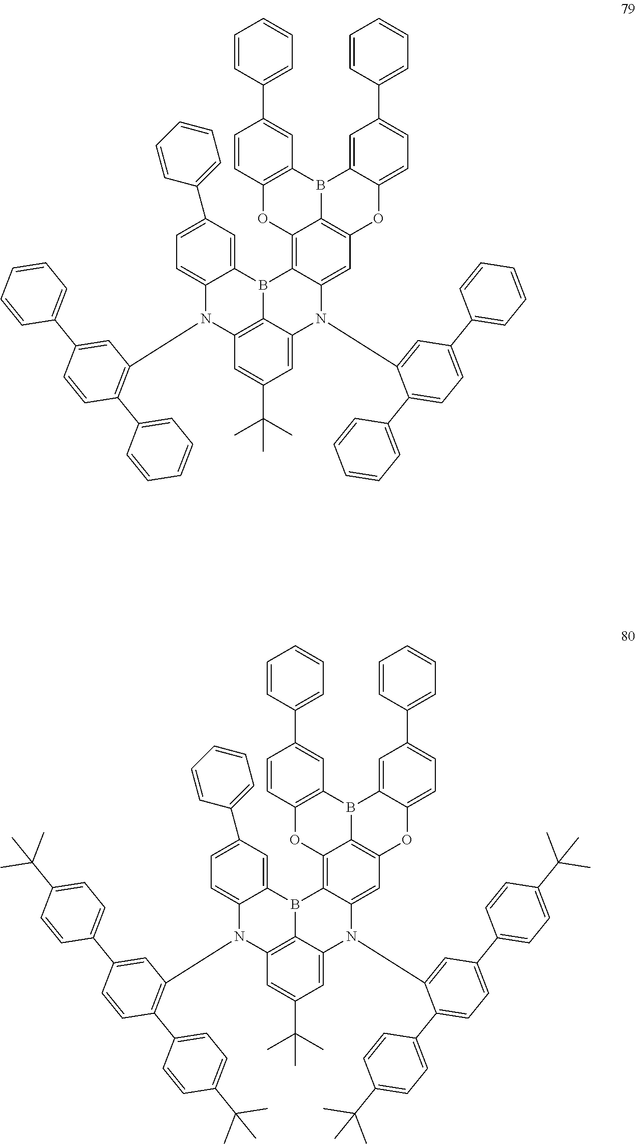 [SMILES: CC(C)(C)c1cc2c3c(c1)N(c1cc(-c4ccccc4)ccc1-c1ccccc1)c1cc4c5c(c1B3c1cc(-c3ccccc3)ccc1N2c1cc(-c2ccccc2)ccc1-c1ccccc1)Oc1ccc(-c2ccccc2)cc1B5c1cc(-c2ccccc2)ccc1O4 ; CC(C)(C)c1ccc(-c2ccc(-c3ccc(C(C)(C)C)cc3)c(N3c4ccc(-c5ccccc5)cc4B4c5c3cc(C(C)(C)C)cc5N(c3cc(-c5ccc(C(C)(C)C)cc5)ccc3-c3ccc(C(C)(C)C)cc3)c3cc5c6c(c34)Oc3ccc(-c4ccccc4)cc3B6c3cc(-c4ccccc4)ccc3O5)c2)cc1]

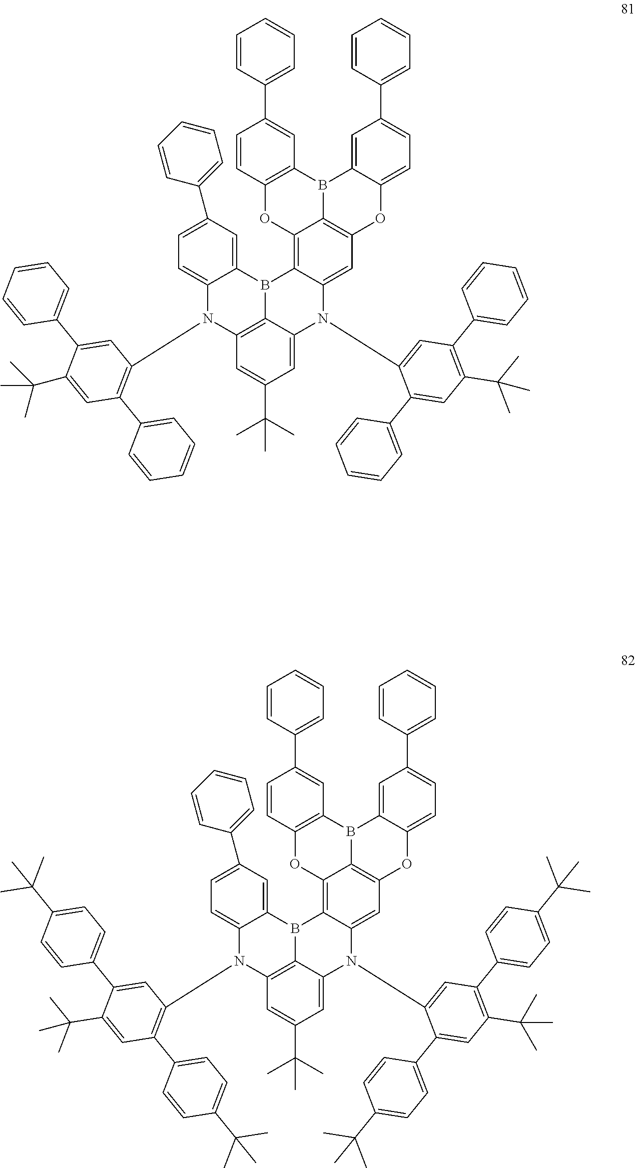

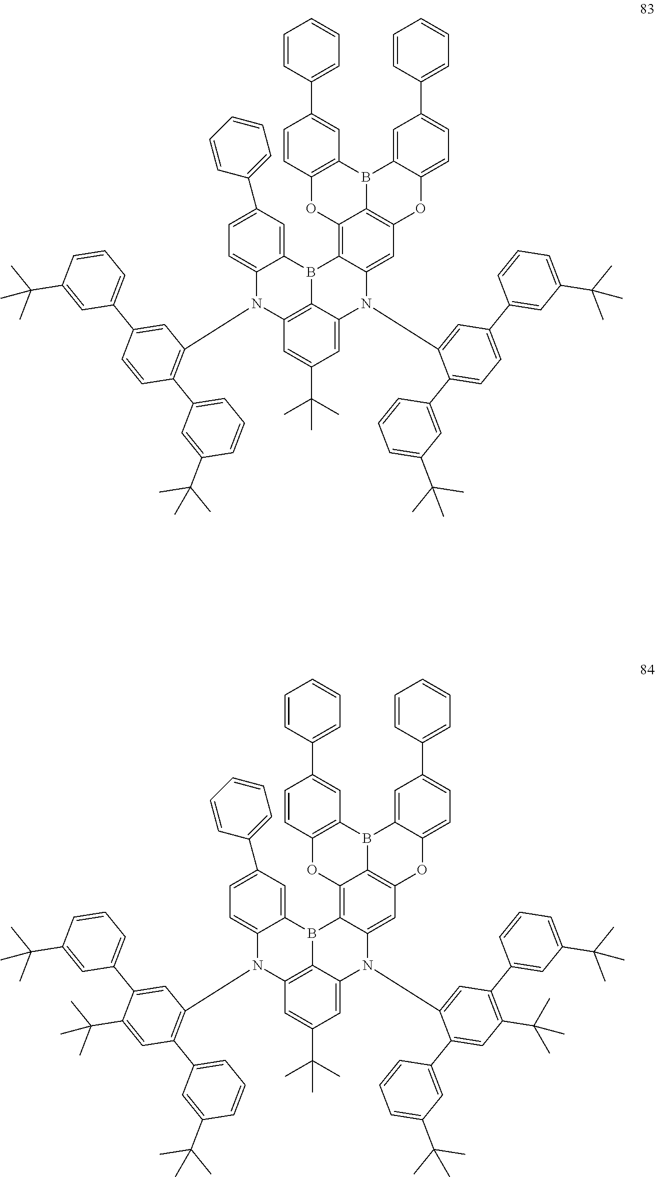

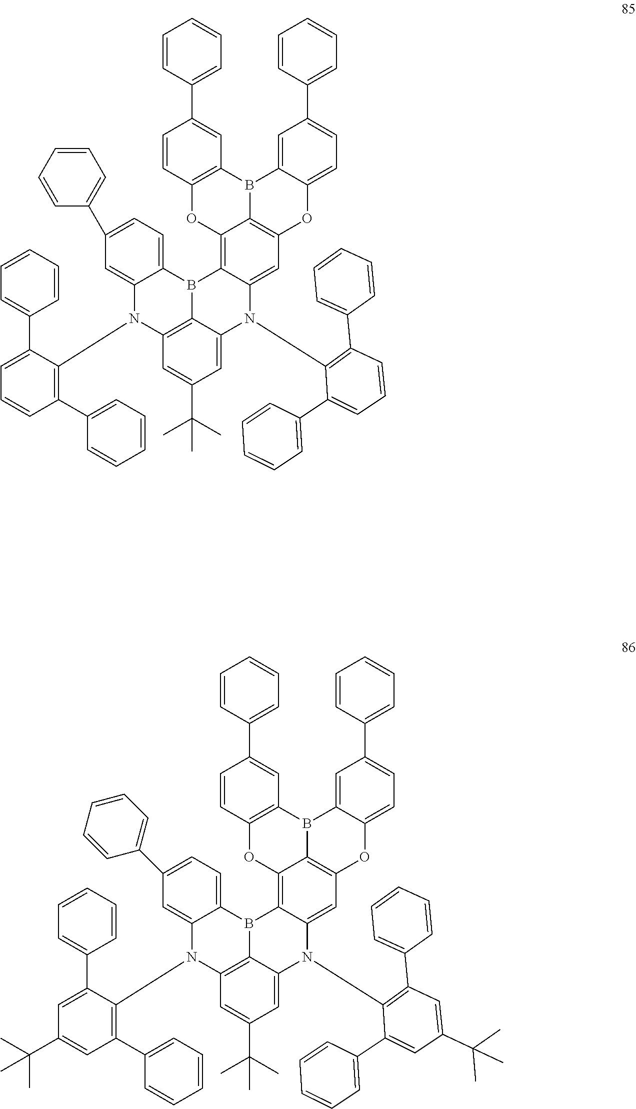 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccc(-c2ccccc2)cc1B5c1cc(-c2ccccc2)ccc1O4 ; CC(C)(C)c1cc(-c2ccccc2)c(N2c3cc(-c4ccccc4)ccc3B3c4c2cc(C(C)(C)C)cc4N(c2c(-c4ccccc4)cc(C(C)(C)C)cc2-c2ccccc2)c2cc4c5c(c23)Oc2ccc(-c3ccccc3)cc2B5c2cc(-c3ccccc3)ccc2O4)c(-c2ccccc2)c1]

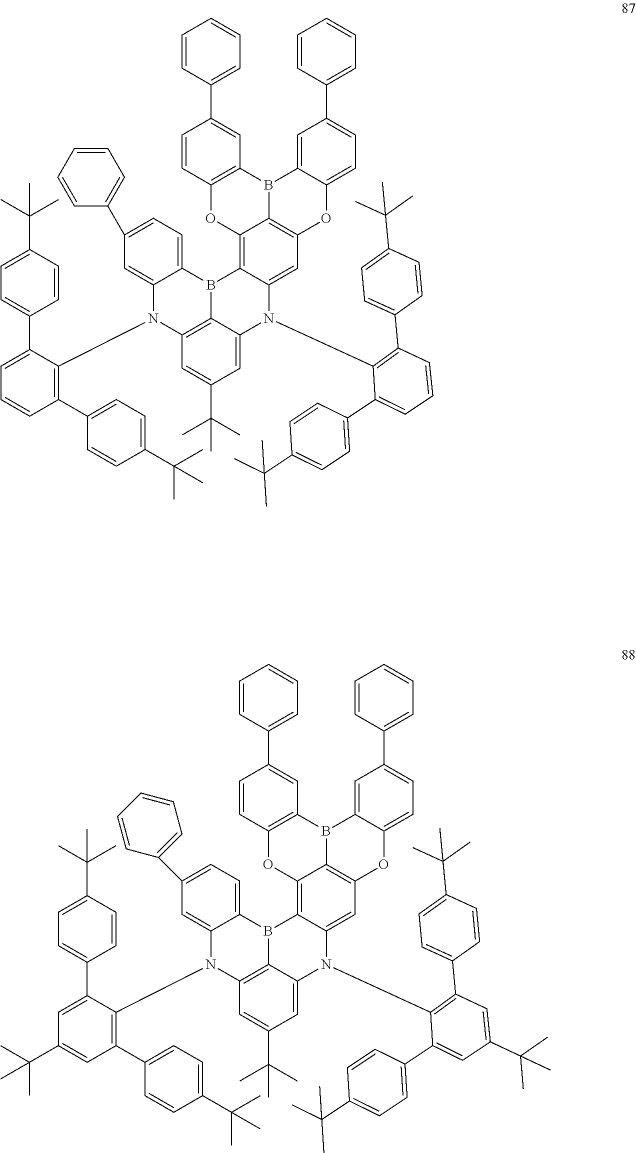 [SMILES: CC(C)(C)c1ccc(-c2cccc(-c3ccc(C(C)(C)C)cc3)c2N2c3cc(-c4ccccc4)ccc3B3c4c2cc(C(C)(C)C)cc4N(c2c(-c4ccc(C(C)(C)C)cc4)cccc2-c2ccc(C(C)(C)C)cc2)c2cc4c5c(c23)Oc2ccc(-c3ccccc3)cc2B5c2cc(-c3ccccc3)ccc2O4)cc1 ; CC(C)(C)c1ccc(-c2cc(C(C)(C)C)cc(-c3ccc(C(C)(C)C)cc3)c2N2c3cc(-c4ccccc4)ccc3B3c4c2cc(C(C)(C)C)cc4N(c2c(-c4ccc(C(C)(C)C)cc4)cc(C(C)(C)C)cc2-c2ccc(C(C)(C)C)cc2)c2cc4c5c(c23)Oc2ccc(-c3ccccc3)cc2B5c2cc(-c3ccccc3)ccc2O4)cc1]

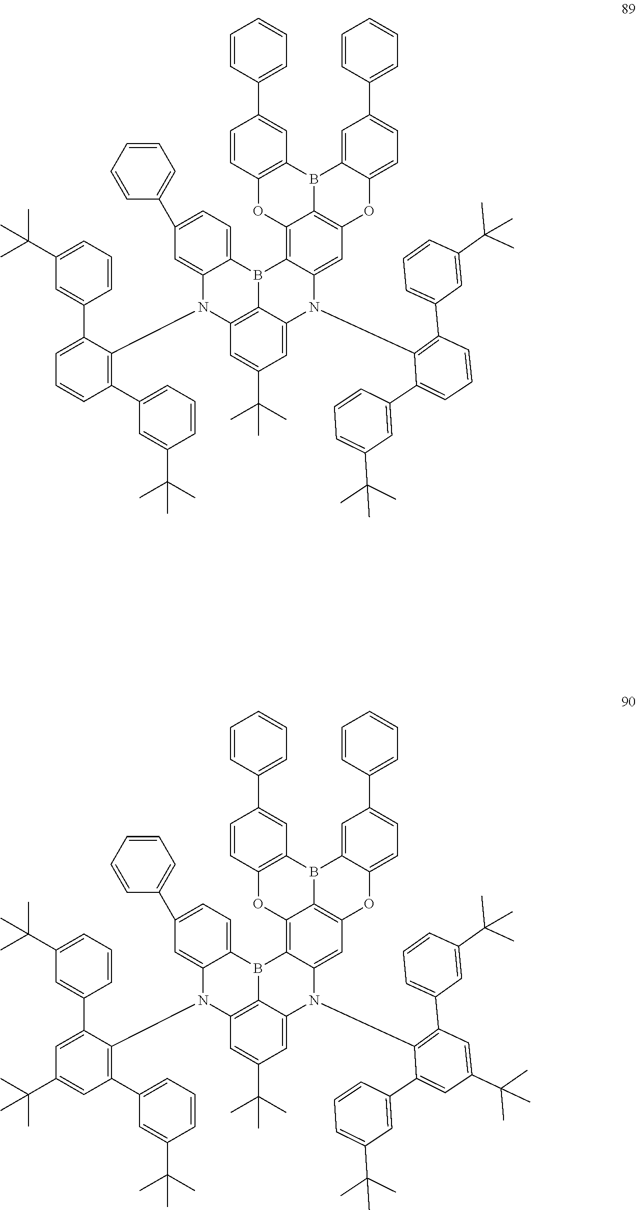

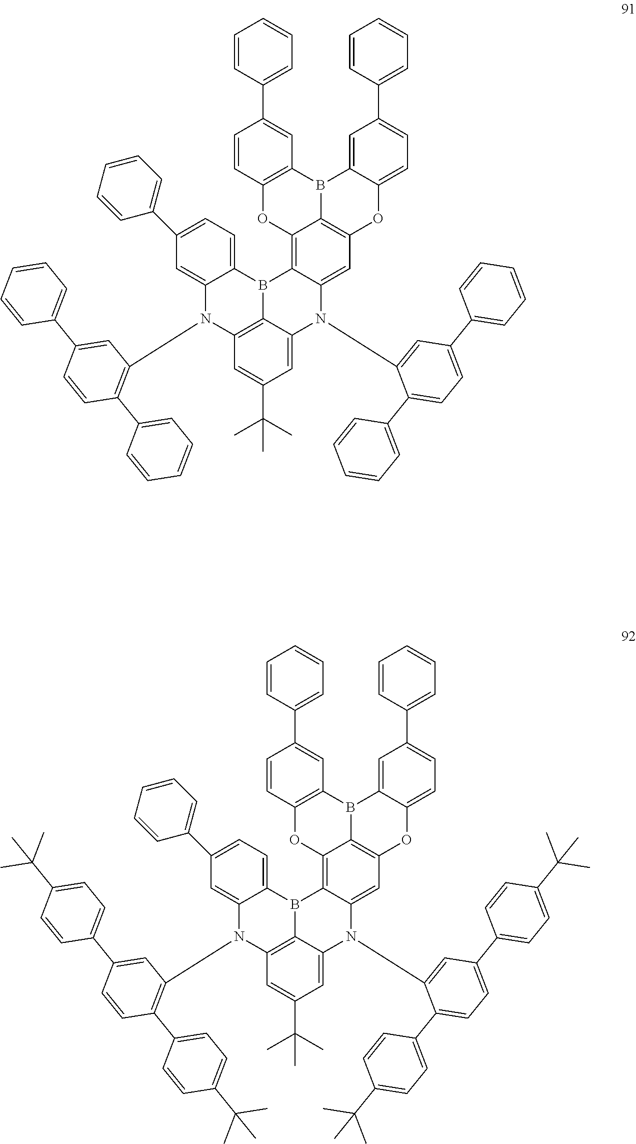 [SMILES: CC(C)(C)c1cc2c3c(c1)N(c1cc(-c4ccccc4)ccc1-c1ccccc1)c1cc4c5c(c1B3c1ccc(-c3ccccc3)cc1N2c1cc(-c2ccccc2)ccc1-c1ccccc1)Oc1ccc(-c2ccccc2)cc1B5c1cc(-c2ccccc2)ccc1O4 ; CC(C)(C)c1ccc(-c2ccc(-c3ccc(C(C)(C)C)cc3)c(N3c4cc(-c5ccccc5)ccc4B4c5c3cc(C(C)(C)C)cc5N(c3cc(-c5ccc(C(C)(C)C)cc5)ccc3-c3ccc(C(C)(C)C)cc3)c3cc5c6c(c34)Oc3ccc(-c4ccccc4)cc3B6c3cc(-c4ccccc4)ccc3O5)c2)cc1]

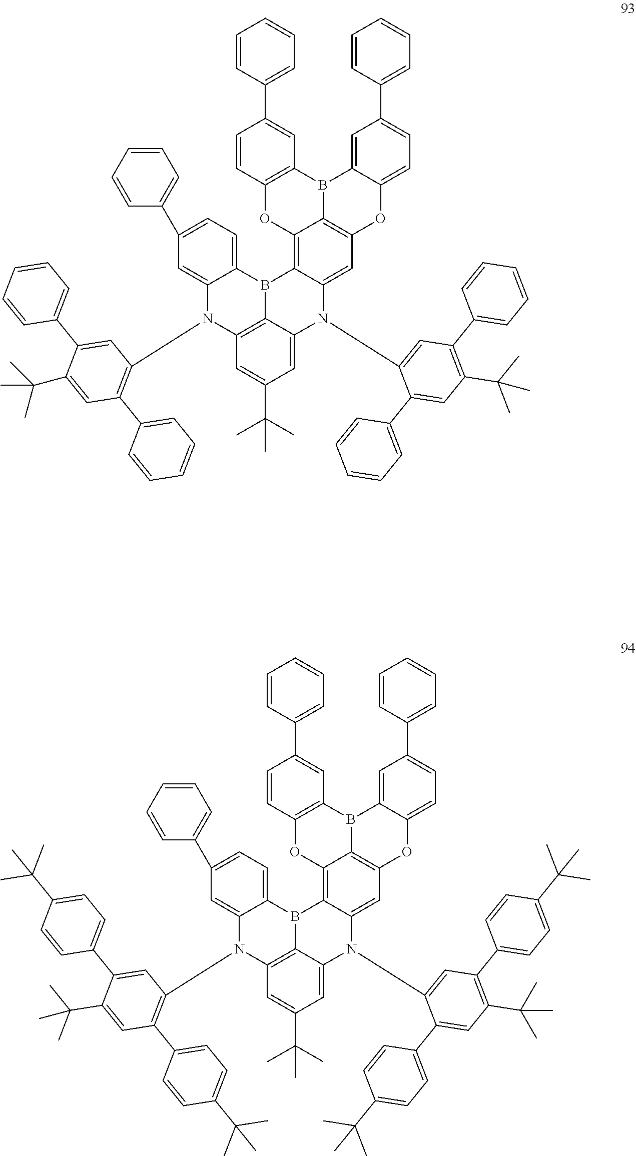

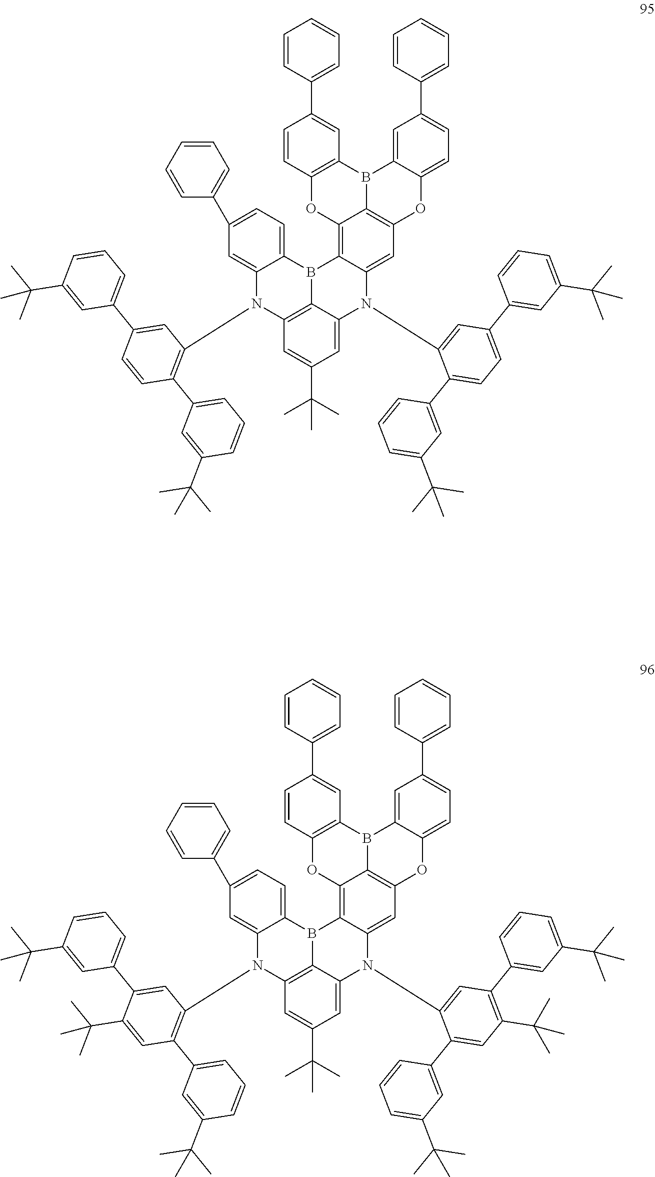

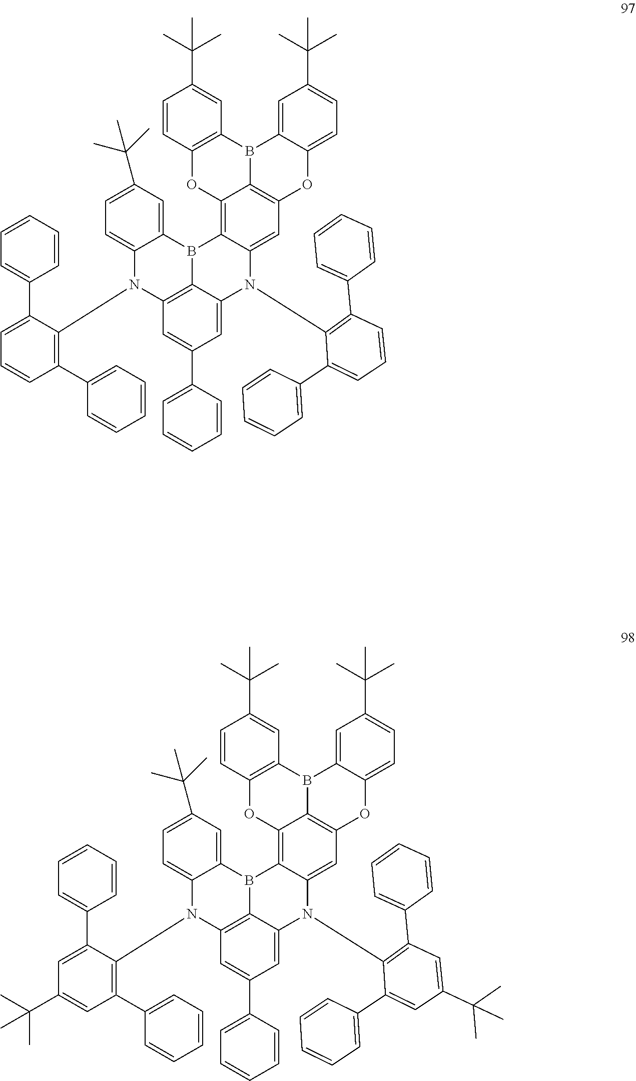 [SMILES: CC(C)(C)c1ccc2c(c1)B1c3cc(C(C)(C)C)ccc3Oc3c1c(cc1c3B3c4cc(C(C)(C)C)ccc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc2c(c1)B1c3cc(C(C)(C)C)ccc3Oc3c1c(cc1c3B3c4cc(C(C)(C)C)ccc4N(c4c(-c5ccccc5)cc(C(C)(C)C)cc4-c4ccccc4)c4cc(-c5ccccc5)cc(c43)N1c1c(-c3ccccc3)cc(C(C)(C)C)cc1-c1ccccc1)O2]

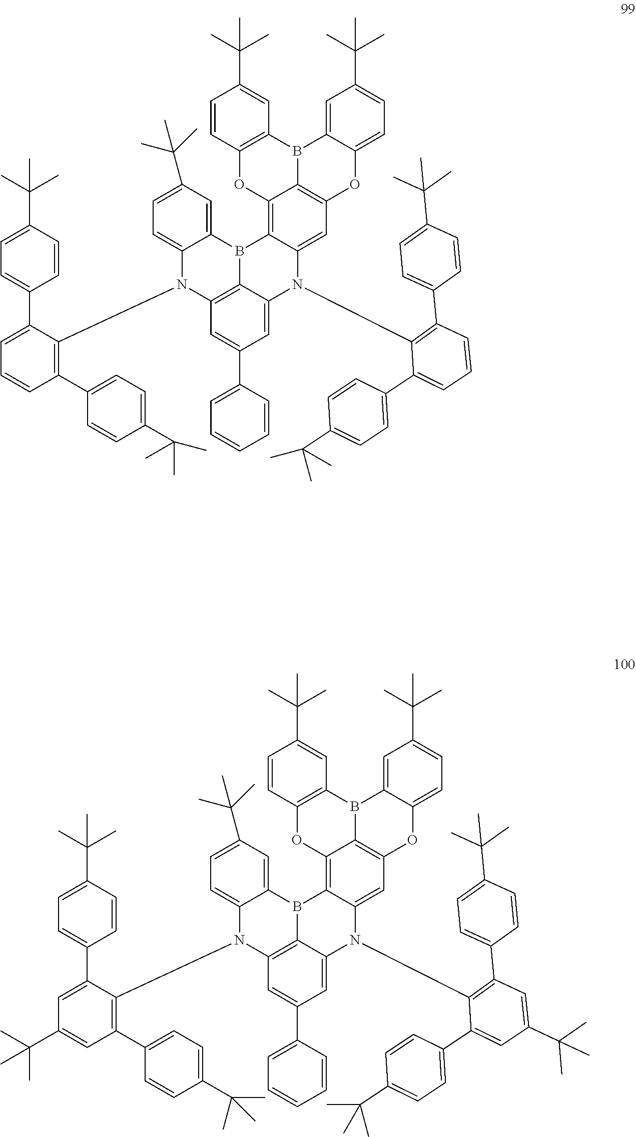 [SMILES: CC(C)(C)c1ccc(-c2cccc(-c3ccc(C(C)(C)C)cc3)c2N2c3ccc(C(C)(C)C)cc3B3c4c2cc(-c2ccccc2)cc4N(c2c(-c4ccc(C(C)(C)C)cc4)cccc2-c2ccc(C(C)(C)C)cc2)c2cc4c5c(c23)Oc2ccc(C(C)(C)C)cc2B5c2cc(C(C)(C)C)ccc2O4)cc1 ; CC(C)(C)c1ccc(-c2cc(C(C)(C)C)cc(-c3ccc(C(C)(C)C)cc3)c2N2c3ccc(C(C)(C)C)cc3B3c4c2cc(-c2ccccc2)cc4N(c2c(-c4ccc(C(C)(C)C)cc4)cc(C(C)(C)C)cc2-c2ccc(C(C)(C)C)cc2)c2cc4c5c(c23)Oc2ccc(C(C)(C)C)cc2B5c2cc(C(C)(C)C)ccc2O4)cc1]

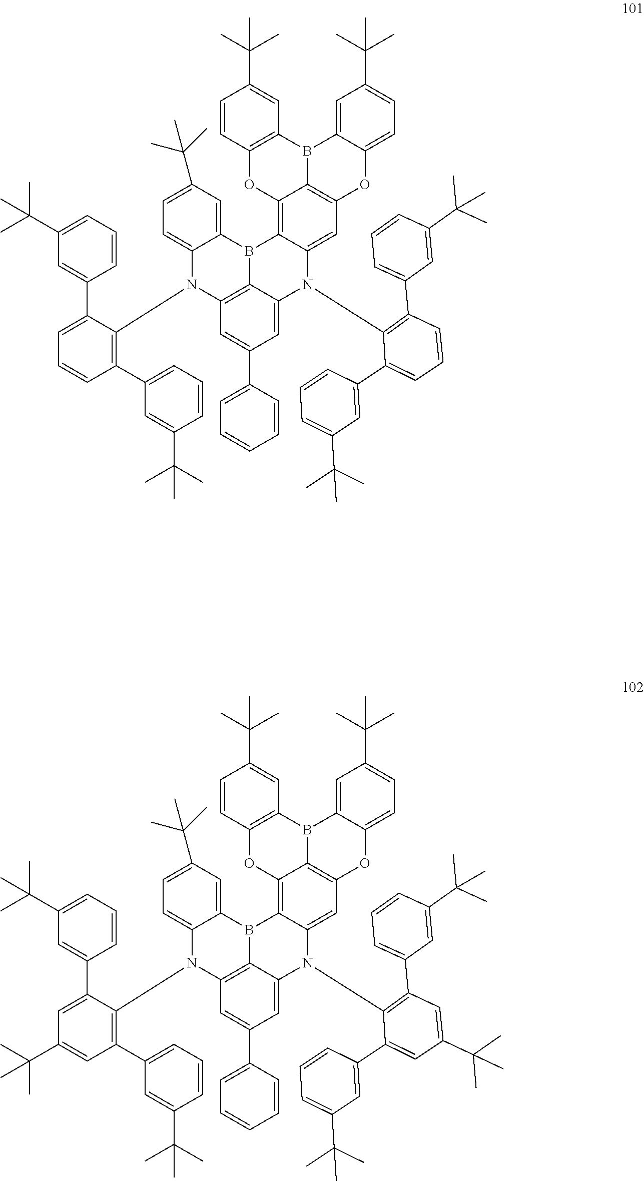

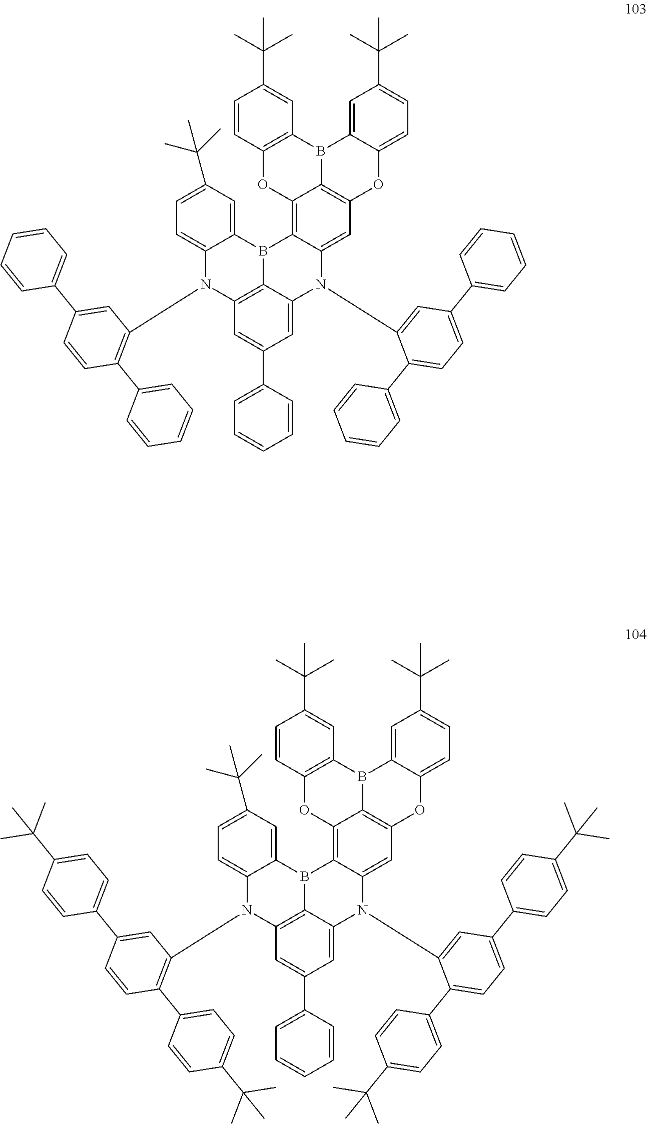 [SMILES: CC(C)(C)c1ccc2c(c1)B1c3cc(C(C)(C)C)ccc3Oc3c1c(cc1c3B3c4cc(C(C)(C)C)ccc4N(c4cc(-c5ccccc5)ccc4-c4ccccc4)c4cc(-c5ccccc5)cc(c43)N1c1cc(-c3ccccc3)ccc1-c1ccccc1)O2 ; CC(C)(C)c1ccc(-c2ccc(-c3ccc(C(C)(C)C)cc3)c(N3c4ccc(C(C)(C)C)cc4B4c5c3cc(-c3ccccc3)cc5N(c3cc(-c5ccc(C(C)(C)C)cc5)ccc3-c3ccc(C(C)(C)C)cc3)c3cc5c6c(c34)Oc3ccc(C(C)(C)C)cc3B6c3cc(C(C)(C)C)ccc3O5)c2)cc1]

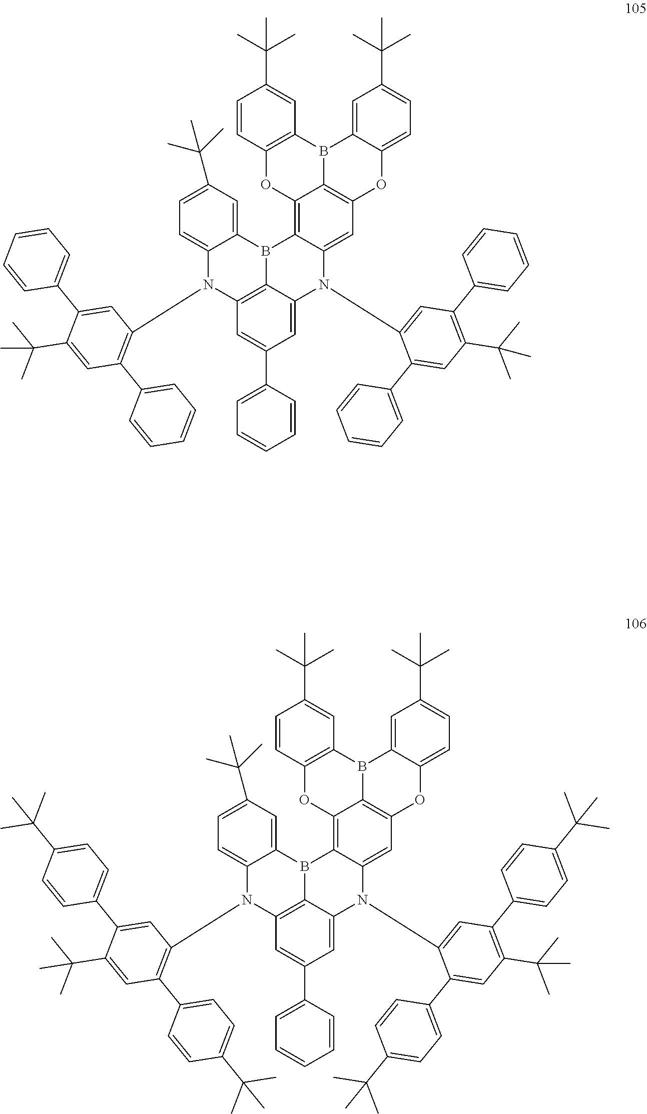

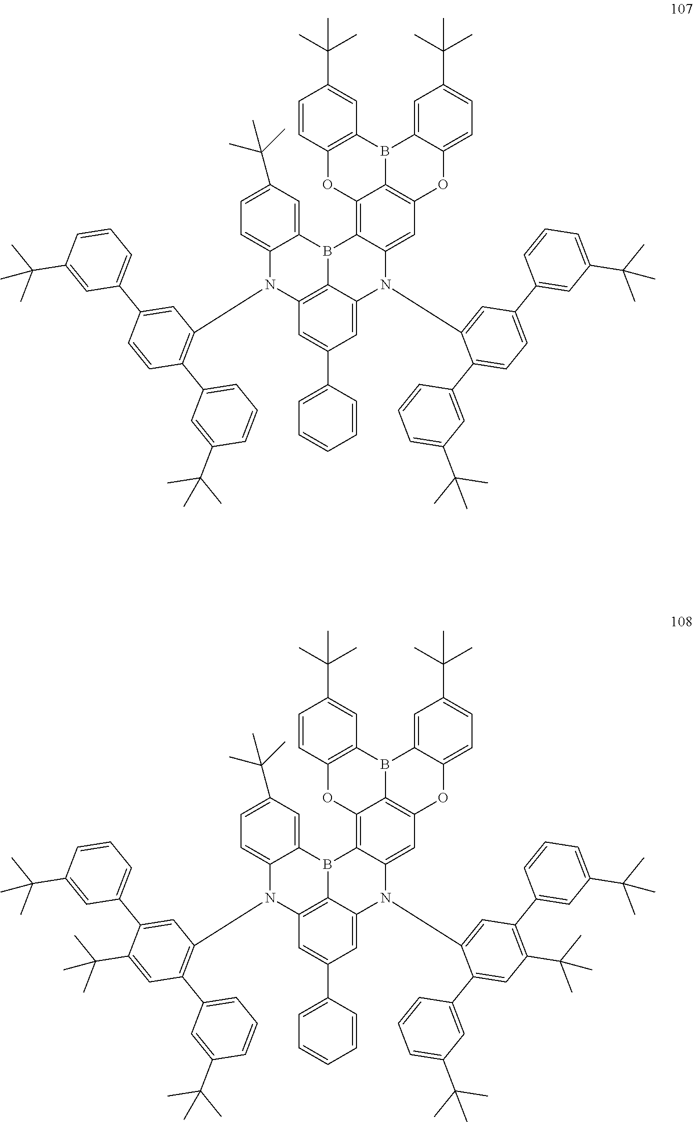

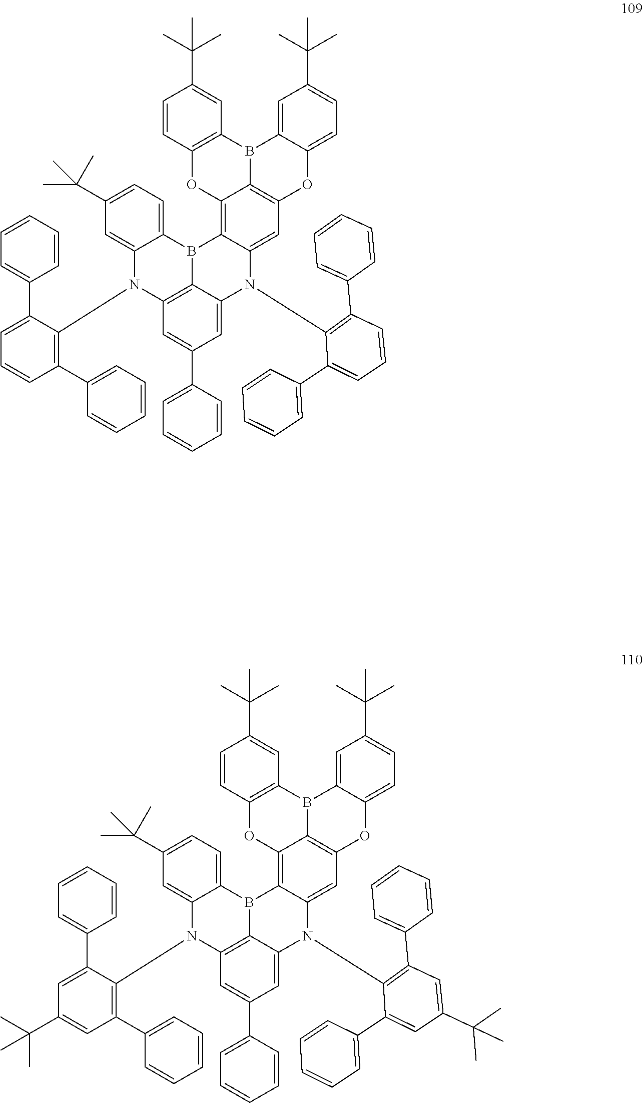 [SMILES: CC(C)(C)c1ccc2c(c1)B1c3cc(C(C)(C)C)ccc3Oc3c1c(cc1c3B3c4ccc(C(C)(C)C)cc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc2c(c1)B1c3cc(C(C)(C)C)ccc3Oc3c1c(cc1c3B3c4ccc(C(C)(C)C)cc4N(c4c(-c5ccccc5)cc(C(C)(C)C)cc4-c4ccccc4)c4cc(-c5ccccc5)cc(c43)N1c1c(-c3ccccc3)cc(C(C)(C)C)cc1-c1ccccc1)O2]

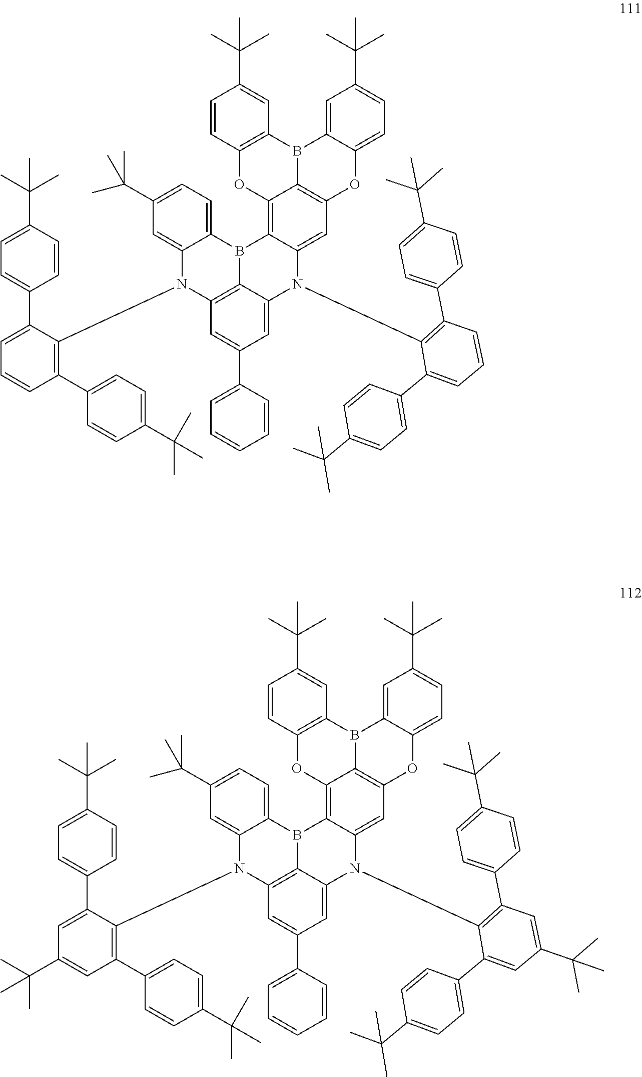 [SMILES: CC(C)(C)c1ccc(-c2cccc(-c3ccc(C(C)(C)C)cc3)c2N2c3cc(C(C)(C)C)ccc3B3c4c2cc(-c2ccccc2)cc4N(c2c(-c4ccc(C(C)(C)C)cc4)cccc2-c2ccc(C(C)(C)C)cc2)c2cc4c5c(c23)Oc2ccc(C(C)(C)C)cc2B5c2cc(C(C)(C)C)ccc2O4)cc1 ; CC(C)(C)c1ccc(-c2cc(C(C)(C)C)cc(-c3ccc(C(C)(C)C)cc3)c2N2c3cc(C(C)(C)C)ccc3B3c4c2cc(-c2ccccc2)cc4N(c2c(-c4ccc(C(C)(C)C)cc4)cc(C(C)(C)C)cc2-c2ccc(C(C)(C)C)cc2)c2cc4c5c(c23)Oc2ccc(C(C)(C)C)cc2B5c2cc(C(C)(C)C)ccc2O4)cc1]

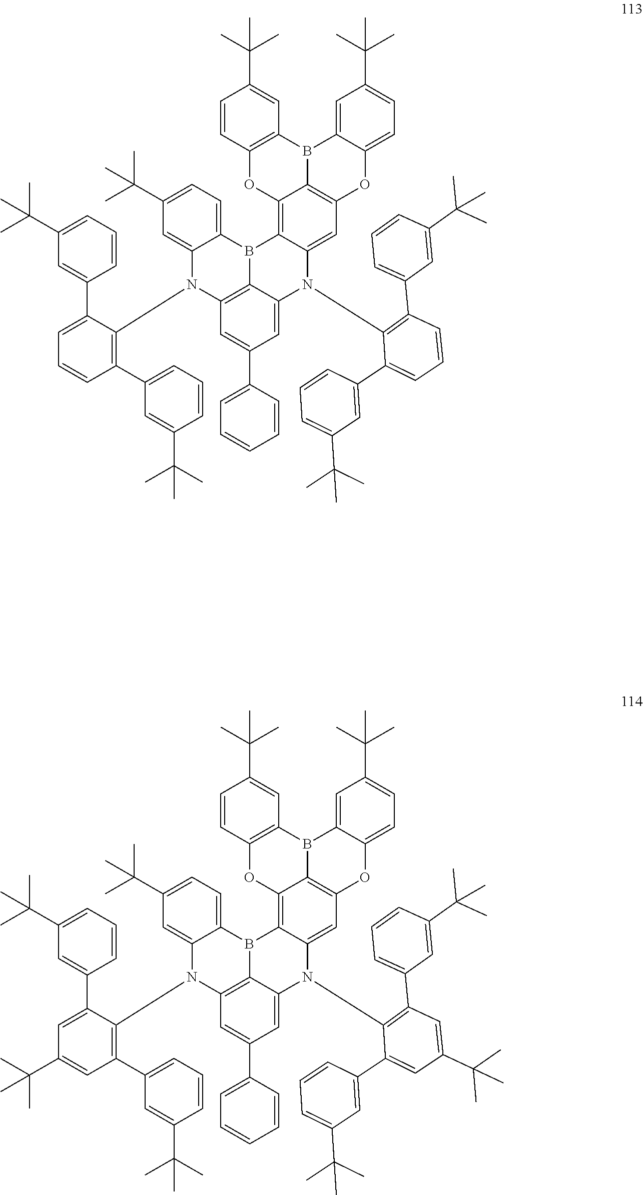

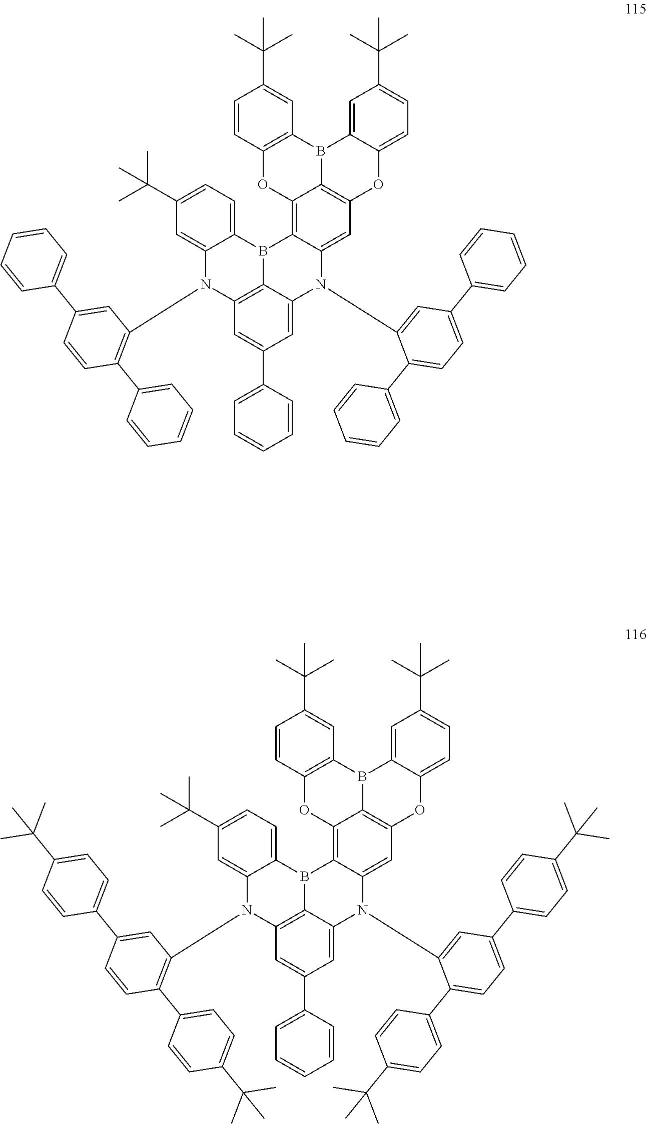 [SMILES: CC(C)(C)c1ccc2c(c1)B1c3cc(C(C)(C)C)ccc3Oc3c1c(cc1c3B3c4ccc(C(C)(C)C)cc4N(c4cc(-c5ccccc5)ccc4-c4ccccc4)c4cc(-c5ccccc5)cc(c43)N1c1cc(-c3ccccc3)ccc1-c1ccccc1)O2 ; CC(C)(C)c1ccc(-c2ccc(-c3ccc(C(C)(C)C)cc3)c(N3c4cc(C(C)(C)C)ccc4B4c5c3cc(-c3ccccc3)cc5N(c3cc(-c5ccc(C(C)(C)C)cc5)ccc3-c3ccc(C(C)(C)C)cc3)c3cc5c6c(c34)Oc3ccc(C(C)(C)C)cc3B6c3cc(C(C)(C)C)ccc3O5)c2)cc1]

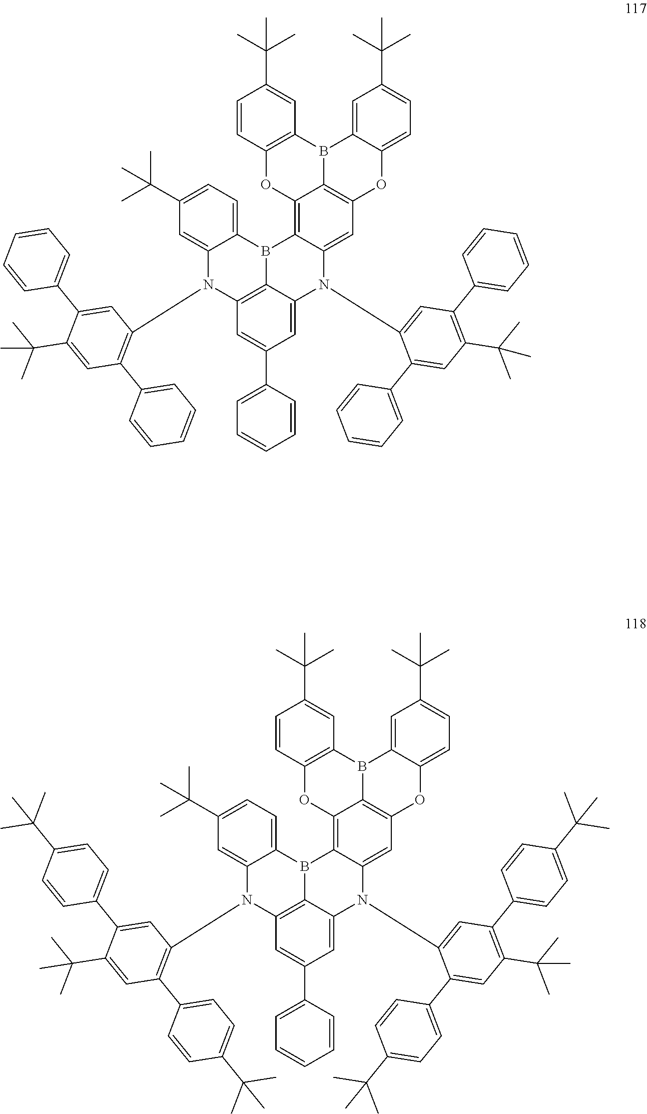

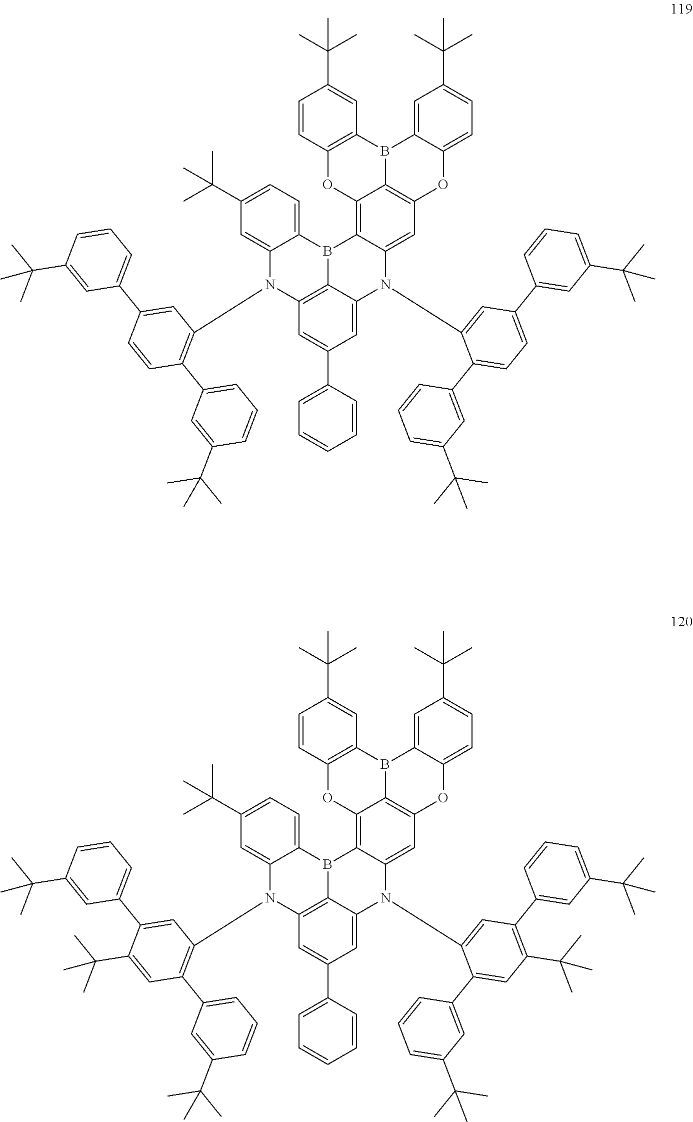

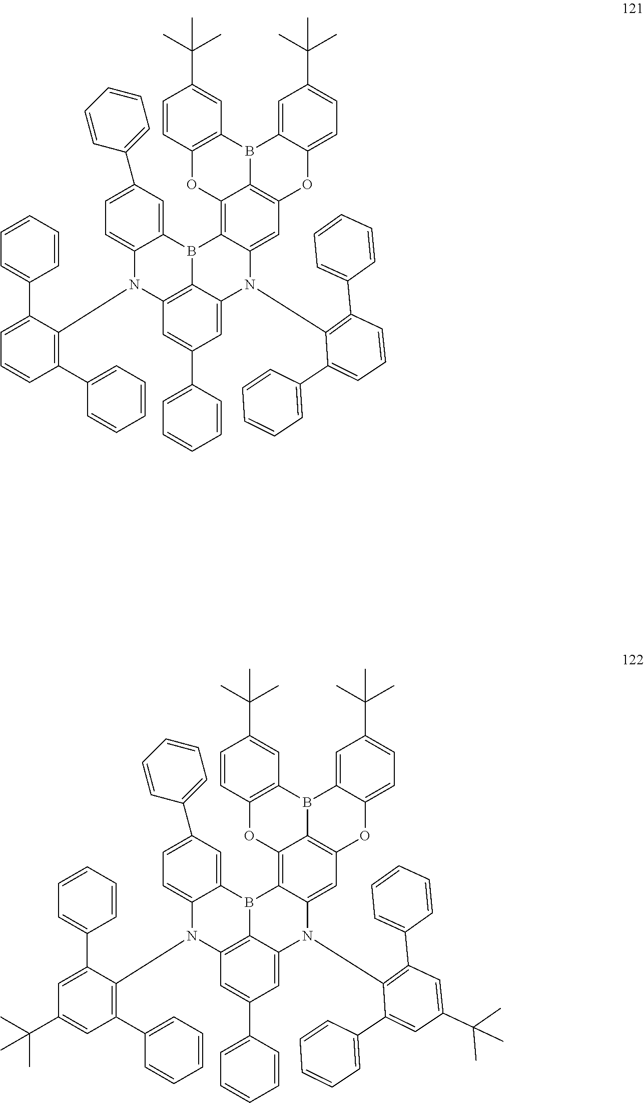 [SMILES: CC(C)(C)c1ccc2c(c1)B1c3cc(C(C)(C)C)ccc3Oc3c1c(cc1c3B3c4cc(-c5ccccc5)ccc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc2c(c1)B1c3cc(C(C)(C)C)ccc3Oc3c1c(cc1c3B3c4cc(-c5ccccc5)ccc4N(c4c(-c5ccccc5)cc(C(C)(C)C)cc4-c4ccccc4)c4cc(-c5ccccc5)cc(c43)N1c1c(-c3ccccc3)cc(C(C)(C)C)cc1-c1ccccc1)O2]

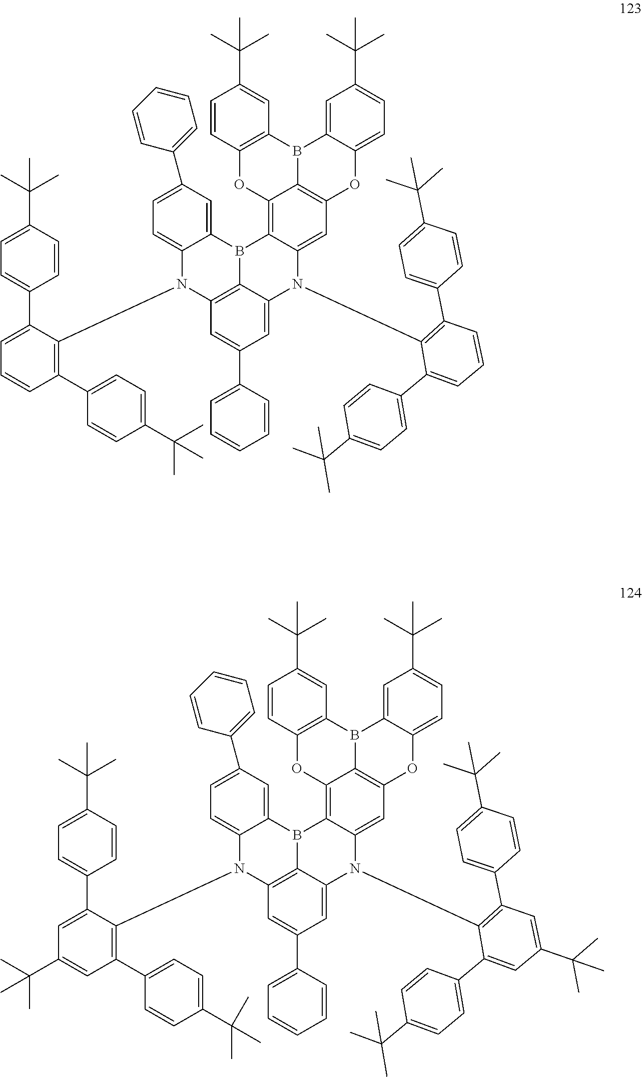 [SMILES: CC(C)(C)c1ccc(-c2cccc(-c3ccc(C(C)(C)C)cc3)c2N2c3ccc(-c4ccccc4)cc3B3c4c2cc(-c2ccccc2)cc4N(c2c(-c4ccc(C(C)(C)C)cc4)cccc2-c2ccc(C(C)(C)C)cc2)c2cc4c5c(c23)Oc2ccc(C(C)(C)C)cc2B5c2cc(C(C)(C)C)ccc2O4)cc1 ; CC(C)(C)c1ccc(-c2cc(C(C)(C)C)cc(-c3ccc(C(C)(C)C)cc3)c2N2c3ccc(-c4ccccc4)cc3B3c4c2cc(-c2ccccc2)cc4N(c2c(-c4ccc(C(C)(C)C)cc4)cc(C(C)(C)C)cc2-c2ccc(C(C)(C)C)cc2)c2cc4c5c(c23)Oc2ccc(C(C)(C)C)cc2B5c2cc(C(C)(C)C)ccc2O4)cc1]

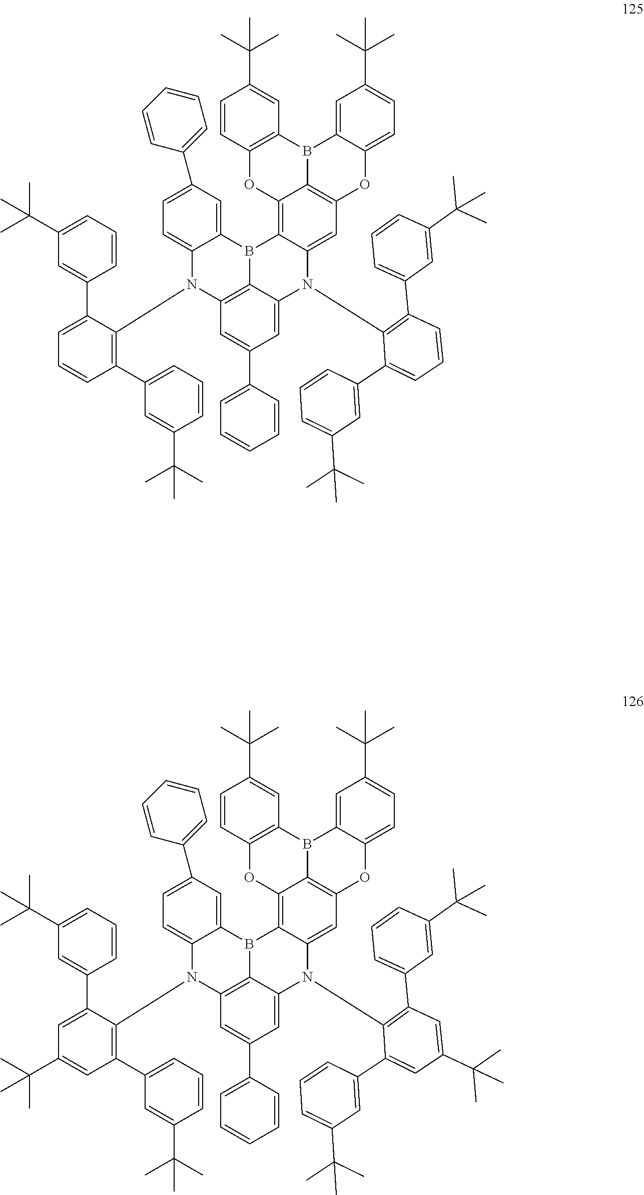

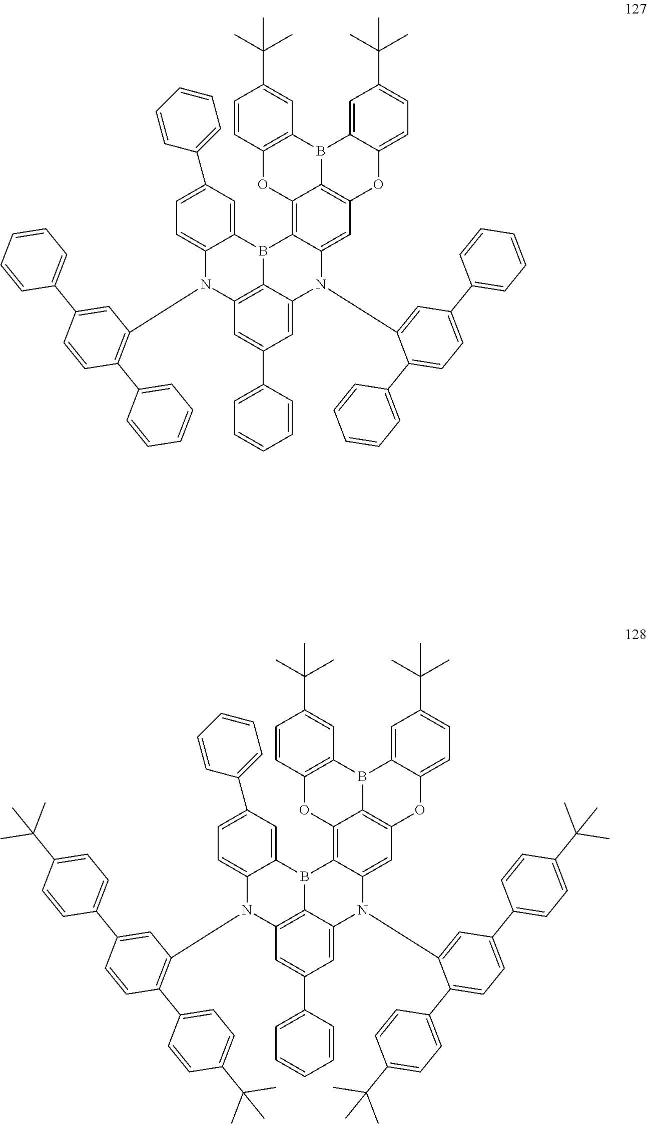 [SMILES: CC(C)(C)c1ccc2c(c1)B1c3cc(C(C)(C)C)ccc3Oc3c1c(cc1c3B3c4cc(-c5ccccc5)ccc4N(c4cc(-c5ccccc5)ccc4-c4ccccc4)c4cc(-c5ccccc5)cc(c43)N1c1cc(-c3ccccc3)ccc1-c1ccccc1)O2 ; CC(C)(C)c1ccc(-c2ccc(-c3ccc(C(C)(C)C)cc3)c(N3c4ccc(-c5ccccc5)cc4B4c5c3cc(-c3ccccc3)cc5N(c3cc(-c5ccc(C(C)(C)C)cc5)ccc3-c3ccc(C(C)(C)C)cc3)c3cc5c6c(c34)Oc3ccc(C(C)(C)C)cc3B6c3cc(C(C)(C)C)ccc3O5)c2)cc1]

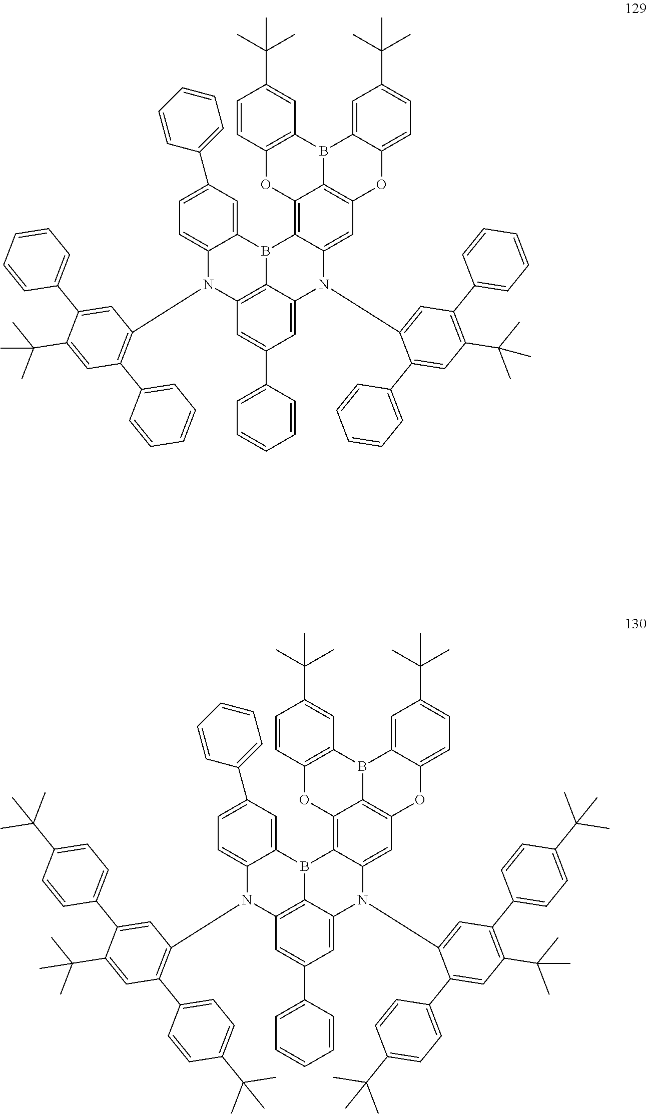

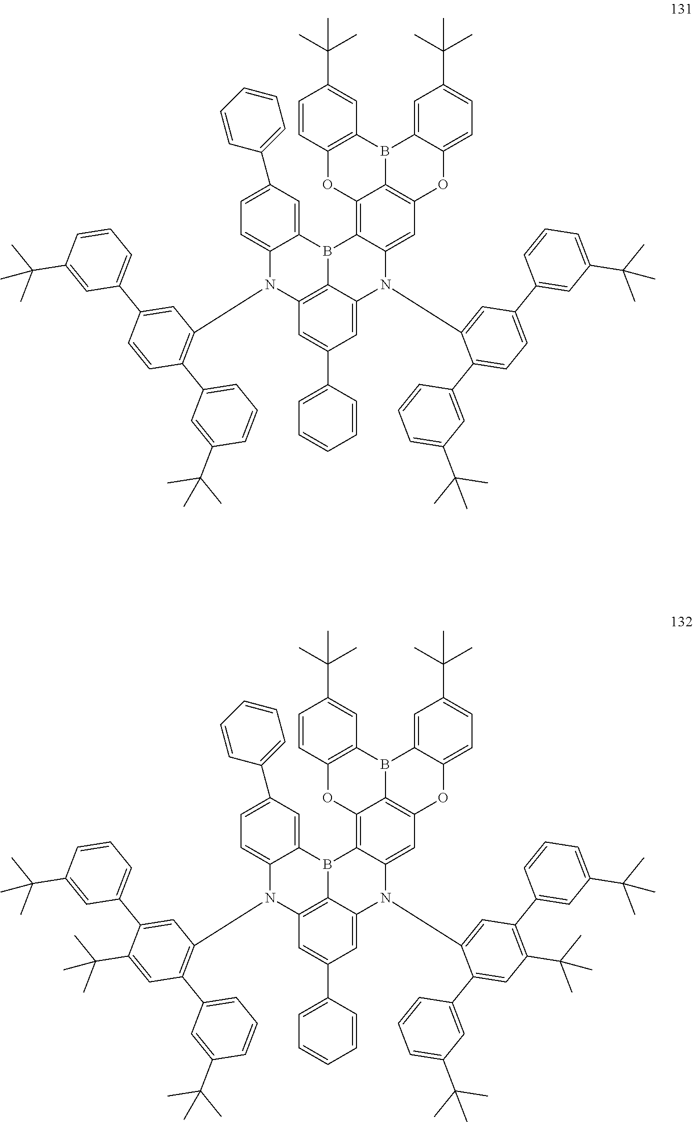

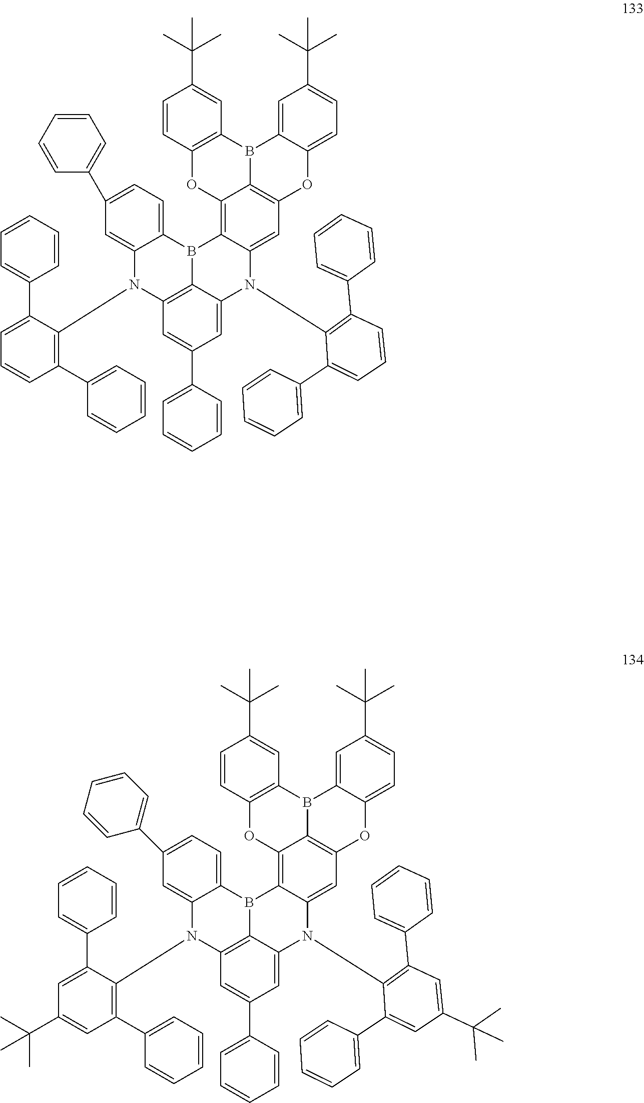 [SMILES: CC(C)(C)c1ccc2c(c1)B1c3cc(C(C)(C)C)ccc3Oc3c1c(cc1c3B3c4ccc(-c5ccccc5)cc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc2c(c1)B1c3cc(C(C)(C)C)ccc3Oc3c1c(cc1c3B3c4ccc(-c5ccccc5)cc4N(c4c(-c5ccccc5)cc(C(C)(C)C)cc4-c4ccccc4)c4cc(-c5ccccc5)cc(c43)N1c1c(-c3ccccc3)cc(C(C)(C)C)cc1-c1ccccc1)O2]

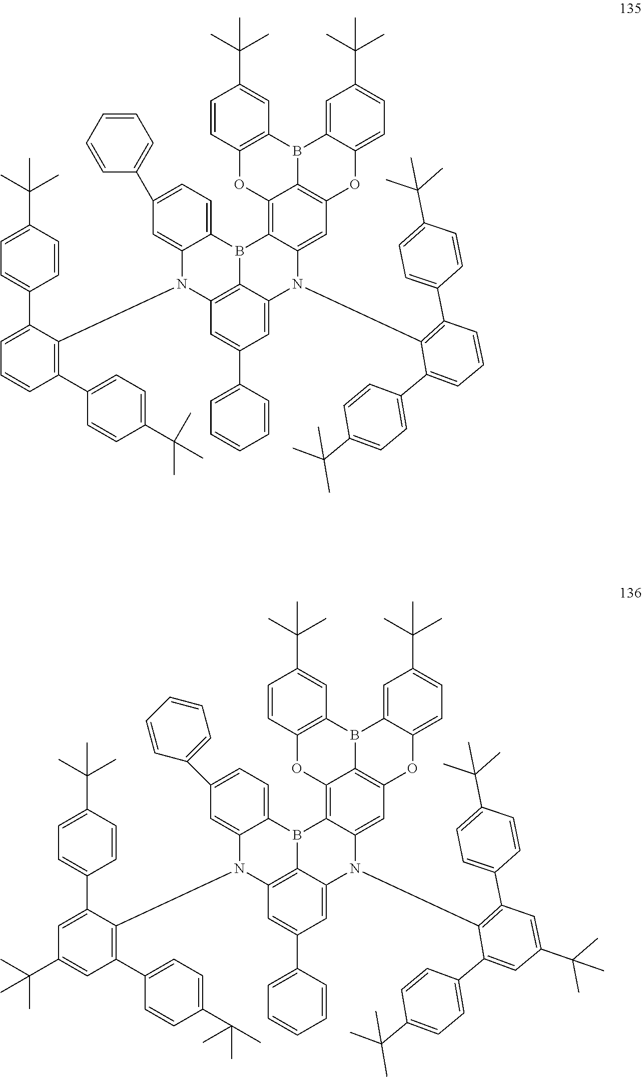 [SMILES: CC(C)(C)c1ccc(-c2cccc(-c3ccc(C(C)(C)C)cc3)c2N2c3cc(-c4ccccc4)ccc3B3c4c2cc(-c2ccccc2)cc4N(c2c(-c4ccc(C(C)(C)C)cc4)cccc2-c2ccc(C(C)(C)C)cc2)c2cc4c5c(c23)Oc2ccc(C(C)(C)C)cc2B5c2cc(C(C)(C)C)ccc2O4)cc1 ; CC(C)(C)c1ccc(-c2cc(C(C)(C)C)cc(-c3ccc(C(C)(C)C)cc3)c2N2c3cc(-c4ccccc4)ccc3B3c4c2cc(-c2ccccc2)cc4N(c2c(-c4ccc(C(C)(C)C)cc4)cc(C(C)(C)C)cc2-c2ccc(C(C)(C)C)cc2)c2cc4c5c(c23)Oc2ccc(C(C)(C)C)cc2B5c2cc(C(C)(C)C)ccc2O4)cc1]

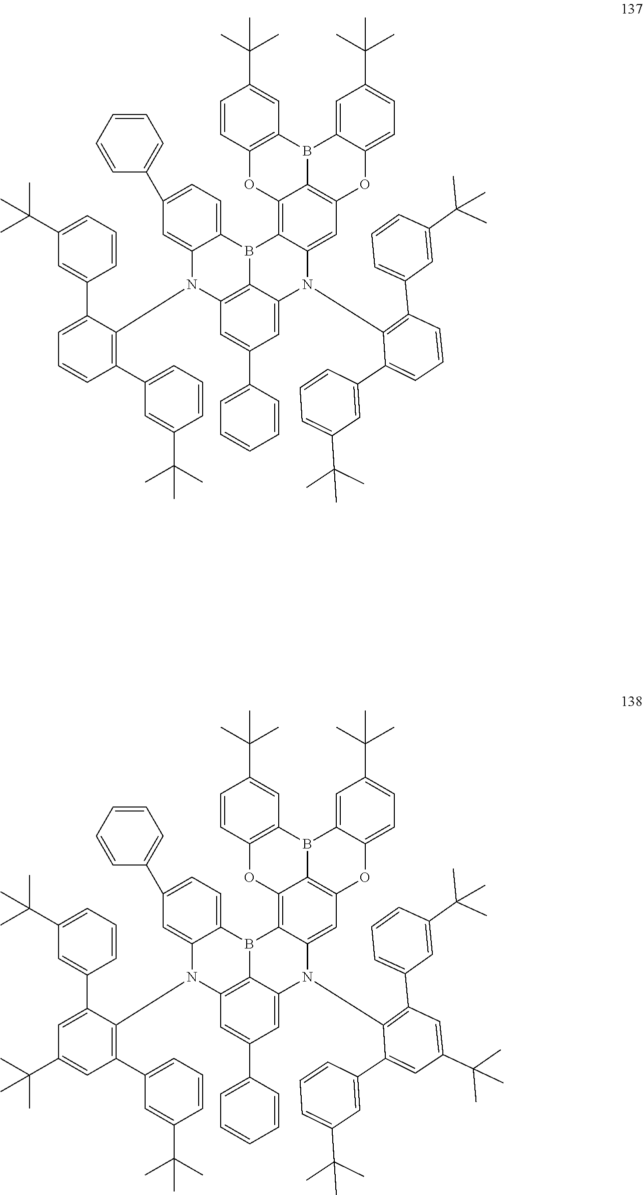

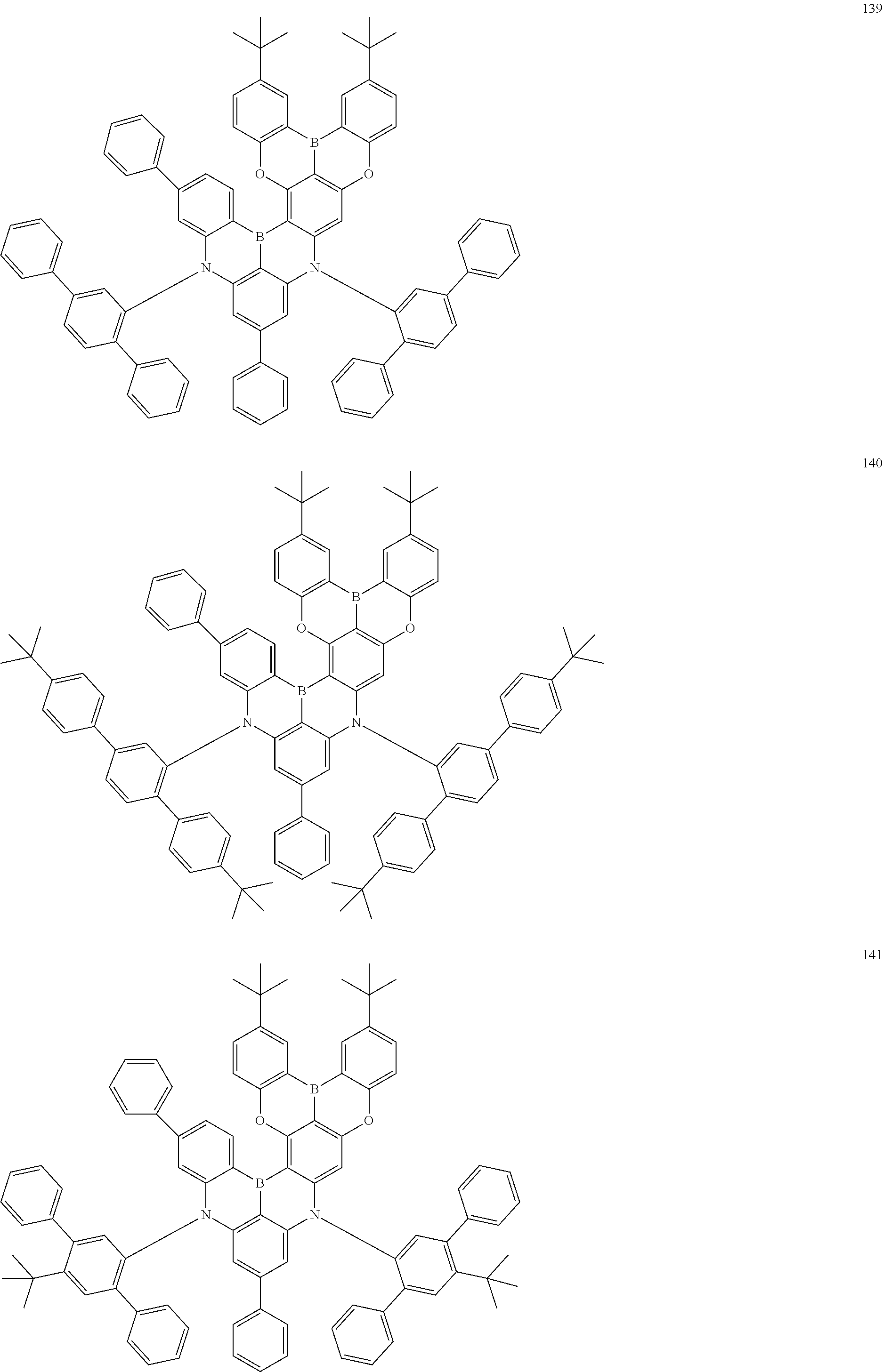

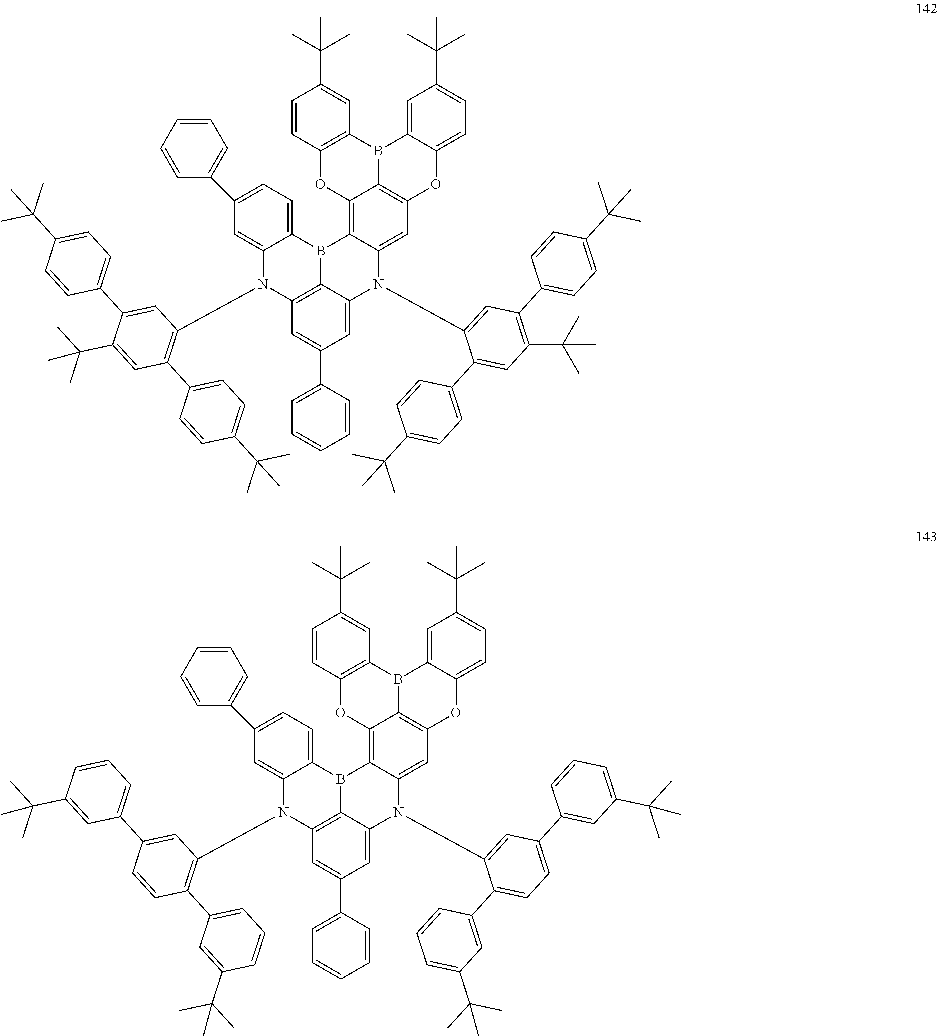

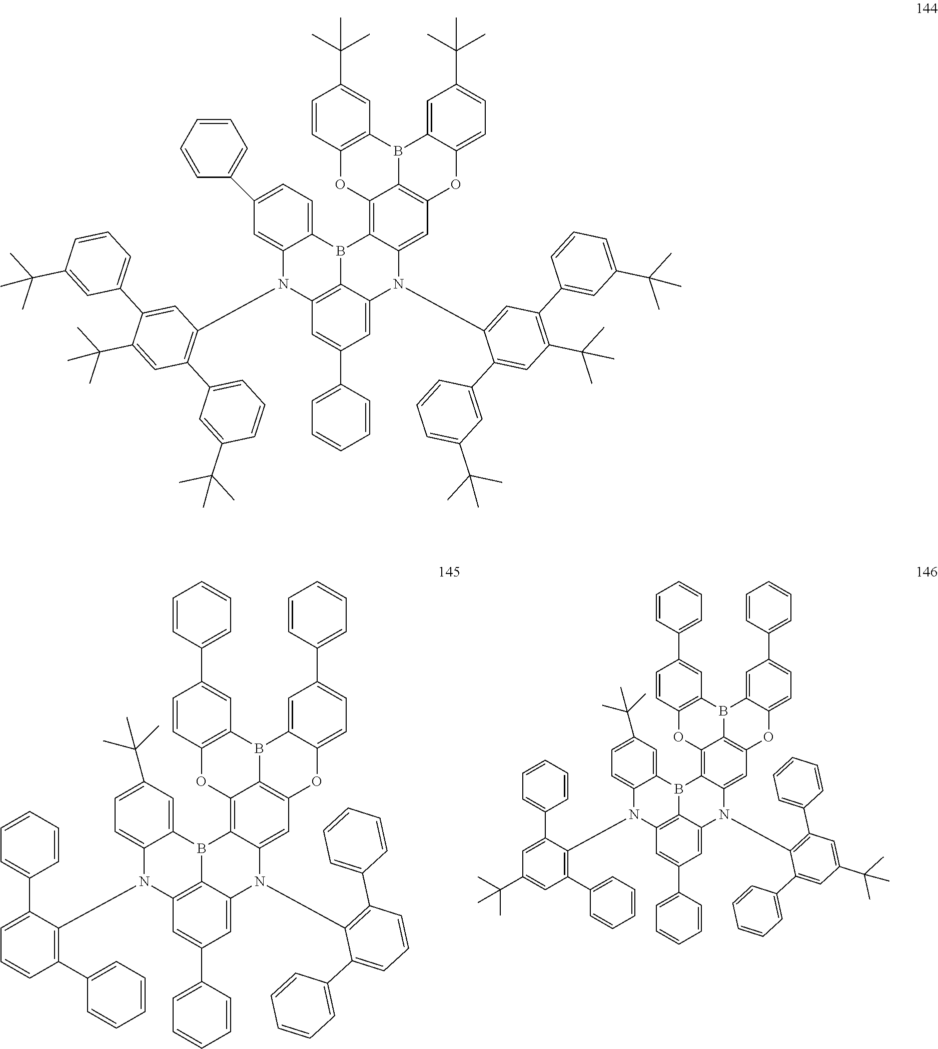

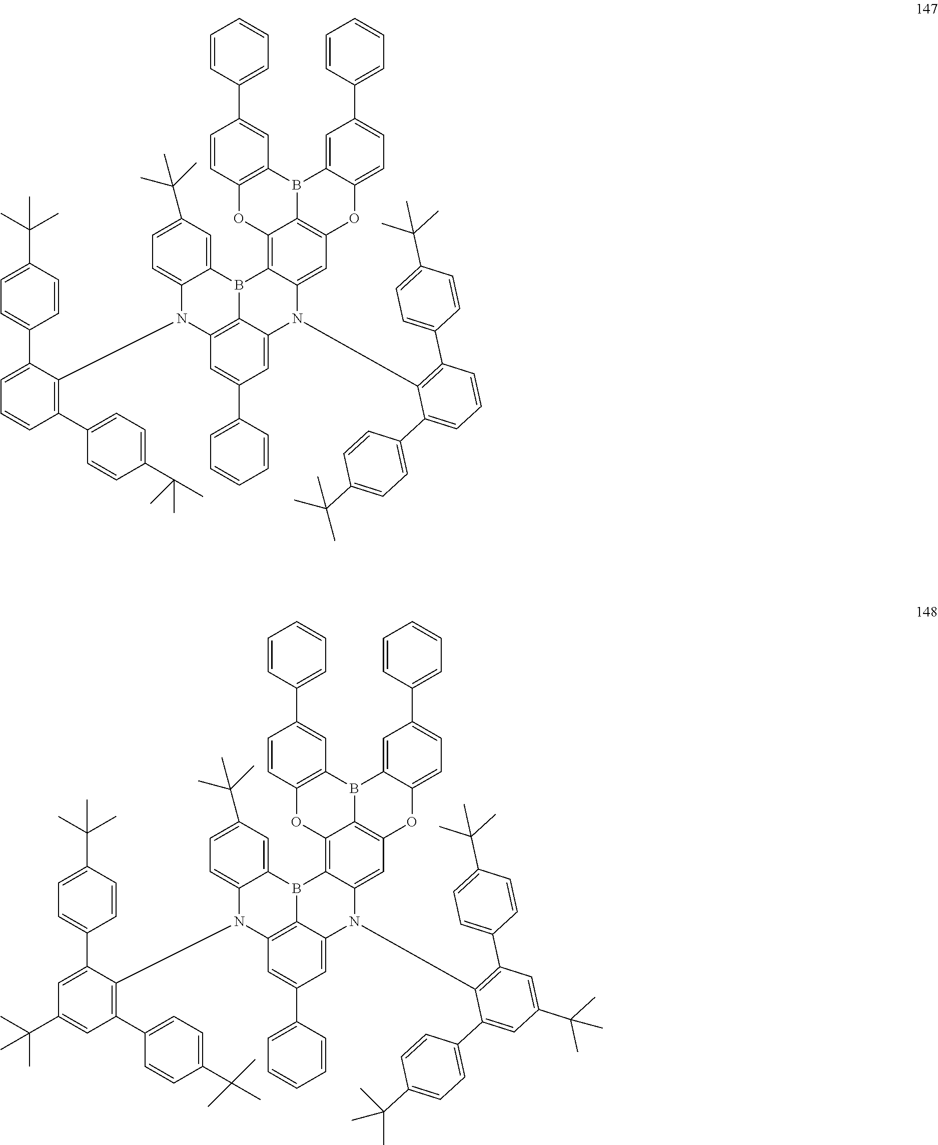 [SMILES: CC(C)(C)c1ccc(-c2cccc(-c3ccc(C(C)(C)C)cc3)c2N2c3ccc(C(C)(C)C)cc3B3c4c2cc(-c2ccccc2)cc4N(c2c(-c4ccc(C(C)(C)C)cc4)cccc2-c2ccc(C(C)(C)C)cc2)c2cc4c5c(c23)Oc2ccc(-c3ccccc3)cc2B5c2cc(-c3ccccc3)ccc2O4)cc1 ; CC(C)(C)c1ccc(-c2cc(C(C)(C)C)cc(-c3ccc(C(C)(C)C)cc3)c2N2c3ccc(C(C)(C)C)cc3B3c4c2cc(-c2ccccc2)cc4N(c2c(-c4ccc(C(C)(C)C)cc4)cc(C(C)(C)C)cc2-c2ccc(C(C)(C)C)cc2)c2cc4c5c(c23)Oc2ccc(-c3ccccc3)cc2B5c2cc(-c3ccccc3)ccc2O4)cc1]

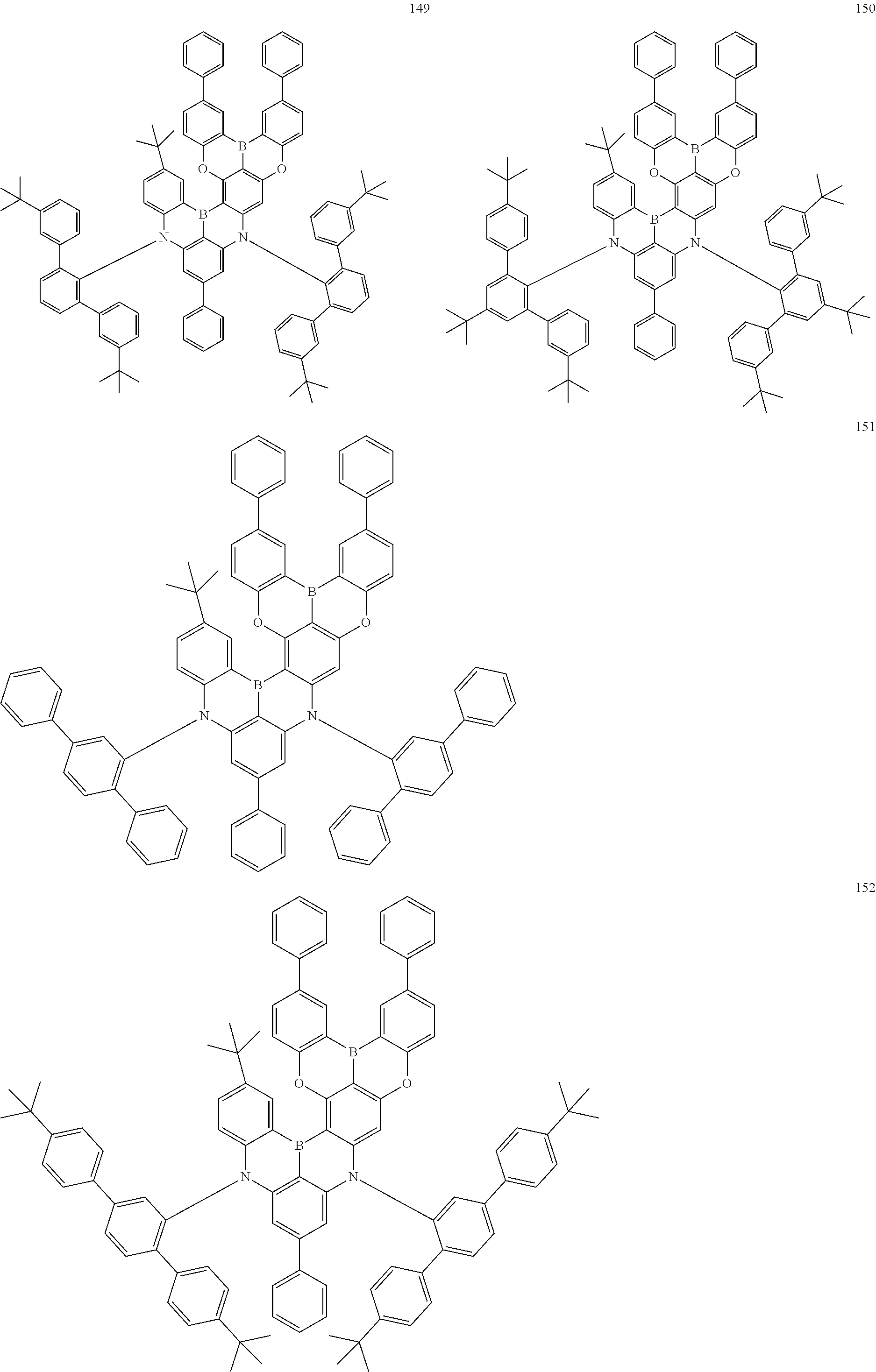

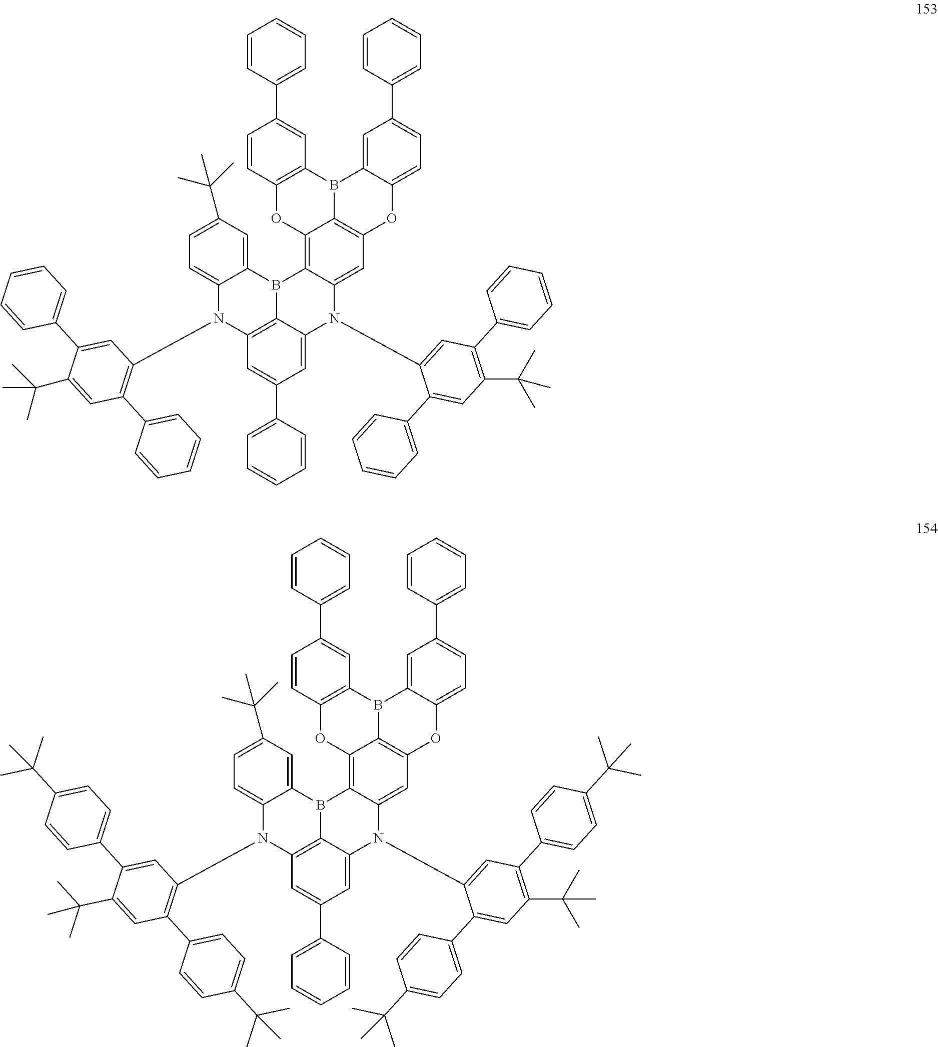 [SMILES: CC(C)(C)c1ccc2c(c1)B1c3c(cc(-c4ccccc4)cc3N(c3cc(-c4ccccc4)c(C(C)(C)C)cc3-c3ccccc3)c3cc4c5c(c31)Oc1ccc(-c3ccccc3)cc1B5c1cc(-c3ccccc3)ccc1O4)N2c1cc(-c2ccccc2)c(C(C)(C)C)cc1-c1ccccc1 ; CC(C)(C)c1ccc(-c2cc(C(C)(C)C)c(-c3ccc(C(C)(C)C)cc3)cc2N2c3ccc(C(C)(C)C)cc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Oc2ccc(-c3ccccc3)cc2B5c2cc(-c3ccccc3)ccc2O4)cc1]

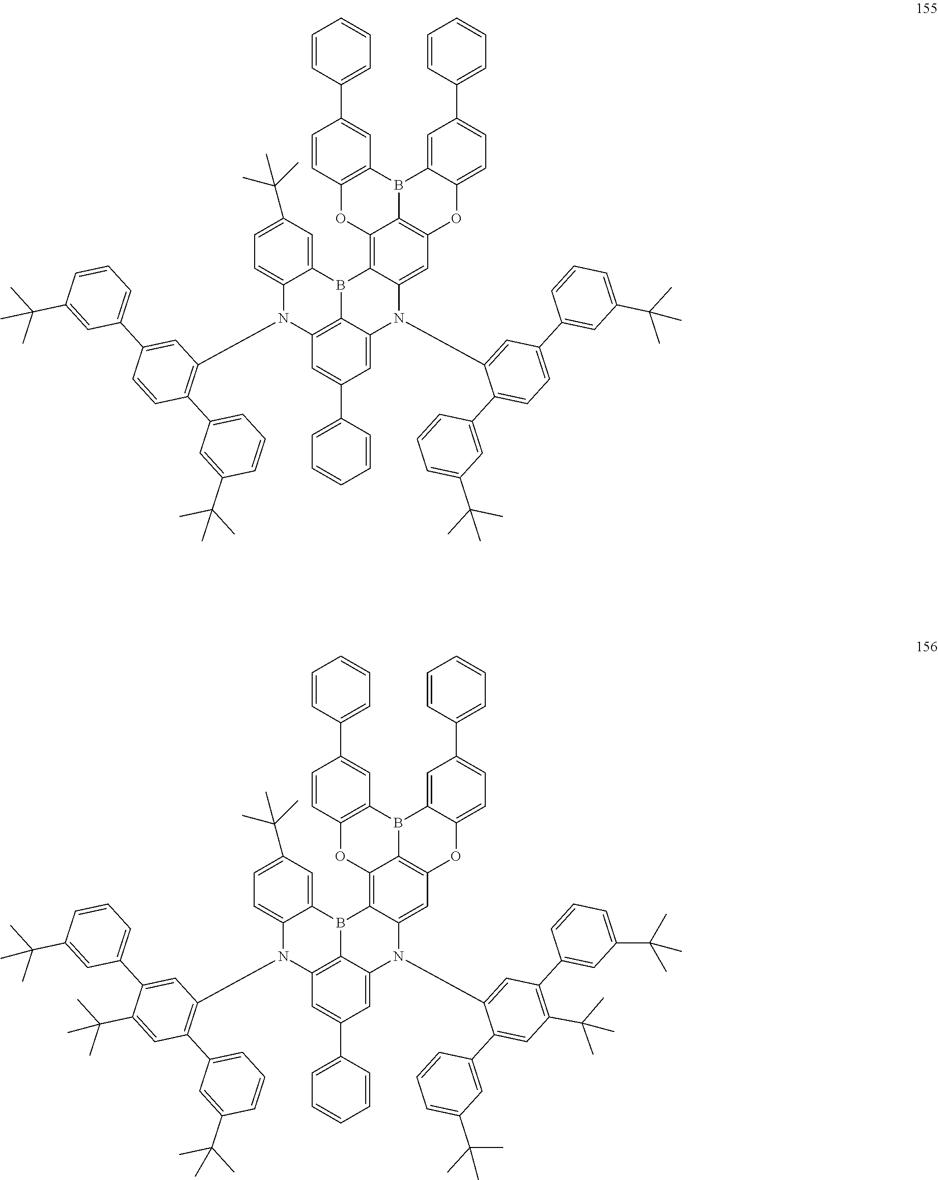

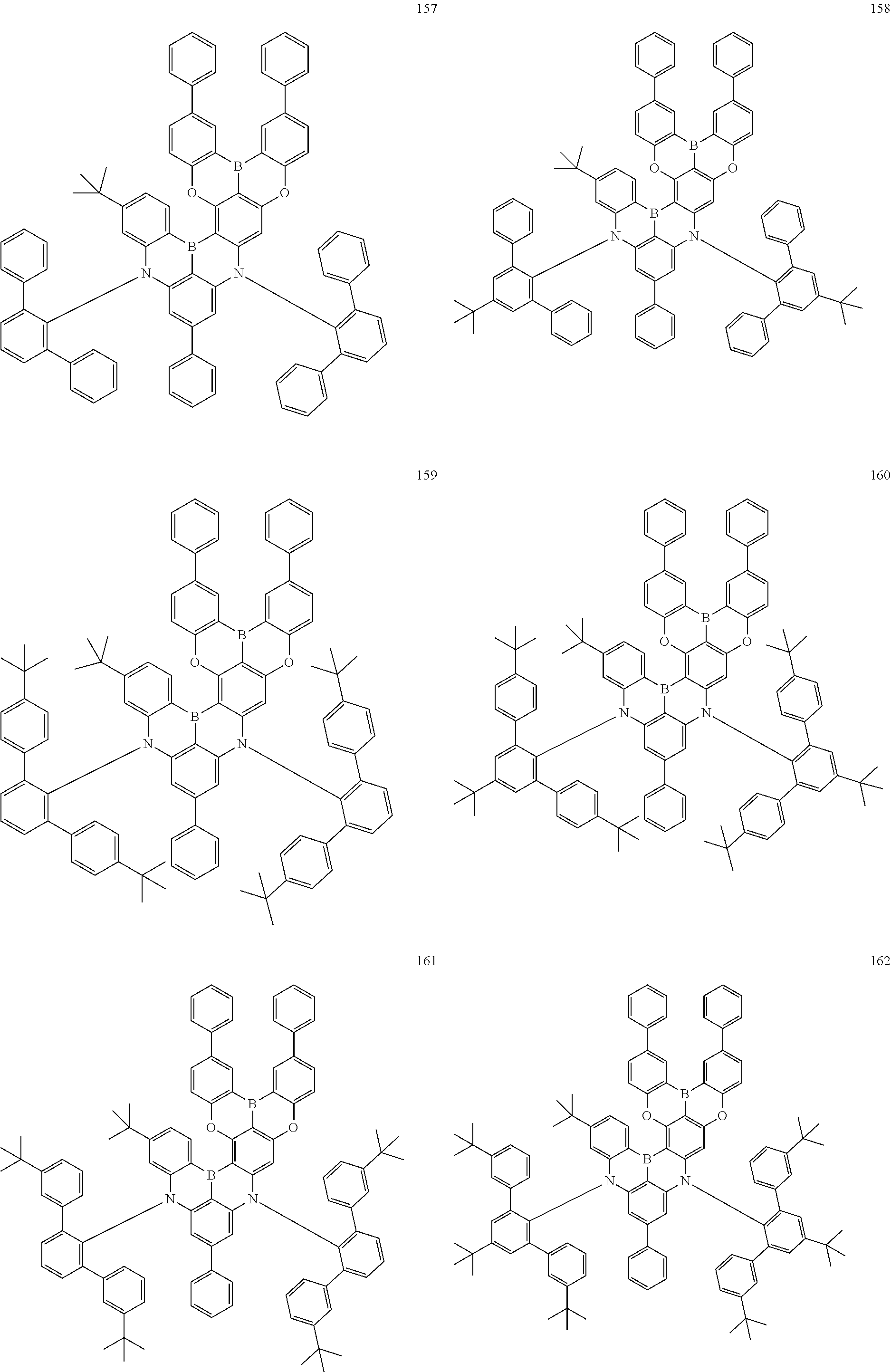

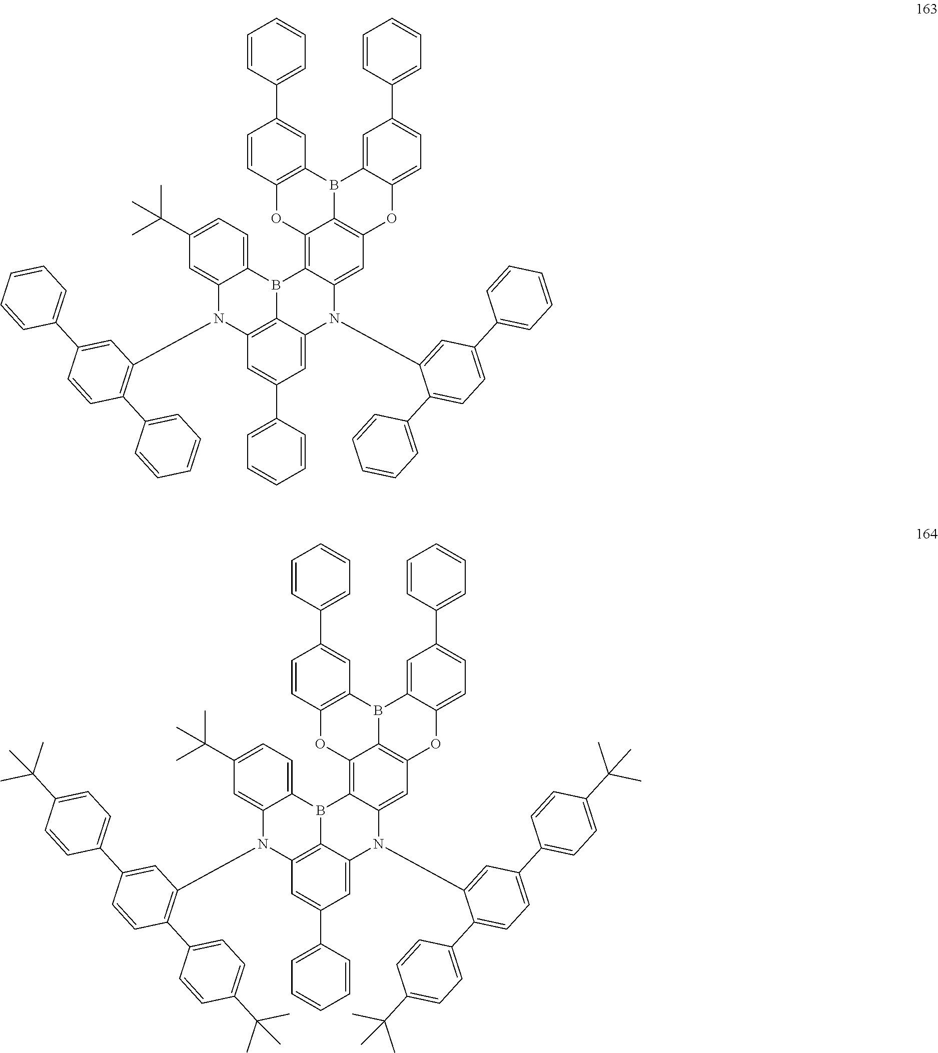 [SMILES: CC(C)(C)c1ccc2c(c1)N(c1cc(-c3ccccc3)ccc1-c1ccccc1)c1cc(-c3ccccc3)cc3c1B2c1c(cc2c4c1Oc1ccc(-c5ccccc5)cc1B4c1cc(-c4ccccc4)ccc1O2)N3c1cc(-c2ccccc2)ccc1-c1ccccc1 ; CC(C)(C)c1ccc(-c2ccc(-c3ccc(C(C)(C)C)cc3)c(N3c4cc(C(C)(C)C)ccc4B4c5c3cc(-c3ccccc3)cc5N(c3cc(-c5ccc(C(C)(C)C)cc5)ccc3-c3ccc(C(C)(C)C)cc3)c3cc5c6c(c34)Oc3ccc(-c4ccccc4)cc3B6c3cc(-c4ccccc4)ccc3O5)c2)cc1]

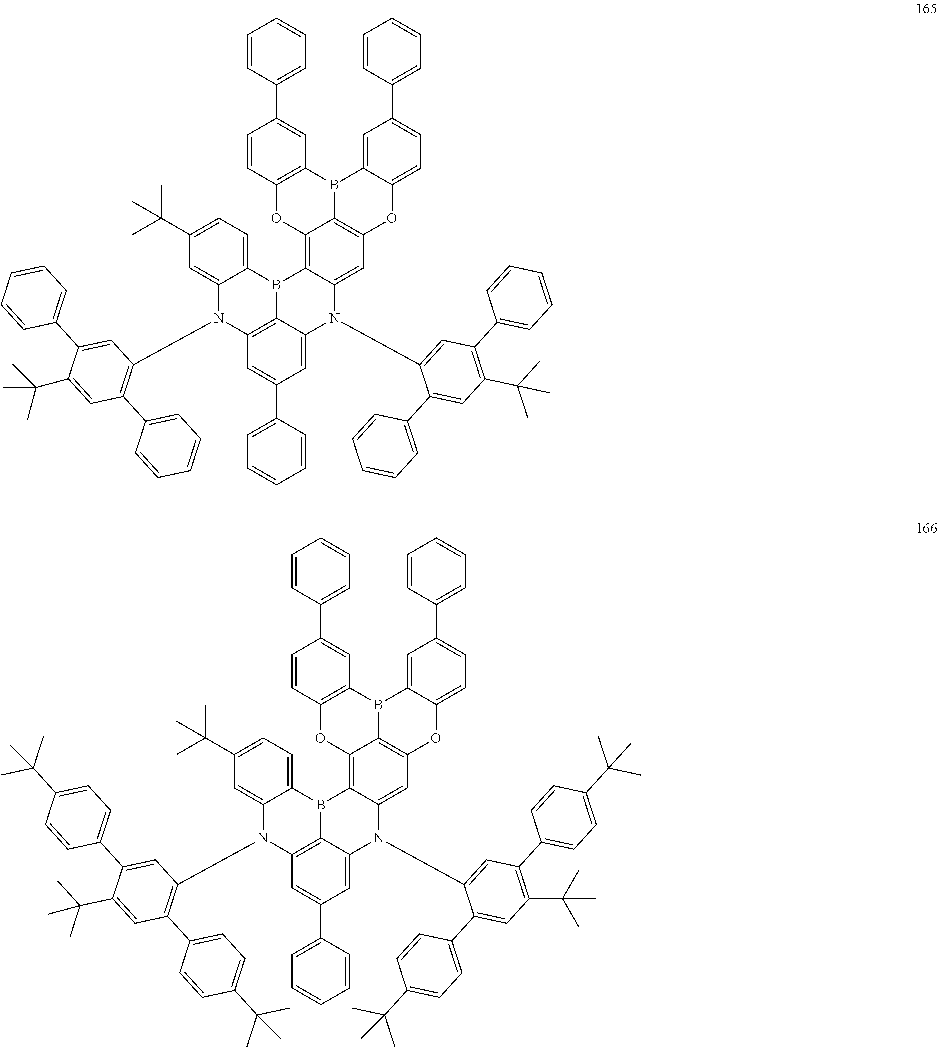 [SMILES: CC(C)(C)c1ccc2c(c1)N(c1cc(-c3ccccc3)c(C(C)(C)C)cc1-c1ccccc1)c1cc(-c3ccccc3)cc3c1B2c1c(cc2c4c1Oc1ccc(-c5ccccc5)cc1B4c1cc(-c4ccccc4)ccc1O2)N3c1cc(-c2ccccc2)c(C(C)(C)C)cc1-c1ccccc1 ; CC(C)(C)c1ccc(-c2cc(C(C)(C)C)c(-c3ccc(C(C)(C)C)cc3)cc2N2c3cc(C(C)(C)C)ccc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Oc2ccc(-c3ccccc3)cc2B5c2cc(-c3ccccc3)ccc2O4)cc1]

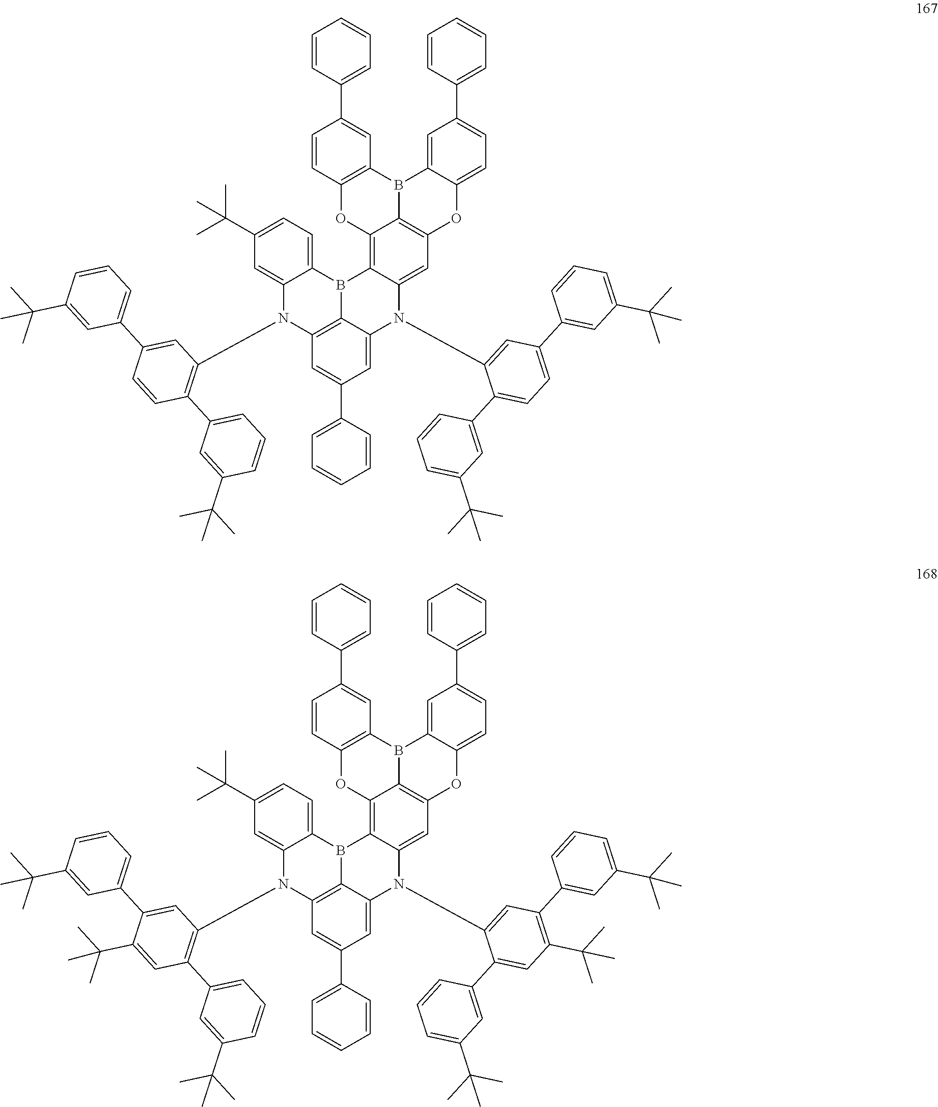

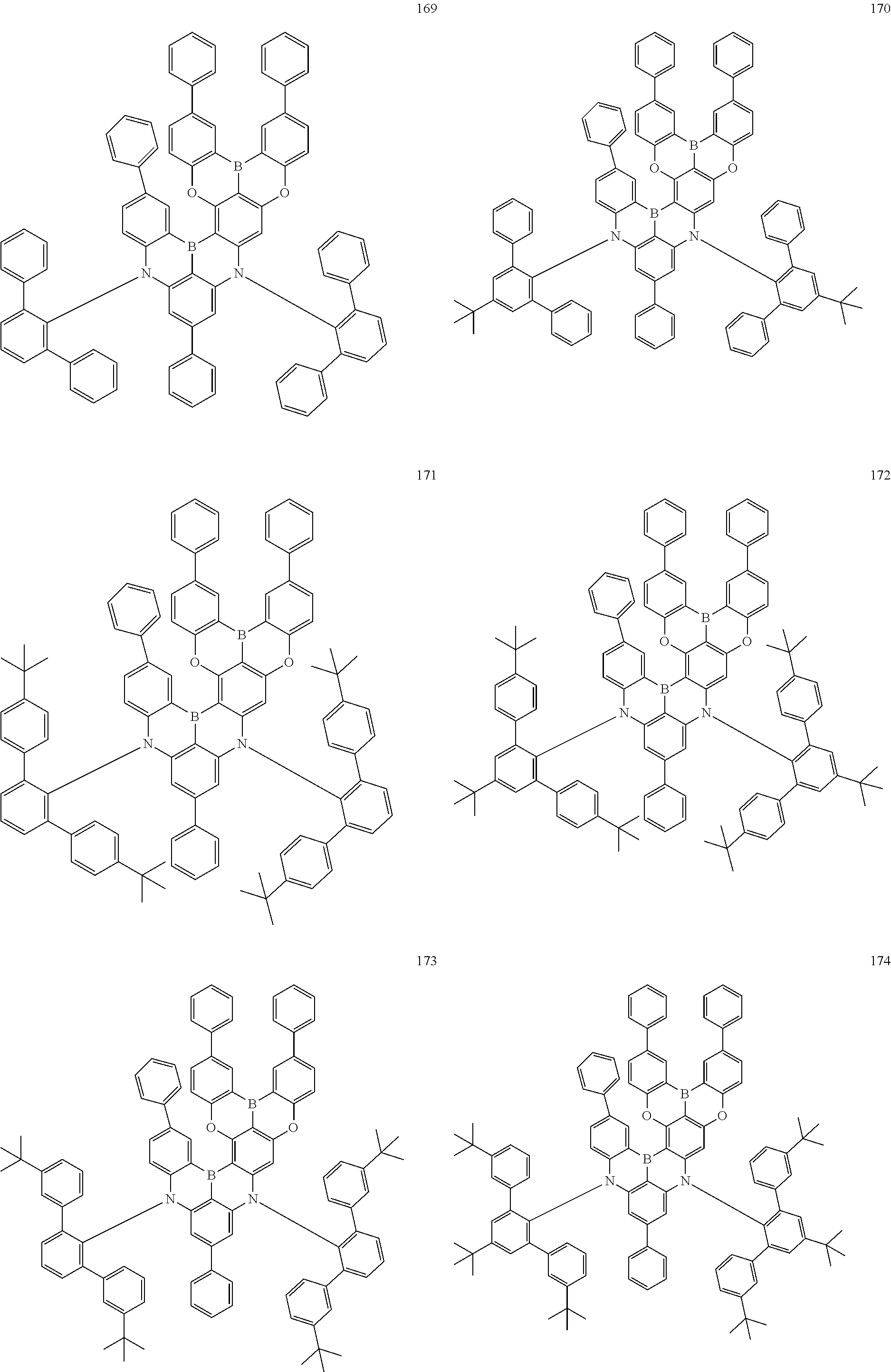

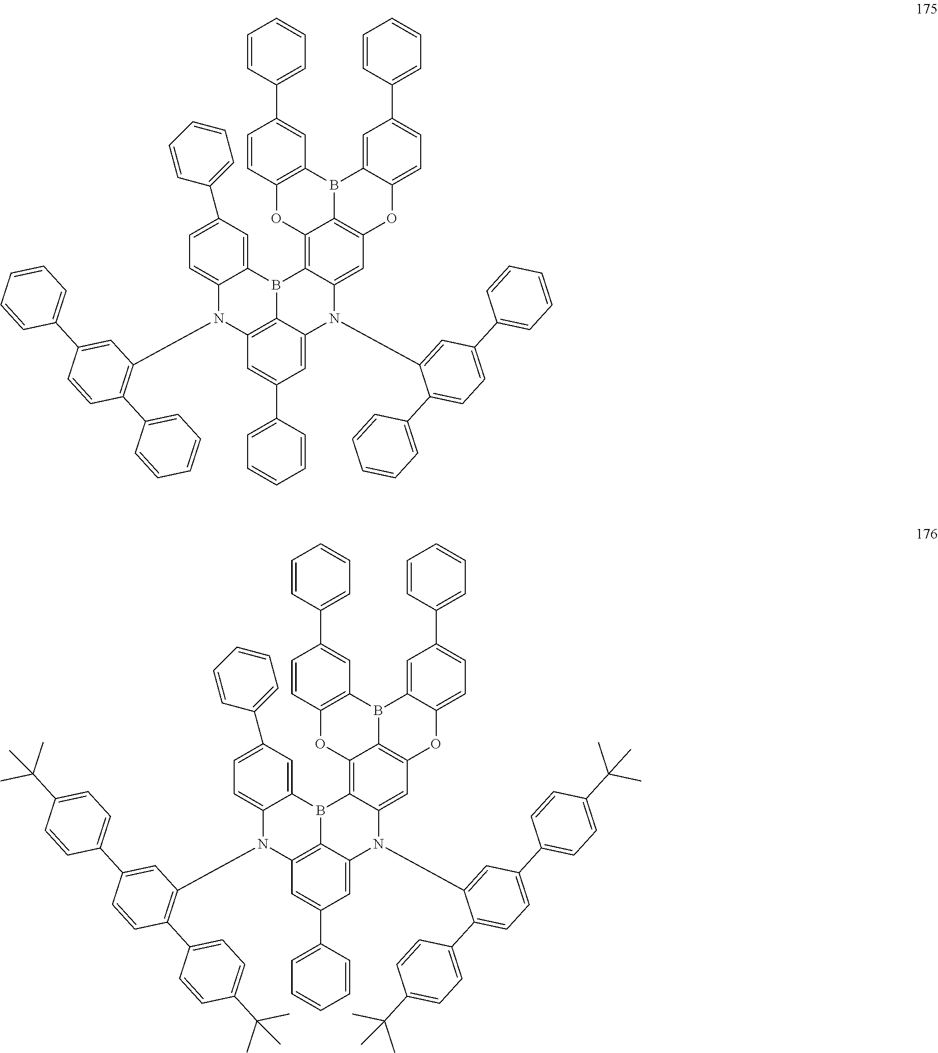 [SMILES: c1ccc(-c2ccc3c(c2)B2c4cc(-c5ccccc5)ccc4Oc4c2c(cc2c4B4c5cc(-c6ccccc6)ccc5N(c5cc(-c6ccccc6)ccc5-c5ccccc5)c5cc(-c6ccccc6)cc(c54)N2c2cc(-c4ccccc4)ccc2-c2ccccc2)O3)cc1 ; CC(C)(C)c1ccc(-c2ccc(-c3ccc(C(C)(C)C)cc3)c(N3c4ccc(-c5ccccc5)cc4B4c5c3cc(-c3ccccc3)cc5N(c3cc(-c5ccc(C(C)(C)C)cc5)ccc3-c3ccc(C(C)(C)C)cc3)c3cc5c6c(c34)Oc3ccc(-c4ccccc4)cc3B6c3cc(-c4ccccc4)ccc3O5)c2)cc1]

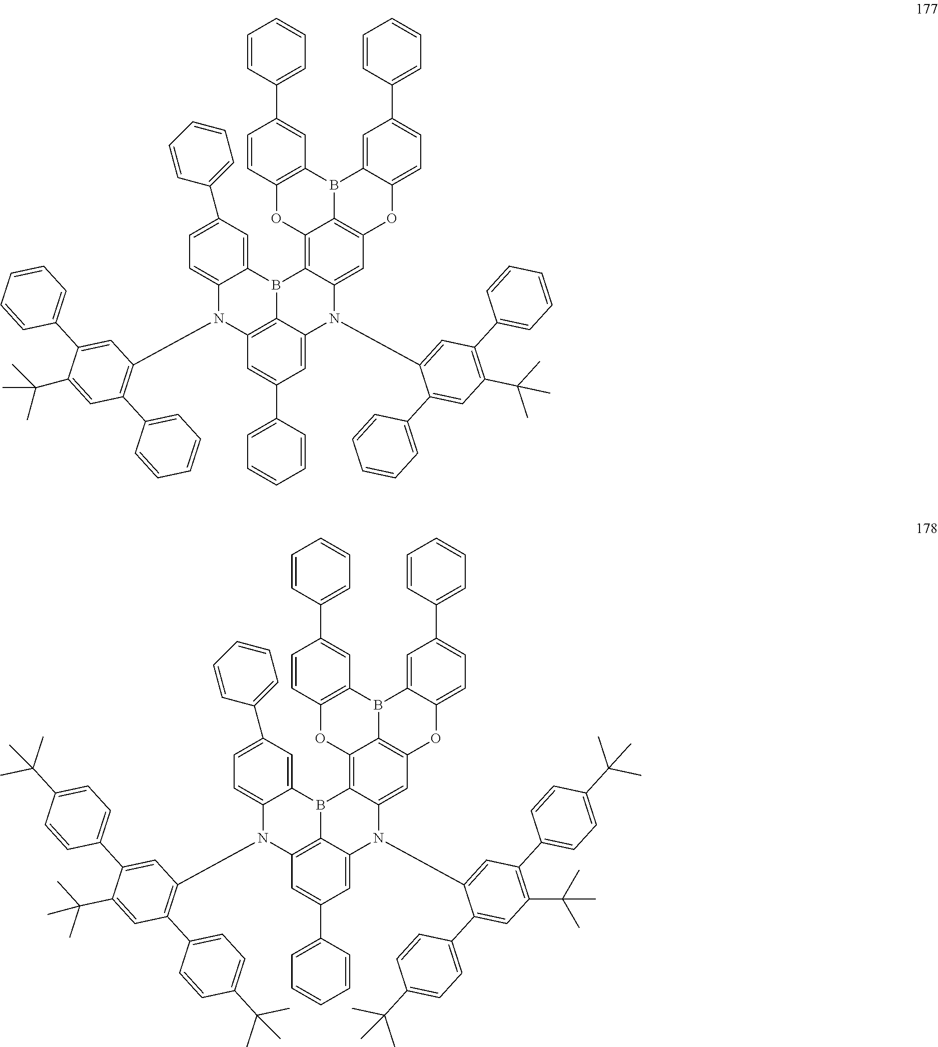 [SMILES: CC(C)(C)c1cc(-c2ccccc2)c(N2c3ccc(-c4ccccc4)cc3B3c4c2cc(-c2ccccc2)cc4N(c2cc(-c4ccccc4)c(C(C)(C)C)cc2-c2ccccc2)c2cc4c5c(c23)Oc2ccc(-c3ccccc3)cc2B5c2cc(-c3ccccc3)ccc2O4)cc1-c1ccccc1 ; CC(C)(C)c1ccc(-c2cc(C(C)(C)C)c(-c3ccc(C(C)(C)C)cc3)cc2N2c3ccc(-c4ccccc4)cc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Oc2ccc(-c3ccccc3)cc2B5c2cc(-c3ccccc3)ccc2O4)cc1]

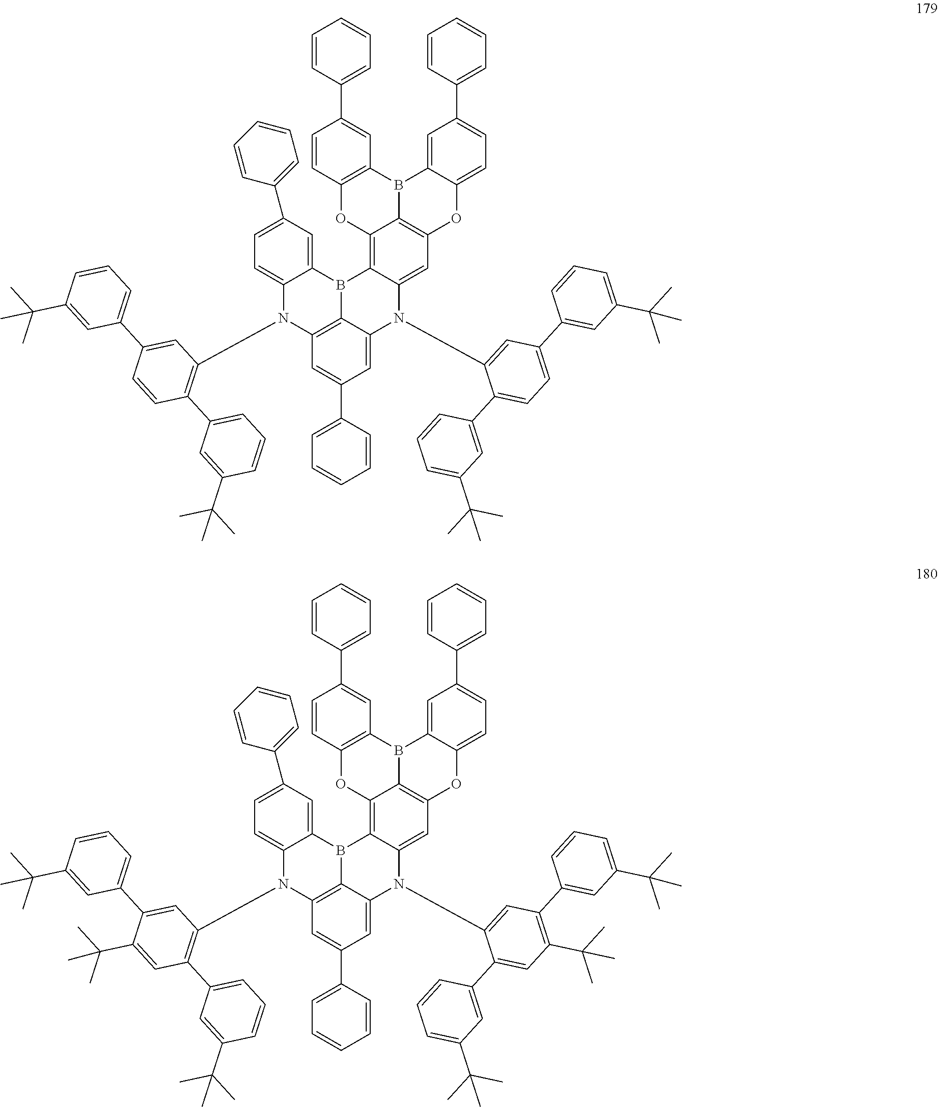

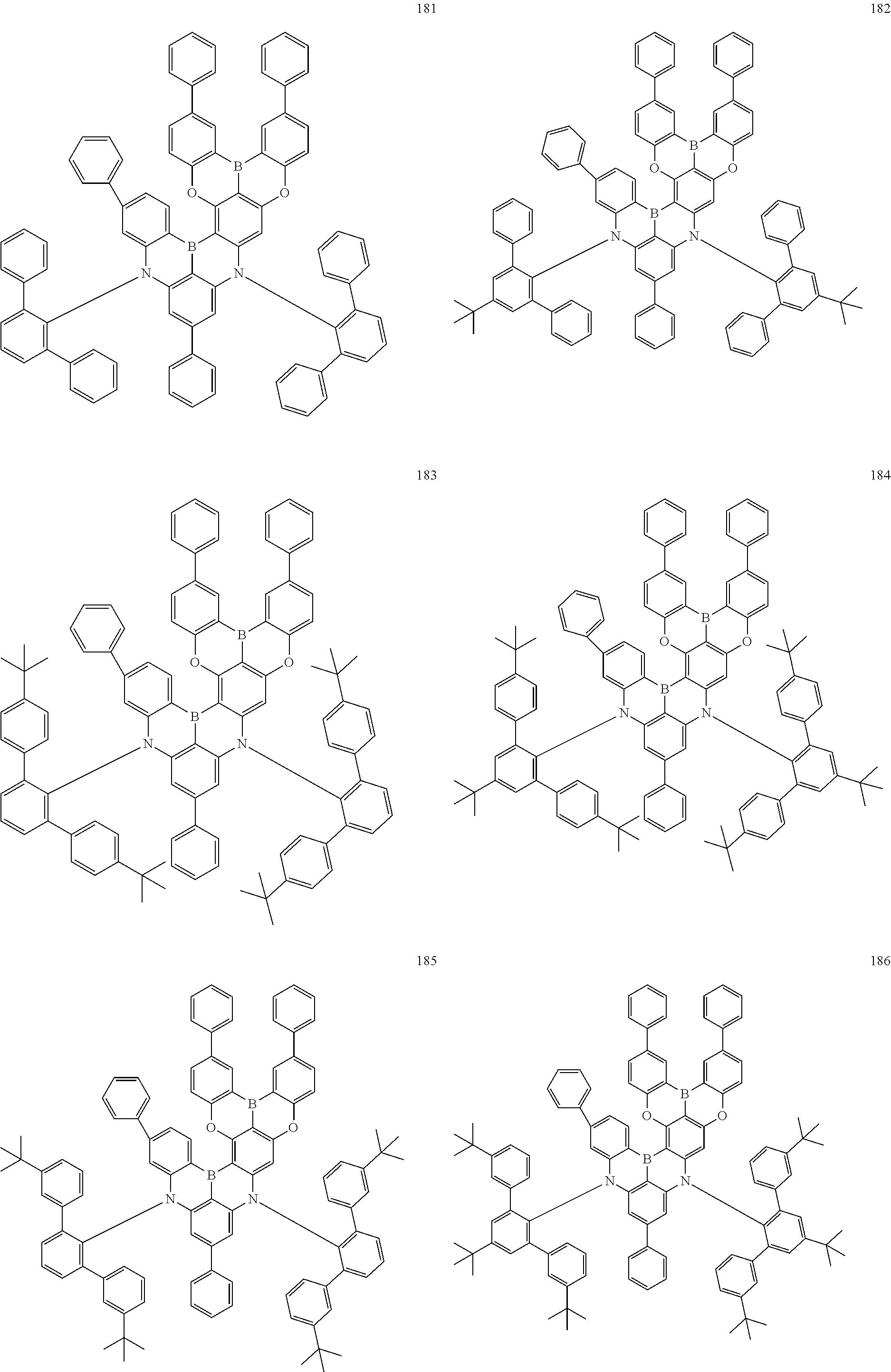

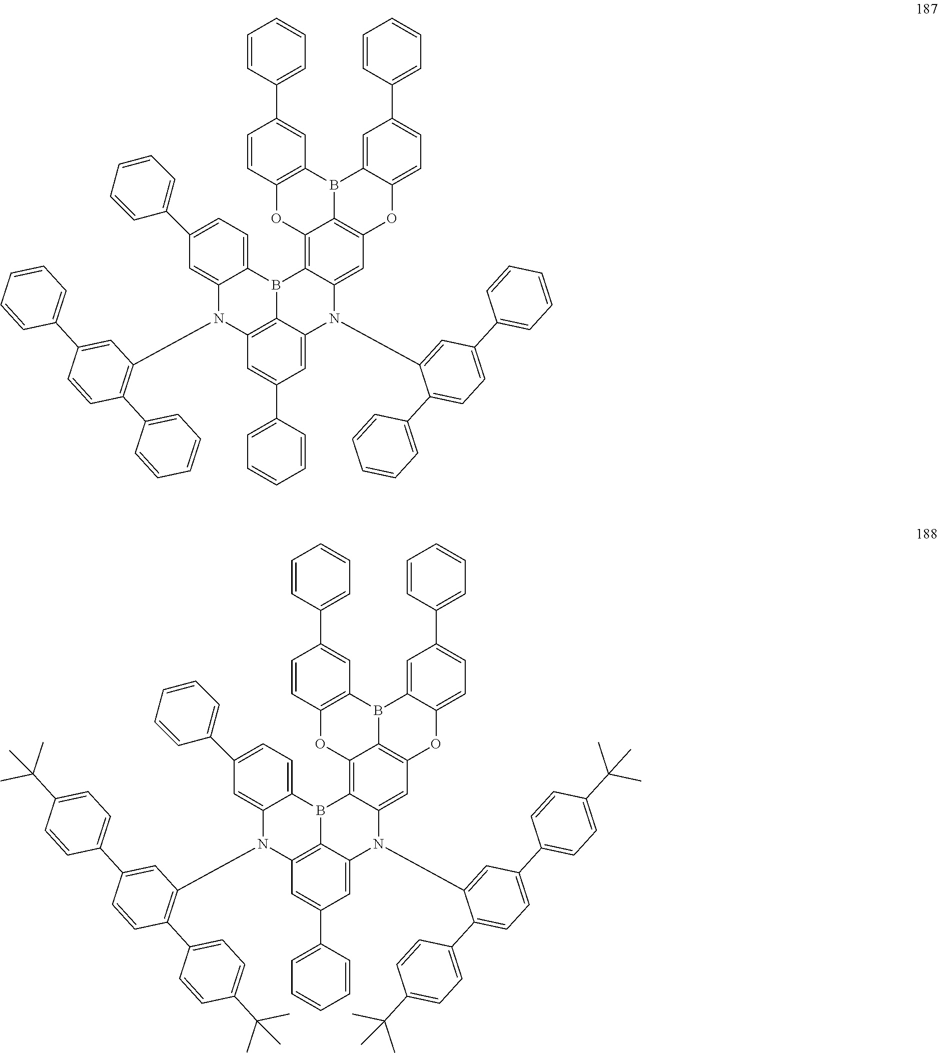 [SMILES: c1ccc(-c2ccc3c(c2)B2c4cc(-c5ccccc5)ccc4Oc4c2c(cc2c4B4c5ccc(-c6ccccc6)cc5N(c5cc(-c6ccccc6)ccc5-c5ccccc5)c5cc(-c6ccccc6)cc(c54)N2c2cc(-c4ccccc4)ccc2-c2ccccc2)O3)cc1 ; CC(C)(C)c1ccc(-c2ccc(-c3ccc(C(C)(C)C)cc3)c(N3c4cc(-c5ccccc5)ccc4B4c5c3cc(-c3ccccc3)cc5N(c3cc(-c5ccc(C(C)(C)C)cc5)ccc3-c3ccc(C(C)(C)C)cc3)c3cc5c6c(c34)Oc3ccc(-c4ccccc4)cc3B6c3cc(-c4ccccc4)ccc3O5)c2)cc1]

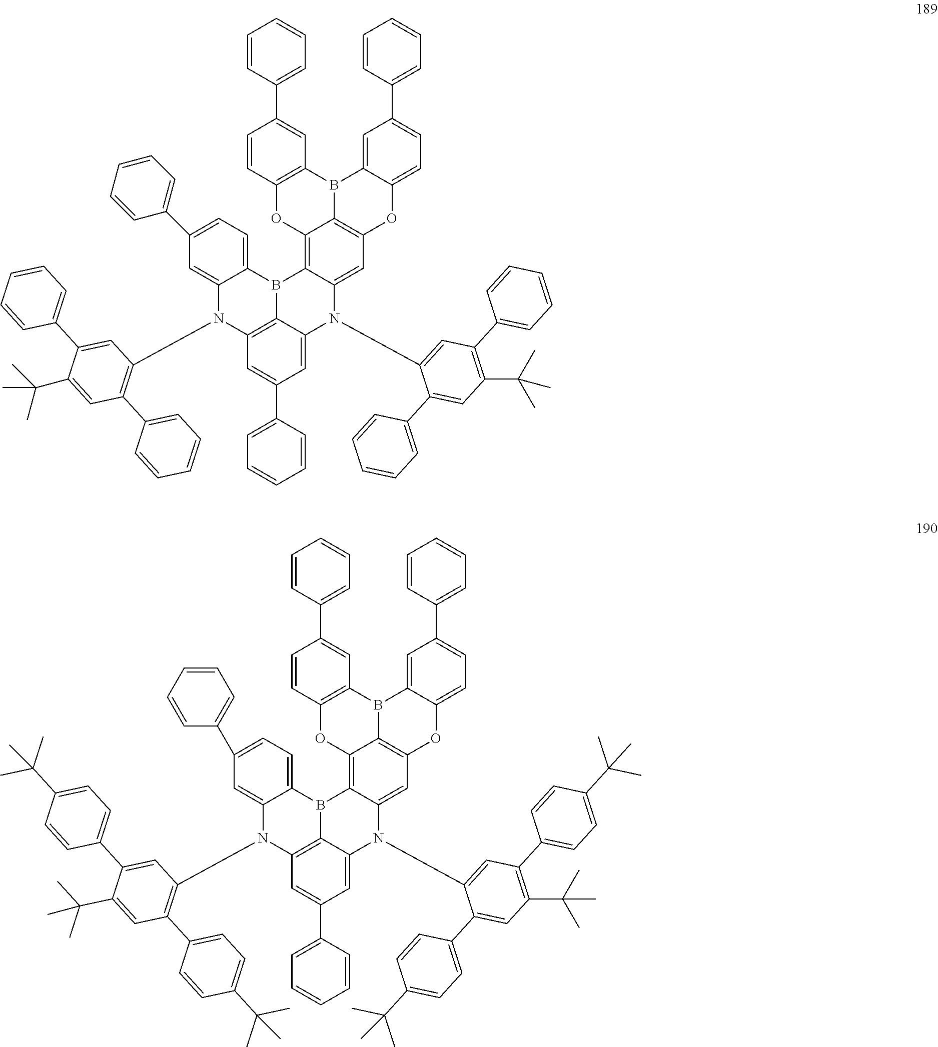 [SMILES: CC(C)(C)c1cc(-c2ccccc2)c(N2c3cc(-c4ccccc4)ccc3B3c4c2cc(-c2ccccc2)cc4N(c2cc(-c4ccccc4)c(C(C)(C)C)cc2-c2ccccc2)c2cc4c5c(c23)Oc2ccc(-c3ccccc3)cc2B5c2cc(-c3ccccc3)ccc2O4)cc1-c1ccccc1 ; CC(C)(C)c1ccc(-c2cc(C(C)(C)C)c(-c3ccc(C(C)(C)C)cc3)cc2N2c3cc(-c4ccccc4)ccc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Oc2ccc(-c3ccccc3)cc2B5c2cc(-c3ccccc3)ccc2O4)cc1]

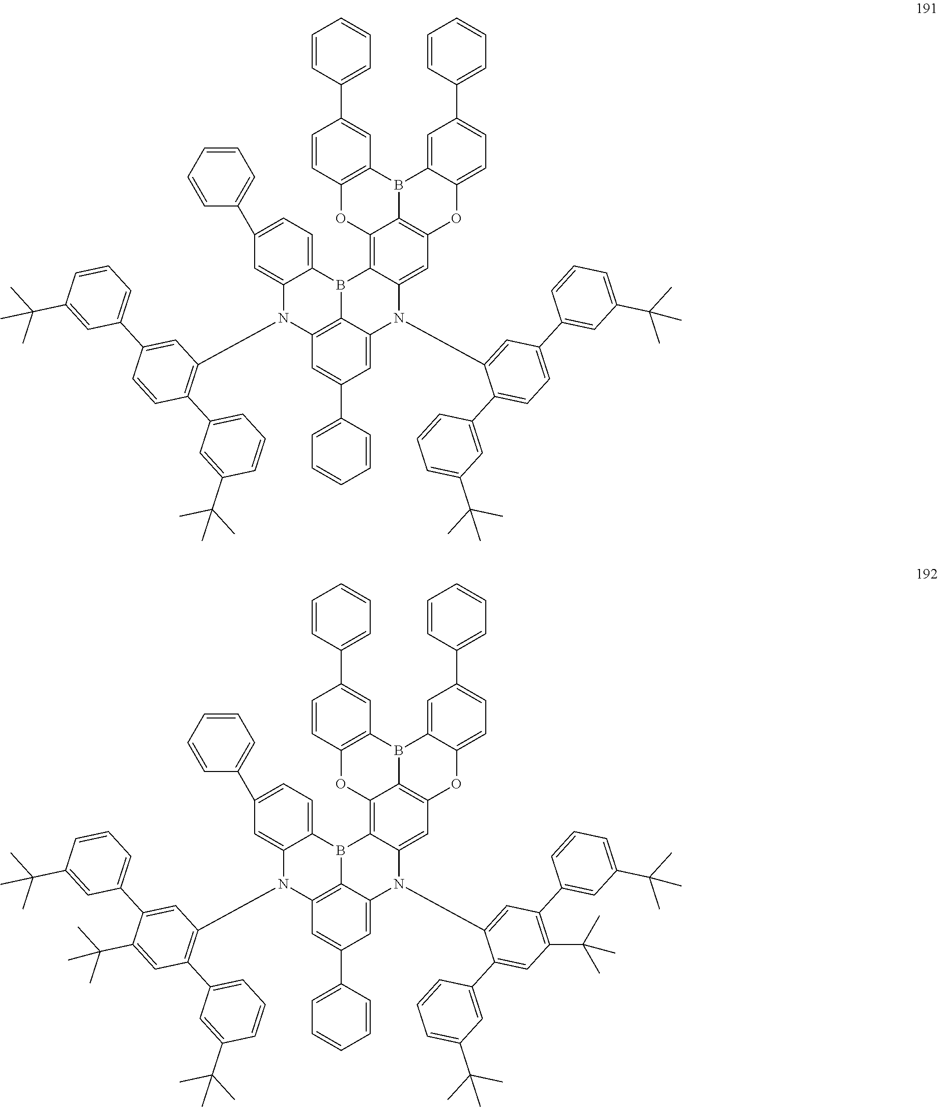

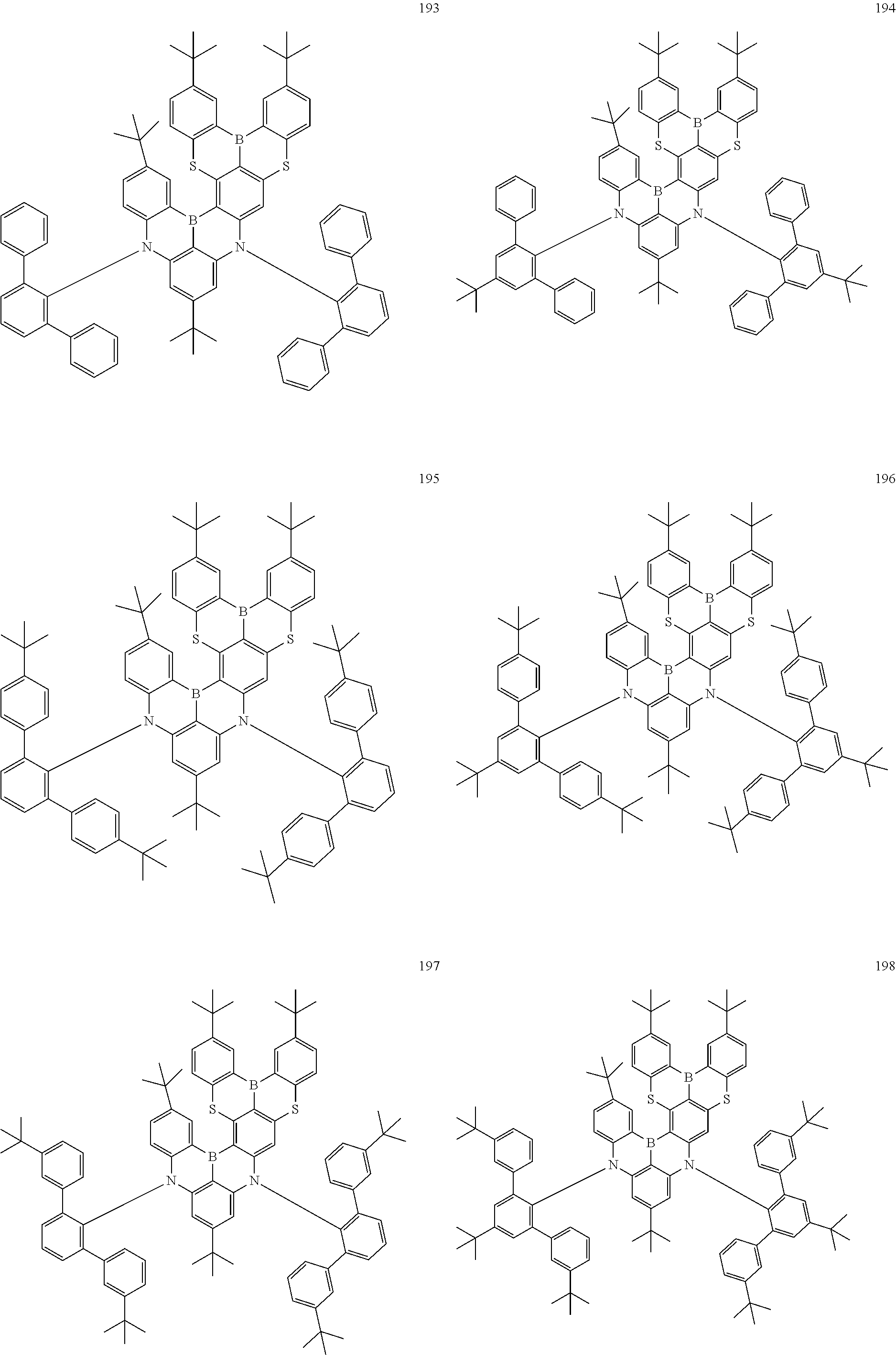

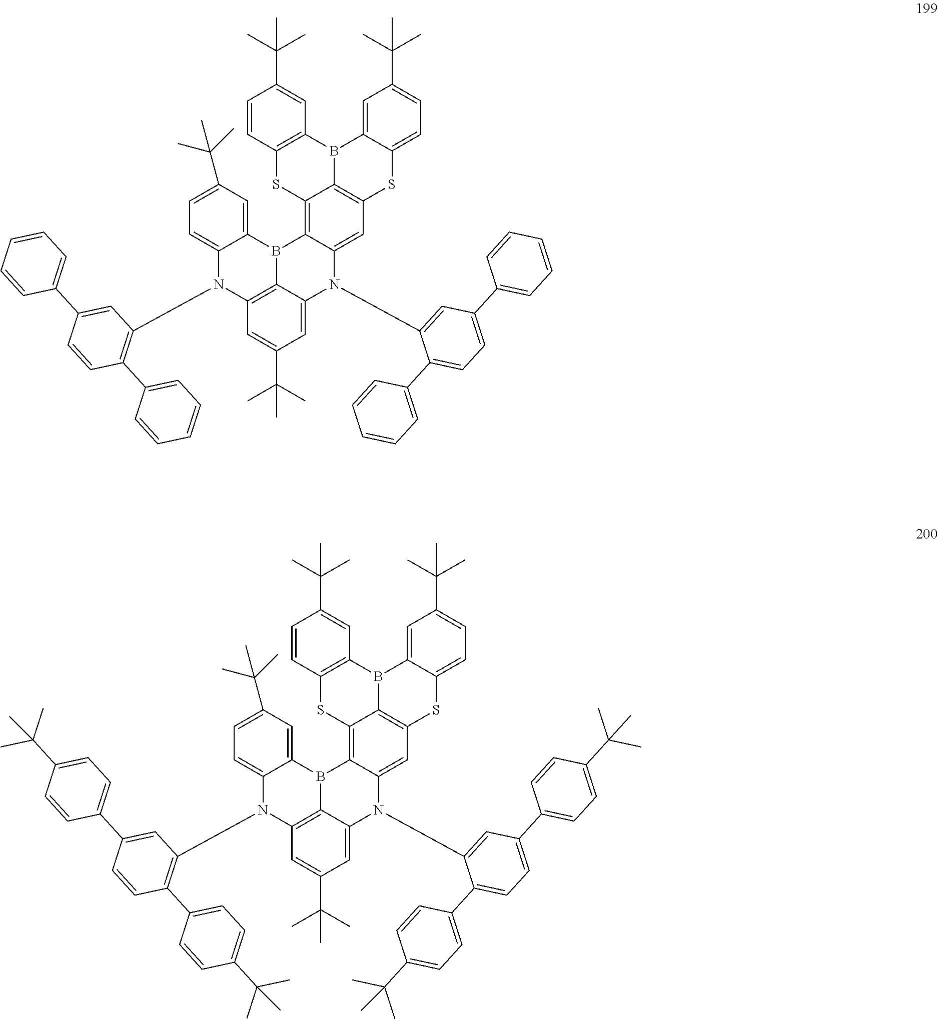 [SMILES: CC(C)(C)c1ccc2c(c1)B1c3cc(C(C)(C)C)ccc3Sc3c1c(cc1c3B3c4cc(C(C)(C)C)ccc4N(c4cc(-c5ccccc5)ccc4-c4ccccc4)c4cc(C(C)(C)C)cc(c43)N1c1cc(-c3ccccc3)ccc1-c1ccccc1)S2 ; CC(C)(C)c1ccc(-c2ccc(-c3ccc(C(C)(C)C)cc3)c(N3c4ccc(C(C)(C)C)cc4B4c5c3cc(C(C)(C)C)cc5N(c3cc(-c5ccc(C(C)(C)C)cc5)ccc3-c3ccc(C(C)(C)C)cc3)c3cc5c6c(c34)Sc3ccc(C(C)(C)C)cc3B6c3cc(C(C)(C)C)ccc3S5)c2)cc1]

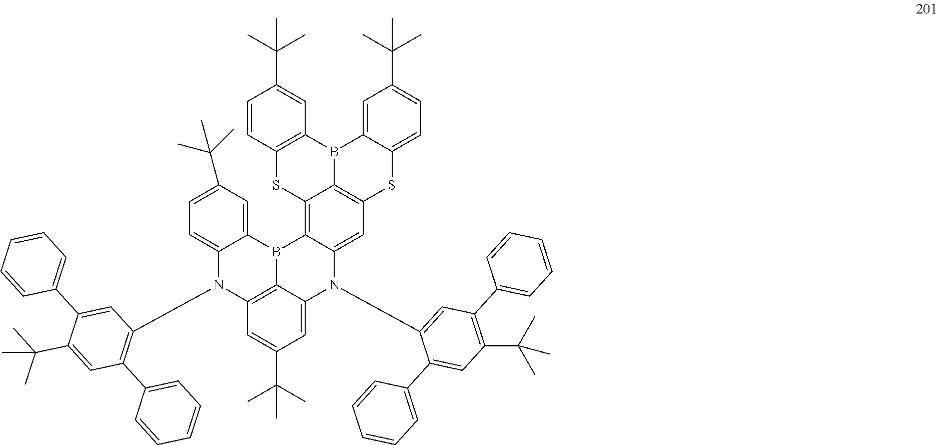 [SMILES: CC(C)(C)c1ccc2c(c1)B1c3cc(C(C)(C)C)ccc3Sc3c1c(cc1c3B3c4cc(C(C)(C)C)ccc4N(c4cc(-c5ccccc5)c(C(C)(C)C)cc4-c4ccccc4)c4cc(C(C)(C)C)cc(c43)N1c1cc(-c3ccccc3)c(C(C)(C)C)cc1-c1ccccc1)S2]

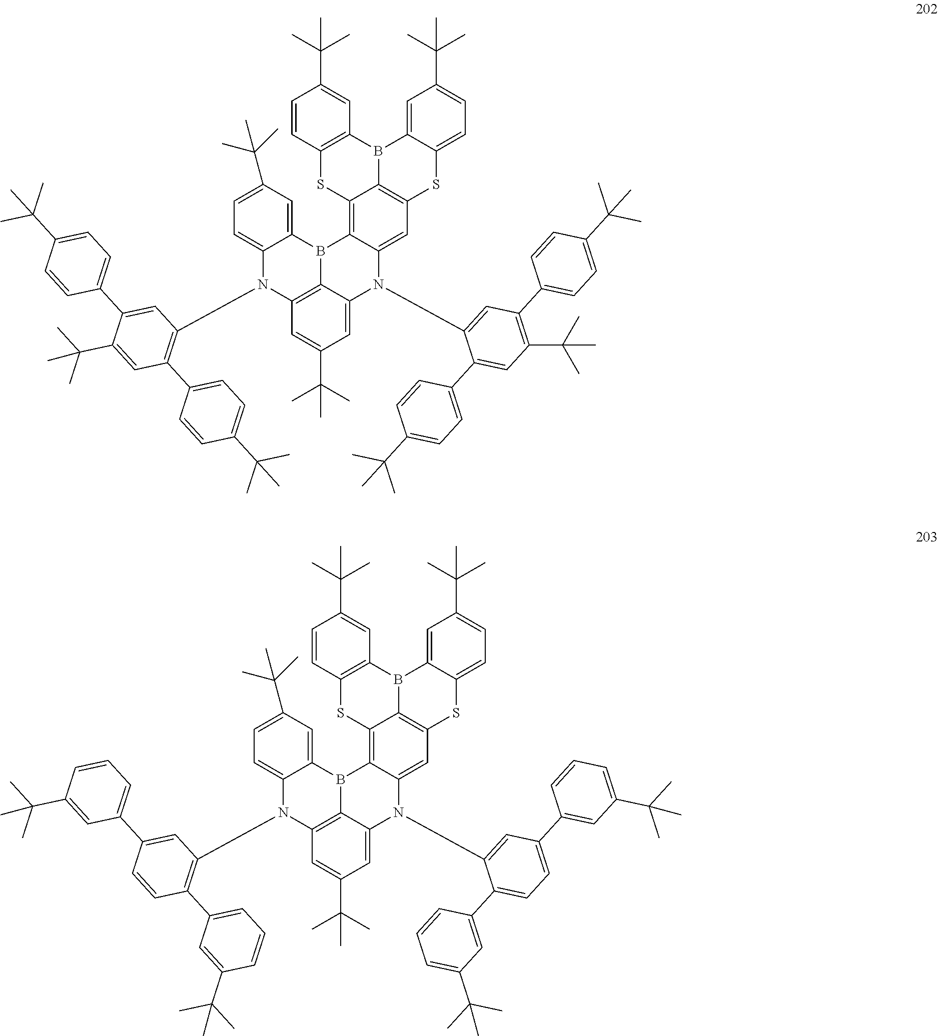

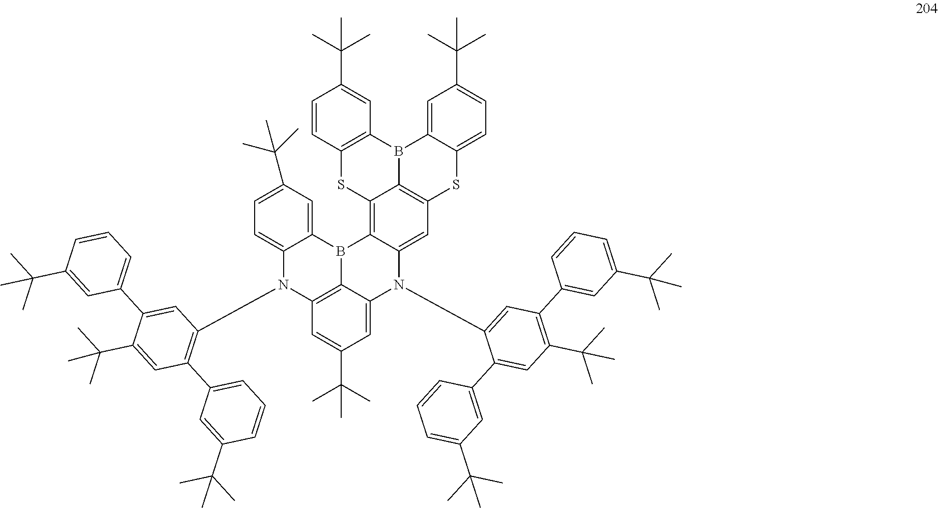 [SMILES: CC(C)(C)c1cccc(-c2cc(C(C)(C)C)c(-c3cccc(C(C)(C)C)c3)cc2N2c3ccc(C(C)(C)C)cc3B3c4c2cc(C(C)(C)C)cc4N(c2cc(-c4cccc(C(C)(C)C)c4)c(C(C)(C)C)cc2-c2cccc(C(C)(C)C)c2)c2cc4c5c(c23)Sc2ccc(C(C)(C)C)cc2B5c2cc(C(C)(C)C)ccc2S4)c1]

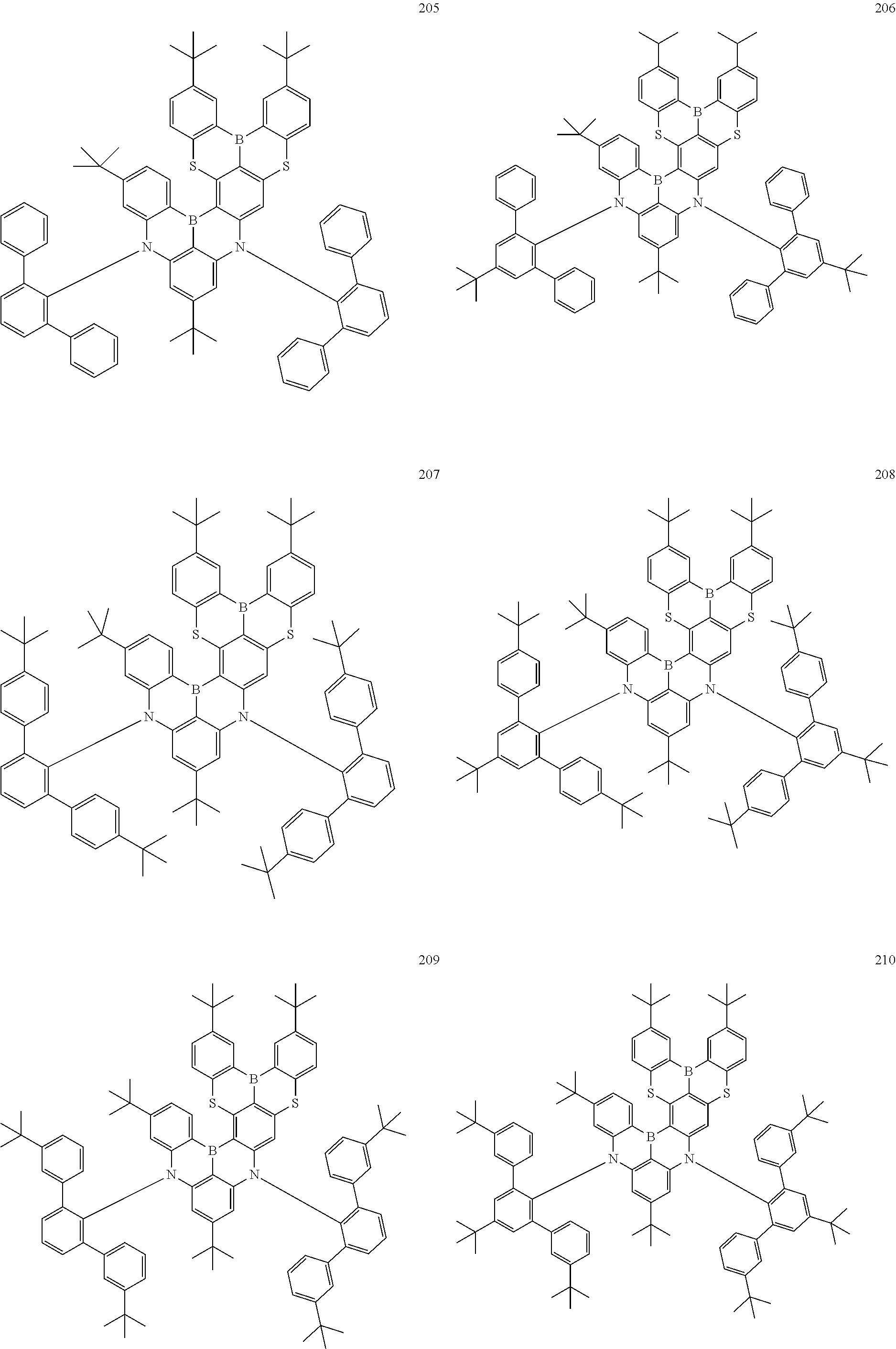

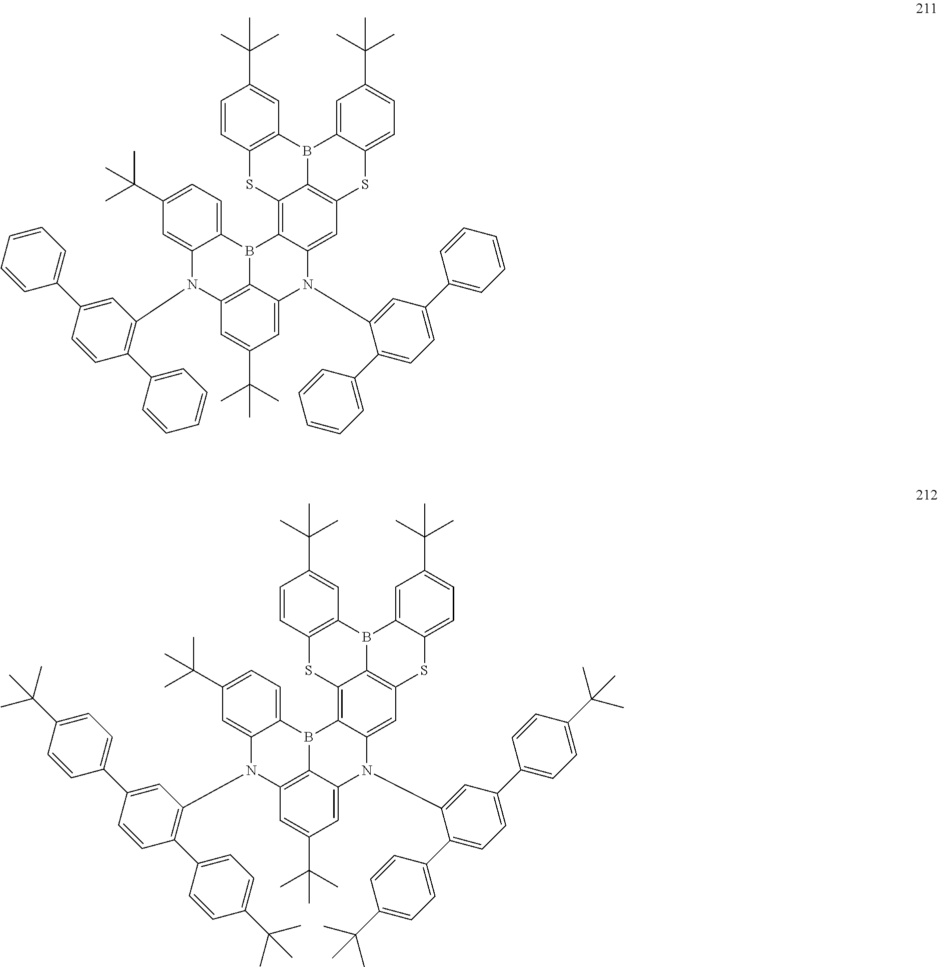 [SMILES: CC(C)(C)c1ccc2c(c1)B1c3cc(C(C)(C)C)ccc3Sc3c1c(cc1c3B3c4ccc(C(C)(C)C)cc4N(c4cc(-c5ccccc5)ccc4-c4ccccc4)c4cc(C(C)(C)C)cc(c43)N1c1cc(-c3ccccc3)ccc1-c1ccccc1)S2 ; CC(C)(C)c1ccc(-c2ccc(-c3ccc(C(C)(C)C)cc3)c(N3c4cc(C(C)(C)C)ccc4B4c5c3cc(C(C)(C)C)cc5N(c3cc(-c5ccc(C(C)(C)C)cc5)ccc3-c3ccc(C(C)(C)C)cc3)c3cc5c6c(c34)Sc3ccc(C(C)(C)C)cc3B6c3cc(C(C)(C)C)ccc3S5)c2)cc1]

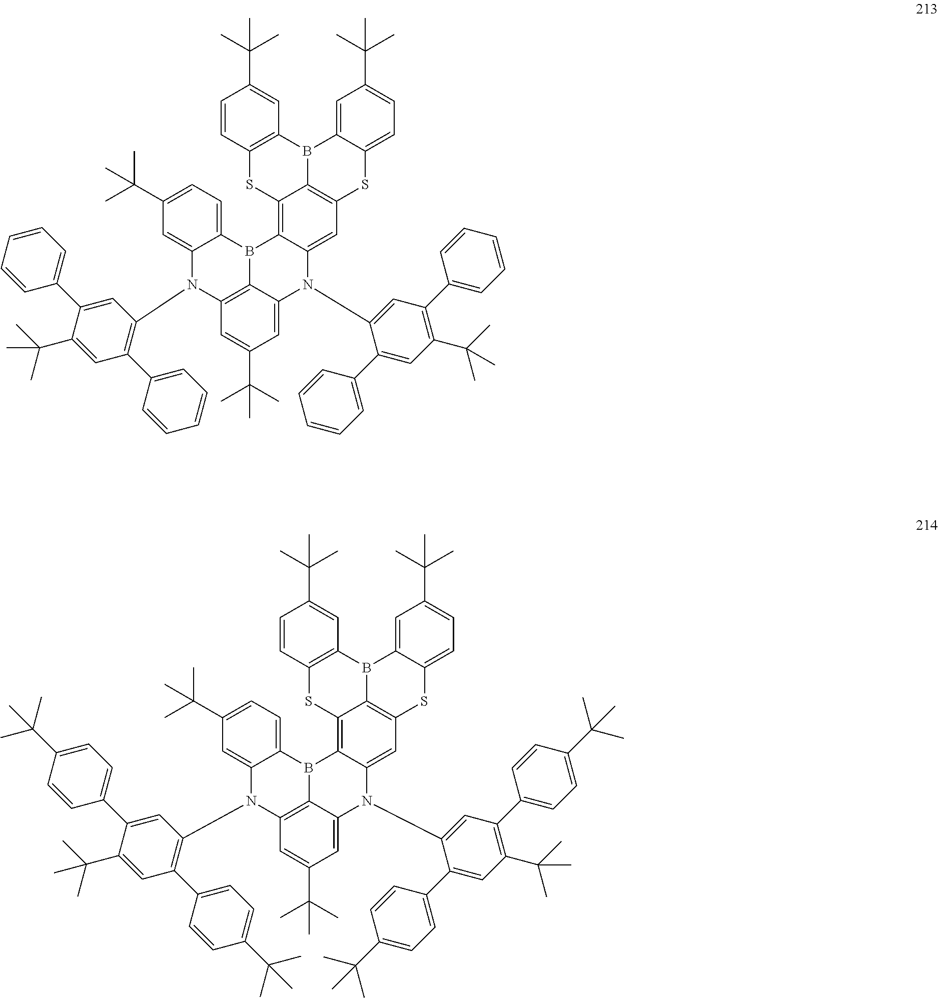 [SMILES: CC(C)(C)c1ccc2c(c1)B1c3cc(C(C)(C)C)ccc3Sc3c1c(cc1c3B3c4ccc(C(C)(C)C)cc4N(c4cc(-c5ccccc5)c(C(C)(C)C)cc4-c4ccccc4)c4cc(C(C)(C)C)cc(c43)N1c1cc(-c3ccccc3)c(C(C)(C)C)cc1-c1ccccc1)S2 ; CC(C)(C)c1ccc(-c2cc(C(C)(C)C)c(-c3ccc(C(C)(C)C)cc3)cc2N2c3cc(C(C)(C)C)ccc3B3c4c2cc(C(C)(C)C)cc4N(c2cc(-c4ccc(C(C)(C)C)cc4)c(C(C)(C)C)cc2-c2ccc(C(C)(C)C)cc2)c2cc4c5c(c23)Sc2ccc(C(C)(C)C)cc2B5c2cc(C(C)(C)C)ccc2S4)cc1]

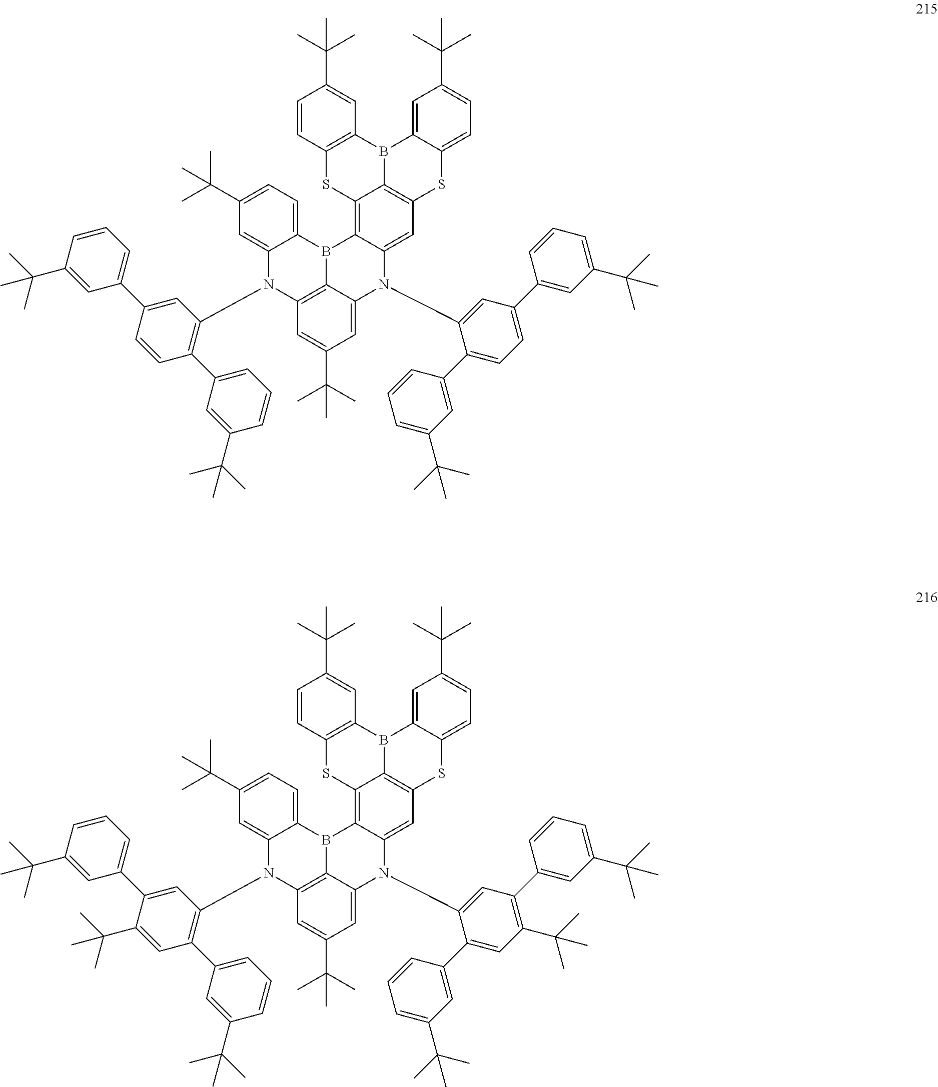

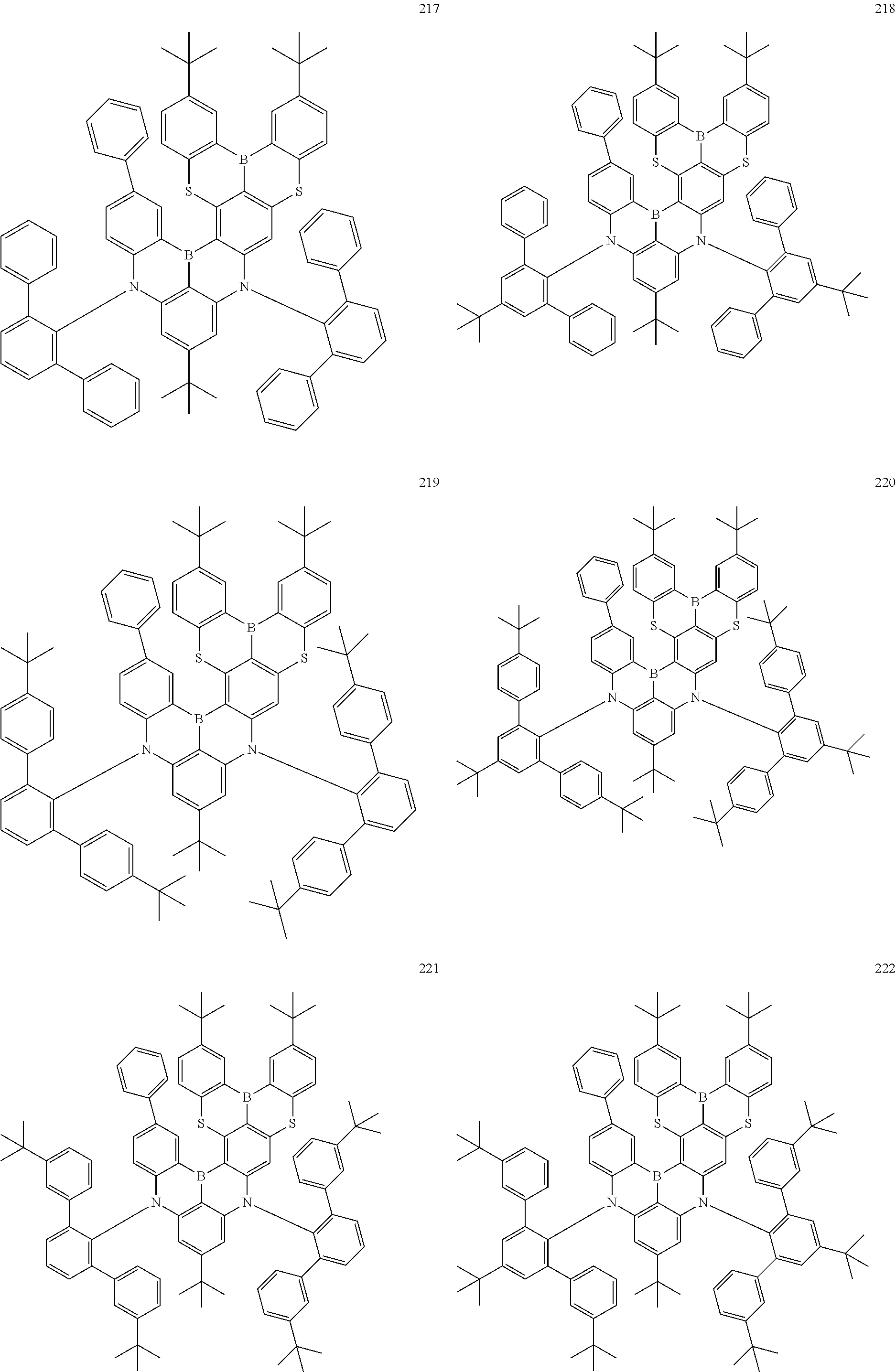

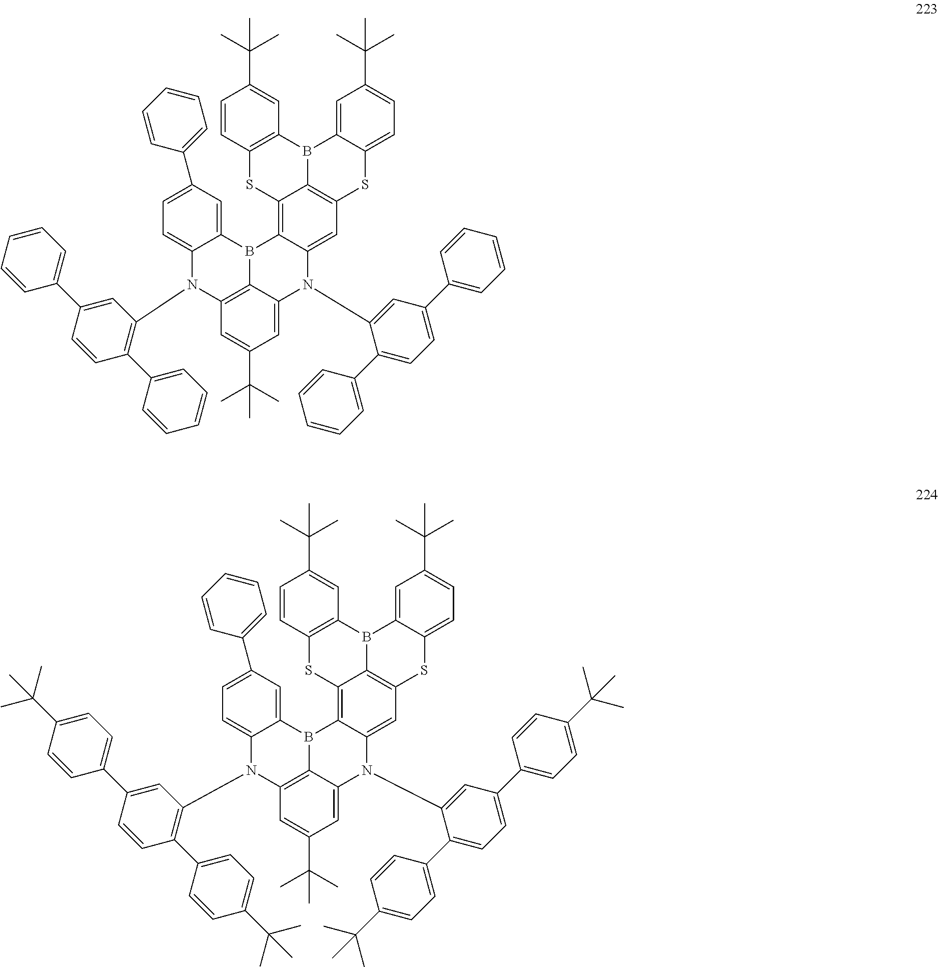 [SMILES: CC(C)(C)c1ccc2c(c1)B1c3cc(C(C)(C)C)ccc3Sc3c1c(cc1c3B3c4cc(-c5ccccc5)ccc4N(c4cc(-c5ccccc5)ccc4-c4ccccc4)c4cc(C(C)(C)C)cc(c43)N1c1cc(-c3ccccc3)ccc1-c1ccccc1)S2 ; CC(C)(C)c1ccc(-c2ccc(-c3ccc(C(C)(C)C)cc3)c(N3c4ccc(-c5ccccc5)cc4B4c5c3cc(C(C)(C)C)cc5N(c3cc(-c5ccc(C(C)(C)C)cc5)ccc3-c3ccc(C(C)(C)C)cc3)c3cc5c6c(c34)Sc3ccc(C(C)(C)C)cc3B6c3cc(C(C)(C)C)ccc3S5)c2)cc1]

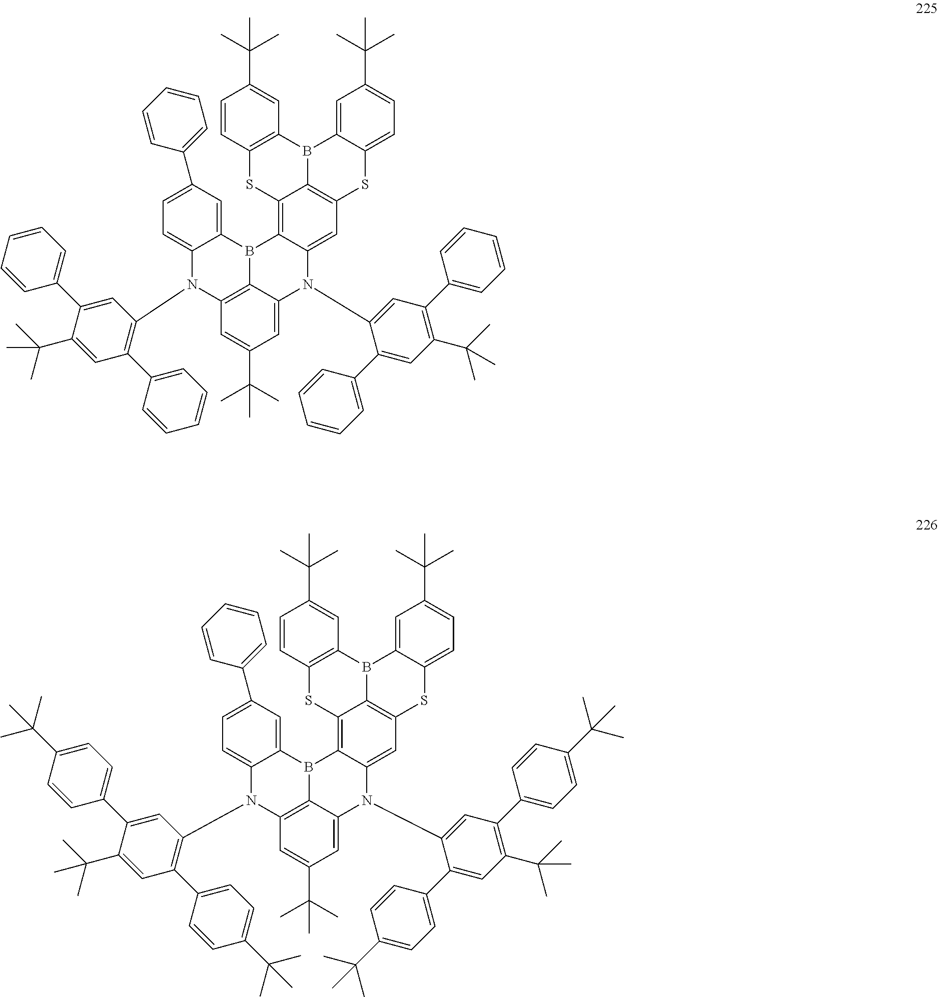 [SMILES: CC(C)(C)c1ccc2c(c1)B1c3cc(C(C)(C)C)ccc3Sc3c1c(cc1c3B3c4cc(-c5ccccc5)ccc4N(c4cc(-c5ccccc5)c(C(C)(C)C)cc4-c4ccccc4)c4cc(C(C)(C)C)cc(c43)N1c1cc(-c3ccccc3)c(C(C)(C)C)cc1-c1ccccc1)S2 ; CC(C)(C)c1ccc(-c2cc(C(C)(C)C)c(-c3ccc(C(C)(C)C)cc3)cc2N2c3ccc(-c4ccccc4)cc3B3c4c2cc(C(C)(C)C)cc4N(c2cc(-c4ccc(C(C)(C)C)cc4)c(C(C)(C)C)cc2-c2ccc(C(C)(C)C)cc2)c2cc4c5c(c23)Sc2ccc(C(C)(C)C)cc2B5c2cc(C(C)(C)C)ccc2S4)cc1]

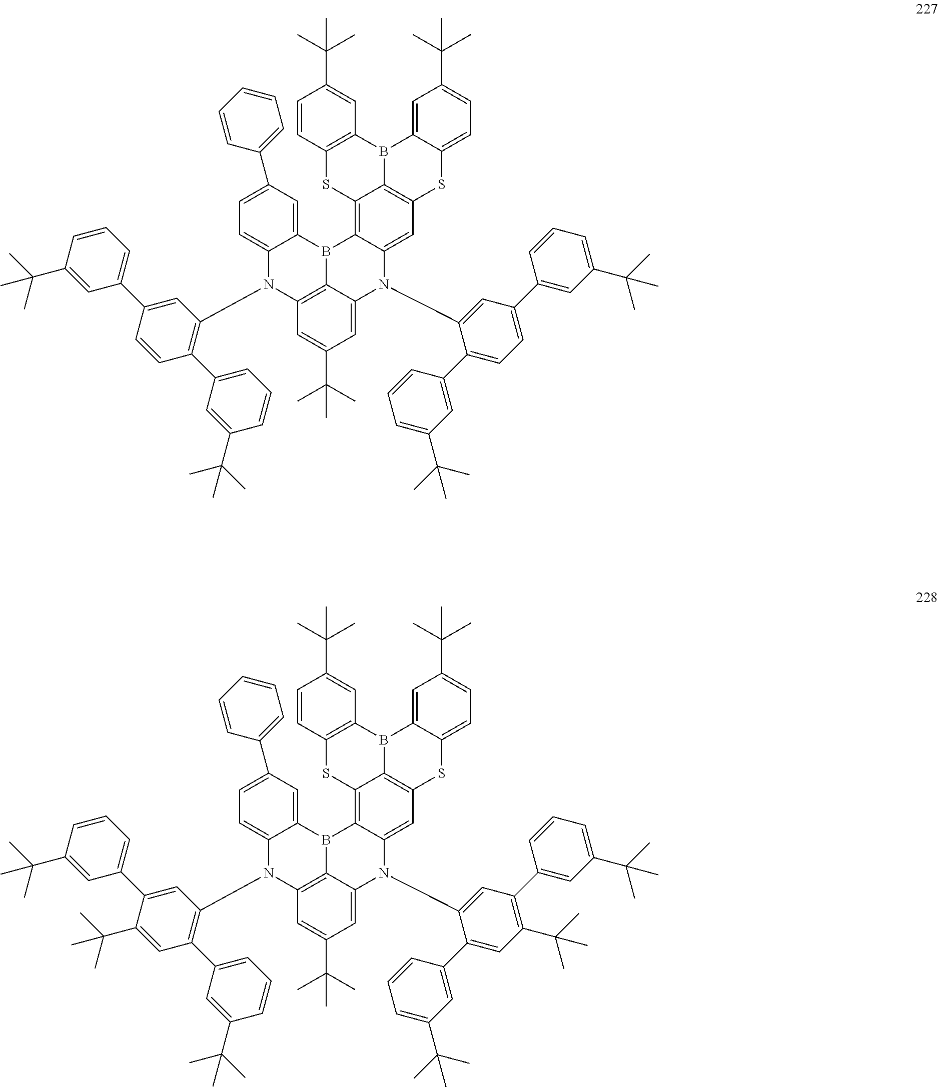

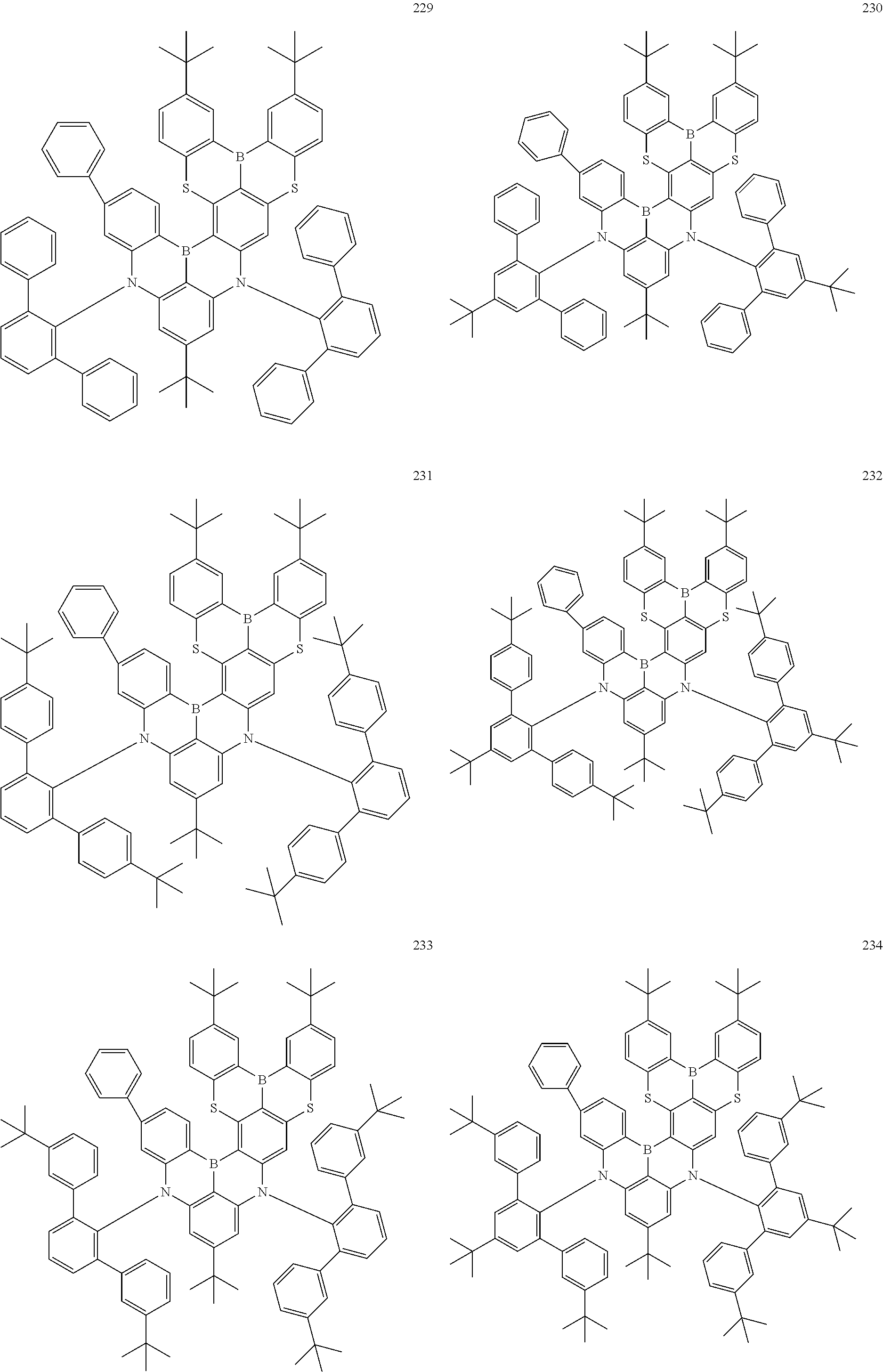

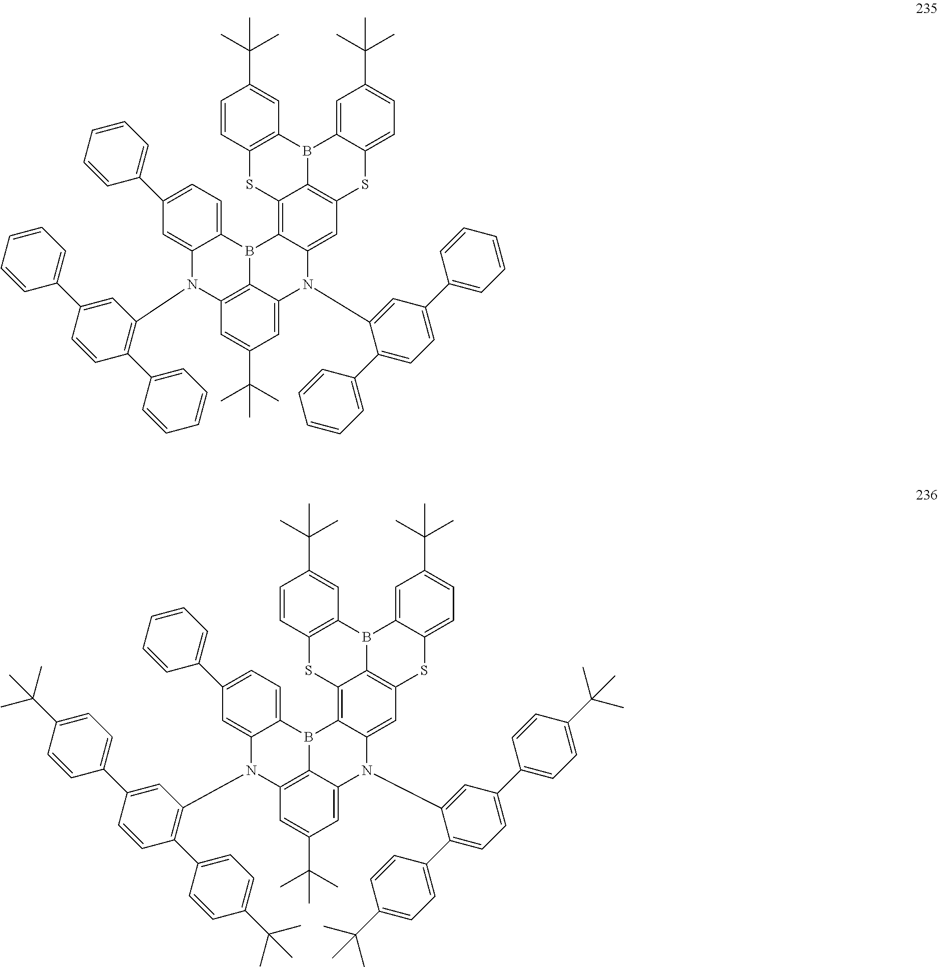 [SMILES: CC(C)(C)c1ccc2c(c1)B1c3cc(C(C)(C)C)ccc3Sc3c1c(cc1c3B3c4ccc(-c5ccccc5)cc4N(c4cc(-c5ccccc5)ccc4-c4ccccc4)c4cc(C(C)(C)C)cc(c43)N1c1cc(-c3ccccc3)ccc1-c1ccccc1)S2 ; CC(C)(C)c1ccc(-c2ccc(-c3ccc(C(C)(C)C)cc3)c(N3c4cc(-c5ccccc5)ccc4B4c5c3cc(C(C)(C)C)cc5N(c3cc(-c5ccc(C(C)(C)C)cc5)ccc3-c3ccc(C(C)(C)C)cc3)c3cc5c6c(c34)Sc3ccc(C(C)(C)C)cc3B6c3cc(C(C)(C)C)ccc3S5)c2)cc1]

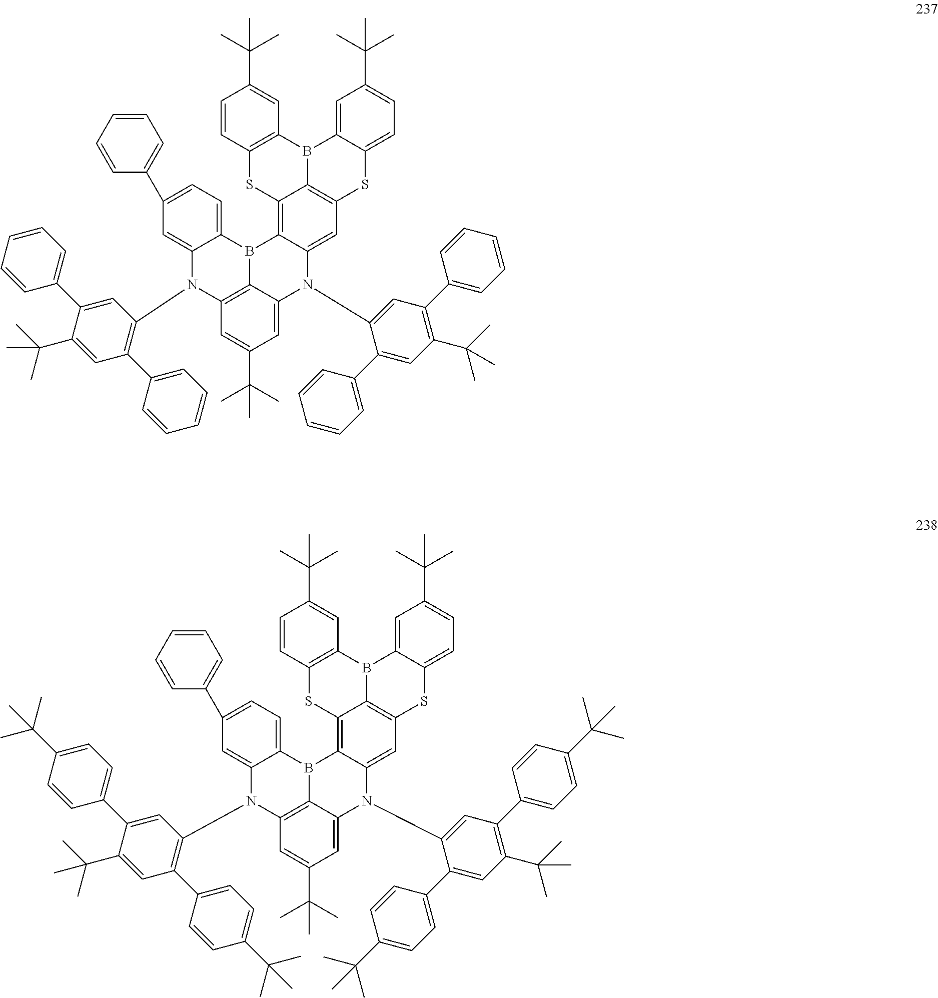 [SMILES: CC(C)(C)c1ccc2c(c1)B1c3cc(C(C)(C)C)ccc3Sc3c1c(cc1c3B3c4ccc(-c5ccccc5)cc4N(c4cc(-c5ccccc5)c(C(C)(C)C)cc4-c4ccccc4)c4cc(C(C)(C)C)cc(c43)N1c1cc(-c3ccccc3)c(C(C)(C)C)cc1-c1ccccc1)S2 ; CC(C)(C)c1ccc(-c2cc(C(C)(C)C)c(-c3ccc(C(C)(C)C)cc3)cc2N2c3cc(-c4ccccc4)ccc3B3c4c2cc(C(C)(C)C)cc4N(c2cc(-c4ccc(C(C)(C)C)cc4)c(C(C)(C)C)cc2-c2ccc(C(C)(C)C)cc2)c2cc4c5c(c23)Sc2ccc(C(C)(C)C)cc2B5c2cc(C(C)(C)C)ccc2S4)cc1]

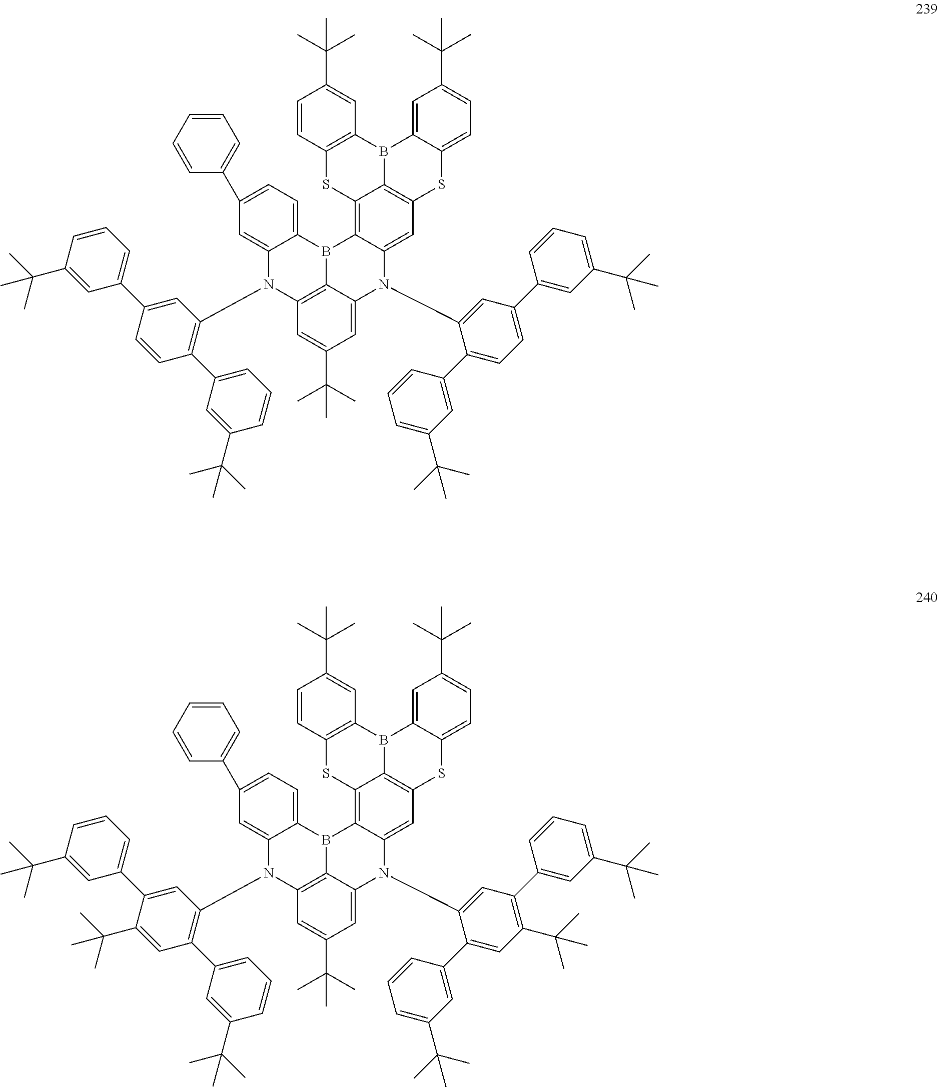

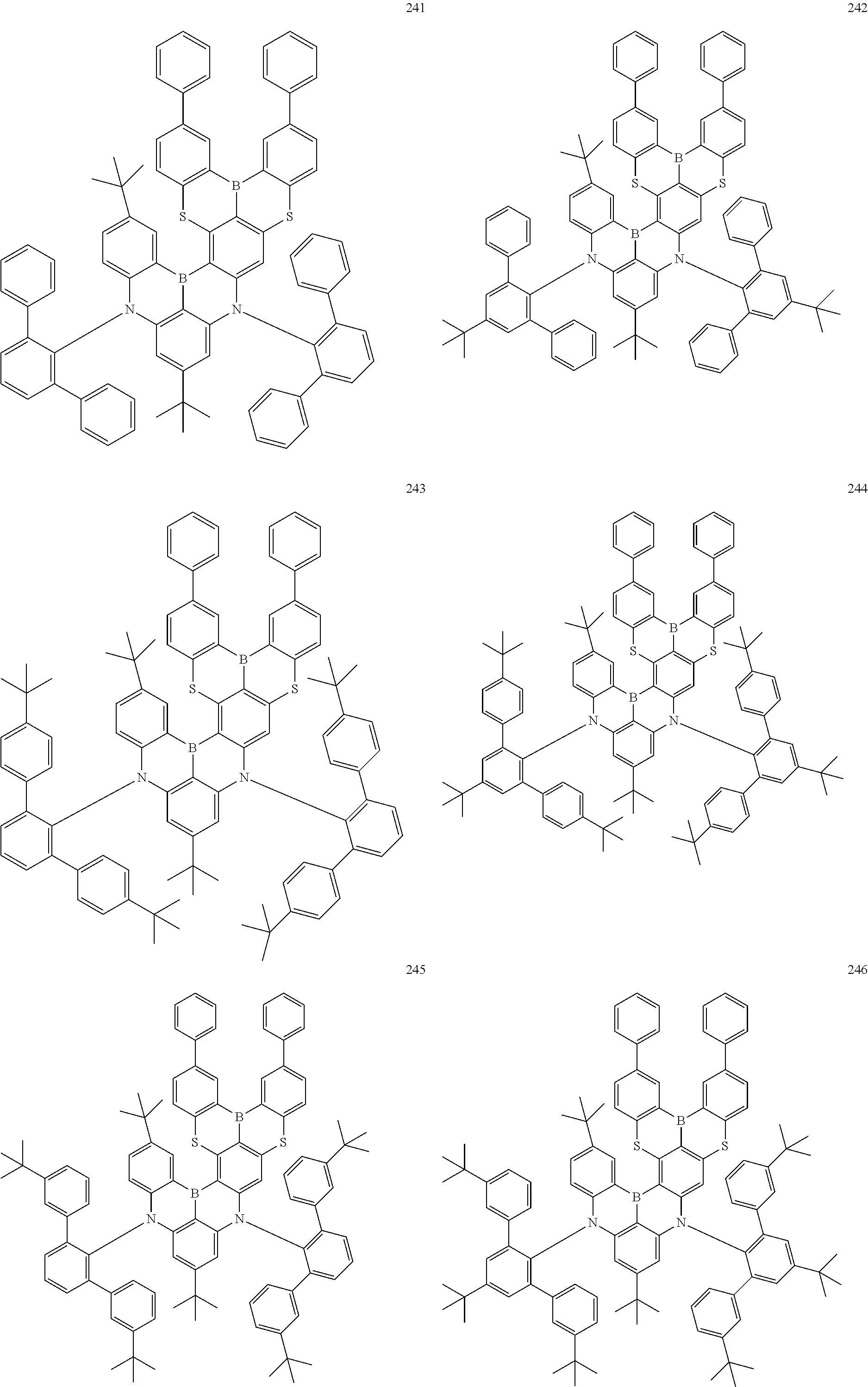

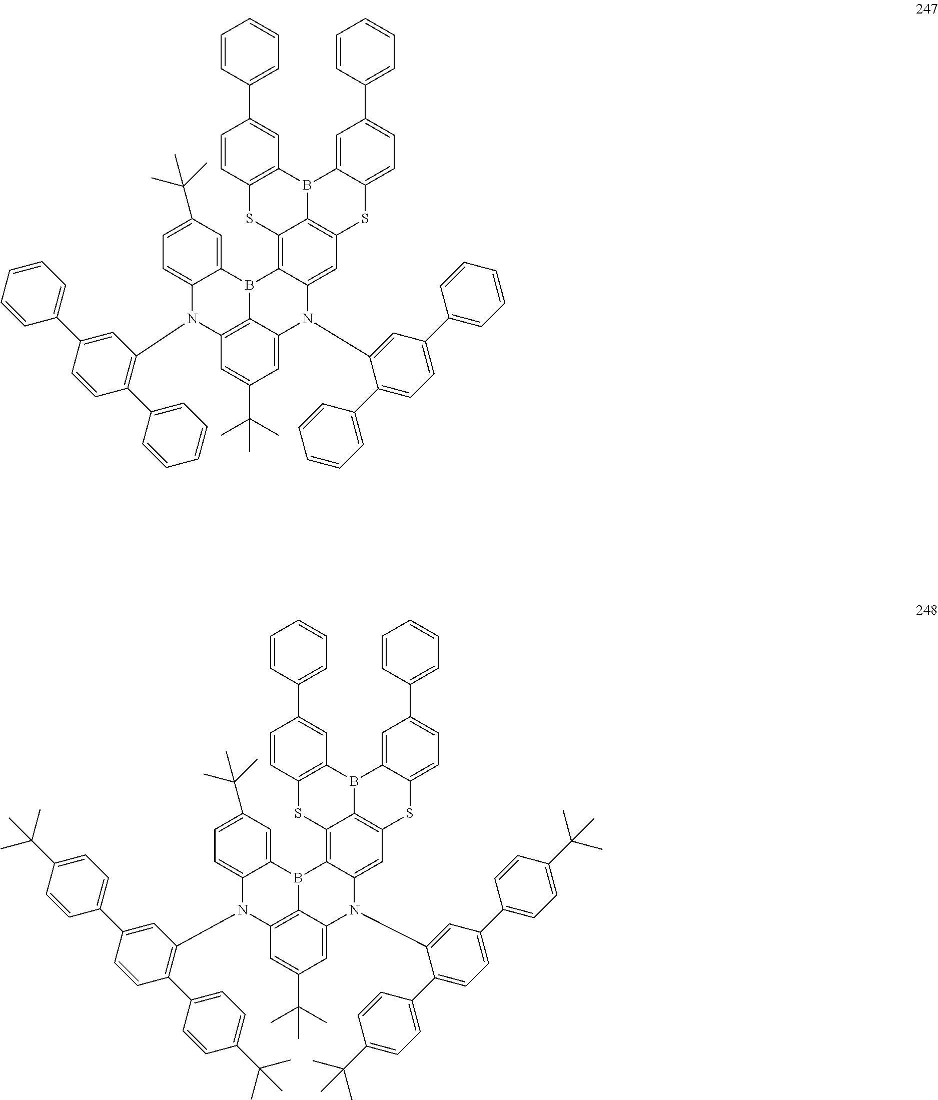 [SMILES: CC(C)(C)c1ccc2c(c1)B1c3c(cc(C(C)(C)C)cc3N(c3cc(-c4ccccc4)ccc3-c3ccccc3)c3cc4c5c(c31)Sc1ccc(-c3ccccc3)cc1B5c1cc(-c3ccccc3)ccc1S4)N2c1cc(-c2ccccc2)ccc1-c1ccccc1 ; CC(C)(C)c1ccc(-c2ccc(-c3ccc(C(C)(C)C)cc3)c(N3c4ccc(C(C)(C)C)cc4B4c5c3cc(C(C)(C)C)cc5N(c3cc(-c5ccc(C(C)(C)C)cc5)ccc3-c3ccc(C(C)(C)C)cc3)c3cc5c6c(c34)Sc3ccc(-c4ccccc4)cc3B6c3cc(-c4ccccc4)ccc3S5)c2)cc1]

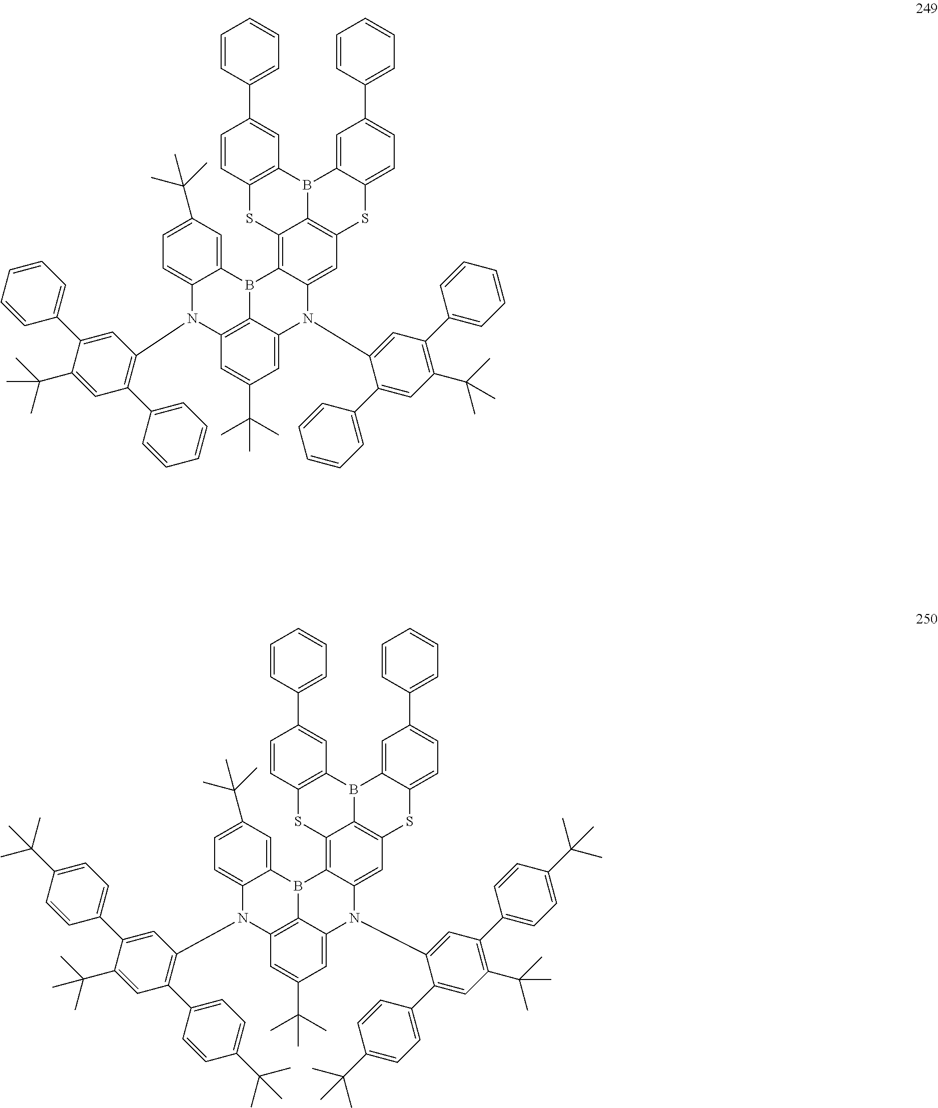 [SMILES: CC(C)(C)c1ccc2c(c1)B1c3c(cc(C(C)(C)C)cc3N(c3cc(-c4ccccc4)c(C(C)(C)C)cc3-c3ccccc3)c3cc4c5c(c31)Sc1ccc(-c3ccccc3)cc1B5c1cc(-c3ccccc3)ccc1S4)N2c1cc(-c2ccccc2)c(C(C)(C)C)cc1-c1ccccc1 ; CC(C)(C)c1ccc(-c2cc(C(C)(C)C)c(-c3ccc(C(C)(C)C)cc3)cc2N2c3ccc(C(C)(C)C)cc3B3c4c2cc(C(C)(C)C)cc4N(c2cc(-c4ccc(C(C)(C)C)cc4)c(C(C)(C)C)cc2-c2ccc(C(C)(C)C)cc2)c2cc4c5c(c23)Sc2ccc(-c3ccccc3)cc2B5c2cc(-c3ccccc3)ccc2S4)cc1]

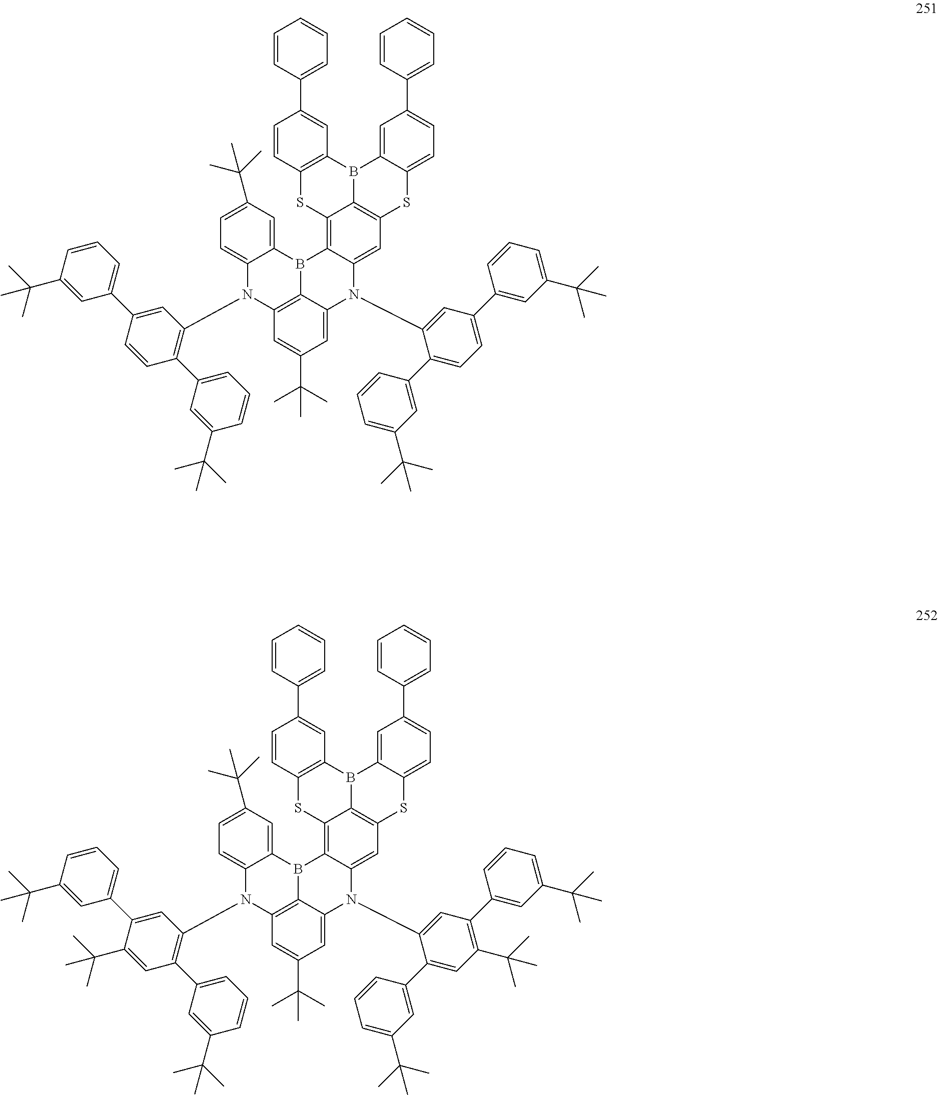

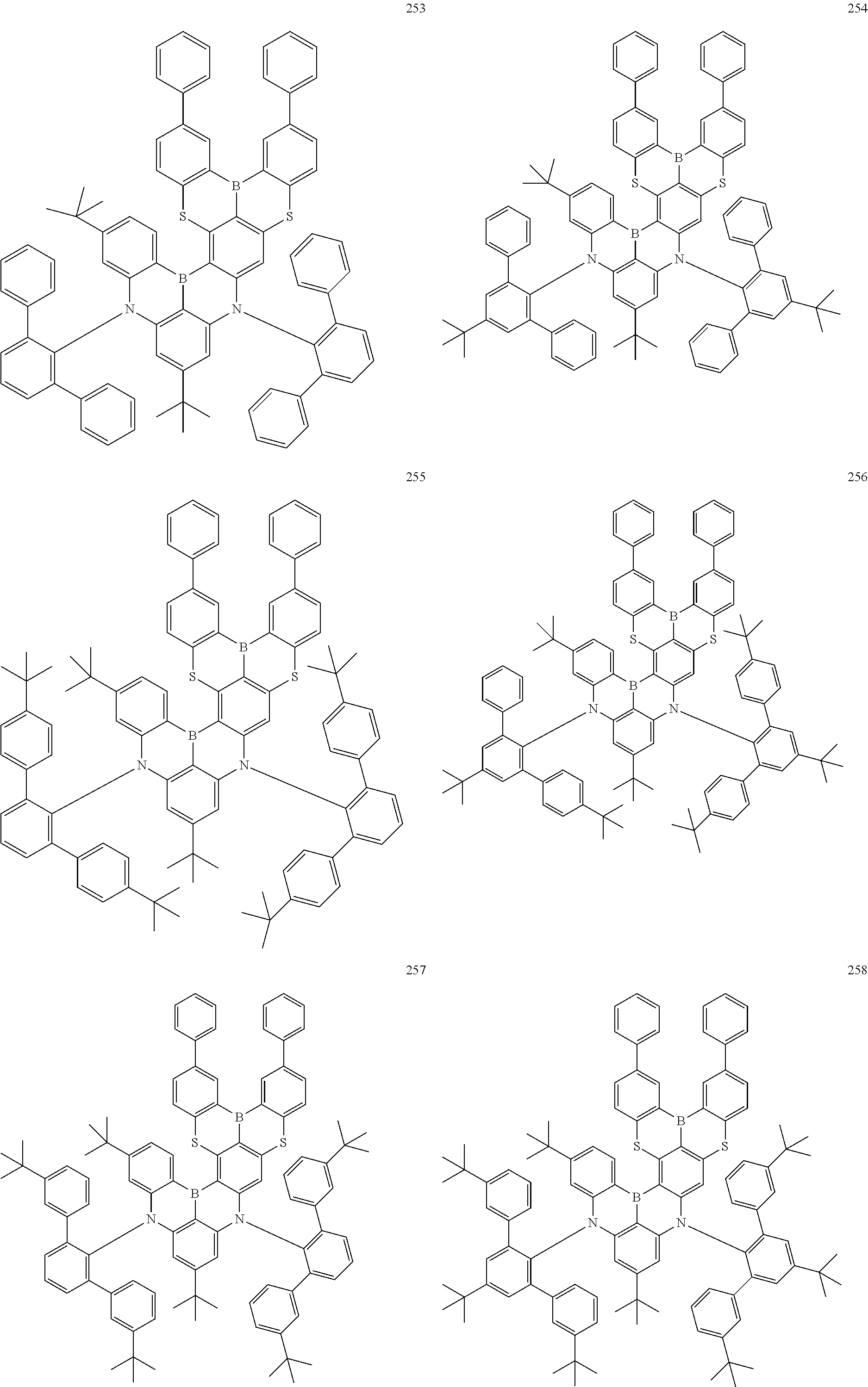

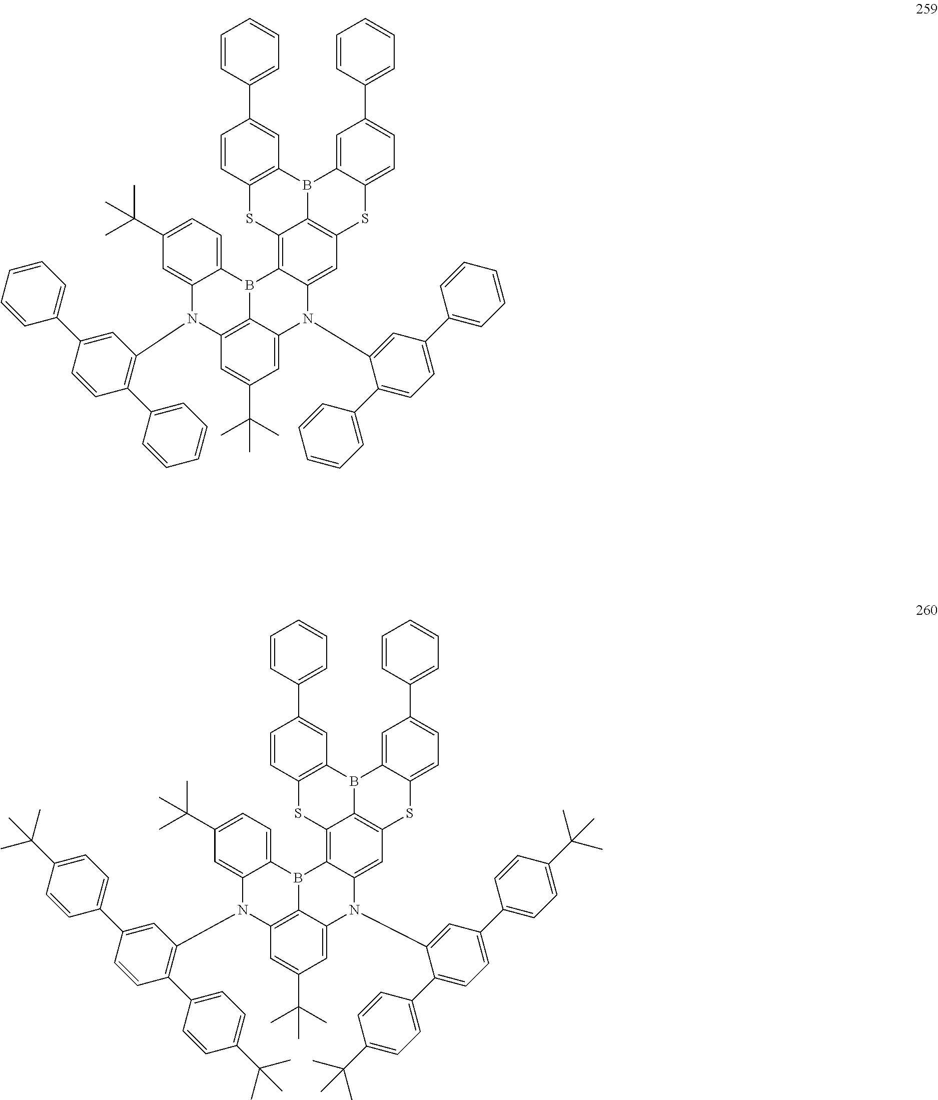 [SMILES: CC(C)(C)c1ccc2c(c1)N(c1cc(-c3ccccc3)ccc1-c1ccccc1)c1cc(C(C)(C)C)cc3c1B2c1c(cc2c4c1Sc1ccc(-c5ccccc5)cc1B4c1cc(-c4ccccc4)ccc1S2)N3c1cc(-c2ccccc2)ccc1-c1ccccc1 ; CC(C)(C)c1ccc(-c2ccc(-c3ccc(C(C)(C)C)cc3)c(N3c4cc(C(C)(C)C)ccc4B4c5c3cc(C(C)(C)C)cc5N(c3cc(-c5ccc(C(C)(C)C)cc5)ccc3-c3ccc(C(C)(C)C)cc3)c3cc5c6c(c34)Sc3ccc(-c4ccccc4)cc3B6c3cc(-c4ccccc4)ccc3S5)c2)cc1]

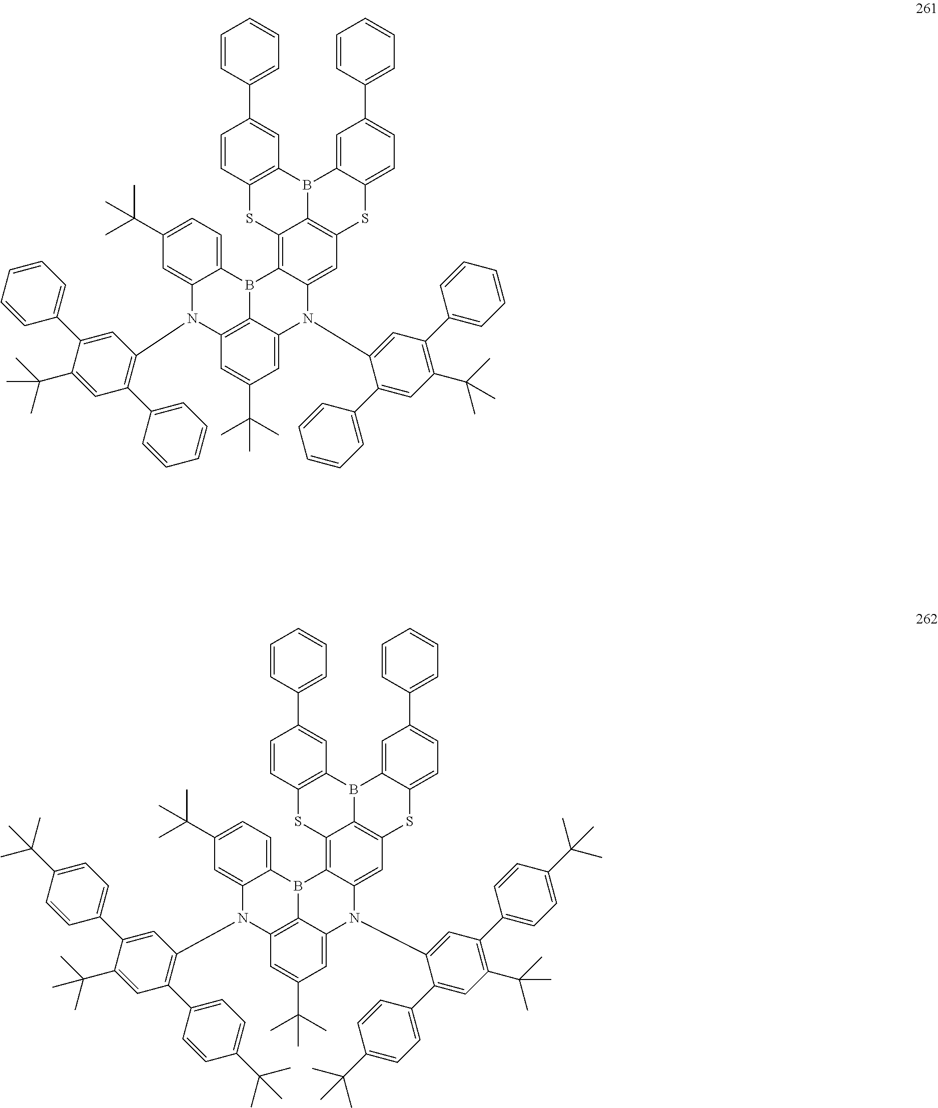 [SMILES: CC(C)(C)c1ccc2c(c1)N(c1cc(-c3ccccc3)c(C(C)(C)C)cc1-c1ccccc1)c1cc(C(C)(C)C)cc3c1B2c1c(cc2c4c1Sc1ccc(-c5ccccc5)cc1B4c1cc(-c4ccccc4)ccc1S2)N3c1cc(-c2ccccc2)c(C(C)(C)C)cc1-c1ccccc1 ; CC(C)(C)c1ccc(-c2cc(C(C)(C)C)c(-c3ccc(C(C)(C)C)cc3)cc2N2c3cc(C(C)(C)C)ccc3B3c4c2cc(C(C)(C)C)cc4N(c2cc(-c4ccc(C(C)(C)C)cc4)c(C(C)(C)C)cc2-c2ccc(C(C)(C)C)cc2)c2cc4c5c(c23)Sc2ccc(-c3ccccc3)cc2B5c2cc(-c3ccccc3)ccc2S4)cc1]

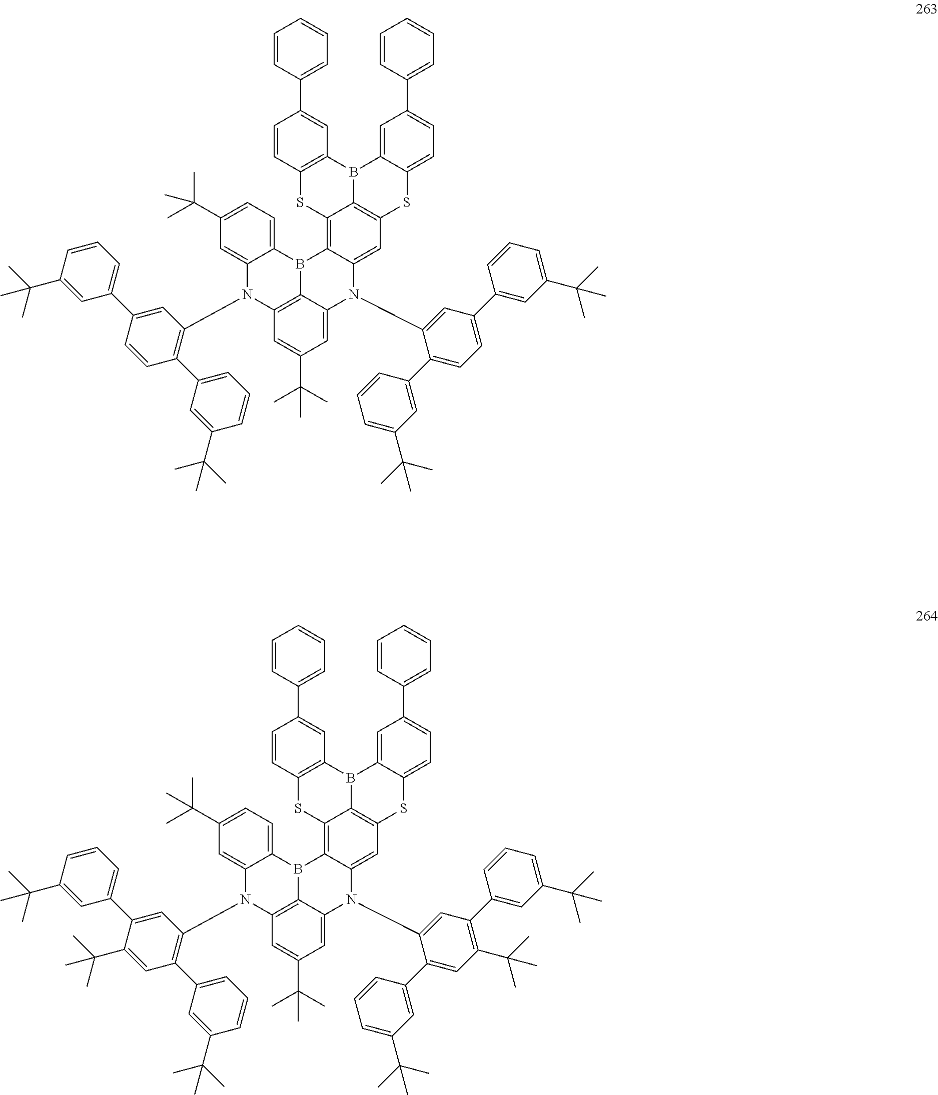

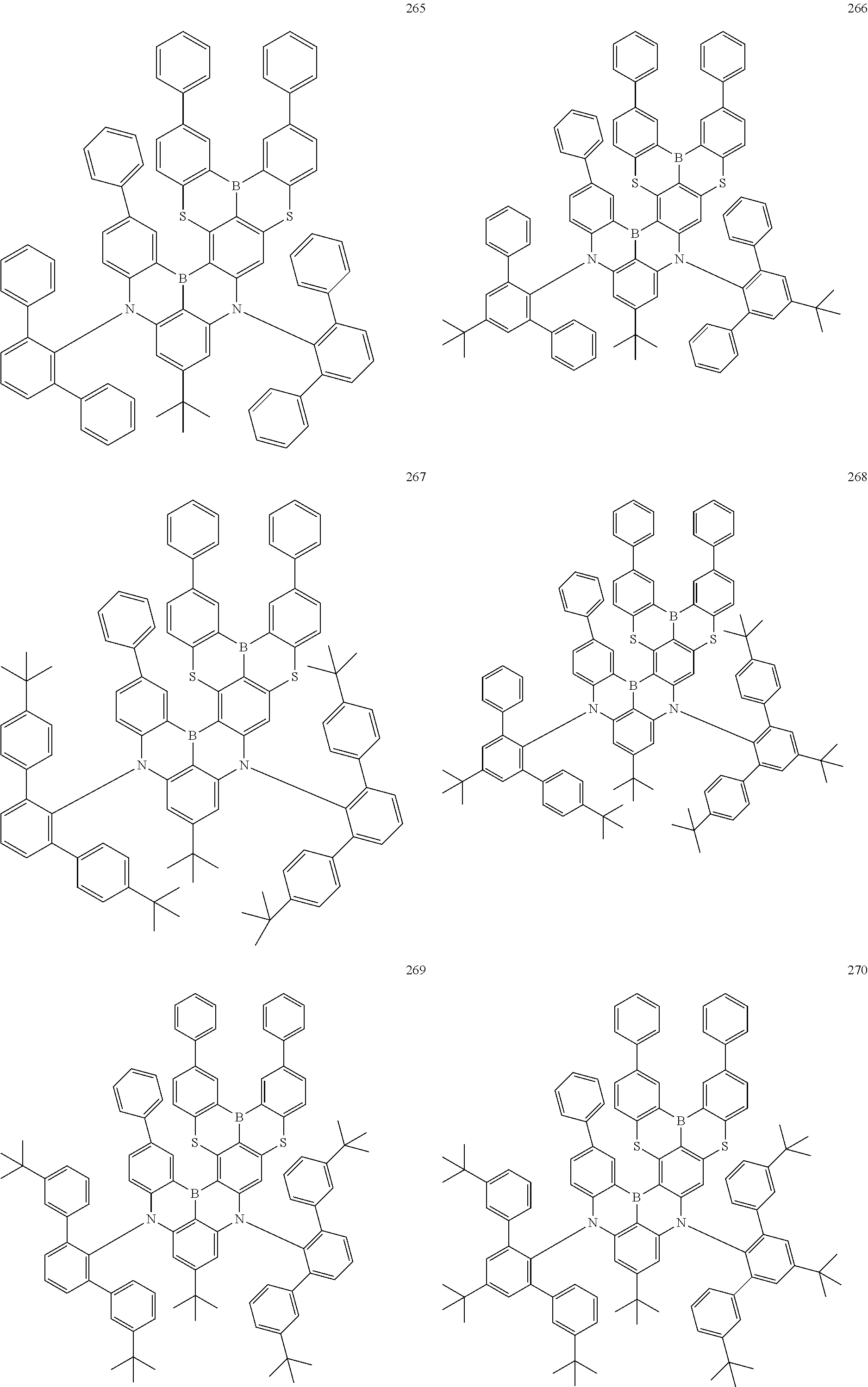

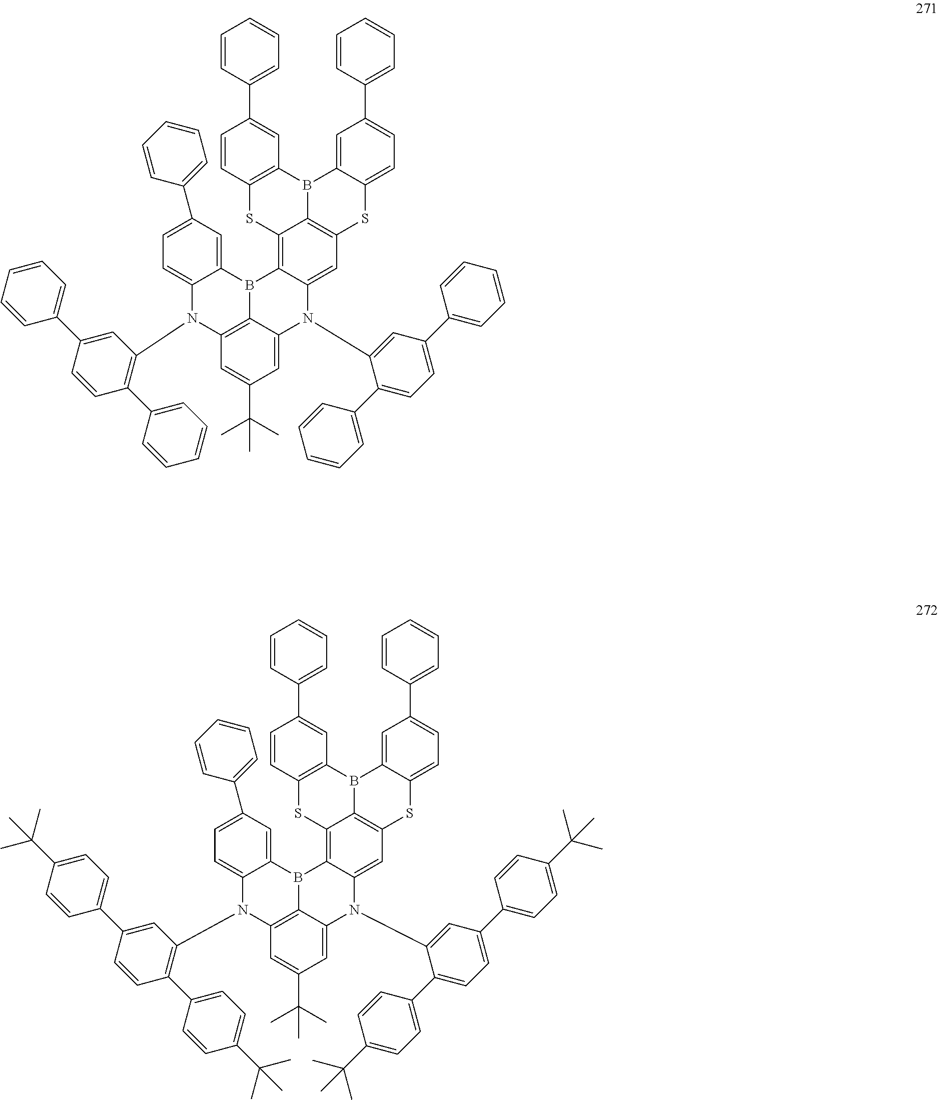 [SMILES: CC(C)(C)c1cc2c3c(c1)N(c1cc(-c4ccccc4)ccc1-c1ccccc1)c1cc4c5c(c1B3c1cc(-c3ccccc3)ccc1N2c1cc(-c2ccccc2)ccc1-c1ccccc1)Sc1ccc(-c2ccccc2)cc1B5c1cc(-c2ccccc2)ccc1S4 ; CC(C)(C)c1ccc(-c2ccc(-c3ccc(C(C)(C)C)cc3)c(N3c4ccc(-c5ccccc5)cc4B4c5c3cc(C(C)(C)C)cc5N(c3cc(-c5ccc(C(C)(C)C)cc5)ccc3-c3ccc(C(C)(C)C)cc3)c3cc5c6c(c34)Sc3ccc(-c4ccccc4)cc3B6c3cc(-c4ccccc4)ccc3S5)c2)cc1]

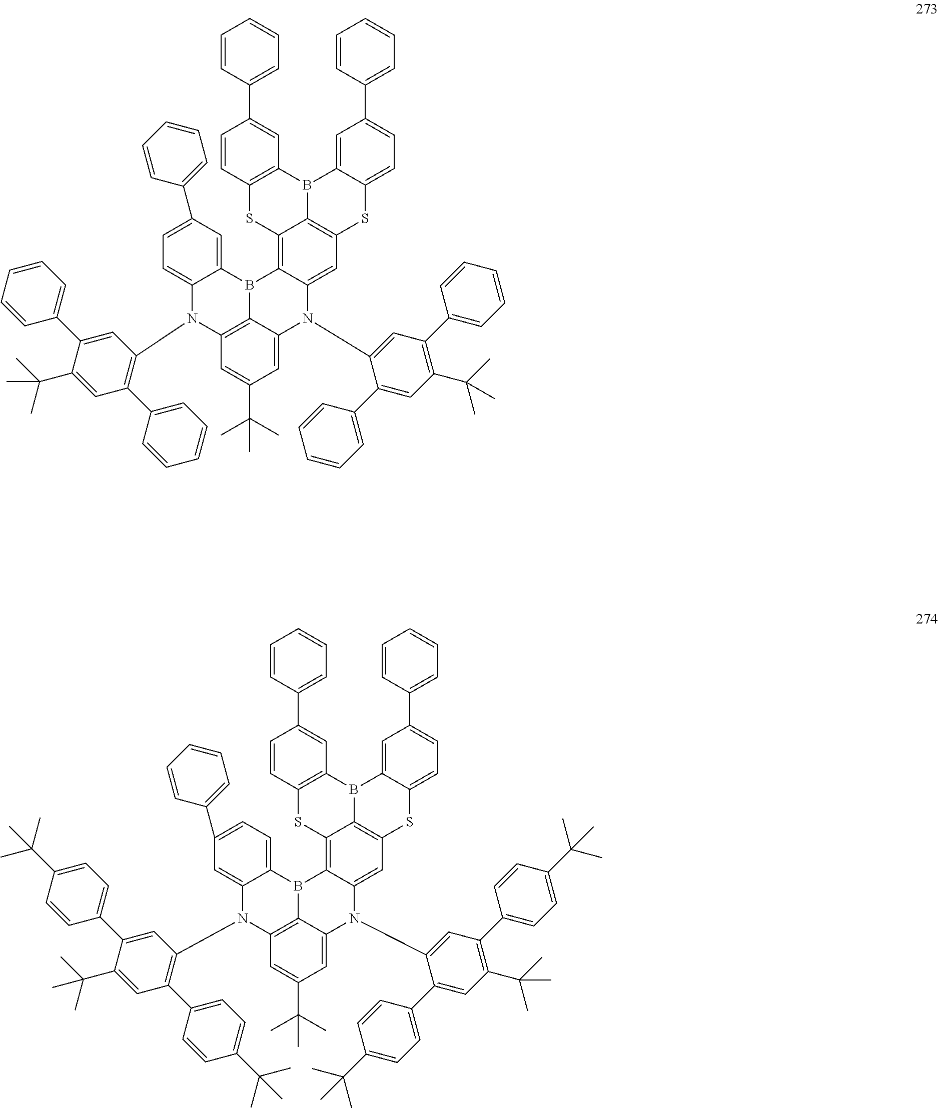 [SMILES: CC(C)(C)c1cc2c3c(c1)N(c1cc(-c4ccccc4)c(C(C)(C)C)cc1-c1ccccc1)c1cc4c5c(c1B3c1cc(-c3ccccc3)ccc1N2c1cc(-c2ccccc2)c(C(C)(C)C)cc1-c1ccccc1)Sc1ccc(-c2ccccc2)cc1B5c1cc(-c2ccccc2)ccc1S4 ; CC(C)(C)c1ccc(-c2cc(C(C)(C)C)c(-c3ccc(C(C)(C)C)cc3)cc2N2c3cc(-c4ccccc4)ccc3B3c4c2cc(C(C)(C)C)cc4N(c2cc(-c4ccc(C(C)(C)C)cc4)c(C(C)(C)C)cc2-c2ccc(C(C)(C)C)cc2)c2cc4c5c(c23)Sc2ccc(-c3ccccc3)cc2B5c2cc(-c3ccccc3)ccc2S4)cc1]

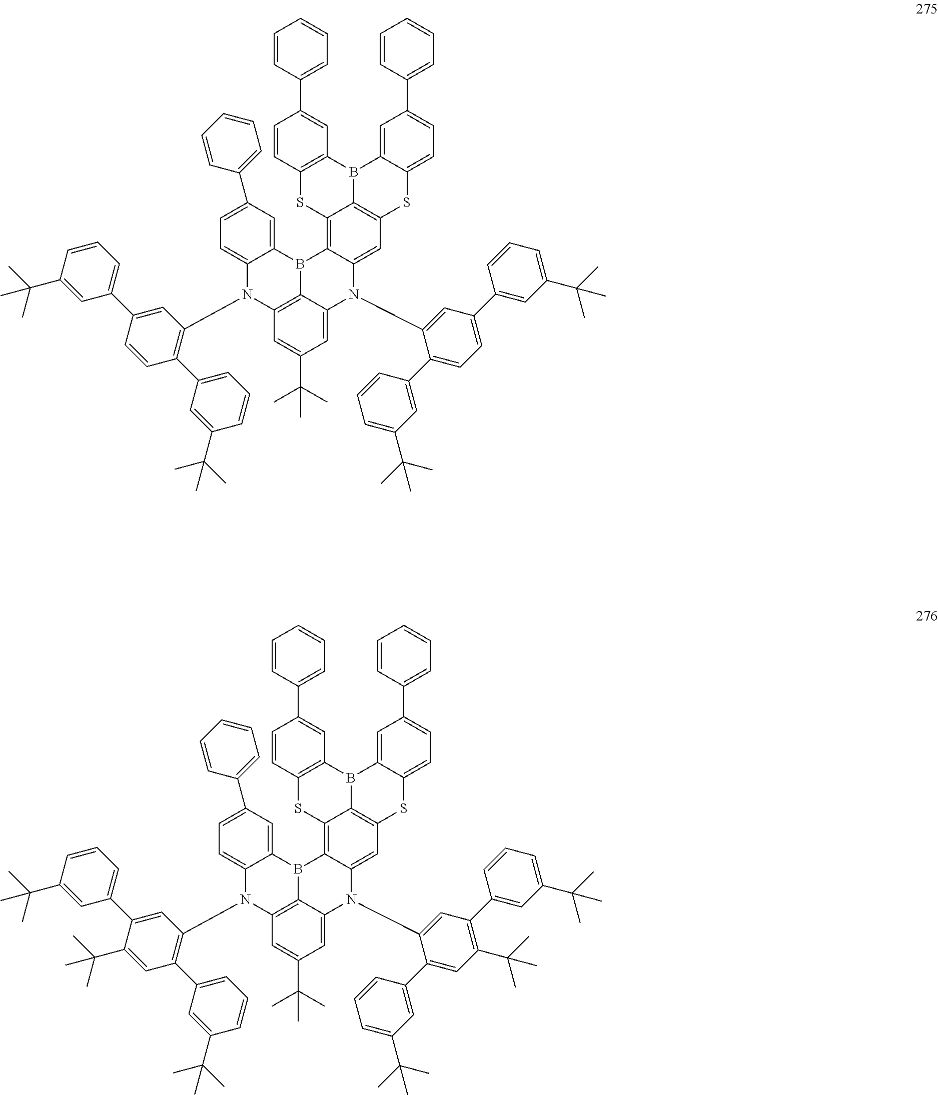

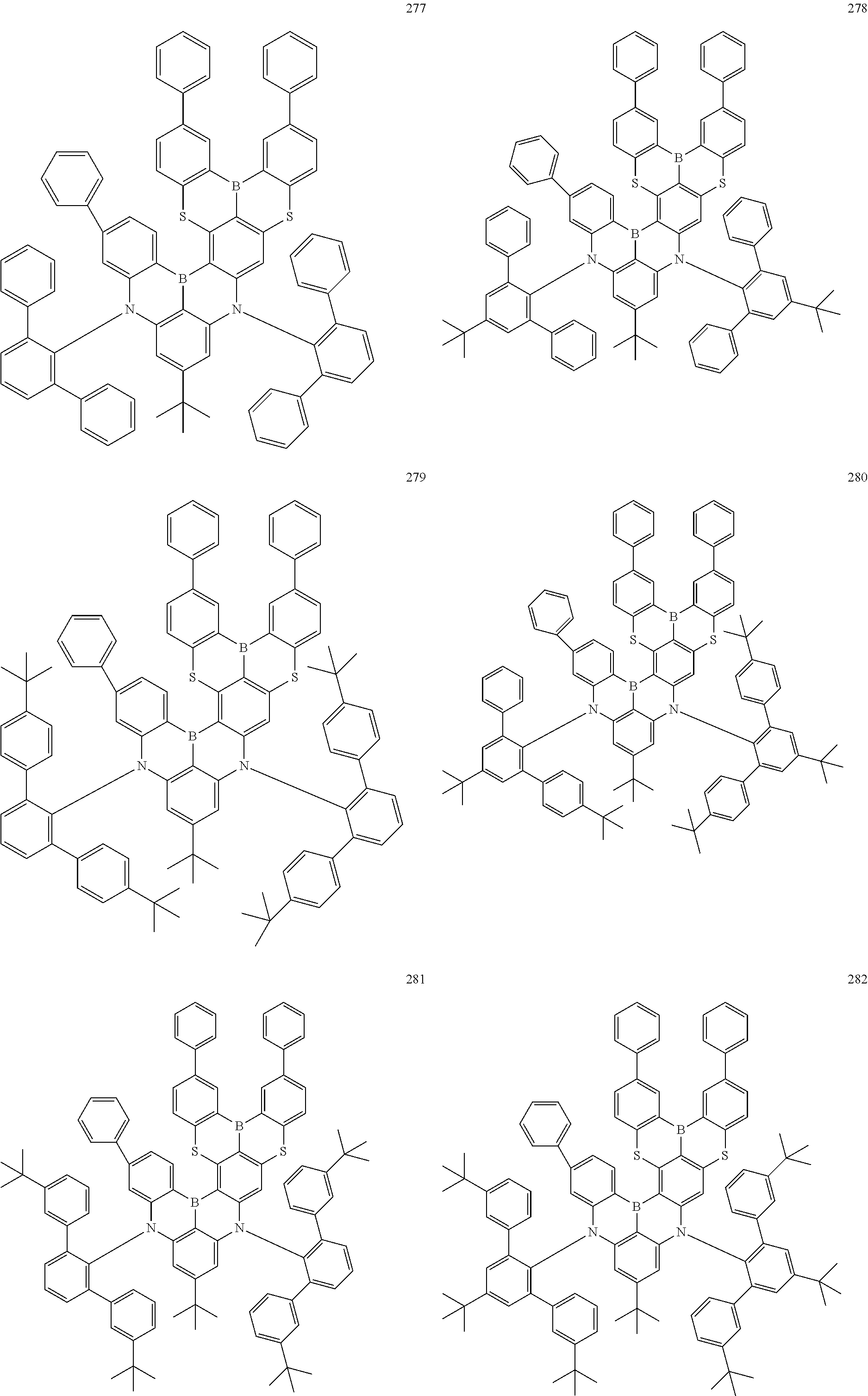

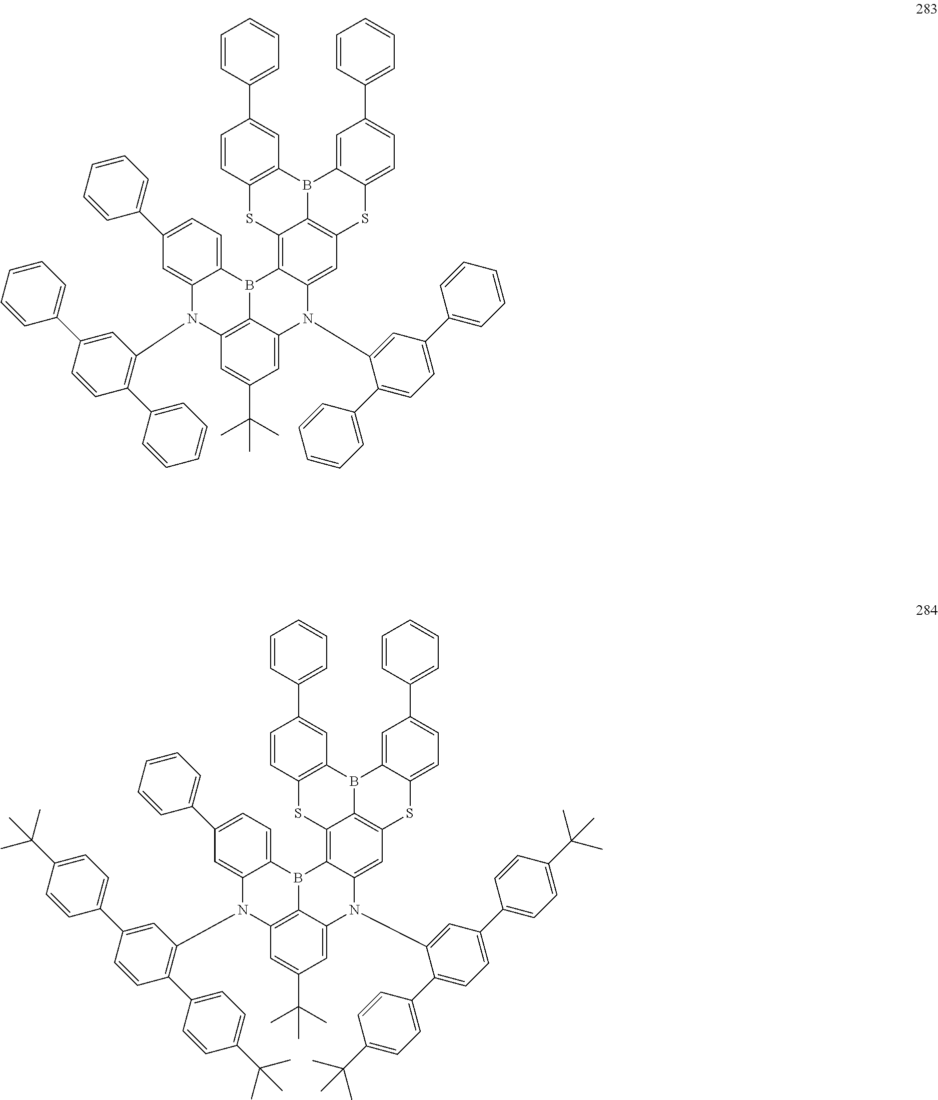 [SMILES: CC(C)(C)c1cc2c3c(c1)N(c1cc(-c4ccccc4)ccc1-c1ccccc1)c1cc4c5c(c1B3c1ccc(-c3ccccc3)cc1N2c1cc(-c2ccccc2)ccc1-c1ccccc1)Sc1ccc(-c2ccccc2)cc1B5c1cc(-c2ccccc2)ccc1S4 ; CC(C)(C)c1ccc(-c2ccc(-c3ccc(C(C)(C)C)cc3)c(N3c4cc(-c5ccccc5)ccc4B4c5c3cc(C(C)(C)C)cc5N(c3cc(-c5ccc(C(C)(C)C)cc5)ccc3-c3ccc(C(C)(C)C)cc3)c3cc5c6c(c34)Sc3ccc(-c4ccccc4)cc3B6c3cc(-c4ccccc4)ccc3S5)c2)cc1]

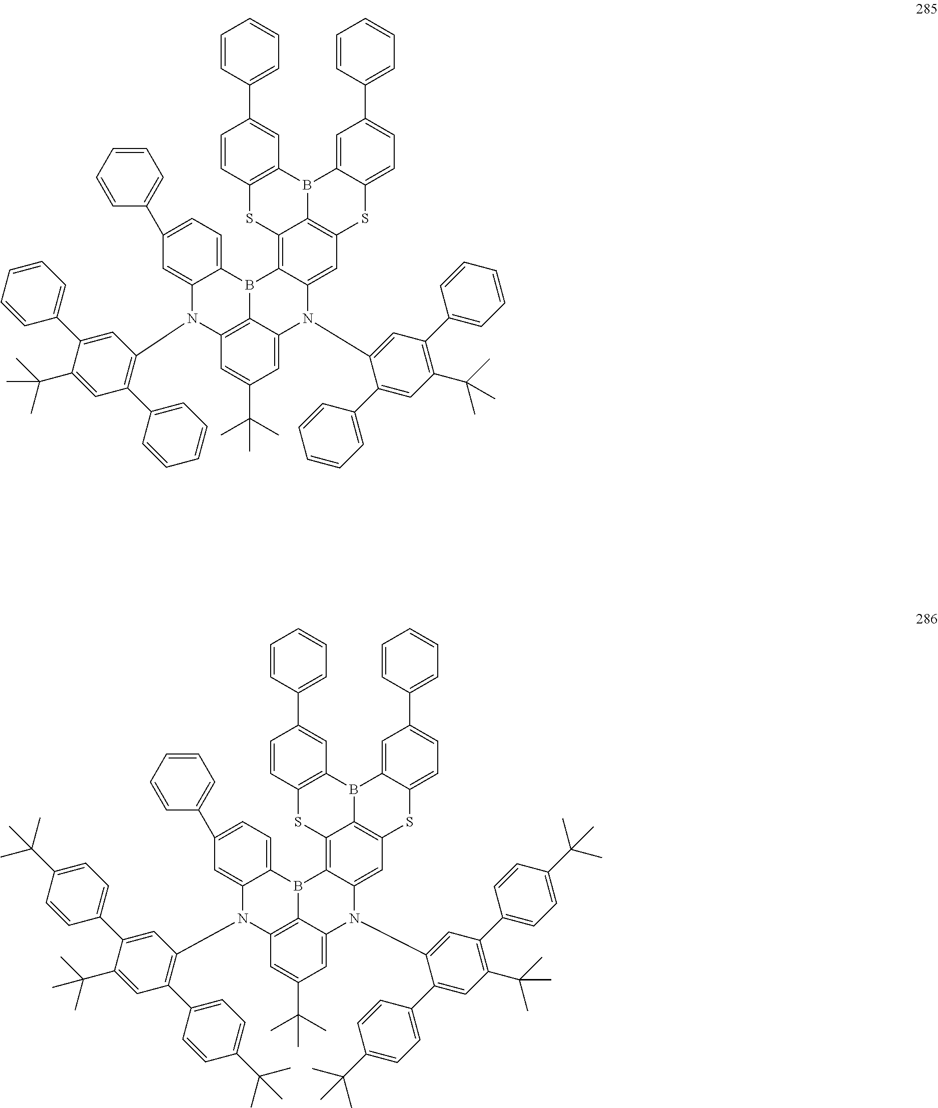 [SMILES: CC(C)(C)c1cc2c3c(c1)N(c1cc(-c4ccccc4)c(C(C)(C)C)cc1-c1ccccc1)c1cc4c5c(c1B3c1ccc(-c3ccccc3)cc1N2c1cc(-c2ccccc2)c(C(C)(C)C)cc1-c1ccccc1)Sc1ccc(-c2ccccc2)cc1B5c1cc(-c2ccccc2)ccc1S4 ; CC(C)(C)c1ccc(-c2cc(C(C)(C)C)c(-c3ccc(C(C)(C)C)cc3)cc2N2c3cc(-c4ccccc4)ccc3B3c4c2cc(C(C)(C)C)cc4N(c2cc(-c4ccc(C(C)(C)C)cc4)c(C(C)(C)C)cc2-c2ccc(C(C)(C)C)cc2)c2cc4c5c(c23)Sc2ccc(-c3ccccc3)cc2B5c2cc(-c3ccccc3)ccc2S4)cc1]

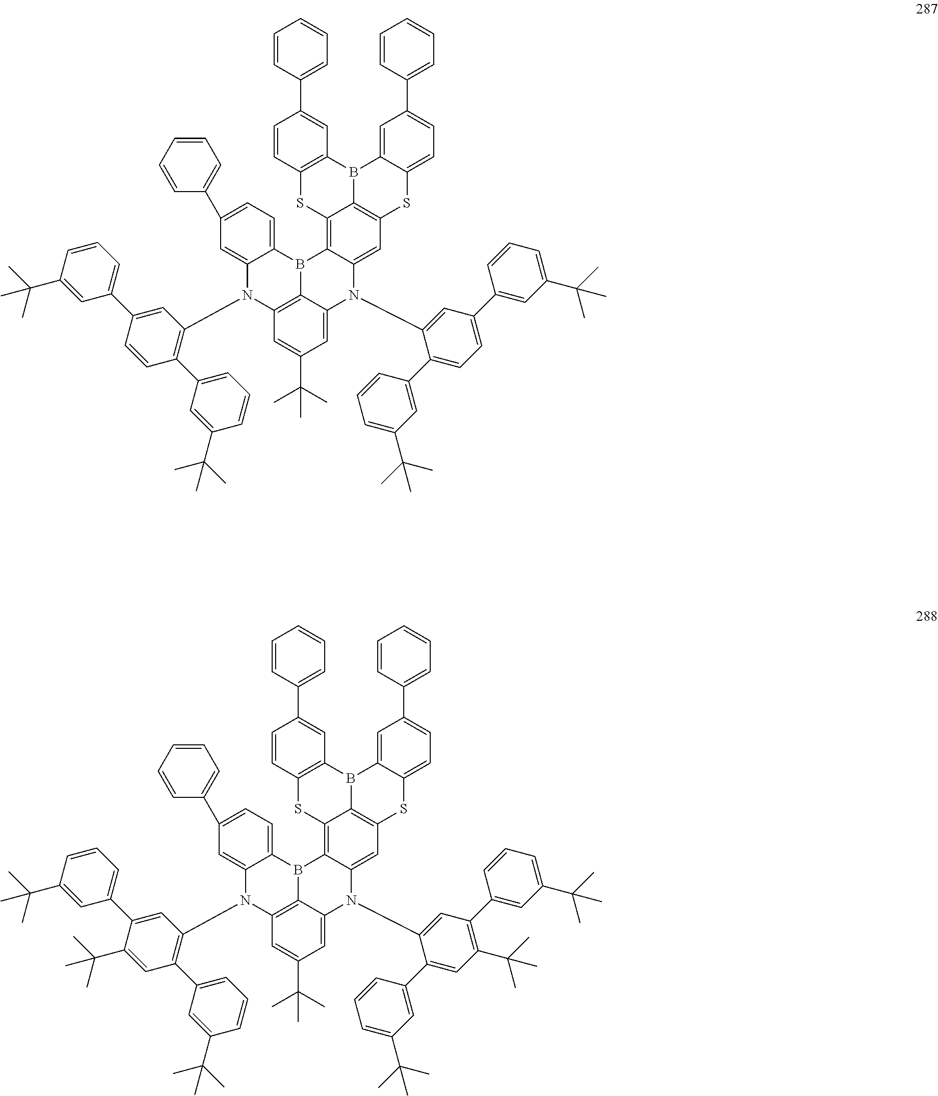

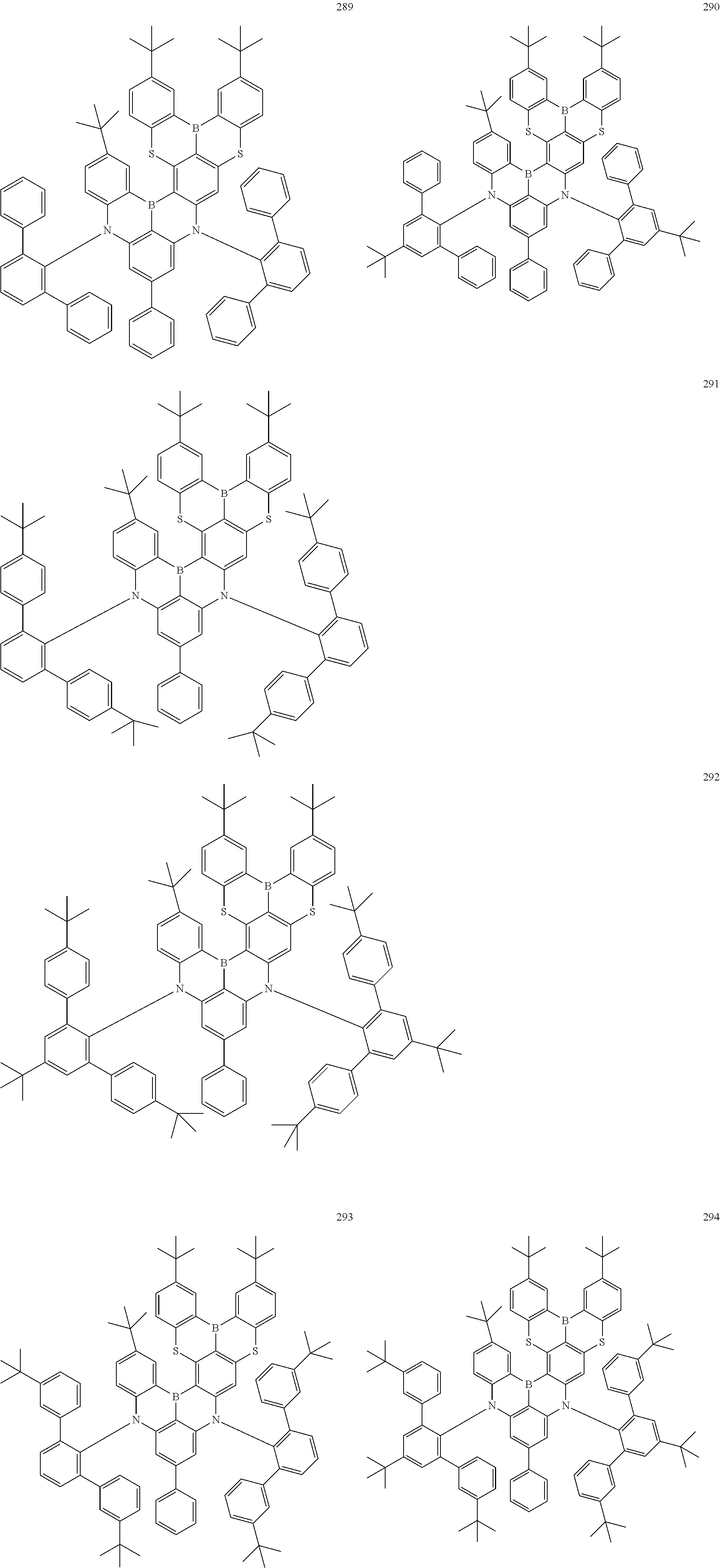

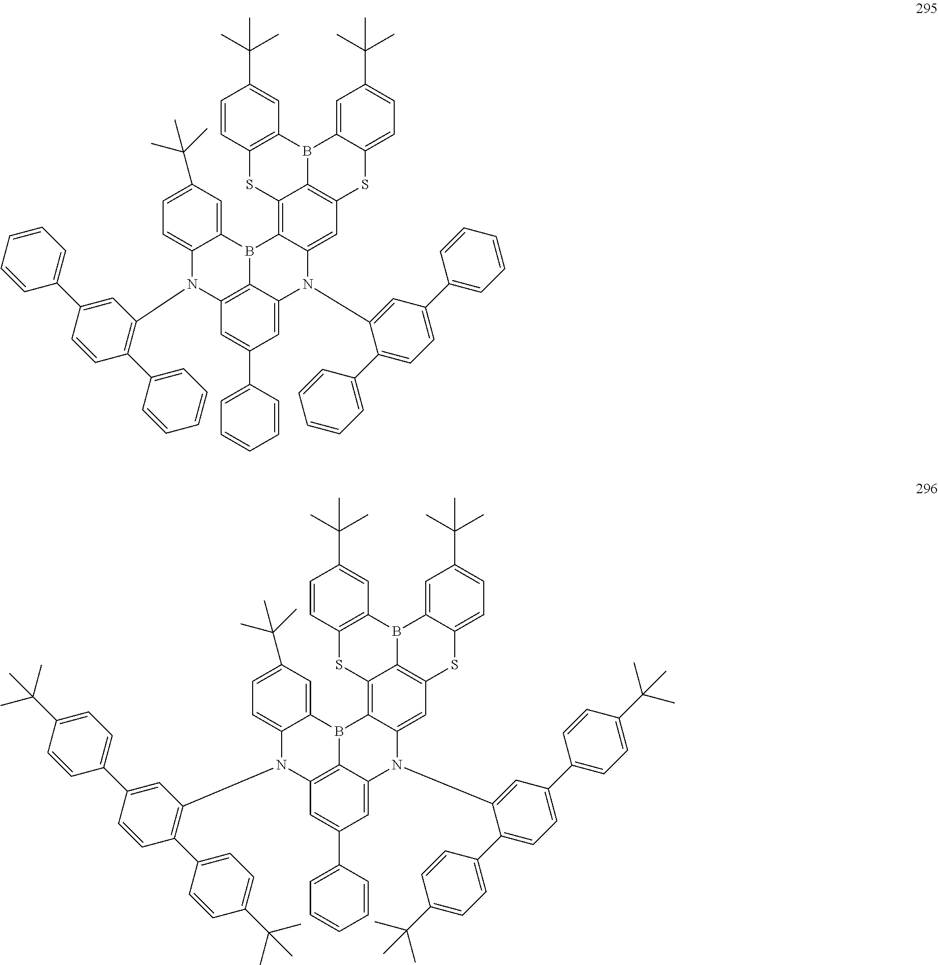 [SMILES: CC(C)(C)c1ccc2c(c1)B1c3cc(C(C)(C)C)ccc3Sc3c1c(cc1c3B3c4cc(C(C)(C)C)ccc4N(c4cc(-c5ccccc5)ccc4-c4ccccc4)c4cc(-c5ccccc5)cc(c43)N1c1cc(-c3ccccc3)ccc1-c1ccccc1)S2 ; CC(C)(C)c1ccc(-c2ccc(-c3ccc(C(C)(C)C)cc3)c(N3c4ccc(C(C)(C)C)cc4B4c5c3cc(-c3ccccc3)cc5N(c3cc(-c5ccc(C(C)(C)C)cc5)ccc3-c3ccc(C(C)(C)C)cc3)c3cc5c6c(c34)Sc3ccc(C(C)(C)C)cc3B6c3cc(C(C)(C)C)ccc3S5)c2)cc1]

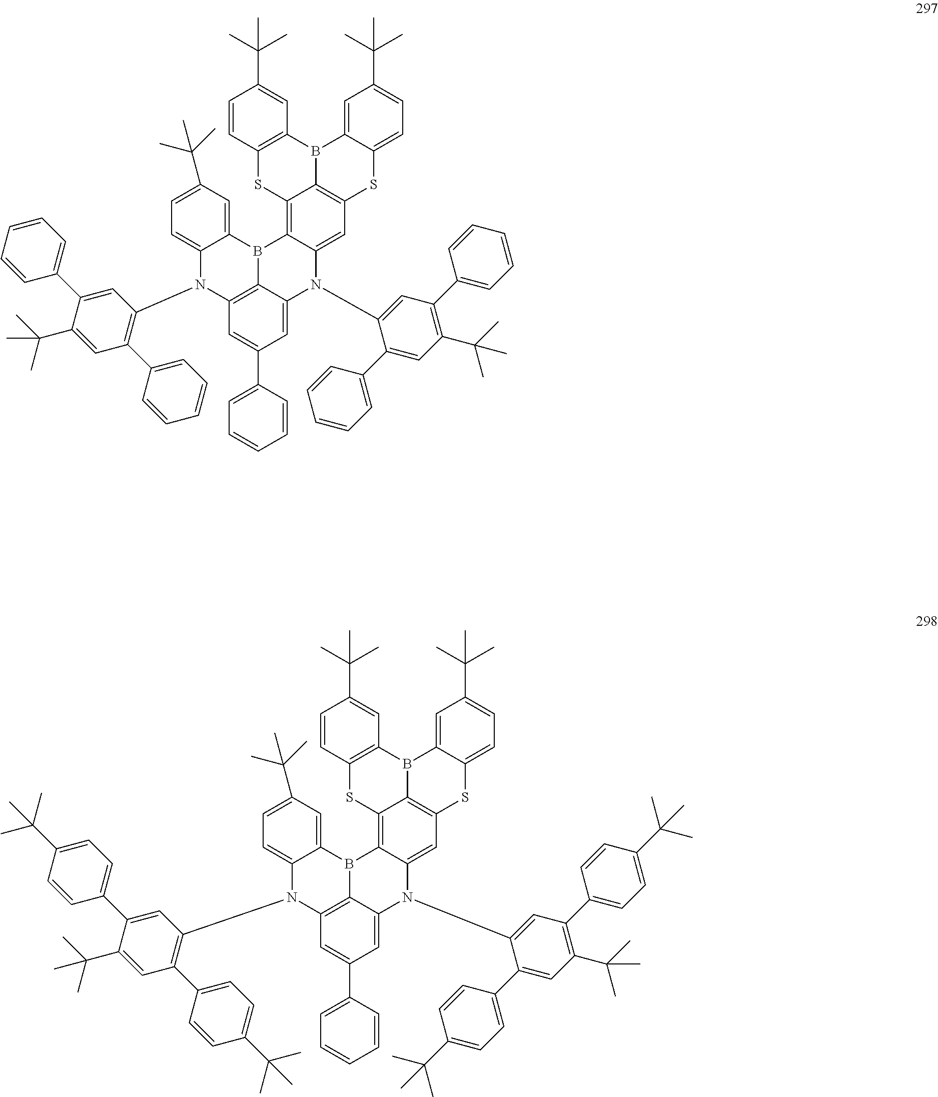 [SMILES: CC(C)(C)c1ccc2c(c1)B1c3cc(C(C)(C)C)ccc3Sc3c1c(cc1c3B3c4cc(C(C)(C)C)ccc4N(c4cc(-c5ccccc5)c(C(C)(C)C)cc4-c4ccccc4)c4cc(-c5ccccc5)cc(c43)N1c1cc(-c3ccccc3)c(C(C)(C)C)cc1-c1ccccc1)S2 ; CC(C)(C)c1ccc(-c2cc(C(C)(C)C)c(-c3ccc(C(C)(C)C)cc3)cc2N2c3ccc(C(C)(C)C)cc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Sc2ccc(C(C)(C)C)cc2B5c2cc(C(C)(C)C)ccc2S4)cc1]

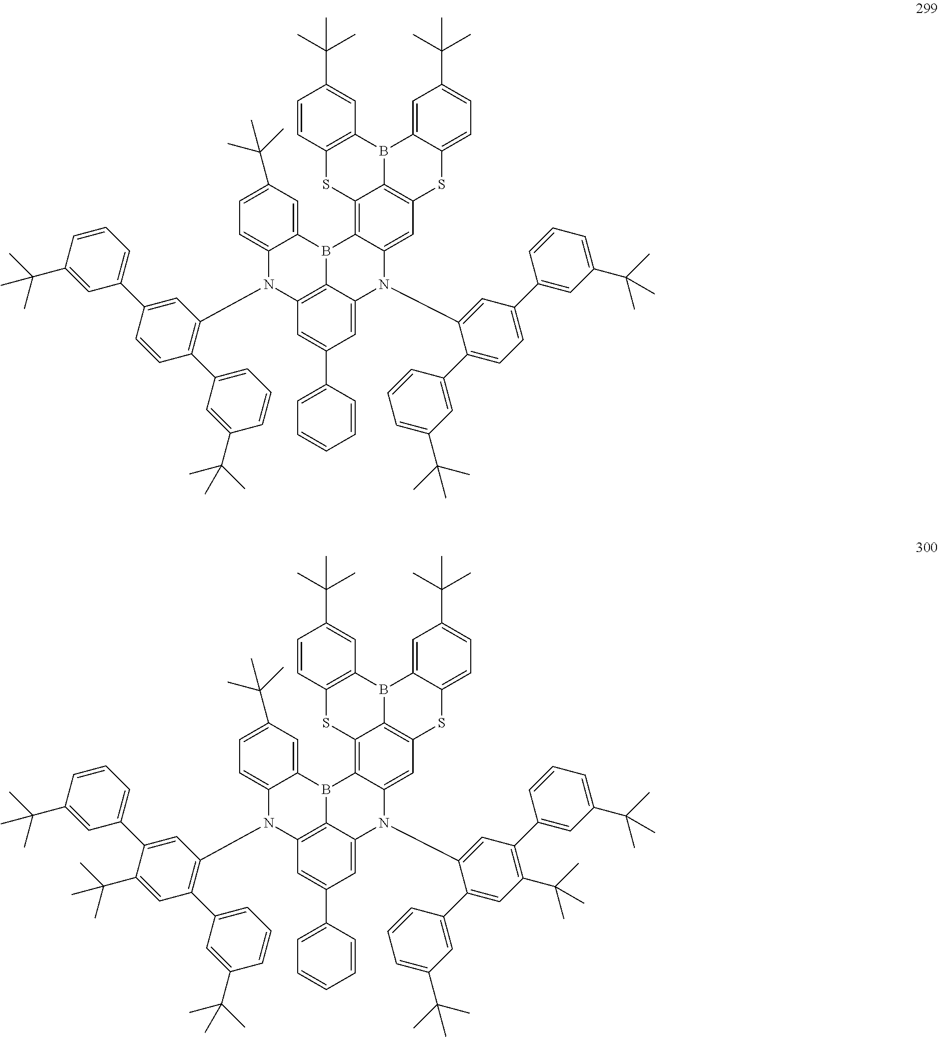

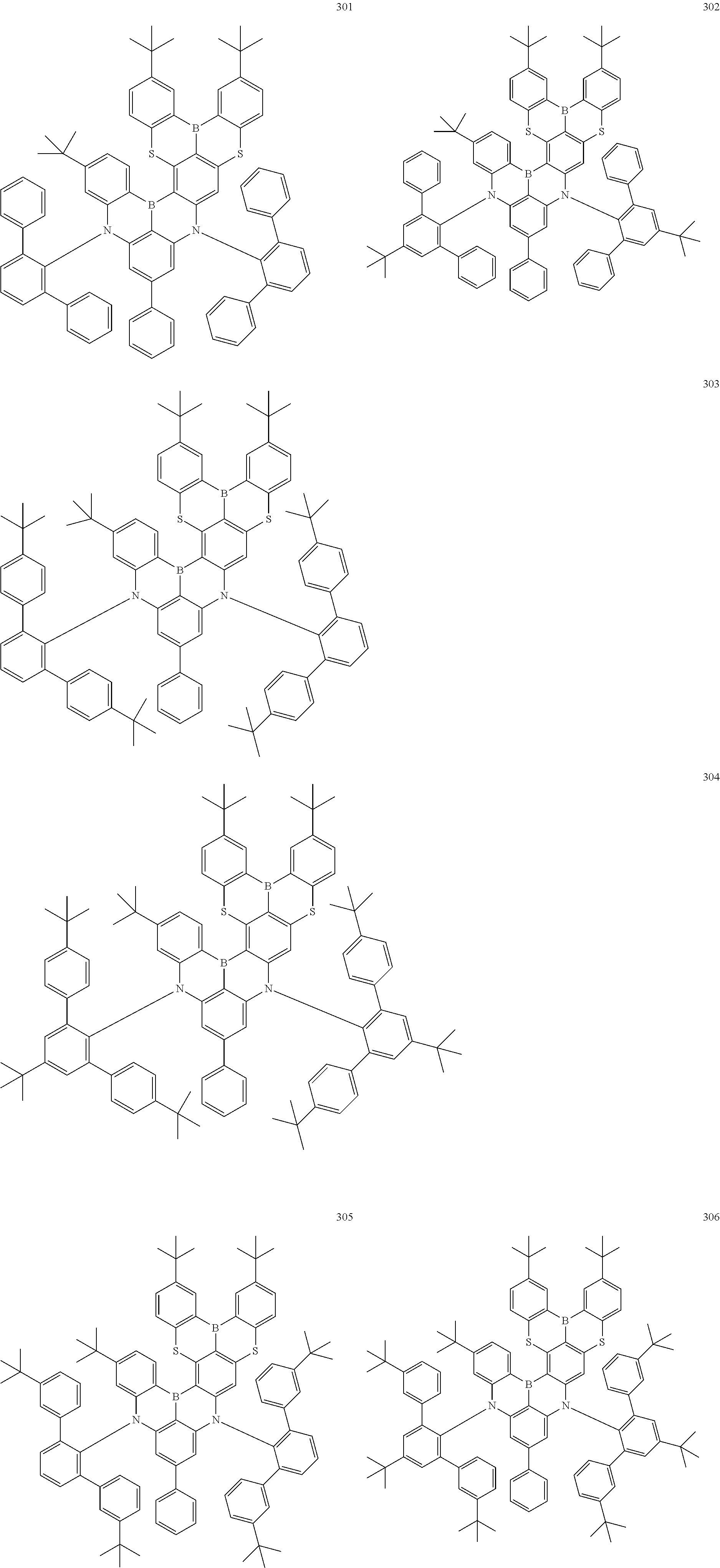

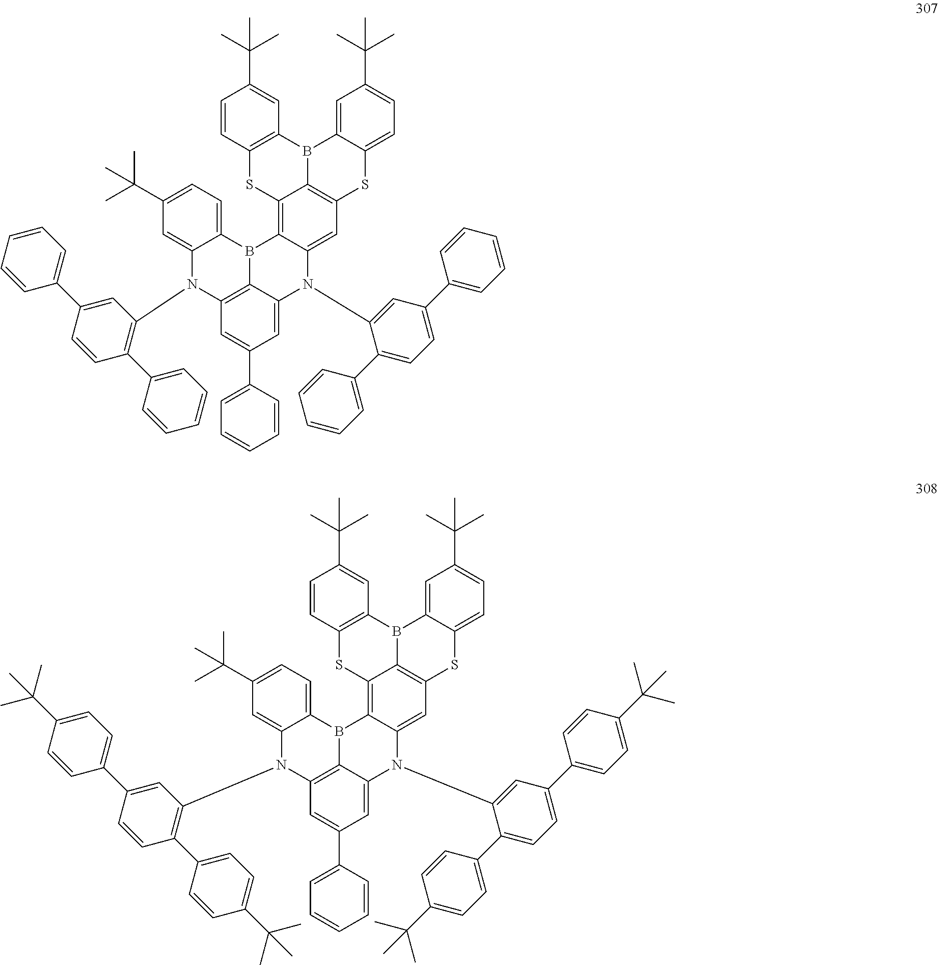 [SMILES: CC(C)(C)c1ccc2c(c1)B1c3cc(C(C)(C)C)ccc3Sc3c1c(cc1c3B3c4ccc(C(C)(C)C)cc4N(c4cc(-c5ccccc5)ccc4-c4ccccc4)c4cc(-c5ccccc5)cc(c43)N1c1cc(-c3ccccc3)ccc1-c1ccccc1)S2 ; CC(C)(C)c1ccc(-c2ccc(-c3ccc(C(C)(C)C)cc3)c(N3c4cc(C(C)(C)C)ccc4B4c5c3cc(-c3ccccc3)cc5N(c3cc(-c5ccc(C(C)(C)C)cc5)ccc3-c3ccc(C(C)(C)C)cc3)c3cc5c6c(c34)Sc3ccc(C(C)(C)C)cc3B6c3cc(C(C)(C)C)ccc3S5)c2)cc1]

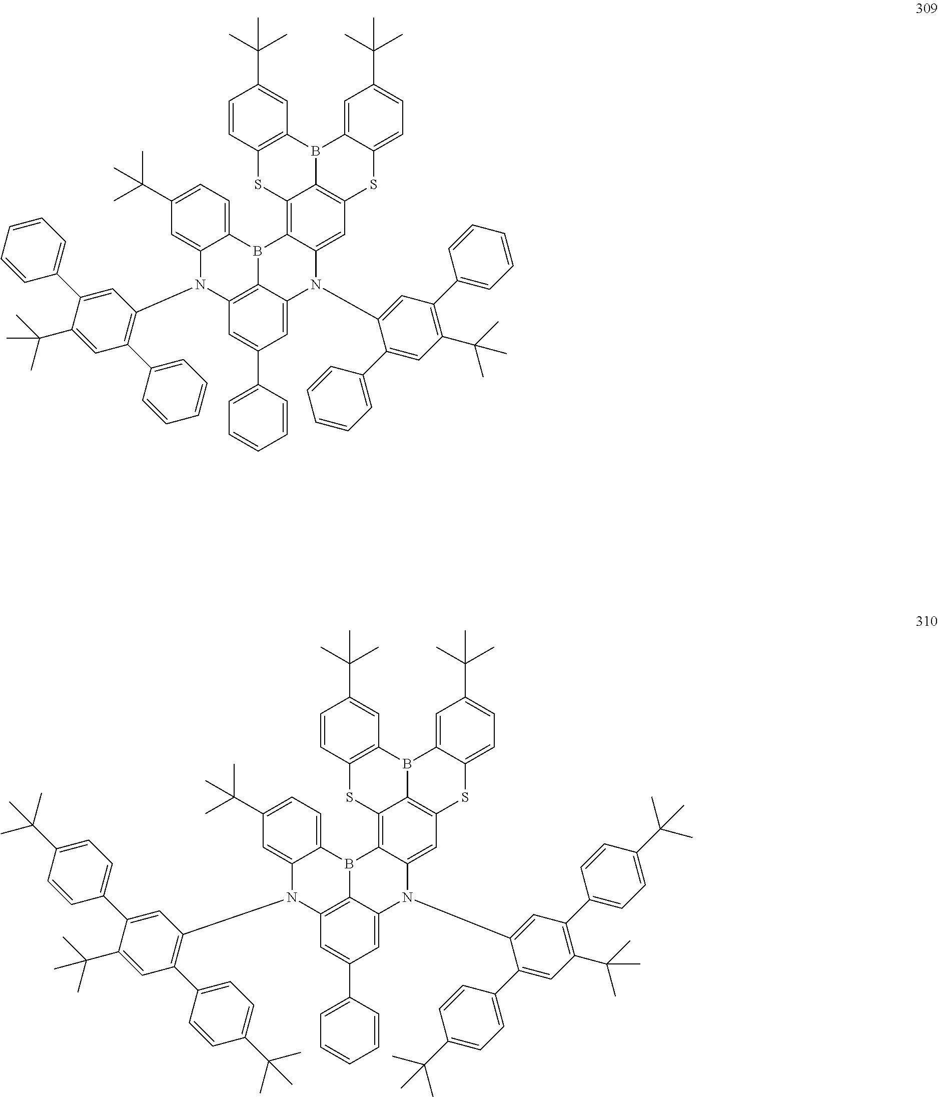 [SMILES: CC(C)(C)c1ccc2c(c1)B1c3cc(C(C)(C)C)ccc3Sc3c1c(cc1c3B3c4ccc(C(C)(C)C)cc4N(c4cc(-c5ccccc5)c(C(C)(C)C)cc4-c4ccccc4)c4cc(-c5ccccc5)cc(c43)N1c1cc(-c3ccccc3)c(C(C)(C)C)cc1-c1ccccc1)S2 ; CC(C)(C)c1ccc(-c2cc(C(C)(C)C)c(-c3ccc(C(C)(C)C)cc3)cc2N2c3cc(C(C)(C)C)ccc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Sc2ccc(C(C)(C)C)cc2B5c2cc(C(C)(C)C)ccc2S4)cc1]

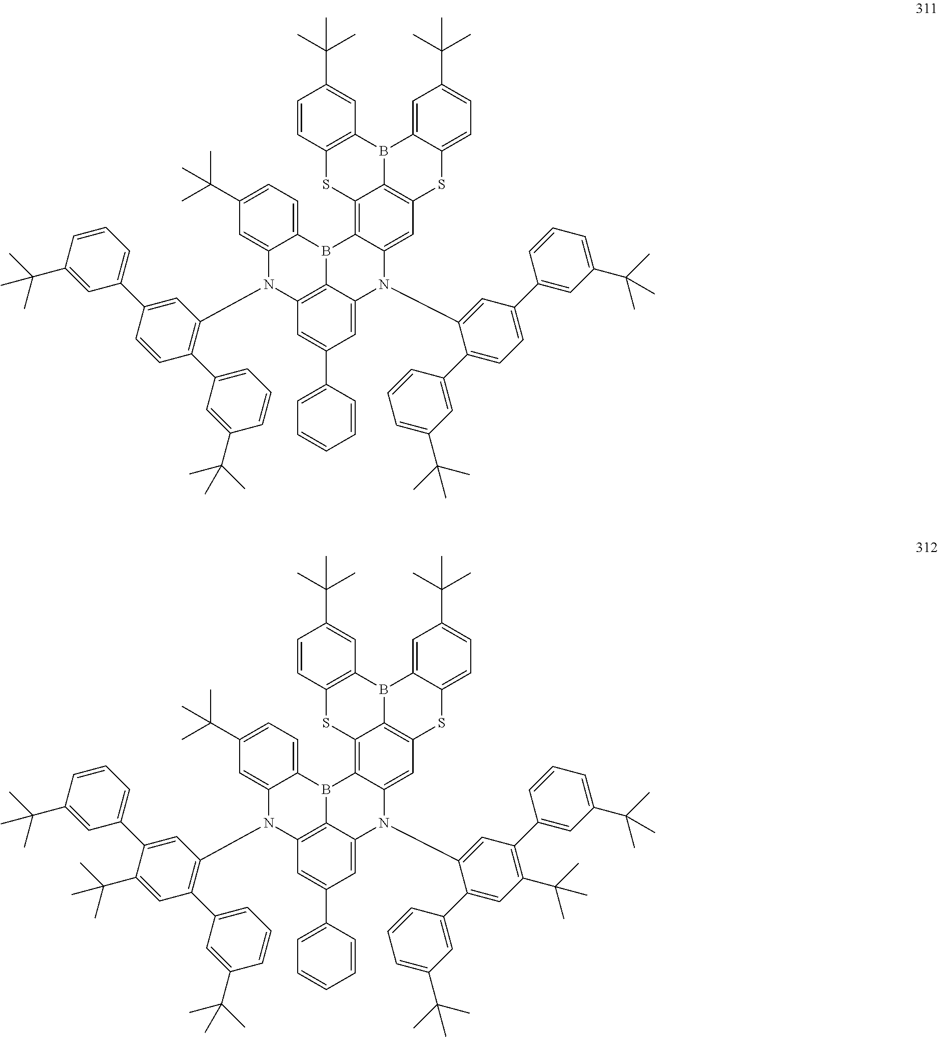

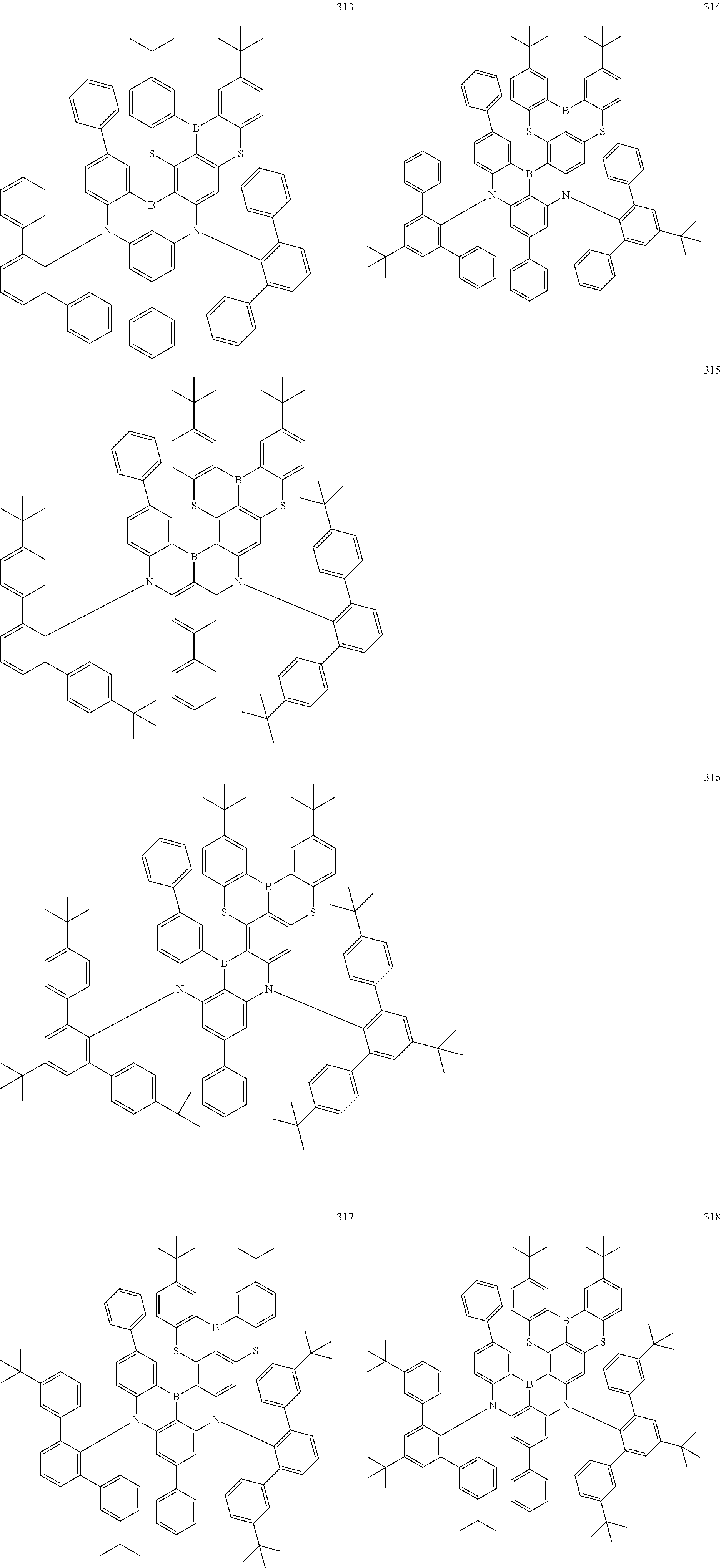

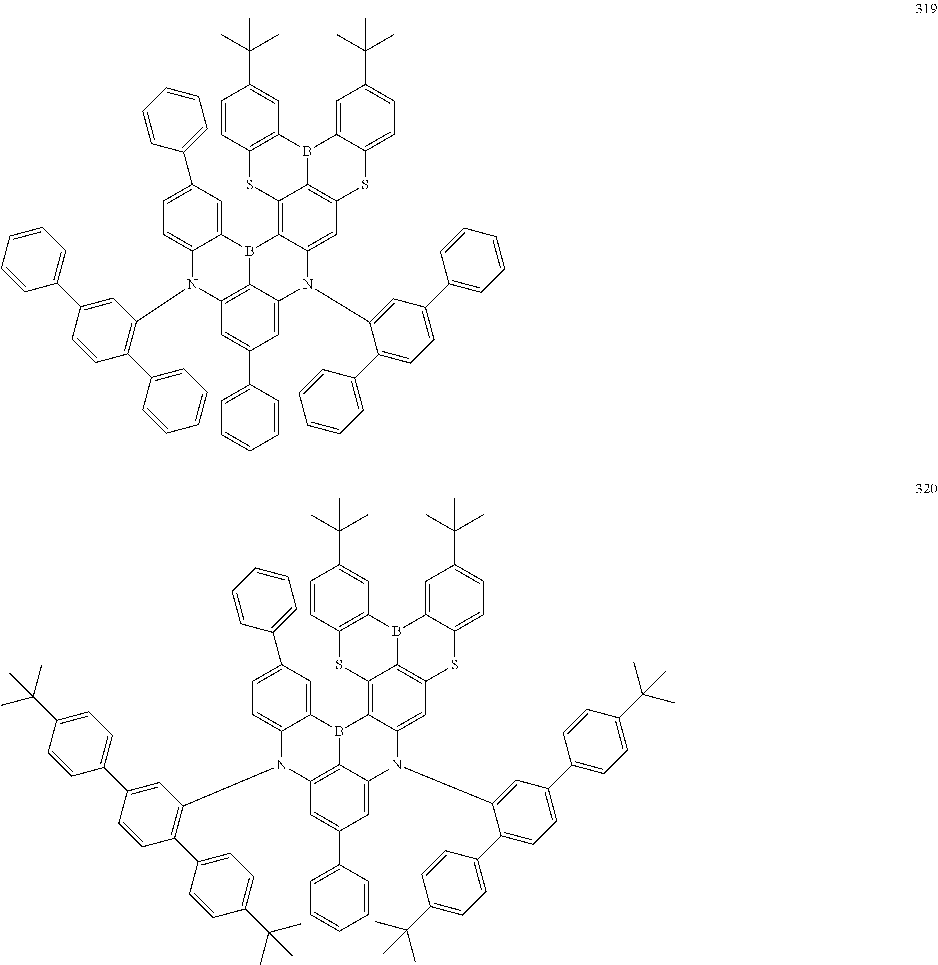 [SMILES: CC(C)(C)c1ccc2c(c1)B1c3cc(C(C)(C)C)ccc3Sc3c1c(cc1c3B3c4cc(-c5ccccc5)ccc4N(c4cc(-c5ccccc5)ccc4-c4ccccc4)c4cc(-c5ccccc5)cc(c43)N1c1cc(-c3ccccc3)ccc1-c1ccccc1)S2 ; CC(C)(C)c1ccc(-c2ccc(-c3ccc(C(C)(C)C)cc3)c(N3c4ccc(-c5ccccc5)cc4B4c5c3cc(-c3ccccc3)cc5N(c3cc(-c5ccc(C(C)(C)C)cc5)ccc3-c3ccc(C(C)(C)C)cc3)c3cc5c6c(c34)Sc3ccc(C(C)(C)C)cc3B6c3cc(C(C)(C)C)ccc3S5)c2)cc1]

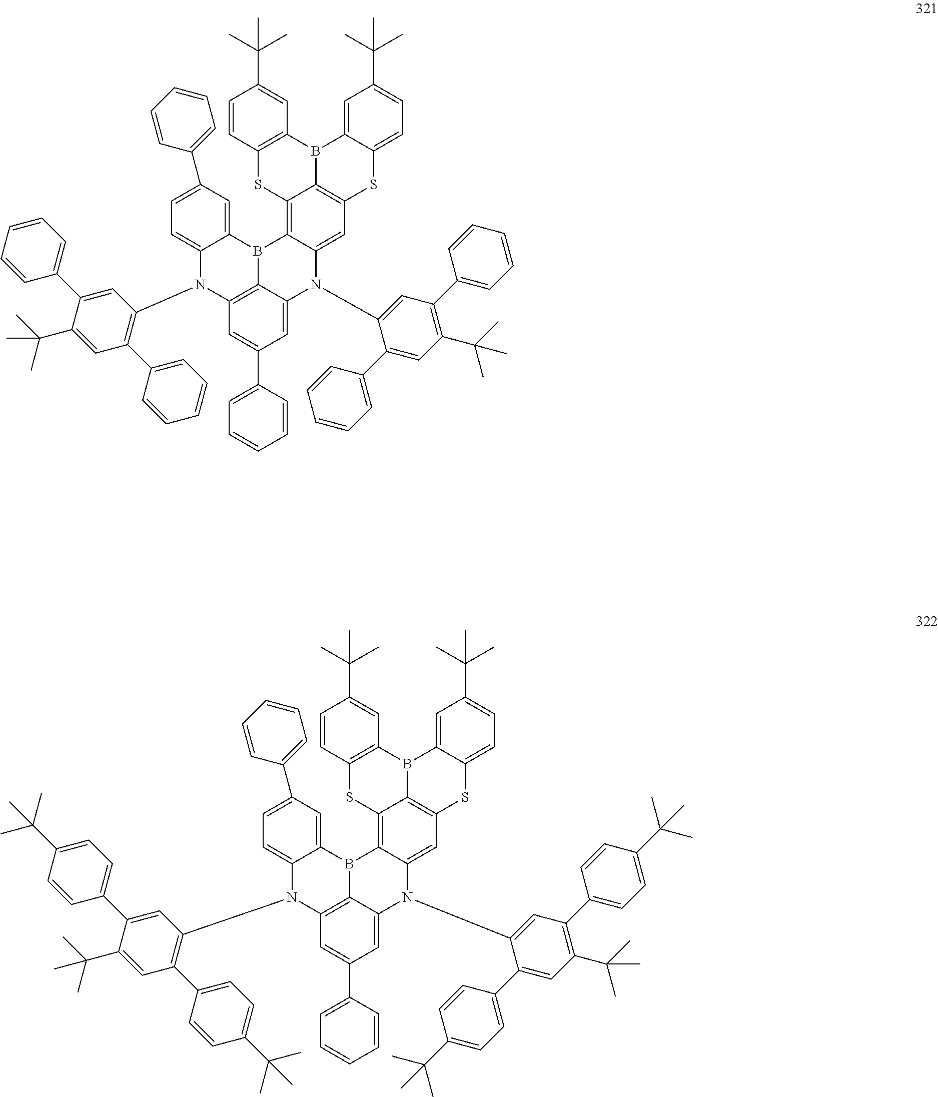 [SMILES: CC(C)(C)c1ccc2c(c1)B1c3cc(C(C)(C)C)ccc3Sc3c1c(cc1c3B3c4cc(-c5ccccc5)ccc4N(c4cc(-c5ccccc5)c(C(C)(C)C)cc4-c4ccccc4)c4cc(-c5ccccc5)cc(c43)N1c1cc(-c3ccccc3)c(C(C)(C)C)cc1-c1ccccc1)S2 ; CC(C)(C)c1ccc(-c2cc(C(C)(C)C)c(-c3ccc(C(C)(C)C)cc3)cc2N2c3ccc(-c4ccccc4)cc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Sc2ccc(C(C)(C)C)cc2B5c2cc(C(C)(C)C)ccc2S4)cc1]

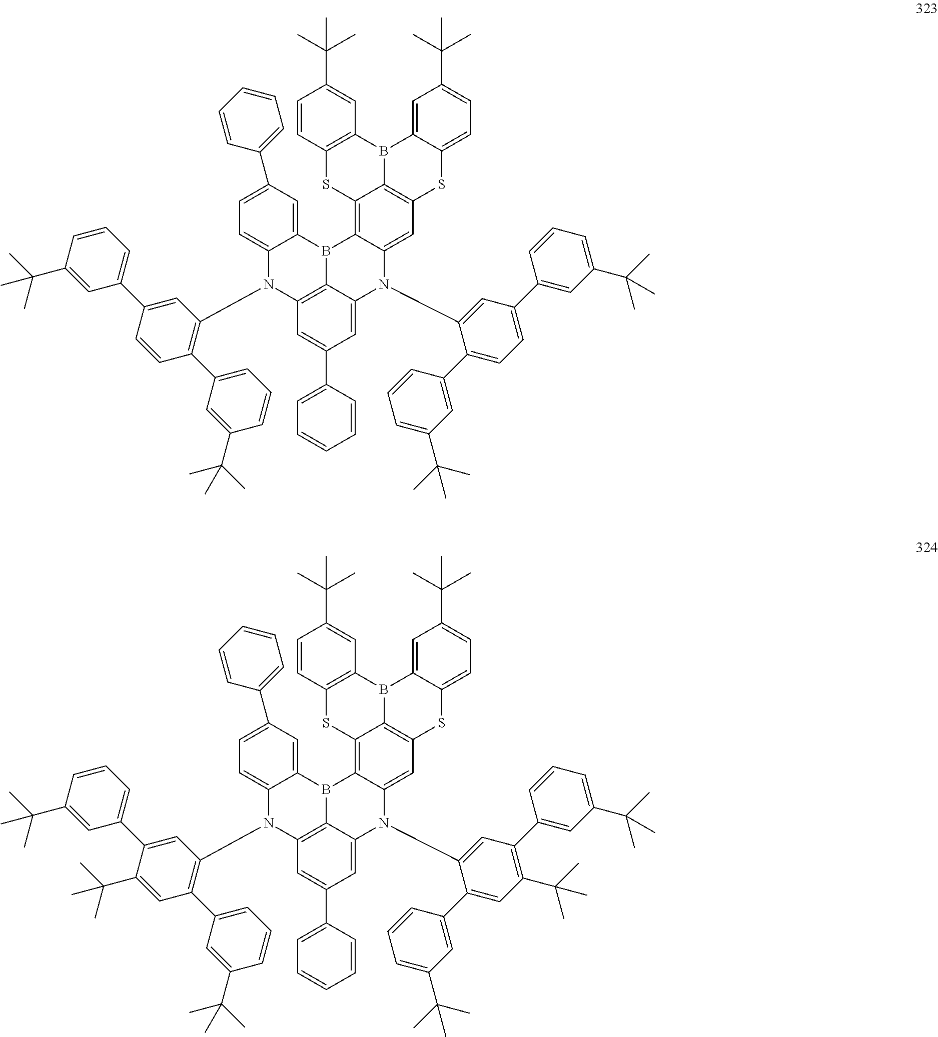

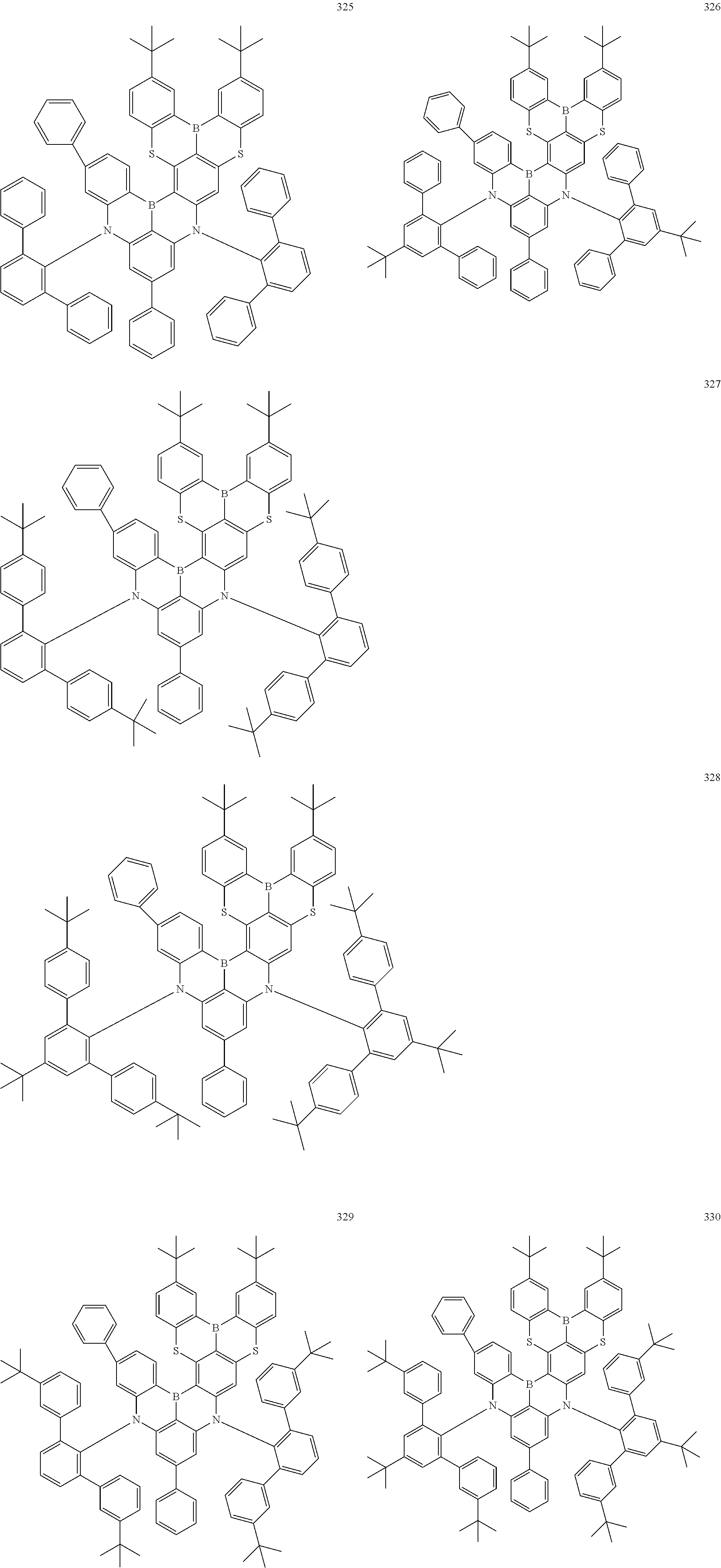

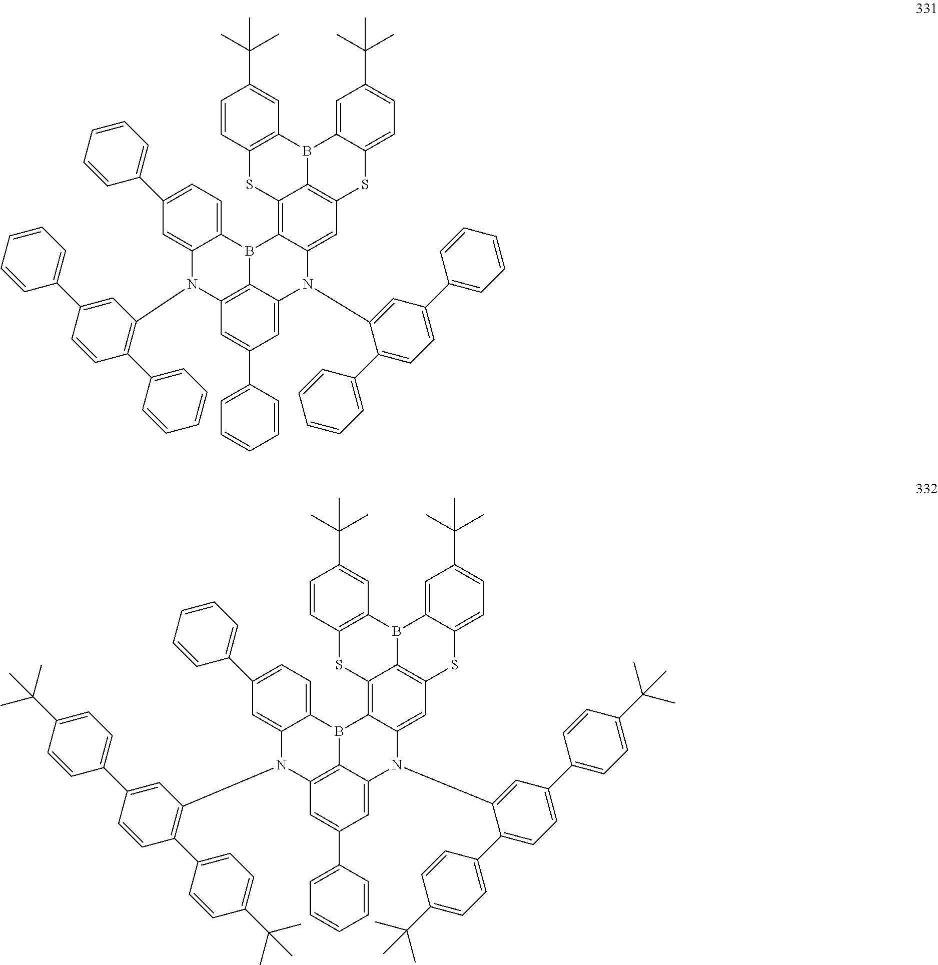 [SMILES: CC(C)(C)c1ccc2c(c1)B1c3cc(C(C)(C)C)ccc3Sc3c1c(cc1c3B3c4ccc(-c5ccccc5)cc4N(c4cc(-c5ccccc5)ccc4-c4ccccc4)c4cc(-c5ccccc5)cc(c43)N1c1cc(-c3ccccc3)ccc1-c1ccccc1)S2 ; CC(C)(C)c1ccc(-c2ccc(-c3ccc(C(C)(C)C)cc3)c(N3c4cc(-c5ccccc5)ccc4B4c5c3cc(-c3ccccc3)cc5N(c3cc(-c5ccc(C(C)(C)C)cc5)ccc3-c3ccc(C(C)(C)C)cc3)c3cc5c6c(c34)Sc3ccc(C(C)(C)C)cc3B6c3cc(C(C)(C)C)ccc3S5)c2)cc1]

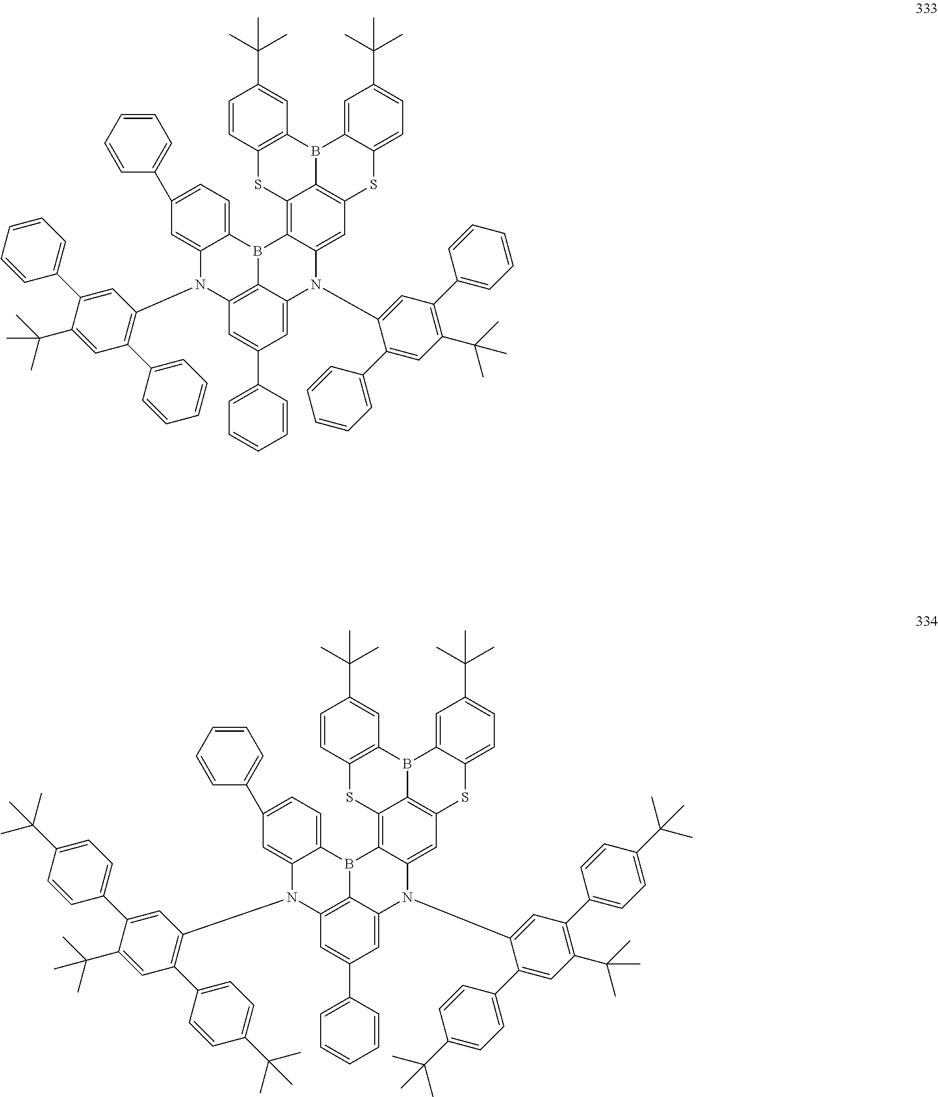 [SMILES: CC(C)(C)c1ccc2c(c1)B1c3cc(C(C)(C)C)ccc3Sc3c1c(cc1c3B3c4ccc(-c5ccccc5)cc4N(c4cc(-c5ccccc5)c(C(C)(C)C)cc4-c4ccccc4)c4cc(-c5ccccc5)cc(c43)N1c1cc(-c3ccccc3)c(C(C)(C)C)cc1-c1ccccc1)S2 ; CC(C)(C)c1ccc(-c2cc(C(C)(C)C)c(-c3ccc(C(C)(C)C)cc3)cc2N2c3cc(-c4ccccc4)ccc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Sc2ccc(C(C)(C)C)cc2B5c2cc(C(C)(C)C)ccc2S4)cc1]

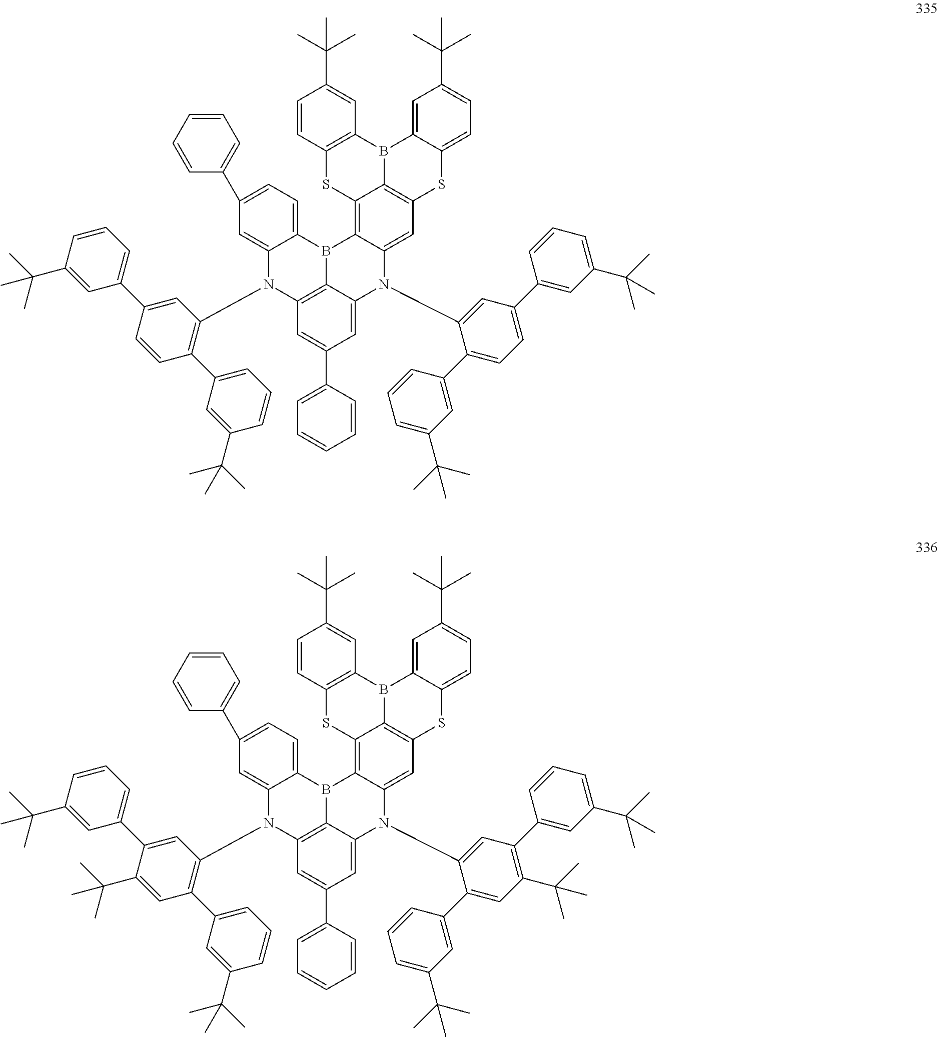

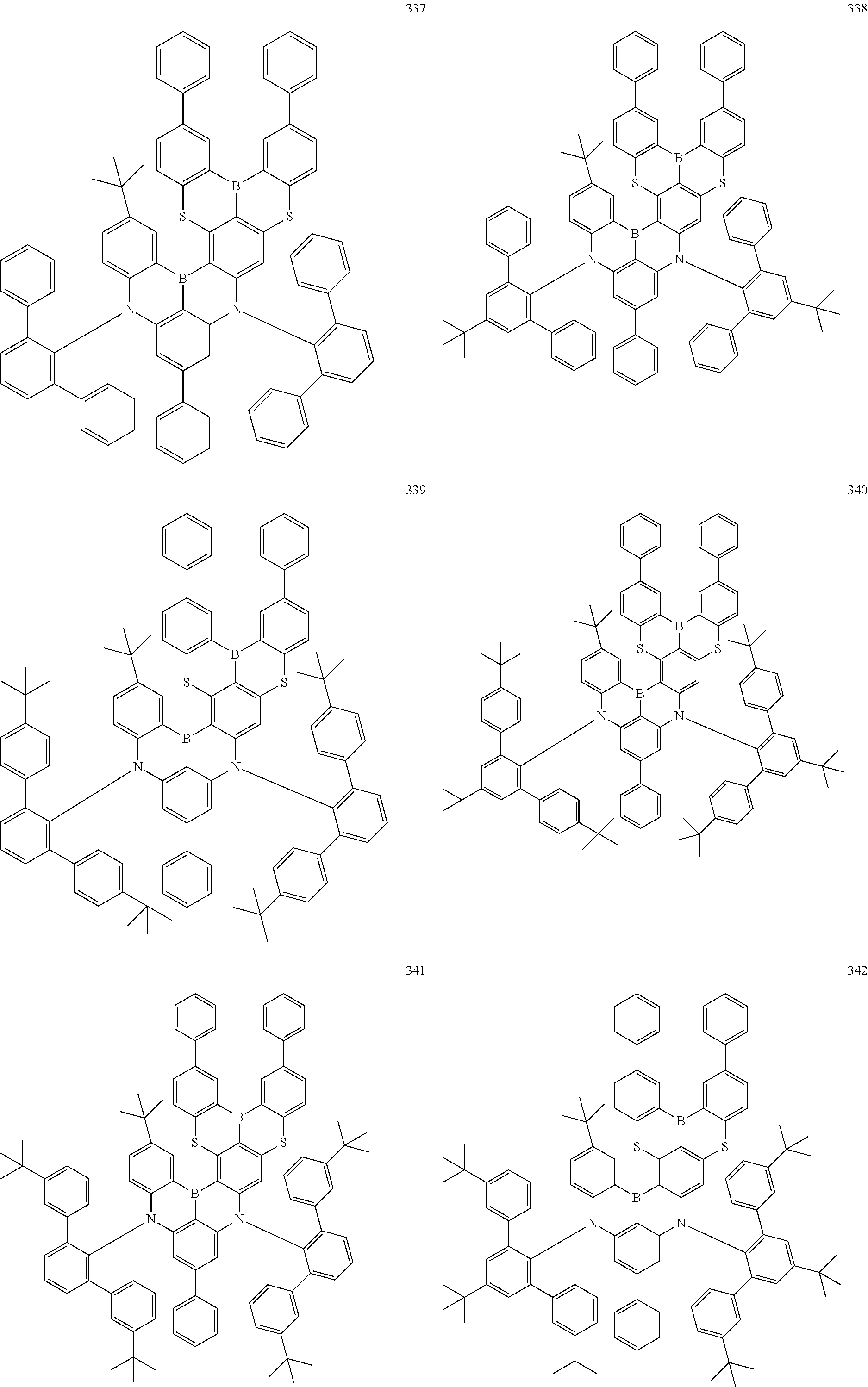

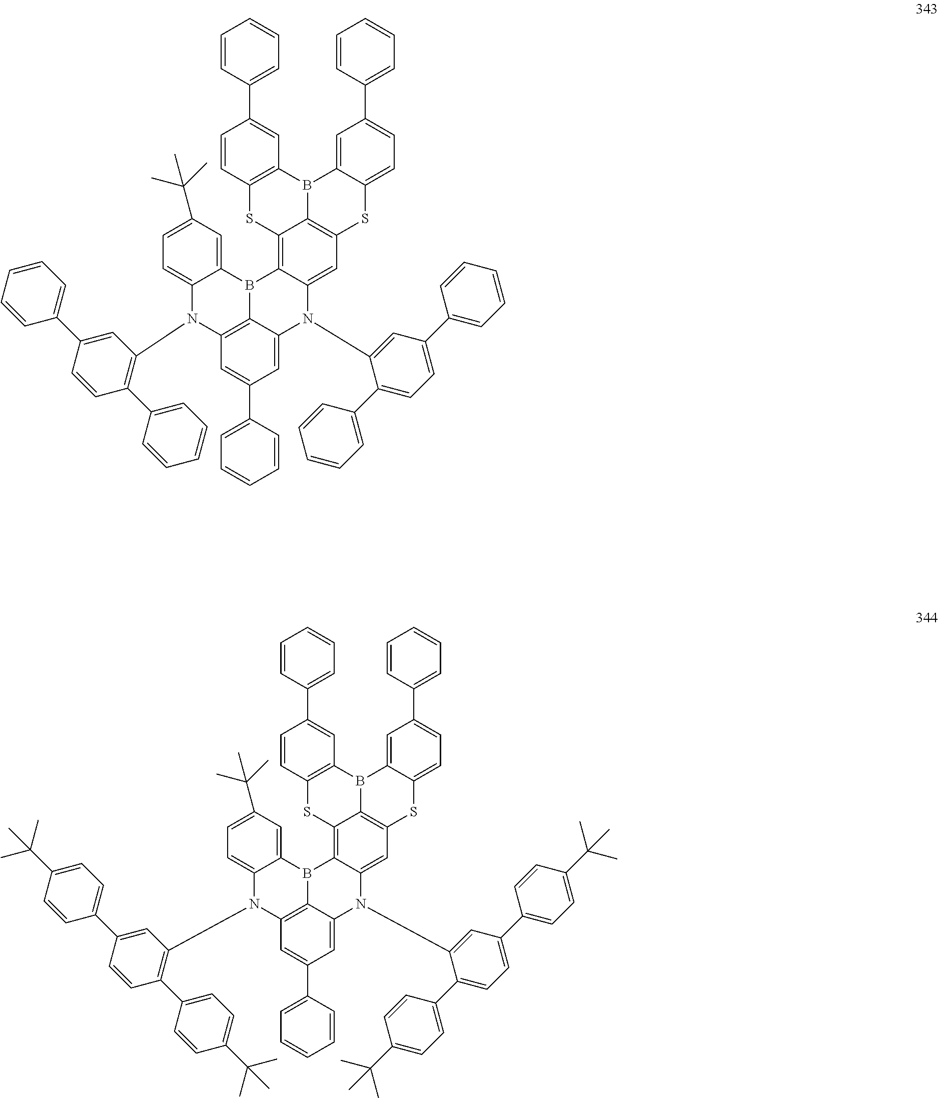 [SMILES: CC(C)(C)c1ccc2c(c1)B1c3c(cc(-c4ccccc4)cc3N(c3cc(-c4ccccc4)ccc3-c3ccccc3)c3cc4c5c(c31)Sc1ccc(-c3ccccc3)cc1B5c1cc(-c3ccccc3)ccc1S4)N2c1cc(-c2ccccc2)ccc1-c1ccccc1 ; CC(C)(C)c1ccc(-c2ccc(-c3ccc(C(C)(C)C)cc3)c(N3c4ccc(C(C)(C)C)cc4B4c5c3cc(-c3ccccc3)cc5N(c3cc(-c5ccc(C(C)(C)C)cc5)ccc3-c3ccc(C(C)(C)C)cc3)c3cc5c6c(c34)Sc3ccc(-c4ccccc4)cc3B6c3cc(-c4ccccc4)ccc3S5)c2)cc1]

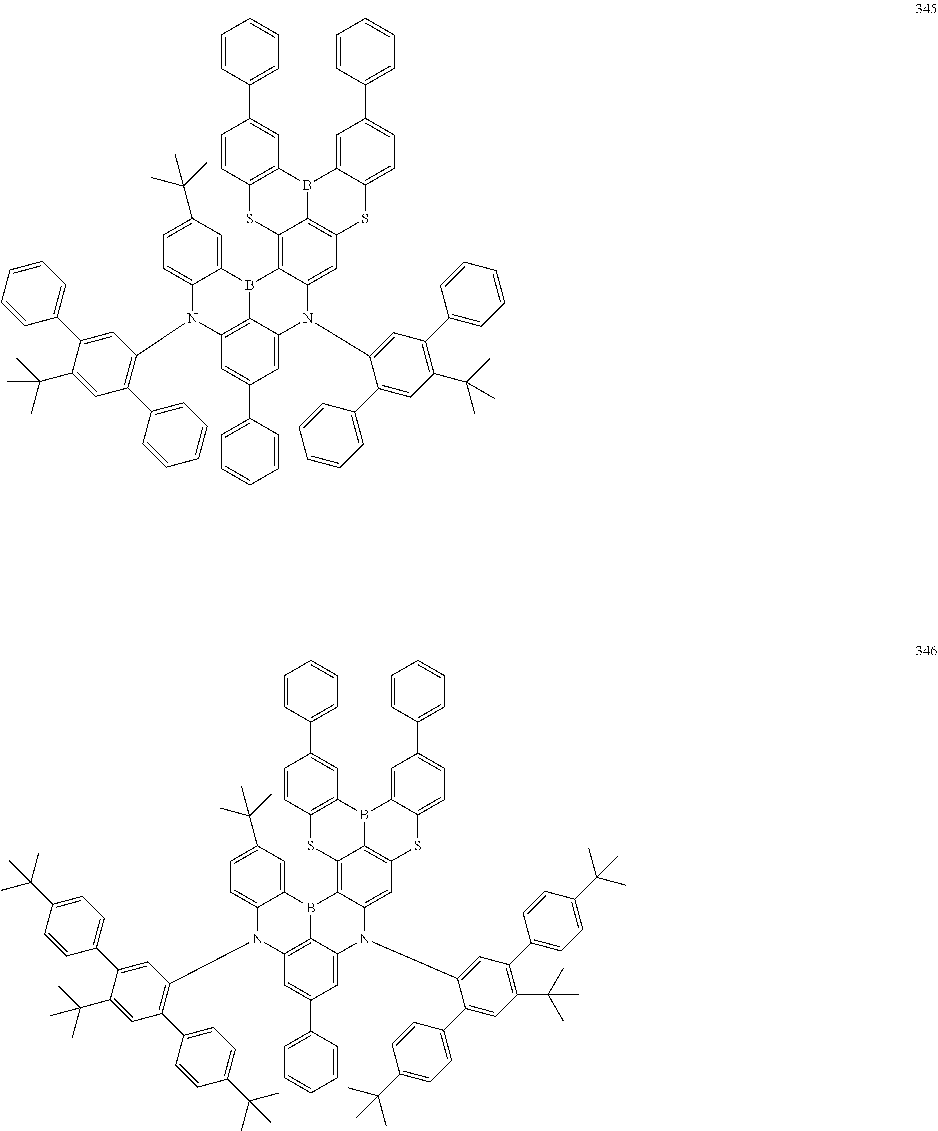 [SMILES: CC(C)(C)c1ccc2c(c1)B1c3c(cc(-c4ccccc4)cc3N(c3cc(-c4ccccc4)c(C(C)(C)C)cc3-c3ccccc3)c3cc4c5c(c31)Sc1ccc(-c3ccccc3)cc1B5c1cc(-c3ccccc3)ccc1S4)N2c1cc(-c2ccccc2)c(C(C)(C)C)cc1-c1ccccc1 ; CC(C)(C)c1ccc(-c2cc(C(C)(C)C)c(-c3ccc(C(C)(C)C)cc3)cc2N2c3ccc(C(C)(C)C)cc3B3c4c2cc(-c2ccccc2)cc4N(c2cc(-c4ccc(C(C)(C)C)cc4)c(C(C)(C)C)cc2-c2ccc(C(C)(C)C)cc2)c2cc4c5c(c23)Sc2ccc(-c3ccccc3)cc2B5c2cc(-c3ccccc3)ccc2S4)cc1]

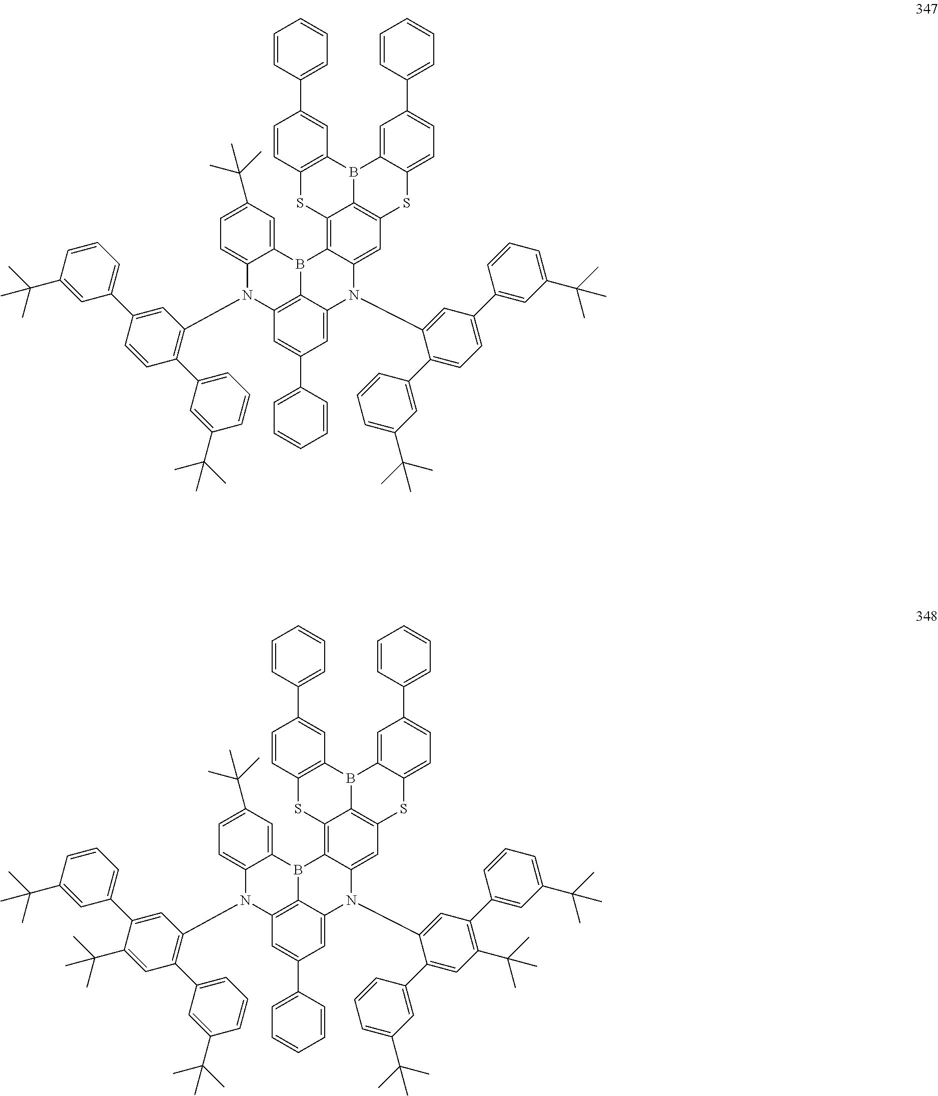

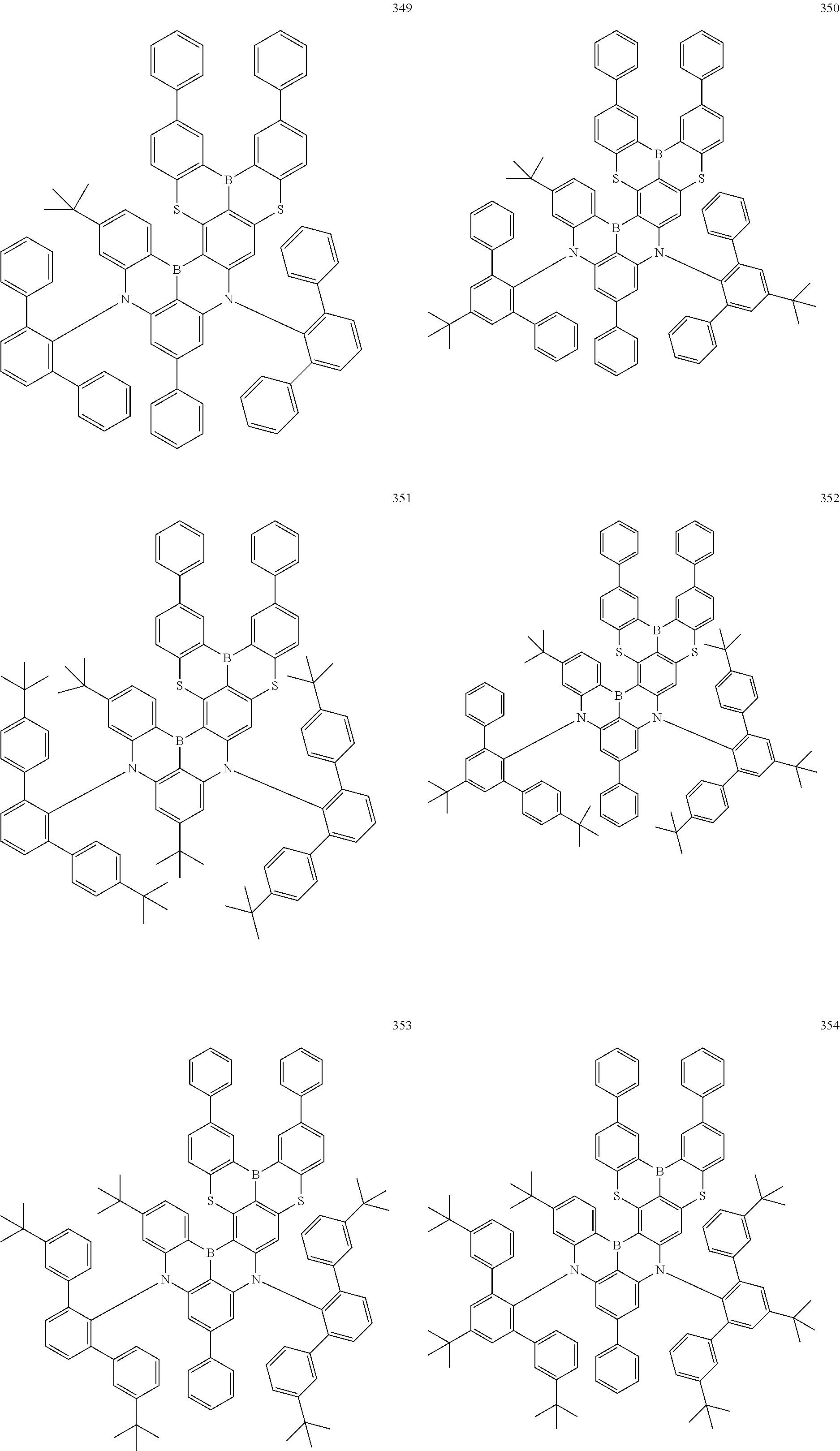

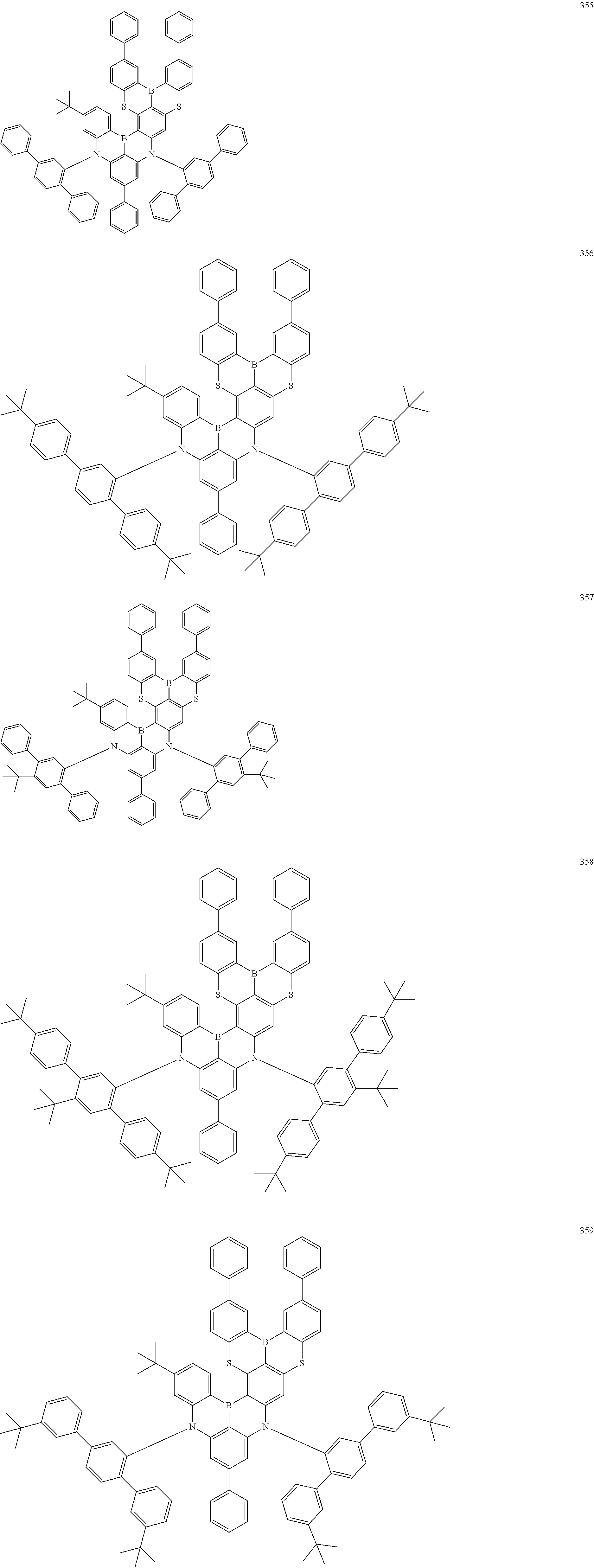

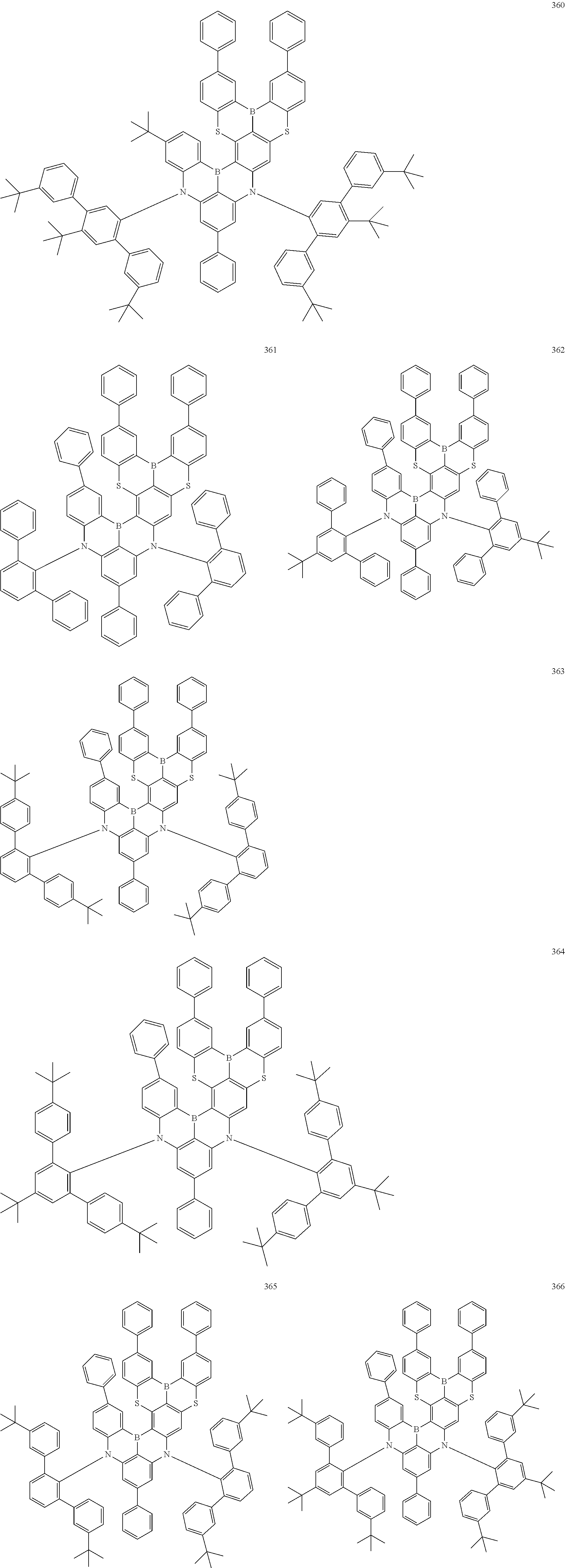

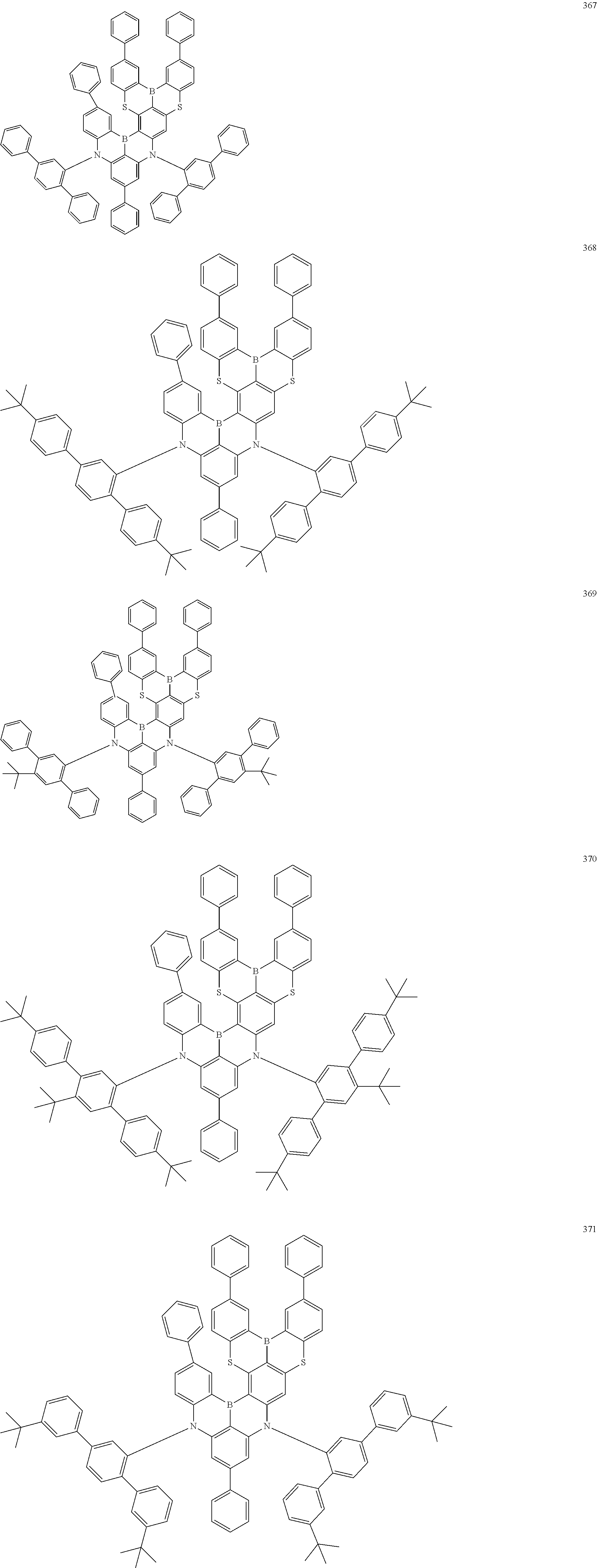

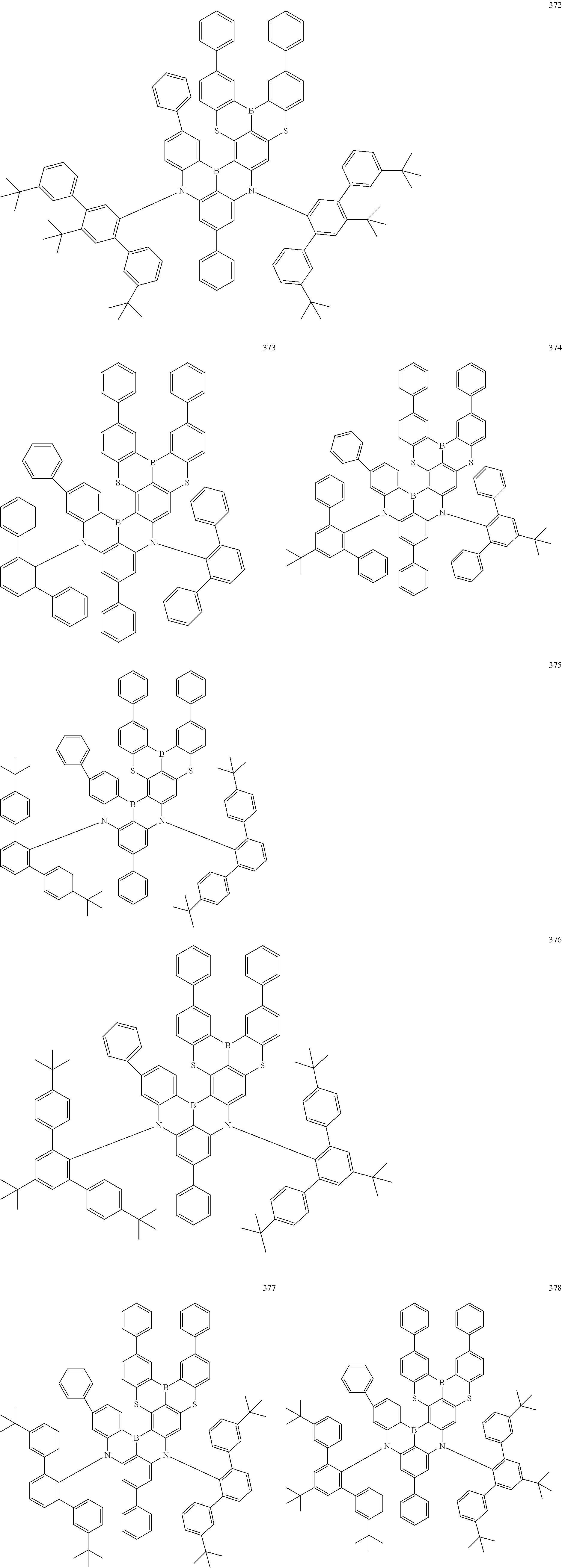

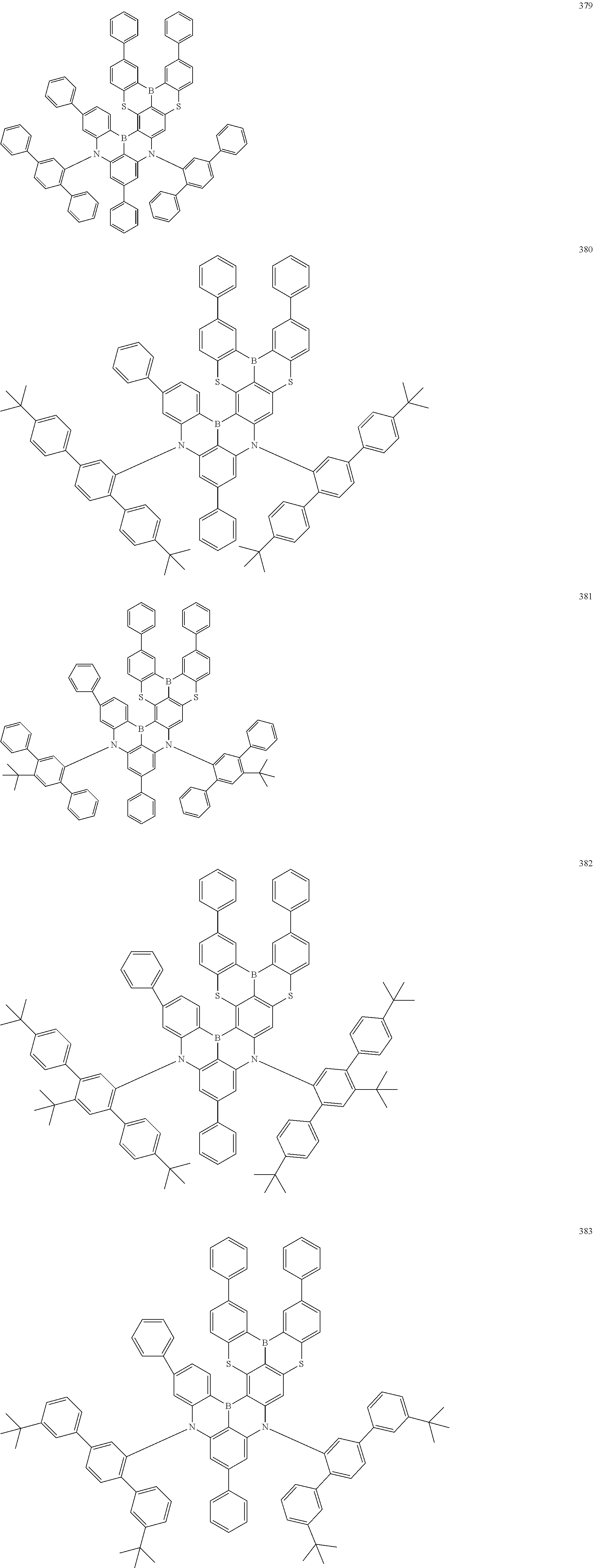

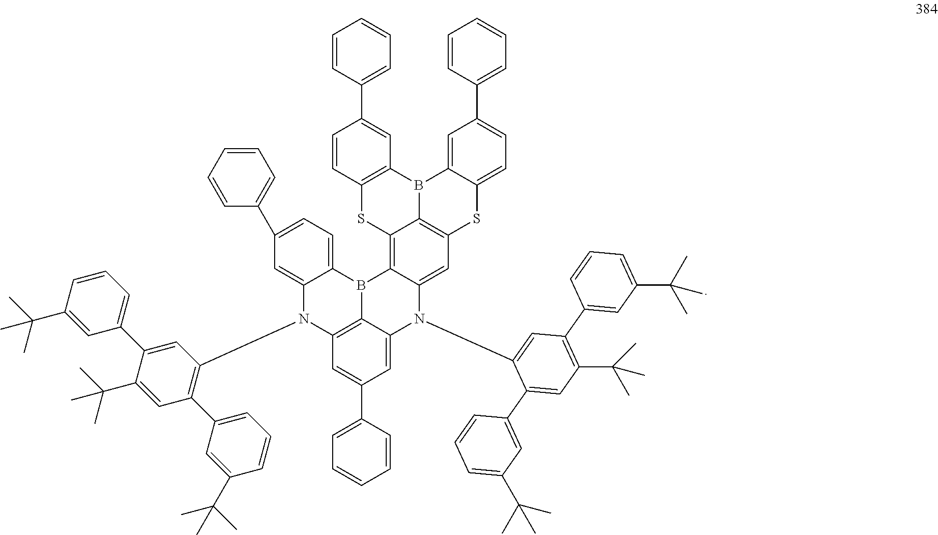 [SMILES: CC(C)(C)c1cccc(-c2cc(C(C)(C)C)c(-c3cccc(C(C)(C)C)c3)cc2N2c3cc(-c4ccccc4)ccc3B3c4c2cc(-c2ccccc2)cc4N(c2cc(-c4cccc(C(C)(C)C)c4)c(C(C)(C)C)cc2-c2cccc(C(C)(C)C)c2)c2cc4c5c(c23)Sc2ccc(-c3ccccc3)cc2B5c2cc(-c3ccccc3)ccc2S4)c1]

A method of synthesizing the condensed cyclic compound may be recognized by those skilled in the art by referring to the synthesis examples described below.

### Light-Emitting Device

According to another aspect, a light-emitting device is provided, including: a first electrode; a second electrode facing the first electrode; and an interlayer arranged between the first electrode and the second electrode, wherein the interlayer includes an emission layer, and wherein the interlayer further includes at least one of the condensed cyclic compounds.

The condensed cyclic compound may be included in the emission layer of the light-emitting device.

According to one or more embodiments, the condensed cyclic compound included in the emission layer may be an emitter.

The ratio of the fluorescence luminescent component emitted from the condensed cyclic compound, which is the emitter, with respect to the total luminescent components emitted from emission layer may be greater than or equal to about 70%, for example, about 70% to about 100%, about 70% to about 95%, about 70% to about 90%, about 70% to about 85%, or about 70% to about 80%. The fluorescent luminescent component emitted from the condensed cyclic compound may be a luminescent component emitted when an exciton of the condensed cyclic compound transitions from a singlet excited state to a ground state. Therefore, the emission layer may be a fluorescent emission layer. The fluorescent emission layer may be clearly distinct from a phosphorescent emission layer which includes a phosphorescent emitter (e.g., an organometallic compound including a transition metal) and in which the ratio of the phosphorescent luminescent component emitted from the phosphorescent emitter with respect to the total luminescent components is about 70% or more.

The emission layer may further include a sensitizer in addition to the emitter.

According to another example, the emission layer may further include a host in addition to the emitter.

According to another example, the emission layer may further include a sensitizer and a host in addition to the emitter.

The number of hosts may be represented as m1. m1 may be an integer greater than or equal to 1 (for example, 1 or 2). When m1 is 2 or more, two or more hosts in the emission layer may be different from each other. When m1 is 2 or more, the host of the emission layer may be a mixture of different hosts. In one or more embodiments, m1 is 2, the host includes a first host and a second host, and the first host and the second host may be different from each other. The emitter and m1 hosts may be different from each other. In one or more embodiments, the emitter may be a delayed fluorescence emitter.

When m1 is 2, the weight ratio of two different hosts included in the emission layer may be about 1:9 to about 9:1, about 2:8 to about 8:2, about 3:7 to about 7:3, or about 4:6 to about 6:4. When the weight ratio is satisfied, movement of holes and electrons in the emission layer may occur efficiently.

According to one or more embodiments, the emission layer may further include a sensitizer and a host in addition to the condensed cyclic compound as an emitter, and excitation energy (or exciton) in the emission layer moves from at least one of the sensitizer and the host to the condensed cyclic compound, and the condensed cyclic compound may absorb excitation energy from at least one of the sensitizer and the host and undergoes a radiative transition to a ground state to emit the same light as fluorescence, thereby enabling the light-emitting device to emit light.

When the emission layer further includes a sensitizer, 25% of the singlet excitons formed in the host in the emission layer may be transferred to the sensitizer through Förster energy transfer, and 75% of the energy of the triplet excitons formed in the host may be transferred to the singlet excited state and triplet excited state of the sensitizer. Among these, the triplet exciton transferred to the triplet excited state and the singlet exciton of the sensitizer may be transferred to the singlet excited state of the condensed cyclic compound, which is the emitter, through Förster energy transfer. Thereby, both singlet excitons and triplet excitons generated in the emission layer are transferred to the singlet excited state of the condensed cyclic compound and then undergo a radiative transition to the ground state, thereby emitting fluorescence with high luminescence efficiency, i.e., hyper fluorescence.

The weight of m1 hosts in the emission layer may be greater than the weight of the condensed cyclic compound or the total weight of the condensed cyclic compound and the sensitizer. The weight of m1 hosts in the emission layer may be about 60 wt % to about 99 wt %, about 70 wt % to about 97 wt %, about 80 wt % to about 96 wt %, or about 82 wt % to about 90 wt %, per 100 wt % of the emission layer.

The emission layer may emit a blue light (e.g., blue fluorescence).

The FWHM of fluorescence emitted from the emission layer may be about 5 nm to about 30 nm, about 10 nm to about 30 nm, or about 20 nm to about 30 nm.

As another example, the emission peak wavelength (maximum emission peak wavelength) of fluorescence emitted from the emission layer may be about 400 nm to about 500 nm, about 440 nm to about 470 nm, about 445 nm to about 470 nm, about 450 nm to about 470 nm, about 440 nm to about 465 nm, about 445 nm to about 465 nm, about 450 nm to about 465 nm, about 440 nm to about 460 nm, about 445 nm to about 460 nm, or about 450 nm to about 460 nm.

As another example, the CIEy value of light emitted from the emission layer may be about 0.040 to about 0.170, about 0.050 to about 0.170, about 0.060 to about 0.170, about 0.040 to about 0.165, about 0.050 to about 0.165, or about 0.060 to about 0.165.

The amount (weight) of the condensed cyclic compound, which is an emitter in the emission layer, may be about 0.01 parts by weight to about 40 parts by weight, about 0.1 parts by weight to about 20 parts by weight, about 0.1 parts by weight to about 10 parts by weight, about 0.1 parts by weight to about 5 parts by weight, about 0.5 parts by weight to about 5 parts by weight, or about 0.6 parts by weight to about 2 parts by weight, based on 100 parts by weight of the emission layer.

The term “emitter” as used herein refers to a material capable of emitting light by receiving excitons from a host, a sensitizer, and/or an auxiliary dopant and transitioning the same to the ground state.

The first electrode may be an anode, which is a hole injection electrode, and the second electrode may be a cathode, which is an electron injection electrode, or the first electrode may be a cathode, which is an electron injection electrode, and the second electrode may be an anode, which is a hole injection electrode.

In the organic light-emitting device, the first electrode may be an anode, the second electrode may be a cathode, and the interlayer may further include a hole transport region arranged between the first electrode and the emission layer and an electron transport region arranged between the emission layer and the second electrode, wherein the hole transport region may include a hole injection layer, a hole transport layer, an electron-blocking layer, a buffer layer, or a combination thereof, and the electron transport region may include a buffer layer, a hole-blocking layer, an electron transport layer, an electron injection layer, or a combination thereof.

The term “interlayer” as used herein refers to a single layer and/or a plurality of layers located between the first electrode and the second electrode of an organic light-emitting device. The “interlayer” as used herein may include, in addition to an organic compound, an organometallic complex including a metal.

### Sensitizer

The sensitizer transfers excitation energy (or excitons) from a host to an emitter, and relatively minimizes “Dexter energy transfer from the host to the emitter” that inhibits hyperfluorescence, thereby improving the luminescence efficiency and/or lifetime characteristics of a light-emitting device.

The sensitizer may be an organometallic compound, a delayed fluorescence material, a prompt fluorescence material, or a combination thereof.

The organometallic compound may include a transition metal and n ligands bonded to the transition metal, wherein n may be an integer from 1 to 4.

In one or more embodiments, the transition metal in the organometallic compound may be platinum (Pt) or palladium (Pd), n may be 1, and the ligand may be a tetradentate ligand. The tetradentate ligand may include, for example, a carbene moiety bonded to the transition metal.

In another embodiment, the organometallic compound may include a transition metal and a tetradentate ligand bonded to the transition metal, wherein the transition metal is platinum or palladium, and the tetradentate ligand may include a carbene moiety bonded to the transition metal.

In another embodiment, the transition metal in the organometallic compound may be iridium (Ir) or osmium (Os), n may be 3, and at least one of the n ligands may be a bidentate ligand including —F, a cyano group, or a combination thereof, or a bidentate ligand including a carbene moiety bonded to the transition metal. The bidentate ligand may include an imidazole group or a triazole group.

In some embodiments, the organometallic compound may be an organometallic compound represented by Formula 3 and/or an organometallic compound represented by Formula 5 as described herein. Formulae 3 and 5 will be described herein in detail.

The delayed fluorescence material may be, for example, a thermally activated non-radiative decay material. As another example, the delayed fluorescence material may be a multiple resonance thermally activated delayed fluorescence material, which is different from the delayed fluorescence emitter described herein.

The multiple resonance thermally activated delayed fluorescence material may be a polycyclic compound that i) does not contain a transition metal, and ii) includes a core in which two or more C₃-C₆₀ cyclic groups are condensed with each other. In this regard, two C₃-C₆₀ cyclic groups in the core may be condensed with each other while sharing boron (B) and/or nitrogen (N).

The prompt fluorescence material may be an amino group-containing compound, a styryl group-containing compound, or the like. The prompt fluorescence material may include a naphthalene group, a fluorene group, a spiro-bifluorene group, a benzofluorene group, a dibenzofluorene group, a phenanthrene group, an anthracene group, a fluoranthene group, a triphenylene group, a pyrene group, a chrysene group, a naphthacene group (tetracene group), a picene group, a perylene group, a pentaphene group, an indenoanthracene group, a group represented by one of Formulae 501-1 to 501-21, or a combination thereof:

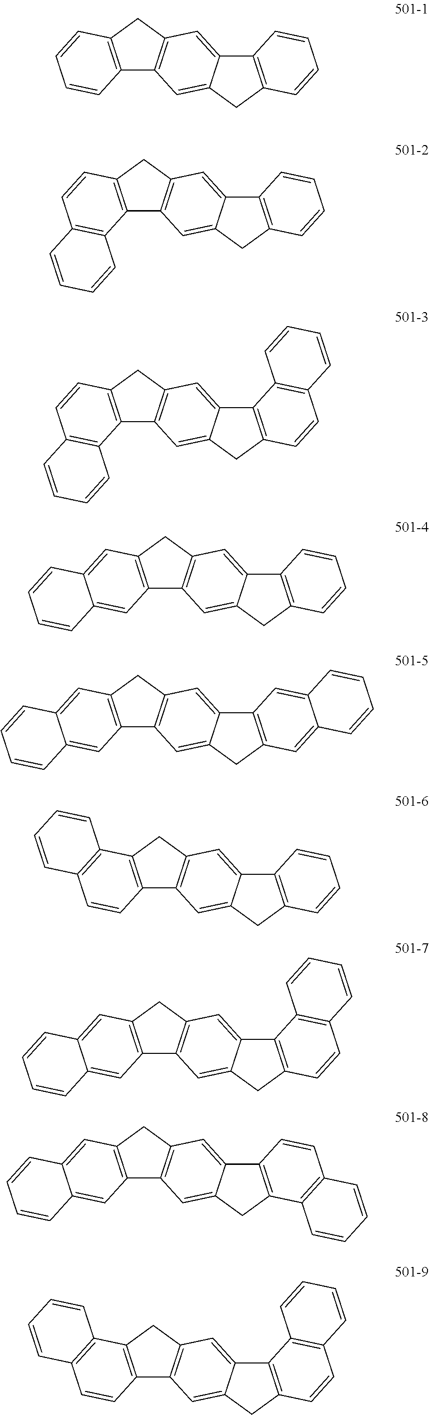

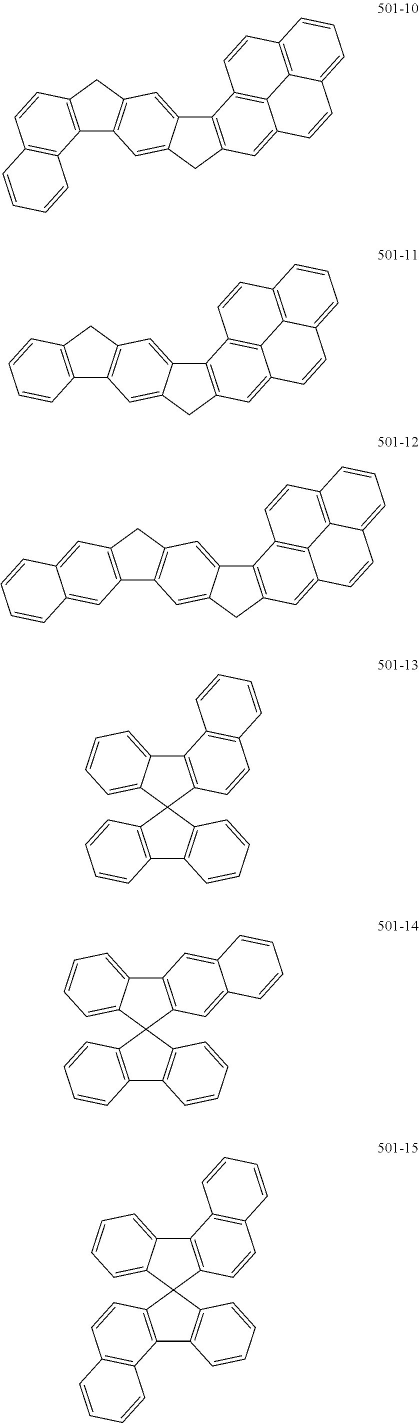

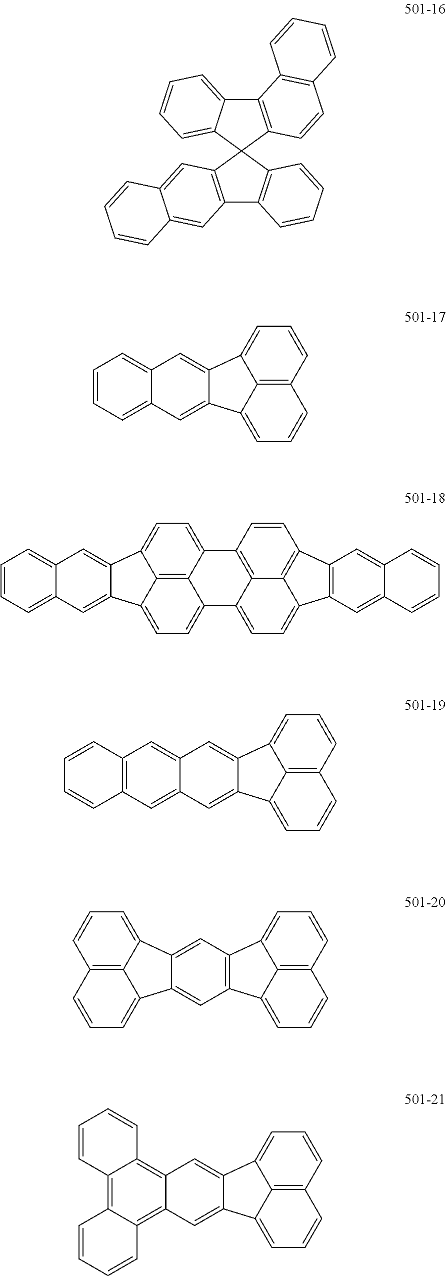

In one or more embodiments, the sensitizer may be an organometallic compound.

The amount (weight) of the sensitizer may be about 0.01 to about 30 parts by weight, about 0.01 to about 20 parts by weight, about 1 to about 18 parts by weight, or about 5 to about 15 parts by weight, based on 100 parts by weight of the emission layer.

### Host

The m1 hosts in the emission layer may include a hole-transporting compound, an electron-transporting compound, an bipolar compound, or a combination thereof. Each of the first host and second host may not include a transition metal.

Regarding the emission layer, when m1 is 2 and two hosts in the emission layer include a hole-transporting compound and an electron-transporting compound, respectively, the hole-transporting compound and the electron-transporting compound may be different from each other.

According to one or more embodiments, the hole-transporting compound may be a compound that includes at least one π electron rich C₃-C₆₀ cyclic group and no electron-transporting group. Examples of the electron-transporting group include a cyano group, a fluoro group, a π-electron deficient nitrogen-containing cyclic group, a phosphine oxide group, a sulfoxide group, or the like.

The “π-electron deficient nitrogen-containing cyclic group” as used herein may be a C₁-C₆₀ heterocyclic group having at least one *—N═*′ moiety as a ring-forming moiety.

Examples of the π-electron deficient nitrogen-containing cyclic group include a triazine group, an imidazole group, or the like.

The “π electron rich C₃-C₆₀ cyclic group” as used herein may be a C₃-C₆₀ cyclic group that does not include a *—N═*′ moiety as a ring-forming moiety. Non-limiting examples of the π electron rich C₃-C₆₀ cyclic group include a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, a dibenzocarbazole group, or the like.

The hole-transporting compound may include two or more carbazole groups.

The hole-transporting compound may include at least one silicon (e.g., a triphenylsilyl group or the like). In some embodiments, the hole-transporting compound may include at least one carbazole group and at least one silicon (e.g., a triphenylsilyl group or the like). The silicon may be linked to nitrogen of the carbazole group via an o-phenylene group or an m-phenylene group.

In some embodiments, the electron-transporting compound may be a compound including at least one electron-transporting group. The electron-transporting group may be a cyano group, a fluoro group, a π electron-deficient nitrogen-containing C₁-C₆₀ cyclic group, a phosphine oxide group, a sulfoxide group, or a combination thereof. In one or more embodiments, the electron-transporting compound may include a triazine group.

The electron-transporting compound may include at least one electron-transporting group (e.g., a triazine group or the like) and at least one π electron rich C₃-C₆₀ cyclic group (e.g., a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, a dibenzocarbazole group, or the like, or a combination thereof).

The electron-transporting compound may include at least one silicon (e.g., a triphenylsilyl group or the like). The electron-transporting compound may include a triazine group, at least one carbazole group, and at least one silicon (e.g., a triphenylsilyl group or the like). The silicon may be linked to carbon of the triazine group via an o-phenylene group or an m-phenylene group. The nitrogen of the carbazole group may be directly bonded to the carbon of the triazine group, or may be linked to the carbon of the triazine group via an o-phenylene group or an m-phenylene group.

According to one or more embodiments, the hole-transporting compound may be a compound represented by Formula 6, but embodiments are not limited thereto:

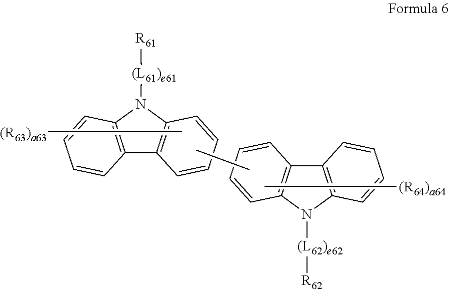

wherein, in Formula 6,
L₆₁ and L₆₂ may each independently be a π electron rich C₃-C₆₀ cyclic group (e.g., a C₆-C₁₂ arylene group or a C₆-C₁₀ arylene group) unsubstituted or substituted with deuterium, a C₁-C₂₀ alkyl group, a deuterated C₁-C₂₀ alkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), or a combination thereof,
e61 and e62 may each independently be an integer from 1 to 6,
R₆₁ to R₆₄ may each independently be:
hydrogen, deuterium, a C₁-C₂₀ alkyl group, or a deuterated C₁-C₂₀ alkyl group;
a π electron rich C₃-C₆₀ cyclic group (e.g., a C₆-C₁₂ aryl group or a C₆-C₁₀ aryl group) unsubstituted or substituted with deuterium, a C₁-C₂₀ alkyl group, a deuterated C₁-C₂₀ alkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), or a combination thereof; or
—Si(Q₃)(Q₄)(Q₅), and
a63 and a64 may each independently be an integer from 0 to 7,
wherein Q₃ to Q₅ and Q₃₃ to Q₃₅ are as described herein.

For example, each of Q₃ to Q₅ and Q₃₃ to Q₃₅ may be a phenyl group.

In some embodiments, the hole-transporting compound may be a compound represented by Formula 6-1, Formula 6-2, or Formula 6-3, but embodiments are not limited thereto:

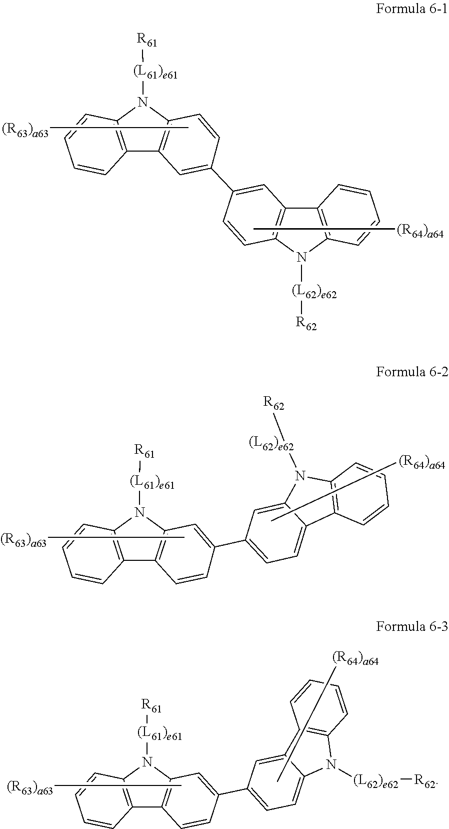

In Formulae 6-1 to 6-3, L₆₁, L₆₂, R₆₁ to R₆₄, e61, e62, a63, and a64 are as described herein.

In some embodiments, the hole-transporting compound may be one of compounds HTH1 to HTH7, but embodiments are not limited thereto:

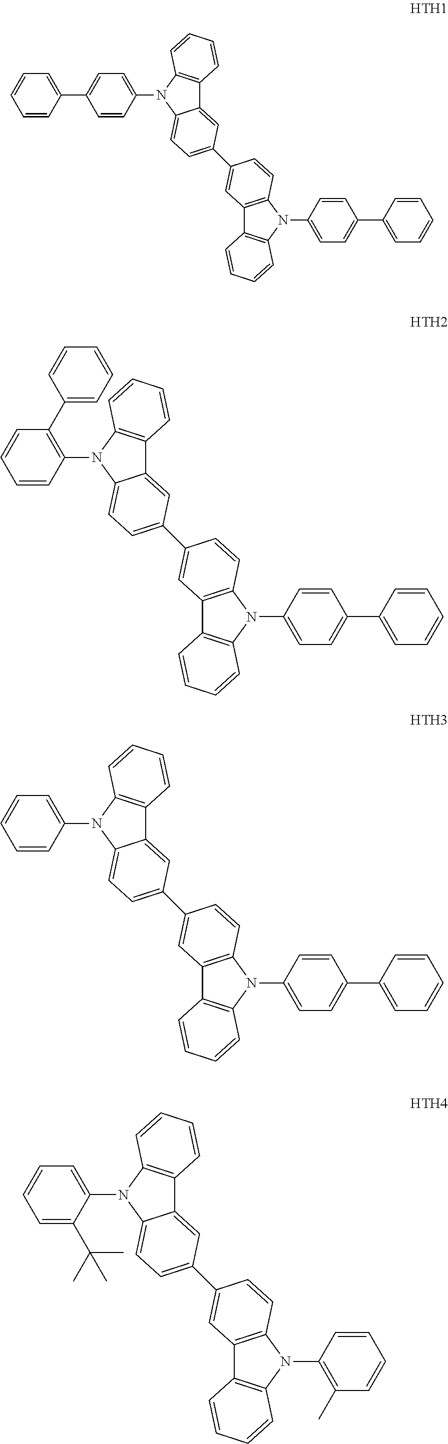 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; Cc1ccccc1-n1c2ccccc2c2cc(-c3ccc4c(c3)c3ccccc3n4-c3ccccc3C(C)(C)C)ccc21]

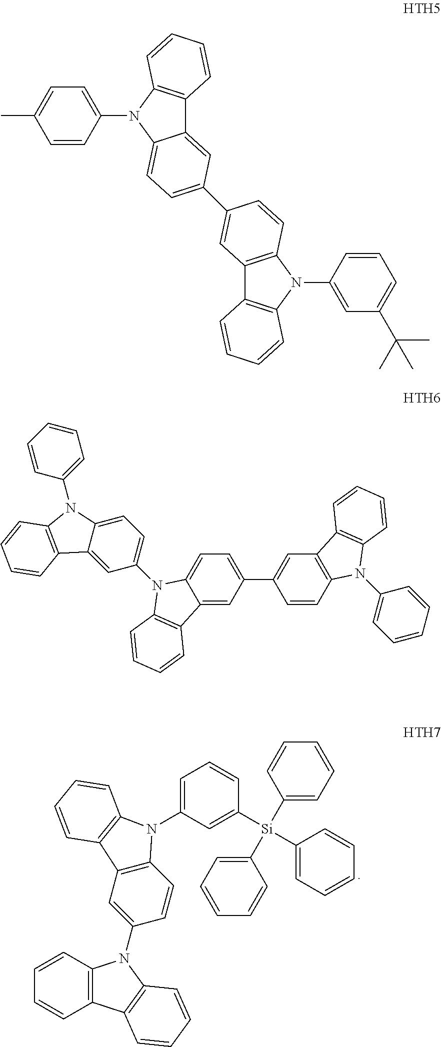 [SMILES: Cc1ccc(-n2c3ccccc3c3cc(-c4ccc5c(c4)c4ccccc4n5-c4cccc(C(C)(C)C)c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1 ; c1ccc([Si](c2ccccc2)(c2ccccc2)c2cccc(-n3c4ccccc4c4cc(-n5c6ccccc6c6ccccc65)ccc43)c2)cc1 ; "."]

In some embodiments, the electron-transporting compound may be a compound represented by Formula 7, but embodiments are not limited thereto:

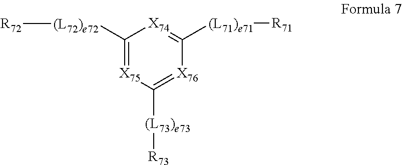

wherein, in Formula 7,
X₇₄ may be C(R₇₄) or N, X₇₅ may be C(R₇₅) or N, X₇₆ may be C(R₇₆) or N, and at least one of X₇₄ to X₇₆ (e.g., all of X₇₄ to X₇₆) may be N,
L₇₁ to L₇₃ may each independently be a C₅-C₃₀ carbocyclic group or a C₁-C₃₀ heterocyclic group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or a combination thereof,
e71 to e73 may each independently be an integer from 1 to 10,
R₇₁ to R₇₆ may each independently be:
hydrogen, deuterium, —F, or a cyano group;
a C₁-C₂₀ alkyl group unsubstituted or substituted with deuterium, —F, a cyano group, or a combination thereof;
a C₅-C₃₀ carbocyclic group or a C₁-C₃₀ heterocyclic group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or a combination thereof; or
—Si(Q₃)(Q₄)(Q₅).

Q₃ to Q₅ and Q₃₃ to Q₃₅ are as described herein. For example, each of Q₃ to Q₅ and Q₃₃ to Q₃₅ may be a phenyl group.

In some embodiments, each of X₇₄ to X₇₆ in Formula 7 may be N.

In some embodiments, L₇₁ to L₇₃ in Formula 7 may each independently be a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or a combination thereof.

In some embodiments, in Formula 7, at least one of L₇₁ in the number of e71, at least one of L₇₂ in the number of e72, at least one of L₇₃ in the number of e73, or a combination thereof may each independently be a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or a combination thereof.

In some embodiments, in Formula 7, at least one of L₇₁ in the number of e71, at least one of L₇₂ in the number of e72, at least one of L₇₃ in the number of e73, or a combination thereof may include a carbazole group, an indolocarbazole group, a benzocarbazole group, a naphthocarbazole group, or a dibenzocarbazole group, wherein the nitrogen atom of the pyrrole group in the carbazole group, the indolocarbazole group, the benzocarbazole group, the naphthocarbazole group, or the dibenzocarbazole group may be linked to a carbon atom of a 6-membered ring including X₇₄ to X₇₆ in Formula 7, with a single bond or adjacent L₇₁, L₇₂ and/or L₇₃ therebetween.

In some embodiments, e71 to e73 in Formula 7 represent the number of L₇₁ to the number of L₇₃, respectively, and may each independently be 1, 2, 3, 4, or 5.

In some embodiments, R₇₁ to R₇₆ in Formula 7 may each independently be:
hydrogen, deuterium, —F, or a cyano group,
a C₁-C₂₀ alkyl group unsubstituted or substituted with deuterium, —F, a cyano group, or a combination thereof;
a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or a combination thereof; or
—Si(Q₃)(Q₄)(Q₅).

In some embodiments, the electron-transporting compound may be one of compounds ETH1 to ETH8, but embodiments are not limited thereto:

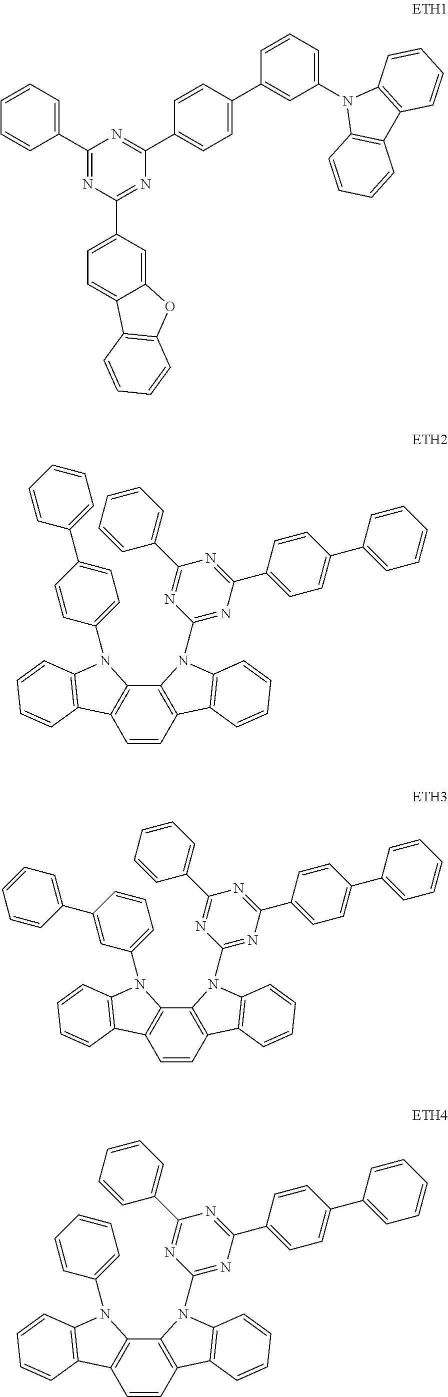 [SMILES: c1ccc(-c2nc(-c3ccc(-c4cccc(-n5c6ccccc6c6ccccc65)c4)cc3)nc(-c3ccc4c(c3)oc3ccccc34)n2)cc1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1 ; c1ccc(-c2ccc(-c3nc(-c4ccccc4)nc(-n4c5ccccc5c5ccc6c7ccccc7n(-c7ccccc7)c6c54)n3)cc2)cc1]

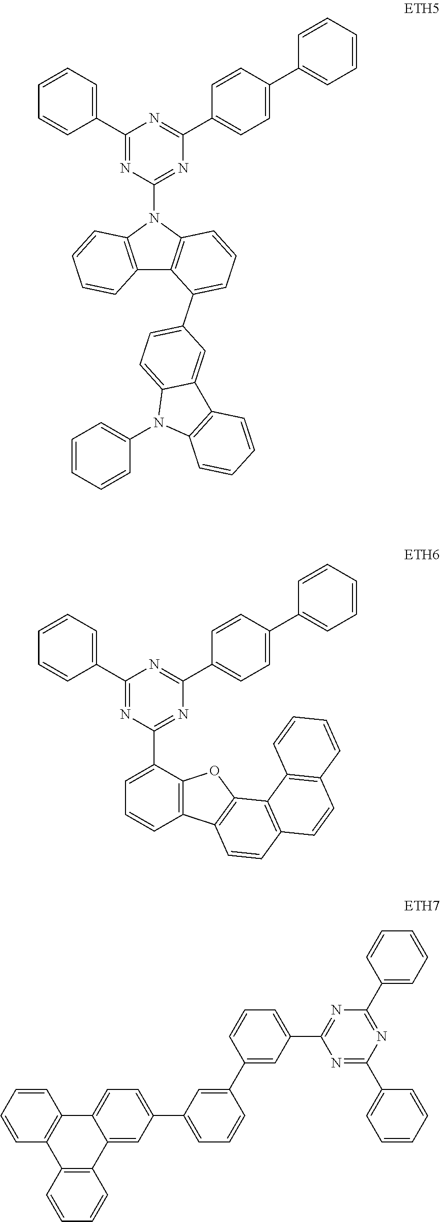 [SMILES: c1ccc(-c2ccc(-c3nc(-c4ccccc4)nc(-n4c5ccccc5c5c(-c6ccc7c(c6)c6ccccc6n7-c6ccccc6)cccc54)n3)cc2)cc1 ; c1ccc(-c2ccc(-c3nc(-c4ccccc4)nc(-c4cccc5c4oc4c5ccc5ccc6ccccc6c54)n3)cc2)cc1 ; c1ccc(-c2nc(-c3ccccc3)nc(-c3cccc(-c4cccc(-c5ccc6c7ccccc7c7ccccc7c6c5)c4)c3)n2)cc1]

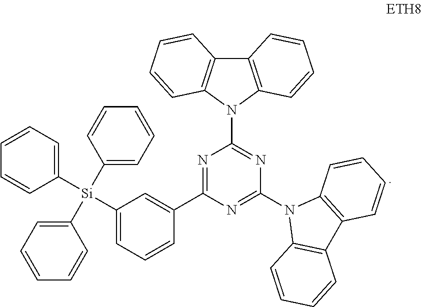 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; "."]

### Description of Formula 3

The organometallic compound may be an organometallic compound represented by Formula 3:

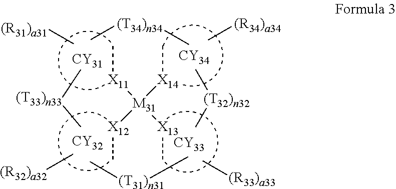

wherein, in Formula 3,
M₃₁ may be a transition metal,
X₁₁ to X₁₄ may each independently be C or N,
two bonds of a bond between X₁₁ and M₃₁, a bond between X₁₂ and M₃₁, a bond between X₁₃ and M₃₁, and a bond between X₁₄ and M₃₁ may each be a coordinate bond, and the other two bonds may each be a covalent bond,
ring CY₃₁ to ring CY₃₄ may each independently be a C₅-C₃₀ carbocyclic group or a C₁-C₃₀ heterocyclic group,
T₃₁ may be a single bond, a double bond, *—N(R₃₅ₐ)—*′, *—B(R₃₅ₐ)—*′, *—P(R₃₅ₐ)—*′, *—C(R₃₅ₐ)(R_{35b})—*′, *—Si(R₃₅ₐ)(R_{35b})—*′, *—Ge(R₃₅ₐ)(R_{35b})*′, *—S—*′, *—Se—*′, *—O—*′, *—C(═O)—*′, *—S(═O)—*′, *—S(═O)₂—*′, *—C(R₃₅ₐ)═*′, *═C(R₃₅ₐ)—*′, *—C(R₃₅ₐ)═C(R_{35b})—*′, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
T₃₂ may be a single bond, a double bond, *—N(R₃₆ₐ)*′, *—B(R₃₆ₐ)—*′, *—P(R₃₆ₐ)—*′, *—C(R₃₆ₐ)(R_{36b})—*′, *—Si(R₃₆ₐ)(R_{36b})—*′, *—Ge(R₃₆ₐ)(R_{36b})*′, *—S—*′, *—Se—*′, *—O—*′, *—C(═O)—*′, *—S(═O)—*′, *—S(═O)₂—*′, *—C(R₃₆ₐ)═*′, *═C(R₃₆ₐ)—*′, *—C(R₃₆ₐ)═C(R_{36b})—*′, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
T₃₃ may be a single bond, a double bond, *—N(R₃₇ₐ)—*′, *—B(R₃₇ₐ)—*′, *—P(R₃₇ₐ)—*′, *—C(R₃₇ₐ)(R_{37b})*′, *—Si(R₃₇ₐ)(R_{37b})—*′, *—Ge(R₃₇ₐ)(R_{37b})*′, *—S—*′, *—Se—*′, *—O—*′, *—C(═O)—*′, *—S(═O)—*′, *—S(═O)₂—*′ *—C(R₃₇ₐ)═*′, *═C(R₃₇ₐ)—*′, *—C(R₃₇ₐ)═C(R_{37b})—*′, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
T₃₄ may be a single bond, a double bond, *—N(R₃₈ₐ)*′, *—B(R₃₈ₐ)—*′, *—P(R₃₈ₐ)—*′, *—C(R₃₈ₐ)(R_{38b})—*′, *—Si(R₃₈ₐ)(R_{38b})—*′, *—Ge(R₃ₐ)(R_{3b})—*′, *—S—*′, *—Se—*′, *—O—*′, *—C(═O)—*′, *—S(═O)—*′, *—S(═O)₂—*′ *—C(R₃₈ₐ)═*′, *═C(R₃₈ₐ)—*′, *—C(R₃₈ₐ)═C(R_{38b})—*′, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
n31 to n34 may each independently be an integer from 0 to 5, and three or more of n31 to n34 may each independently be an integer from 1 to 5,
when n31 is 0, T₃₁ may not be present, when n32 is 0, T₃₂ may not be present, when n33 is 0, T₃₃ may not be present, and when n34 is 0, T₃₄ may not be present,
when n31 is 2 or more, two or more of T₃₁(s) may be identical to or different from each other, when n32 is 2 or more, two or more of T₃₂(s) may be identical to or different from each other, when n33 is 2 or more, two or more of T₃₃(s) may be identical to or different from each other, and when n34 is 2 or more, two or more of T₃₄(s) may be identical to or different from each other,
R₃₁ to R₃₄, R₃₅ₐ, R_{35b}, R₃₆ₐ, R_{36b}, R₃₇ₐ, R_{37b}, R₃₈ₐ, and R_{38b} may each independently be hydrogen, deuterium, —F, —Cl, —Br, —I, —SF₅, —CD₃, —CD₂H, —CDH₂, —CF₃, —CF₂H, —CFH₂, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryl alkyl group, a substituted or unsubstituted C₆-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₁-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
a31 to a34 may each independently be an integer from 0 to 20,
two or more of R₃₁ in the number of a31 may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₂ in the number of a32 may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₃ in the number of a33 may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₄ in the number of a34 may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₁, R₃₂, R₃₃, R₃₄, R₃₅ₐ, R_{35b}, R₃₆ₐ, R_{36b}, R₃₇ₐ, R_{37b}, R₃₈ₐ, and R_{38b} may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
R₁₀ₐ is the same as described in connection with R₃₁,
* and *′ each indicate a binding site to a neighboring atom,
substituents of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryl alkyl group, the substituted C₆-C₆₀ alkyl aryl group, the substituted C₆-C₆₀ aryloxy group, the substituted C₆-C₆₀ arylthio group, the substituted C₁-C₆₀ heteroaryl group, the substituted C₁-C₆₀ alkyl heteroaryl group, the substituted C₁-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may each independently be:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkylthio group, or a C₁-C₆₀ alkoxy group,
a C₁-C₆₀ alkyl group, a C₂-C₆₀ alkenyl group, a C₂-C₆₀ alkynyl group, a C₁-C₆₀ alkylthio group, or a C₁-C₆₀ alkoxy group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl alkyl group, a C₆-C₆₀ alkyl aryl group, a C₆-C₆₀ aryloxy group, a C₆-C₆₀ arylthio group, a C₁-C₆₀ heteroaryl group, a C₁-C₆₀ alkyl heteroaryl group, a C₁-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₃)(Q₁₉), —P(Q₁₈)(Q₁₉), or a combination thereof,
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl alkyl group, a C₆-C₆₀ aryloxy group, a C₆-C₆₀ arylthio group, a C₁-C₆₀ heteroaryl group, a C₁-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —C₁, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl alkyl group, a C₆-C₆₀ alkyl aryl group, a C₆-C₆₀ aryloxy group, a C₆-C₆₀ arylthio group, a C₁-C₆₀ heteroaryl group, a C₁-C₆₀ alkyl heteroaryl group, a C₁-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof, and

Q₁ to Q₉, Q₁₁ to Q₁₉, Q₂₁ to Q₂₉, and Q₃₁ to Q₃₉ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group which is unsubstituted or substituted with deuterium, a C₁-C₆₀ alkyl group, a C₆-C₆₀ aryl group, or a combination thereof, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group which is unsubstituted or substituted with deuterium, a C₁-C₆₀ alkyl group, a C₆-C₆₀ aryl group, or a combination thereof, a C₆-C₆₀ aryloxy group, a C₆-C₆₀ arylthio group, a C₁-C₆₀ heteroaryl group, a C₁-C₆₀ alkyl heteroaryl group, a C₁-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group.

According to one or more embodiments, M₃₁ in Formula 3 may be Pt, Pd or Au.

In some embodiments, M₃₁ in Formula 3 may be Pt or Pd.

In some embodiments, the bond between X₁₁ and M₃₁ in Formula 3 may be a coordinate bond.

In one or more embodiments, in Formula 3, X₁₁ may be C, and a bond between X₁₁ and M₃₁ may be a coordinate bond. That is, X₁₁ in Formula 3 may be C in a carbene moiety.

In one or more embodiments, ring CY₃₁ to ring CY₃₄ in Formula 3 may each independently be i) a first ring, ii) a second ring, iii) a condensed ring group in which two or more first rings are condensed with each other, iv) a condensed ring group in which two or more second rings are condensed with each other, or v) a condensed ring group in which at least one first ring is condensed with at least one second ring,
wherein the first ring may be a cyclopentane group, a cyclopentadiene group, a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and
the second ring may be an adamantane group, a norbornane group, a norbornene group, a cyclohexane group, a cyclohexene group, a benzene group, a pyridine group, a pyrimidine group, a pyrazine group, a pyridazine group, a triazine group, an oxazine group, a thiazine group, a dihydropyrazine group, a dihydropyridine group, or a dihydroazasiline group.

According to one or more embodiments, R₃₁ to R₃₄, R₃₅ₐ, R_{35b}, R₃₆ₐ, R_{36b}, R₃₇ₐ, R_{37b}, R₃₈ₐ, and R_{38b} may each independently be:
hydrogen, deuterium, —F, —Cl, —Br, —I, —SF₅, —CD₃, —CD₂H, —CDH₂, —CF₃, —CF₂H, —CFH₂, a cyano group (CN), a nitro group, an amino group, a C₁-C₂₀ alkyl group, a C₁-C₂₀ alkylthio group, or a C₁-C₂₀ alkoxy group,
a C₁-C₂₀ alkyl group, a C₁-C₂₀ alkylthio group, or a C₁-C₂₀ alkoxy group, each substituted with at least one of deuterium, —F, —Cl, —Br, —I, —SF₅, —CD₃, —CD₂H, —CDH₂, —CF₃, —CF₂H, —CFH₂, a cyano group (CN), a nitro group, an amino group, or a phenyl group; or
a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, or an anthracenyl group, each unsubstituted or substituted with at least one of deuterium, —F, —Cl, —Br, —I, —SF₅, —CD₃, —CD₂H, —CDH₂, —CF₃, —CF₂H, —CFH₂, a cyano group (CN), a nitro group, an amino group, a C₁-C₂₀ alkyl group, a C₁-C₂₀ alkoxy group, a C₁-C₂₀ alkylthio group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, or an anthracenyl group.

According to one or more embodiments, the organometallic compound represented by Formula 3 may be an organometallic compound represented by Formula 3-1 or an organometallic compound represented by Formula 3-2:

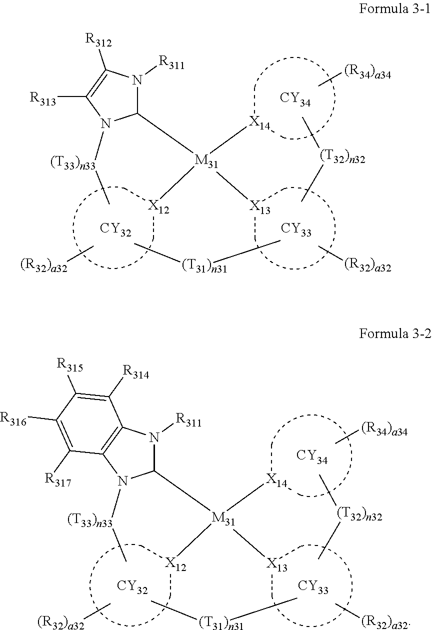

In Formula 3-1 the bond between the carbon of the imidazole group and M₃₁ may be a coordinate bond. That is, the imidazole group in Formula 3-1 may include a carbene moiety bonded to M₃₁.

In Formula 3-2, the bond between the carbon of the benzimidazole group and M₃₁ may be a coordinate bond. That is, the benzimidazole group in Formula 3-2 may include a carbene moiety bonded to M₃₁.

Therefore, it may be easily understood that Formula 3-1′, in which the carbon bonded to M₃₁ in an imidazole group is carbene, is identical to Formula 3-1, and Formula 3-2′, in which the carbon bonded to M₃₁ in a benzimidazole group is carbene, is identical to Formula 3-2:

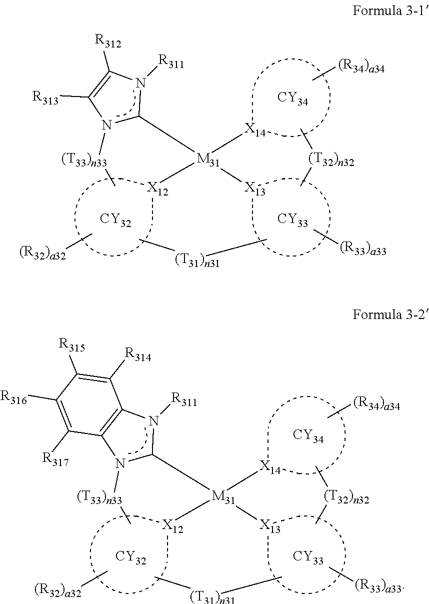

wherein, in Formulae 3-1 and 3-2,
M₃₁, ring CY₃₂, ring CY₃₃, ring CY₃₄, X₁₂, X₁₃, X₁₄, T₃₁, T₃₂, T₃₃, n31, n32, n33, R₃₂, R₃₃, R₃₄, a32, a33, and a34 may respectively be understood by referring to the descriptions of M₃₁, ring CY₃₂, ring CY₃₃, ring CY₃₄, X₁₂, X₁₃, X₁₄, T₃₁, T₃₂, T₃₃, n31, n32, n33, R₃₂, R₃₃, R₃₄, a32, a33, and a34 provided herein, and
R₃₁₁ to R₃₁₇ may each be understood by referring to the description of R₃₁ provided herein.

In one or more embodiments, in Formulae 3-1 and 3-2,
R₃₁₁ to R₃₁₇ may each independently be:
hydrogen, deuterium, —F, —Cl, —Br, —I, —CD₃, —CD₂H, —CDH₂, —CF₃, —CF₂H, —CFH₂, —SF₅, a hydroxyl group, a cyano group, a nitro group, an amino group, an amidino group, a hydrazine group, a hydrazone group, a carboxylic acid group or a salt thereof, a sulfonic acid group or a salt thereof, or a phosphoric acid group or a salt thereof;
a C₁-C₂₀ alkyl group, a C₁-C₂₀ alkylthio group, or a C₁-C₂₀ alkoxy group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, or a combination thereof;
a C₃-C₁₀ cycloalkyl group, a C₁-C₁₀ heterocycloalkyl group, a C₆-C₆₀ aryl group, a C₆-C₆₀ aryl alkyl group, a C₆-C₆₀ aryloxy group, a C₆-C₆₀ arylthio group, a C₁-C₆₀ heteroaryl group, a C₁-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a C₁-C₂₀ alkyl group, a C₁-C₂₀ alkoxy group, a C₁-C₂₀ alkylthio group, or a combination thereof; or
—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉).

At least one of R₃₁₁ to R₃₁₇ of Formula 3-1 and Formula 3-2 may include a C₁-C₂₀ alkyl group, a C₆-C₆₀ aryl group, or a C₇-C₆₀ aryl alkyl group, each unsubstituted or substituted with deuterium, a methyl group, an ethyl group, an n-propyl group, an isopropyl group, an n-butyl group, an isobutyl group, a sec-butyl group, a tert-butyl group, a phenyl group, a cumyl group, or a combination thereof. According to one or more embodiments, the organometallic compound represented by Formula 3 may be an organometallic compound represented by Formula 3-1(1) or an organometallic compound represented by Formula 3-2(1):

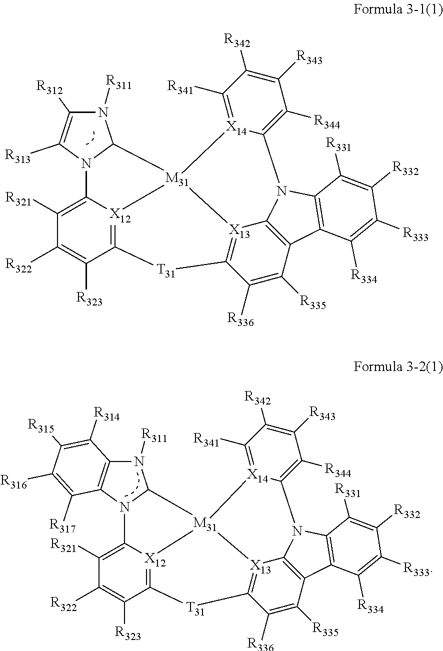

In Formulae 3-1(1) and 3-2(1),
M₃₁, X₁₂, X₁₃, X₁₄, and T₃₁ are each as described herein, and
R₃₁₁ to R₃₁₇ are each as described herein.

R₃₂₁ to R₃₂₃ are each as described in connection with R₃₂, and two or more of R₃₂₁ to R₃₂₃ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
R₃₃₁ to R₃₃₆ are each as described in connection with R₃₃, and two or more of R₃₃₁ to R₃₃₆ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ, and
R₃₄₁ to R₃₄₄ are each as described in connection with R₃₄, and two or more of R₃₄₁ to R₃₄₄ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ. R₁₀ₐ is as described herein.

### Description of Formula 5

The organometallic compound may be an organometallic compound represented by Formula 5:

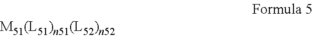

In Formula 5, M₅₁ may be a transition metal.

In one or more embodiments, M₅₁ may be a first-row transition metal of the Periodic Table of Elements, a second-row transition metal of the Periodic Table of Elements, or a third-row transition metal of the Periodic Table of Elements.

In one or more embodiments, M₅₁ may be iridium (Ir), platinum (Pt), osmium (Os), titanium (Ti), zirconium (Zr), hafnium (Hf), europium (Eu), terbium (Tb), thulium (Tm), or rhodium (Rh).

In one or more embodiments, M₅₁ may be Ir, Pt, Os, or Rh.

In some embodiments, M₅₁ may be Ir or Os.

In Formula 5, L₅₁ may be a ligand represented by Formula 5A, and L₅₂ may be a ligand represented by Formula 5B:

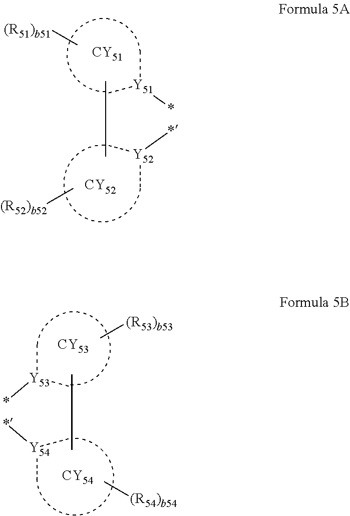

wherein Formulae 5A and 5B are each as described herein.

In Formula 5, n51 may be 1, 2, or 3, wherein, when n51 is 2 or more, two or more of L₅₁ (s) may be identical to or different from each other.

In Formula 5, n52 may be 0, 1, or 2, wherein, when n52 is 2, two L₅₂(s) may be identical to or different from each other.

The sum of n51 and n52 in Formula 5 may be 2 or 3. The sum of n51 and n52 may be 3.

In one or more embodiments, in Formula 5, i) M may be Ir, and the sum of n51 and n52 is 3; or ii) M may be Pt, and the sum of n51 and n52 is 2.

In one or more embodiments, in Formula 5, M may be Ir, and i) n51 may be 1, and n52 may be 2, or ii) n51 may be 2, and n52 may be 1.

L₅₁ and L₅₂ in Formula 5 may be different from each other.

Y₅₁ to Y₅₄ in Formulae 5A to 5B may each independently be C or N. Y₅₁ and Y₅₃ may each be N, and Y₅₂ and Y₅₄ may each be C.

Ring CY₅₁ to ring CY₅₄ in Formulae 5A and 5B may each independently be a C₅-C₃₀ carbocyclic group or a C₁-C₃₀ heterocyclic group.

Ring CY₅₁ to ring CY₅₄ in Formulae 5A and 5B may each independently be i) a third ring, ii) a fourth ring, iii) a condensed ring group in which two or more third rings are condensed with each other, iv) a condensed ring group in which two or more fourth rings are condensed with each other, or v) a condensed ring group in which at least one third ring is condensed with at least one fourth ring,
wherein the third ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and
the fourth ring may be an adamantane group, a norbornane group, a norbornene group, a cyclohexane group, a cyclohexene group, a benzene group, a pyridine group, a pyrimidine group, a pyrazine group, a pyridazine group, or a triazine group.

In some embodiments, ring CY₅₁ to ring CY₅₄ in Formulae 5A and 5B may each independently be a cyclopentane group, a cyclohexane group, a cyclohexene group, a benzene group, a naphthalene group, an anthracene group, a phenanthrene group, a triphenylene group, a pyrene group, a chrysene group, a 1, 2, 3, 4-tetrahydronaphthalene group, a cyclopentadiene group, a pyrrole group, a furan group, a thiophene group, a silole group, a borole group, a phosphole group, a germole group, a selenophene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluoren-9-one group, a dibenzothiophene 5, 5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza9H-fluoren-9-one group, an azadibenzothiophene 5, 5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrazole group, a imidazole group, a triazole group, an oxazole group, an isoxazole group, a thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a pyridinopyrrole group, a pyridinopyrazole group, a pyridinoimidazole group, a pyridinooxazole group, a pyridinoisoxazole group, a pyridinothiazole group, a pyridinoisothiazole group, a pyridinooxadiazole group, a pyridinothiadiazole group, a pyrimidinopyrrole group, a pyrimidinopyrazole group, a pyrimidinoimidazole group, a pyrimidinooxazole group, a pyrimidinoisoxazole group, a pyrimidinothiazole group, a pyrimidinoisothiazole group, a pyrimidinooxadiazole group, a pyrimidinothiadiazole group, a 5, 6, 7, 8-tetrahydroisoquinoline group, a 5, 6, 7, 8-tetrahydroquinoline group, an adamantane group, a norbornane group, a norbornene group, a benzene group condensed with a cyclohexane group, a benzene group condensed with a norbornane group, a pyridine group condensed with a cyclohexane group, or a pyridine group condensed with a norbornane group.

Ring CY₅₁ and ring CY₅₃ in Formulae 5A and 5B may be different from each other.

In one or more embodiments, ring CY₅₂ and ring CY₅₄ in Formulae 5A and 5B may be different from each other.

In one or more embodiments, ring CY₅₁ to ring CY₅₄ in Formulae 5A and 5B may be different from each other.

R₅₁ to R₅₄ in Formulae 5A and 5B may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryl alkyl group, a substituted or unsubstituted C₆-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₁-C₆₀ alkyl heteroaryl group, a substituted or unsubstituted C₁-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₅₁)(Q₅₂), —Si(Q₅₃)(Q₅₄)(Q₅₅), —Ge(Q₅₃)(Q₅₄)(Q₅₅), —B(Q₅₆)(Q₅₇), —P(═O)(Q₅₅)(Q₅₉), or —P(Q₅₅)(Q₅₉). Q₅₁ to Q₅₉ are each the same as described herein.

In one or more embodiments, R₅₁ to R₅₄ in Formulae 5A and 5B may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group or azadibenzothiophenyl group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a (phenyl)C₁-C₁₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or
—N(Q₅₁)(Q₅₂), —Si(Q₅₃)(Q₅₄)(Q₅₅), —Ge(Q₅₃)(Q₅₄)(Q₅₅), —B(Q₅₆)(Q₅₇), —P(═O)(Q₅₈)(Q₅₉), or —P(Q₅₈)(Q₅₉), and
Q₅₁ to Q₅₉ may each independently be:
CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

In one or more embodiments, R₅₁ to R₅₄ may each independently be:
hydrogen, deuterium, —F, or a cyano group;
a C₁-C₂₀ alkyl group unsubstituted or substituted with deuterium, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated a dibenzothiophenyl group, a (C₁-C₂₀ alkyl)dibenzothiophenyl group, or a combination thereof;
a C₃-C₁₀ cycloalkyl group, a C₁-C₁₀ heterocycloalkyl group, a phenyl group, or a biphenyl group, each unsubstituted or substituted with deuterium, a cyano group, a C₁-C₂₀ alkyl group, a deuterated C₁-C₂₀ alkyl group, a fluorinated C₁-C₂₀ alkyl group, a C₁-C₂₀ alkoxy group, a deuterated C₁-C₂₀ alkoxy group, a fluorinated C₁-C₂₀ alkoxy group, a C₁-C₂₀ alkylthio group, a deuterated C₁-C₂₀ alkylthio group, a fluorinated C₁-C₂₀ alkylthio group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated a phenyl group, a (C₁-C₂₀ alkyl)phenyl group, a biphenyl group, a deuterated biphenyl group, a fluorinated a biphenyl group, a (C₁-C₂₀ alkyl)biphenyl group, a dibenzofuranyl group, a deuterated dibenzofuranyl group, a fluorinated a dibenzofuranyl group, a (C₁-C₂₀ alkyl)dibenzofuranyl group, a dibenzothiophenyl group, a deuterated dibenzothiophenyl group, a fluorinated a dibenzothiophenyl group, a (C₁-C₂₀ alkyl)dibenzothiophenyl group, or a combination thereof; or
—Si(Q₅₃)(Q₅₄)(Q₅₅) or —Ge(Q₅₃)(Q₅₄)(Q₅₅).

b51 to b54 in Formulae 5A and 5B indicate the numbers of R₅₁ to R₅₄, respectively, and may each independently be an integer from 0 to 20. When b51 is 2 or more, two or more of R₅₁ may be identical to or different from each other, when b52 is 2 or more, two or more of R₅₂ may be identical to or different from each other, when b53 is 2 or more, two or more of R₅₃ may be identical to or different from each other, and when b54 is 2 or more, two or more of R₅₄ may be identical to or different from each other. In one or more embodiments, b51 to b54 may each independently be an integer from 0 to 8.

According to one or more embodiments, Y₅₂ in Formula 5A may be C, the bond between Y₅₂ and M₅₁ may be a covalent bond, and at least one of R₅₂ in the number of b52 may be a cyano group or —F.

In some embodiments, in Formula 5A, Y₅₁ may be N, the bond between Y₅₁ and M₅₁ may be a coordinate bond, CY₅₁ may be an imidazole group, a triazole group, a benzimidazole group, or a triazolopyridine group, and at least one of R₅₂ in the number of b52 may be a cyano group or —F.

In some embodiments, in Formula 5A, Y₅₁ may be C, and the bond between Y₅₁ and M₅₁ may be a coordinate bond.

In some embodiments, in Formula 5A, Y₅₁ may be C, the bond between Y₅₁ and M₅₁ may be a coordinate bond, and CY₅₁ may be a benzimidazole group or an imidazopyrazine group.

### Specific Examples of Organometallic Compounds Represented by Formula 3 or Formula 5

The organometallic compound represented by Formula 3 or Formula 5 may be one of compounds P1 to P52:

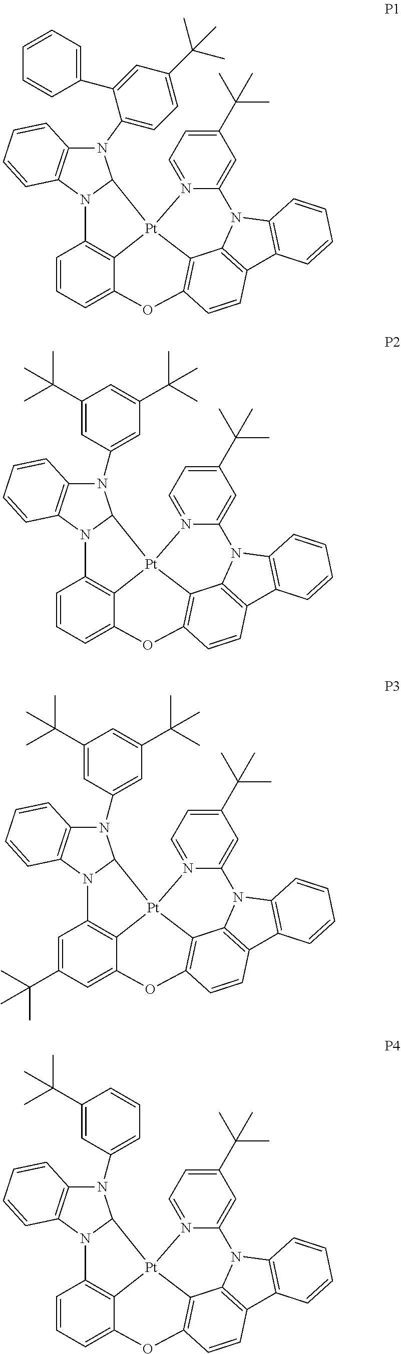

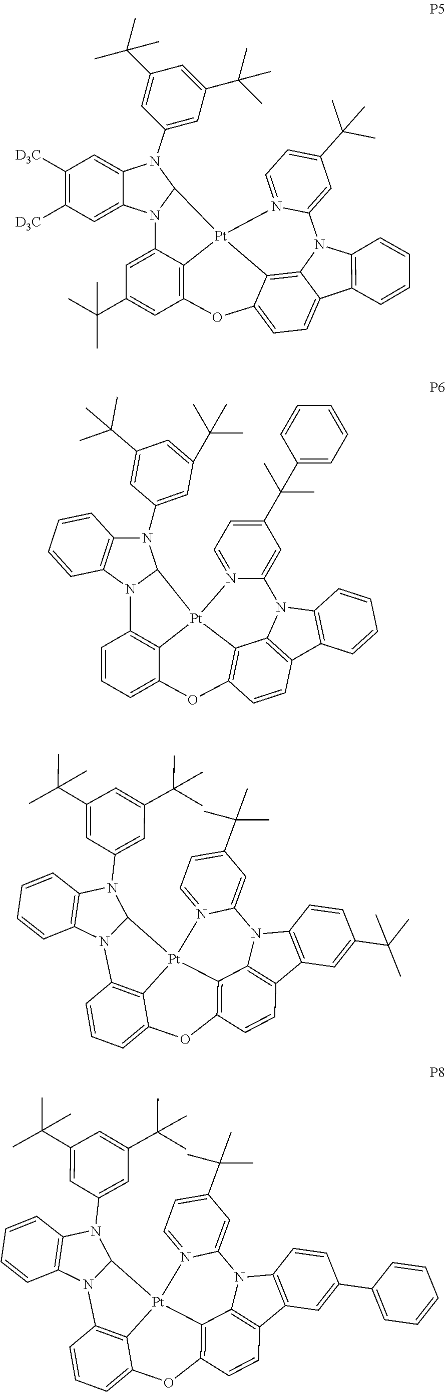

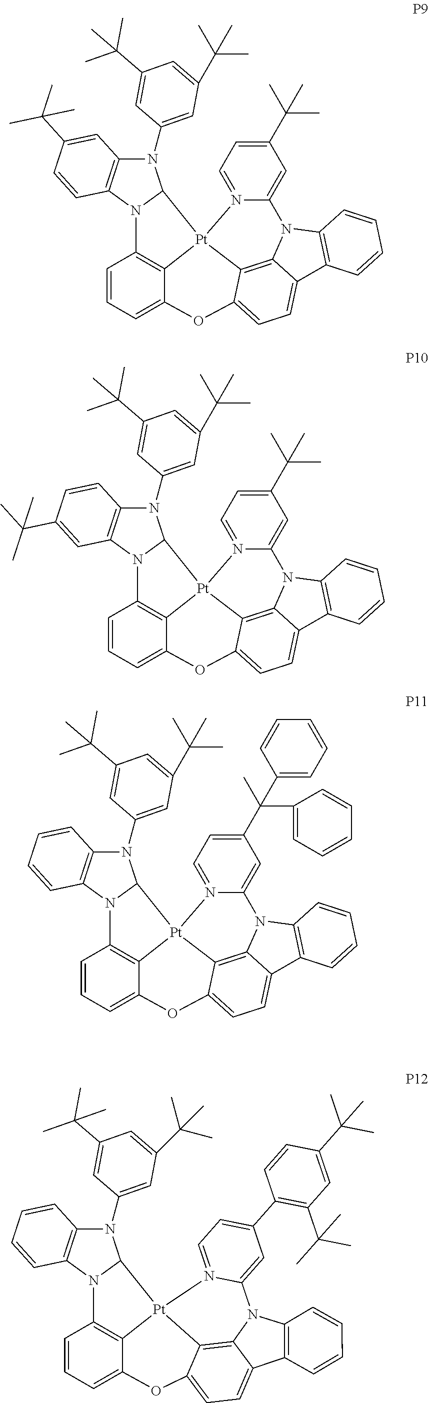

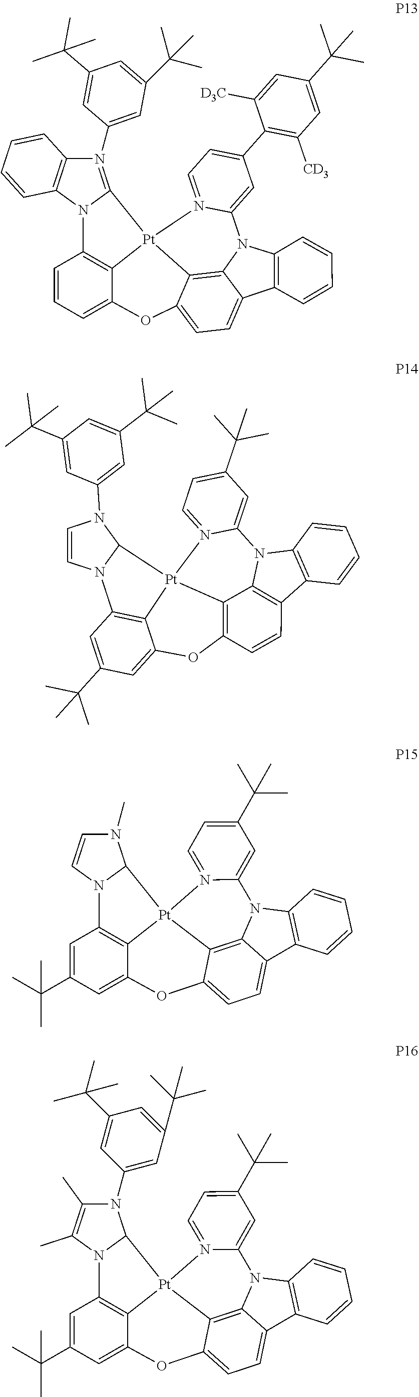

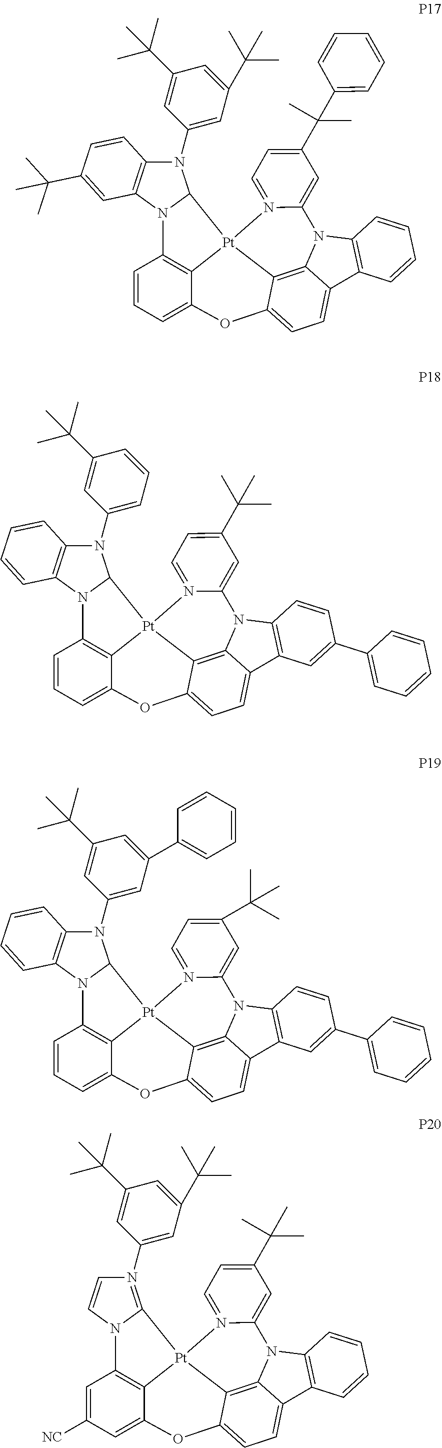

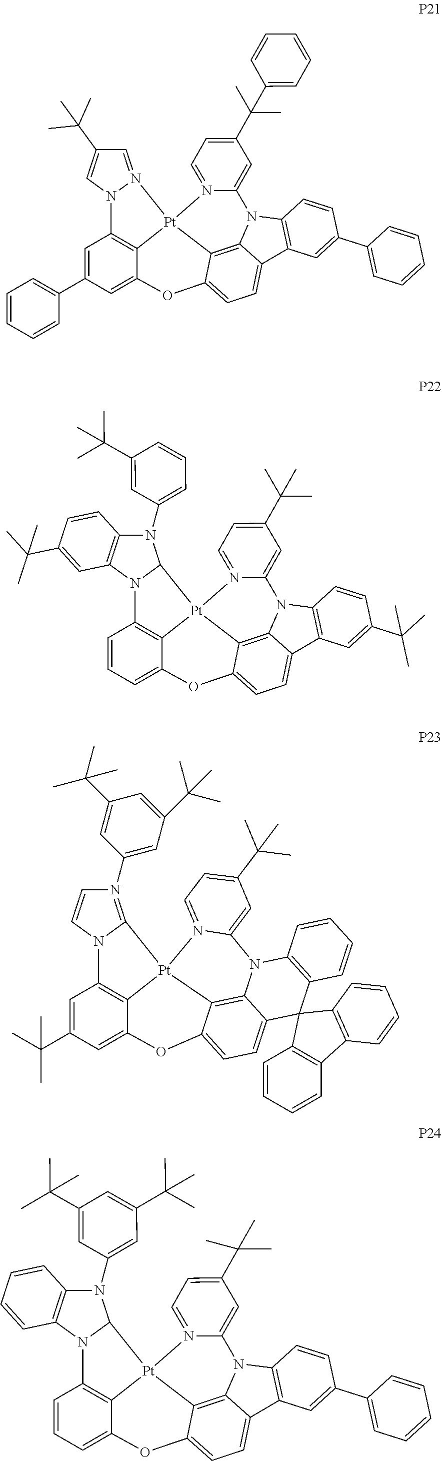

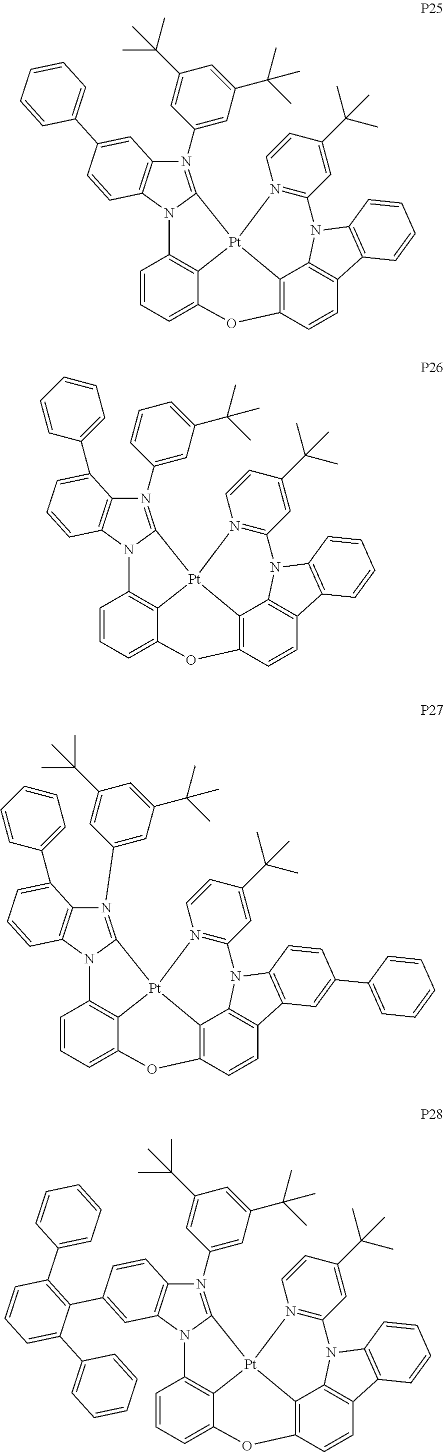

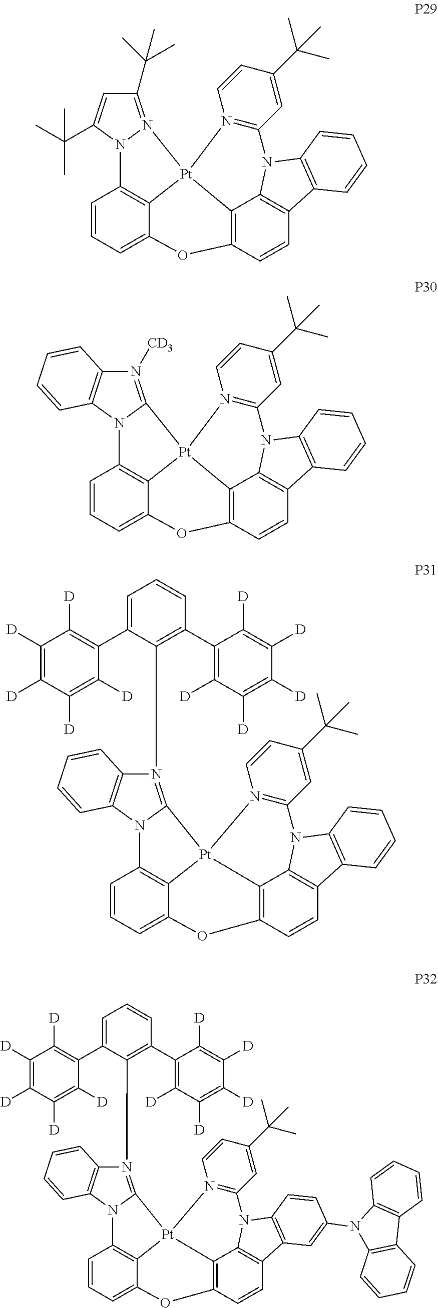

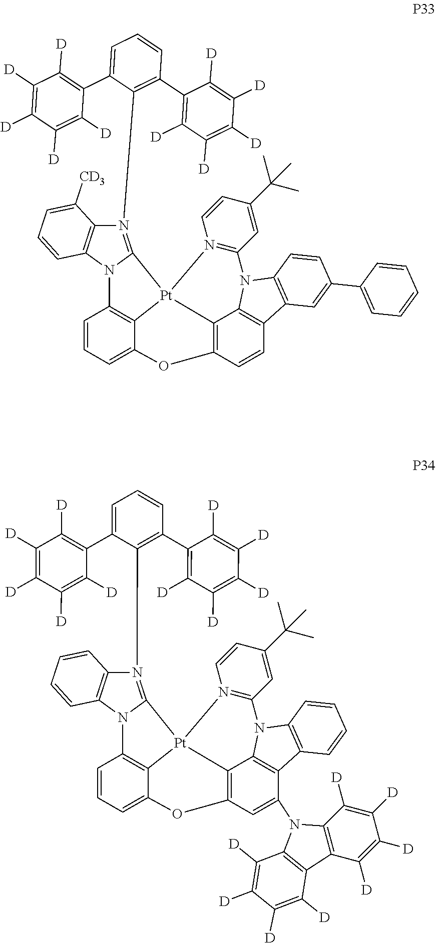

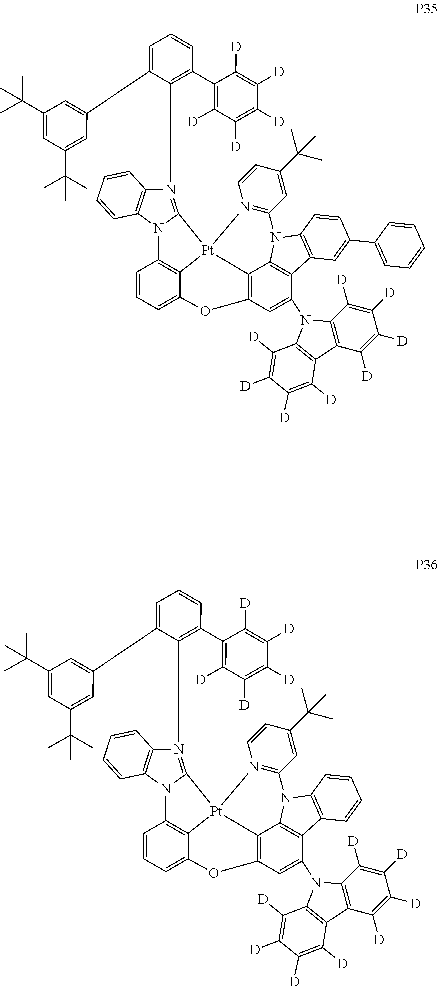

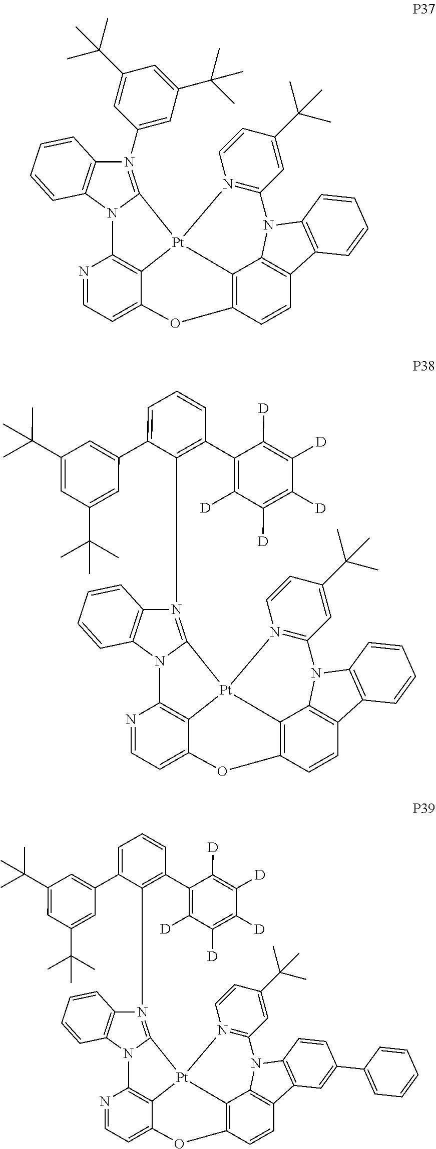

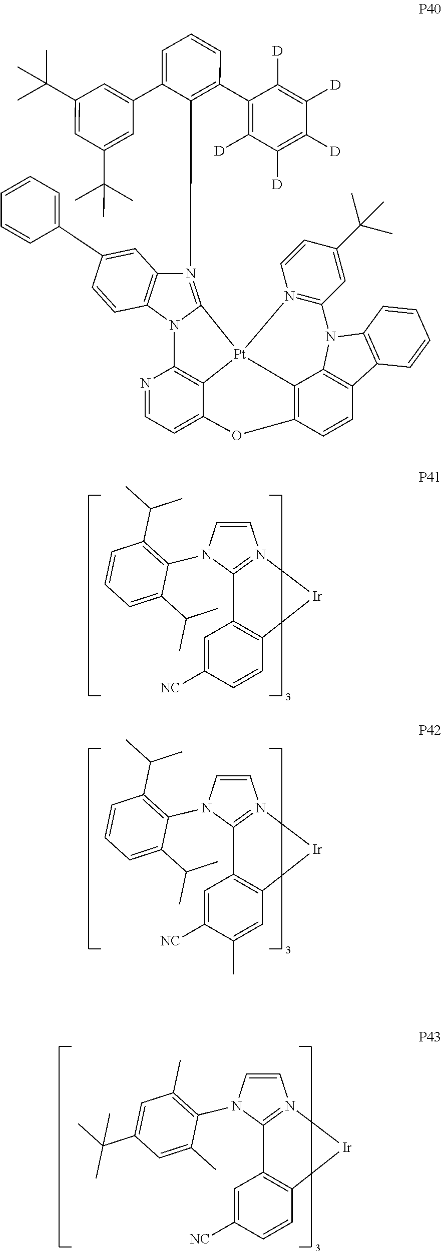

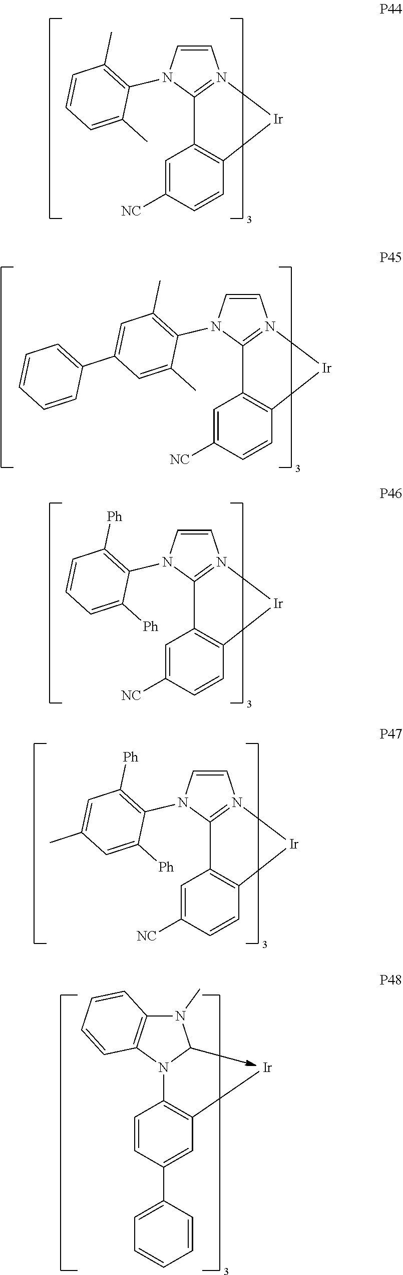

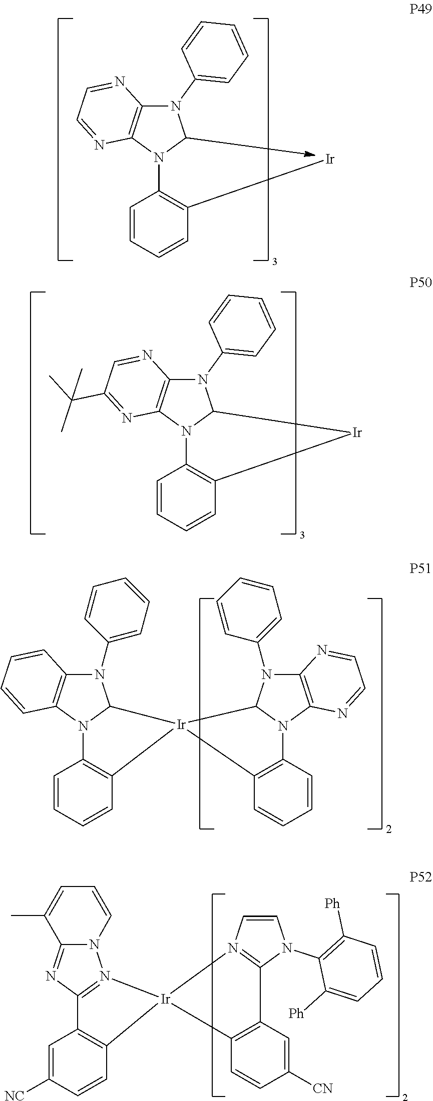

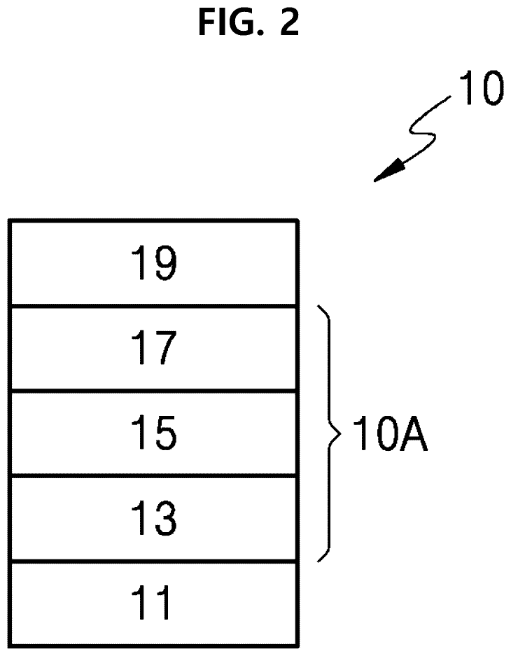

### Description of FIG. 2

FIG. 2 is a schematic cross-sectional view of an organic light-emitting device 10 according to one or more embodiments. Hereinafter, the structure and manufacturing method of the organic light-emitting device 10 according to one or more embodiments will be described with reference to FIG. 2.

In FIG. 2, the organic light-emitting device 10 may include a first electrode 11, a second electrode 19 facing the first electrode 11, and an interlayer 10A between the first electrode 11 and the second electrode 19.

The interlayer 10A may include an emission layer 15, a hole transport region 12 may be arranged between the first electrode 11 and an emission layer 15, and an electron transport region 17 may be arranged between the emission layer 15 and the second electrode 19.

A substrate may be further arranged, wherein the first electrode 11 is disposed on the substrate or the second electrode 19 is disposed on the substrate. The substrate may be a substrate commonly used in organic light-emitting devices, e.g., a glass substrate or a transparent plastic substrate, which have excellent mechanical strength, thermal stability, transparency, surface smoothness, ease of handling, and/or water repellency.

### First Electrode 11

The first electrode 11 may be formed by, for example, depositing or sputtering, onto the substrate, a material for forming the first electrode 11. The first electrode 11 may be an anode. A material for forming the first electrode 11 may include materials with a high work function to facilitate hole injection.

The first electrode 11 may be a reflective electrode, a transflective electrode, or a transmissive electrode. In one or more embodiments, when the first electrode 11 is a transmissive electrode, the material for forming the first electrode 11 may include indium tin oxide (ITO), indium zinc oxide (IZO), tin oxide (SnO₂), zinc oxide (ZnO), or a combination thereof. In one or more embodiments, when the first electrode 11 is a transflective of semi-transmissive electrode or a reflective electrode, the material for forming the first electrode 11 may include magnesium (Mg), silver (Ag), aluminum (Al), aluminum-lithium (Al—Li), calcium (Ca), magnesium-indium (Mg—In), magnesium-silver (Mg—Ag), or a combination thereof.

The first electrode 11 may have a single-layered structure or a multi-layered structure including two or more layers.

### Emission Layer 15

A thickness of the emission layer 15 may be about 100 Å to about 1,000 Å, or about 200 Å to about 600 Å. When the thickness of the emission layer is within the range described above, excellent luminescence characteristics may be obtained without a substantial increase in driving voltage.

According to one or more embodiments, the emission layer 15 may include an emitter as described herein and m1 hosts (and, optionally, a sensitizer).

### Hole Transport Region 13

The hole transport region 13 may be arranged between the first electrode 11 and the emission layer 15 in the organic light-emitting device 10.

The hole transport region 13 may have a single-layer structure or a multi-layer structure.

The hole transport region 13 may have a hole injection layer, a hole transport layer, a hole injection layer/hole transport layer structure, a hole injection layer/first hole transport layer/second hole transport layer structure, a hole injection layer/first hole transport layer/second hole transport layer/electron-blocking layer structure, a hole transport layer/buffer layer structure, a hole injection layer/hole transport layer/buffer layer structure, a hole transport layer/electron-blocking layer structure, or a hole injection layer/hole transport layer/electron-blocking layer structure.

The hole transport region 13 may include any compound having hole-transporting properties.

The hole transport region 13 may include an amine-containing compound.

In one or more embodiments, the hole transport region 13 may include at least one of 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), N,N′-di(1-naphthyl)-N,N′-diphenylbenzidine (NPB), β-NPB, N,N′-bis(3-methylphenyl)-N,N′-diphenyl-[1,1-biphenyl]-4,4′-diamine (TPD), spiro-TPD, spiro-NPB, methylated-NPB, 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor-sulfonic acid (PANI/CSA), polyaniline/poly(4-styrene sulfonate) (PANI/PSS), a compound represented by one of Formula 201 to Formula 205, or a combination thereof, but embodiments are not limited thereto:

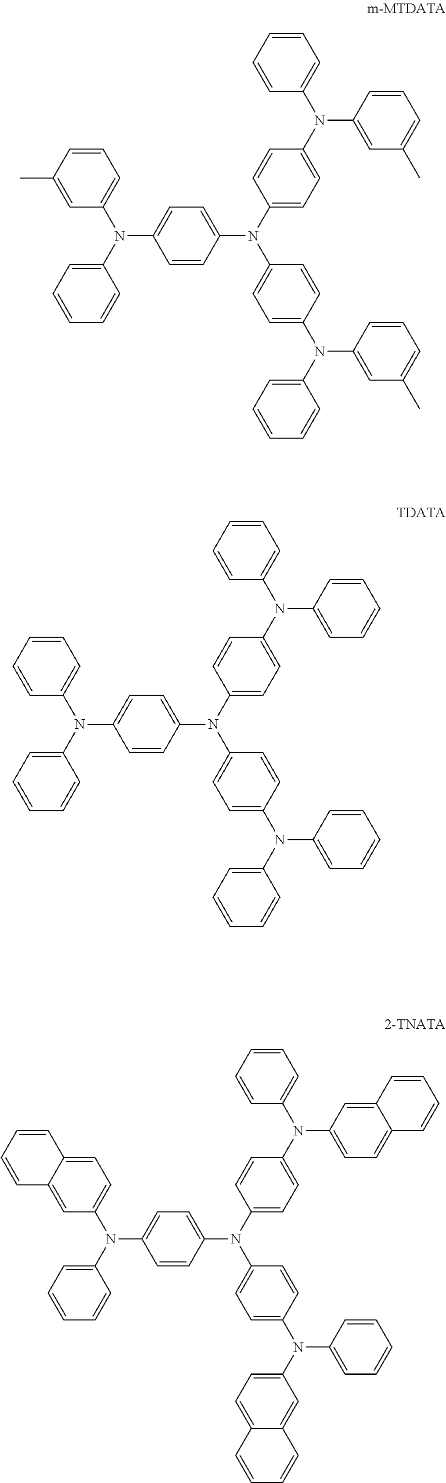

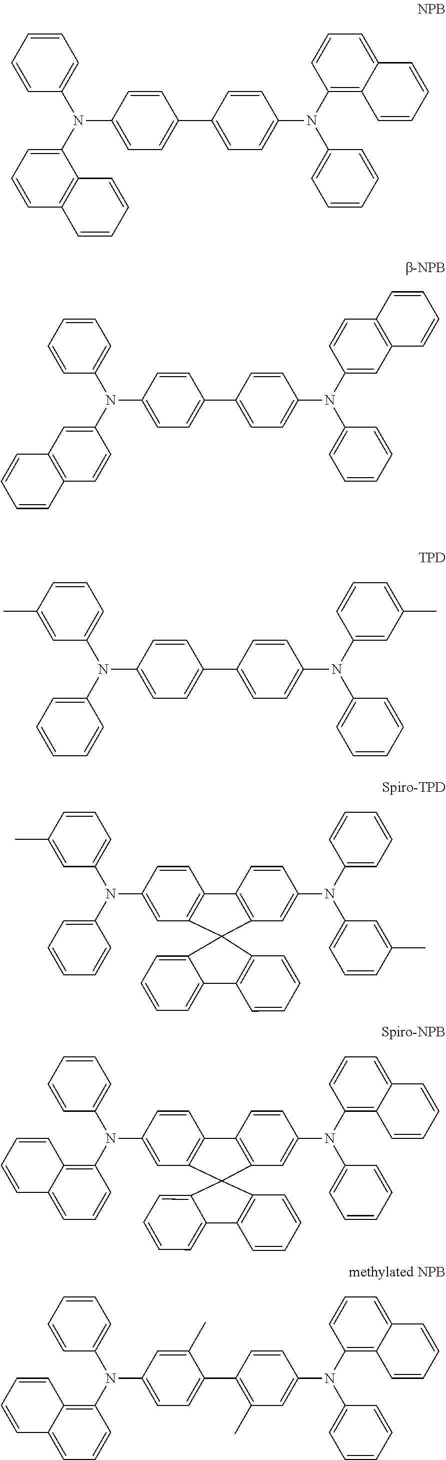

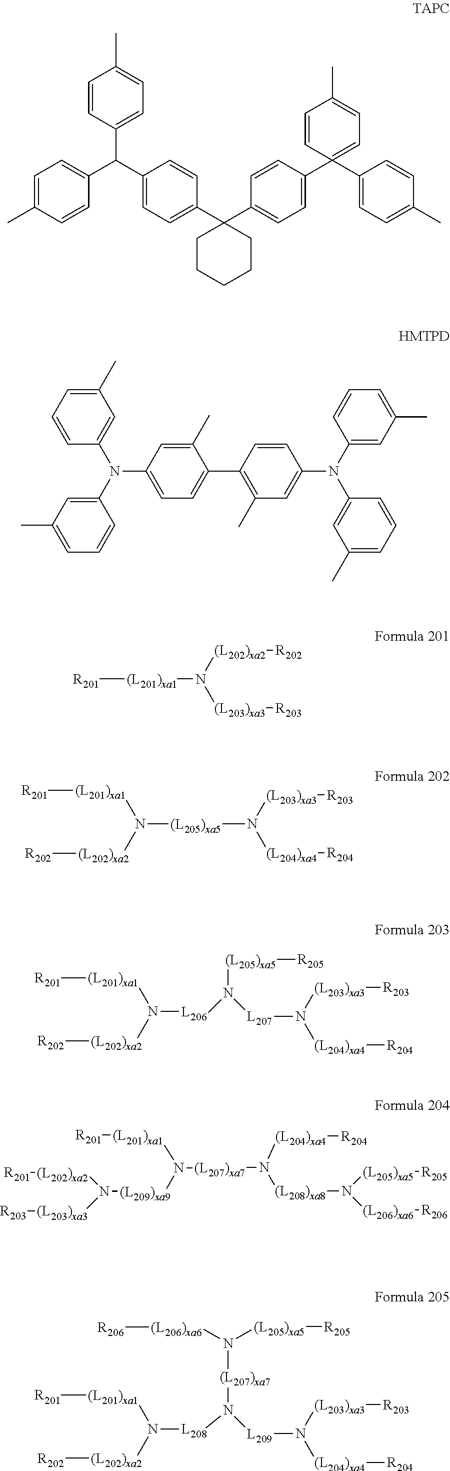

wherein, in Formulae 201 to 205,
L₂₀₁ to L₂₀₉ may each independently be *—O—*′, *—S—*′, a substituted or unsubstituted C₅-C₆₀ carbocyclic group, or a substituted or unsubstituted C₁-C₆₀ heterocyclic group,
xa1 to xa9 may each independently be an integer from 0 to 5, and
R₂₀₁ to R₂₀₆ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryl alkyl group, a substituted or unsubstituted C₆-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₁-C₆₀ alkyl heteroaryl group, a substituted or unsubstituted C₁-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group, wherein neighboring two groups of R₂₀₁ to R₂₀₆ may optionally be linked to each other via a single bond, a dimethyl-methylene group, or a diphenyl-methylene group.

In one or more embodiments,
L₂₀₁ to L₂₀₉ may each independently be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, a hexacene group, a pentacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, or a triindolobenzene group, each unsubstituted or substituted with deuterium, a C₁-C₁₀ alkyl group, a C₁-C₁₀ alkoxy group, a C₁-C₁₀ alkylthio group, a phenyl group, a naphthyl group, a fluorenyl group, a carbazolyl group, a dibenzofuranyl group, a dibenzothiophenyl group, a triphenylenyl group, a biphenyl group, a terphenyl group, a quaterphenyl group (a tetraphenyl group), —Si(Q₁₁)(Q₁₂)(Q₁₃), —P(Q₁₁)(Q₁₂), —P(═O)(Q₁₁)(Q₁₂), or a combination thereof,
xa1 to xa9 may each independently be 0, 1, or 2,
R₂₀₁ to R₂₀₆ may each independently be a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an indenocarbazolyl group, an indolocarbazolyl group, a benzofurocarbazolyl group, or a benzothienocarbazolyl group, each unsubstituted or substituted with deuterium, —F, —Cl, —Br, —I, —SF₅, a hydroxyl group, a cyano group, a nitro group, an amino group, an amidino group, a hydrazine group, a hydrazone group, a C₁-C₂₀ alkyl group, a C₁-C₂₀ alkoxy group, a C₁-C₂₀ alkylthio group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), —N(Q₃₁)(Q₃₂), —P(Q₃₁)(Q₃₂), —P(═O)(Q₃₁)(Q₃₂), or a combination thereof, and
Q₁₁ to Q₁₃ and Q₃₁ to Q₃₃ may each independently be a C₁-C₁₀ alkyl group, a C₁-C₁₀ alkoxy group, a C₁-C₁₀ alkylthio group, a phenyl group, a biphenyl group, a terphenyl group, or a naphthyl group.

According to one or more embodiments, the hole transport region 13 may include a carbazole-containing amine-containing compound.

In some embodiments, the hole transport region 13 may include a carbazole-containing amine compound and a carbazole-free amine-containing compound.

The carbazole-containing amine-containing compound may include compounds represented by Formula 201 including a carbazole group and further including at least one of a dibenzofuran group, a dibenzothiophene group, a fluorene group, a spiro-bifluorene group, an indenocarbazole group, an indolocarbazole group, a benzofurocarbazole group, or a benzothienocarbazole group.

The carbazole-free amine-containing compound may include compounds represented by Formula 201 not including a carbazole group and including at least one of a dibenzofuran group, a dibenzothiophene group, a fluorene group, a spiro-bifluorene group, an indenocarbazole group, an indolocarbazole group, a benzofurocarbazole group, or a benzothienocarbazole group.

In some embodiments, the hole transport region 13 may include a compound represented by Formula 201, a compound represented by Formula 202, or a combination thereof.

According to one or more embodiments, the hole transport region 13 may include a compound represented by Formula 201-1, 202-1, or 201-2, or a combination thereof:

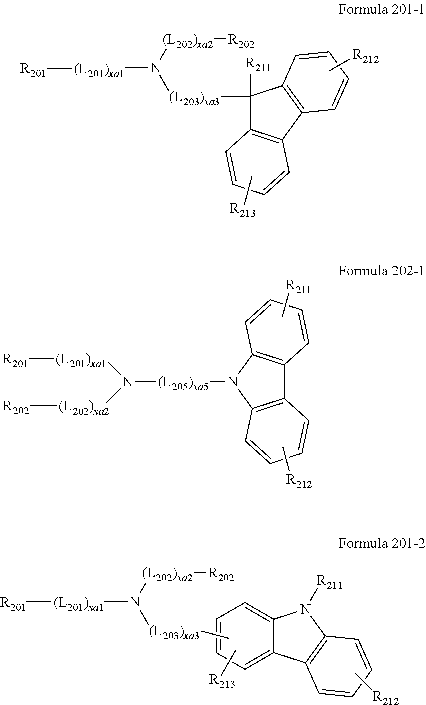

wherein, in Formulae 201-1, 202-1, and 201-2, L₂₀₁ to L₂₀₃, L₂₀₅, xa1 to xa3, xa5, R₂₀₁ and R₂₀₂ are each as described herein, and R₂₁₁ to R₂₁₃ may each independently be hydrogen, deuterium, —F, —Cl, —Br, —I, —SF₅, a hydroxyl group, a cyano group, a nitro group, an amino group, an amidino group, a hydrazine group, a hydrazone group, a C₁-C₂₀ alkyl group, a C₁-C₂₀ alkoxy group, a C₁-C₁₀ alkylthio group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a dimethylfluorenyl group, a diphenylfluorenyl group, a triphenylenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

The hole transport region 13 may include one of the following compounds HT1 to HT39, or a combination thereof, but embodiments are not limited thereto:

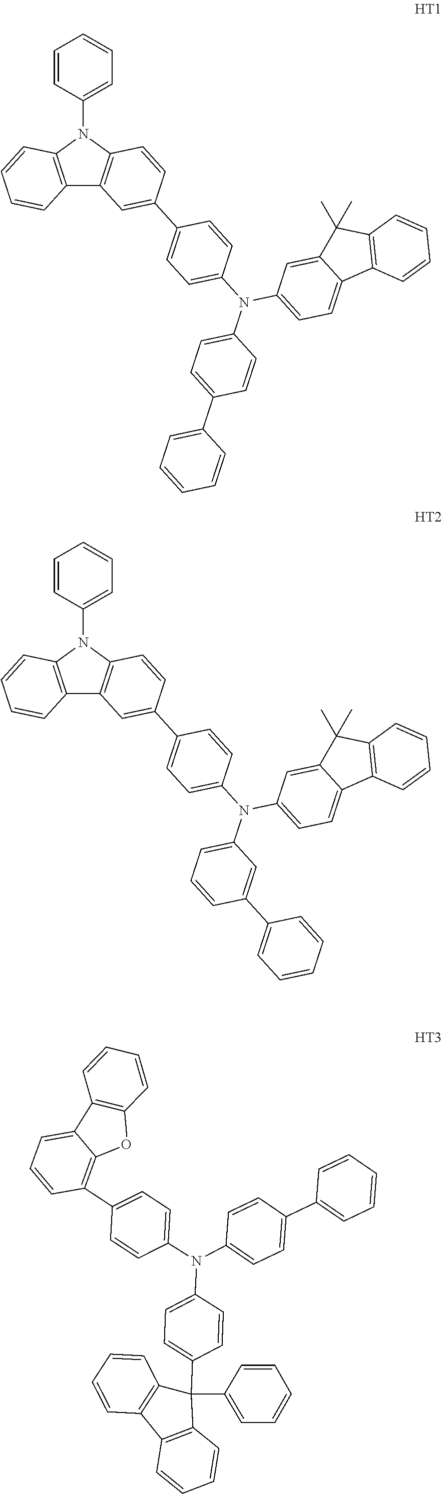 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; c1ccc(-c2ccc(N(c3ccc(-c4cccc5c4oc4ccccc45)cc3)c3ccc(C4(c5ccccc5)c5ccccc5-c5ccccc54)cc3)cc2)cc1]

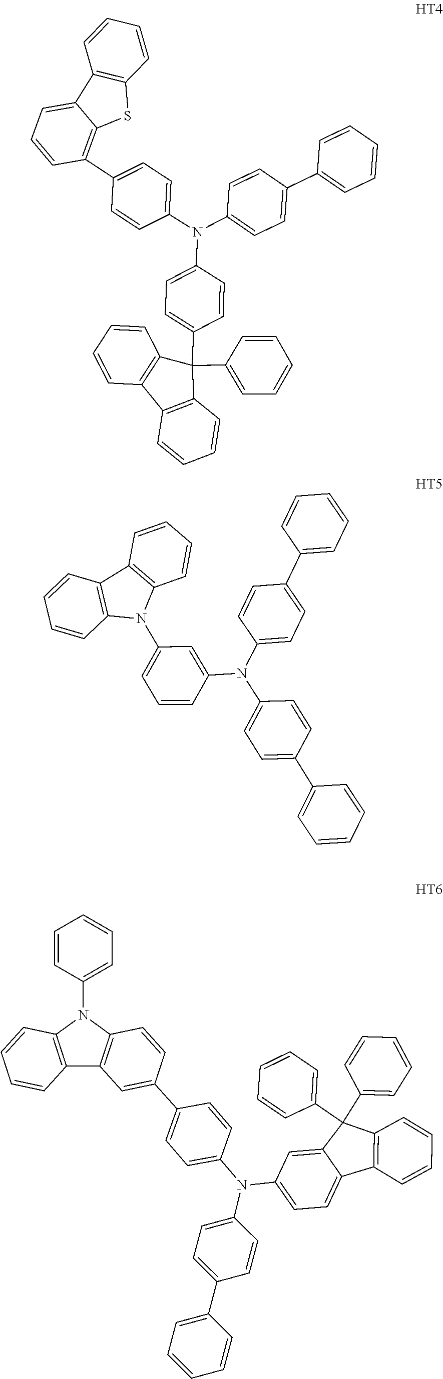 [SMILES: c1ccc(-c2ccc(N(c3ccc(-c4cccc5c4sc4ccccc45)cc3)c3ccc(C4(c5ccccc5)c5ccccc5-c5ccccc54)cc3)cc2)cc1 ; c1ccc(-c2ccc(N(c3ccc(-c4ccccc4)cc3)c3cccc(-n4c5ccccc5c5ccccc54)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

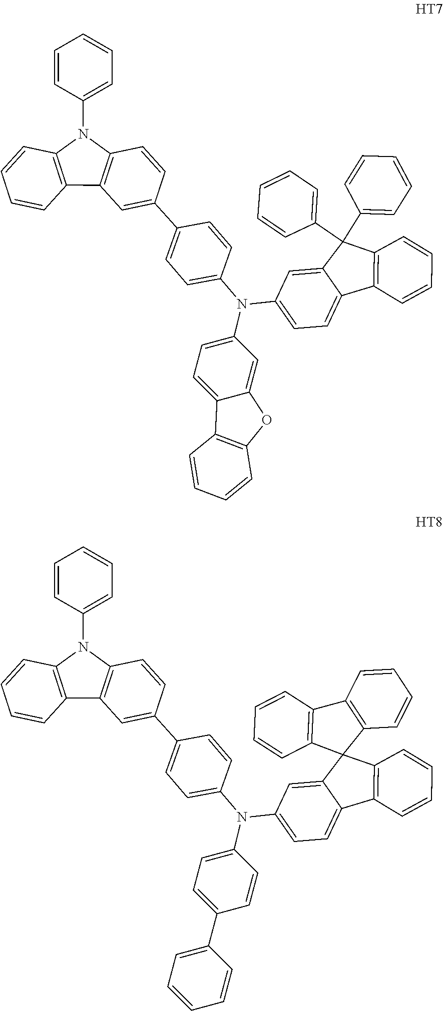 [SMILES: c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

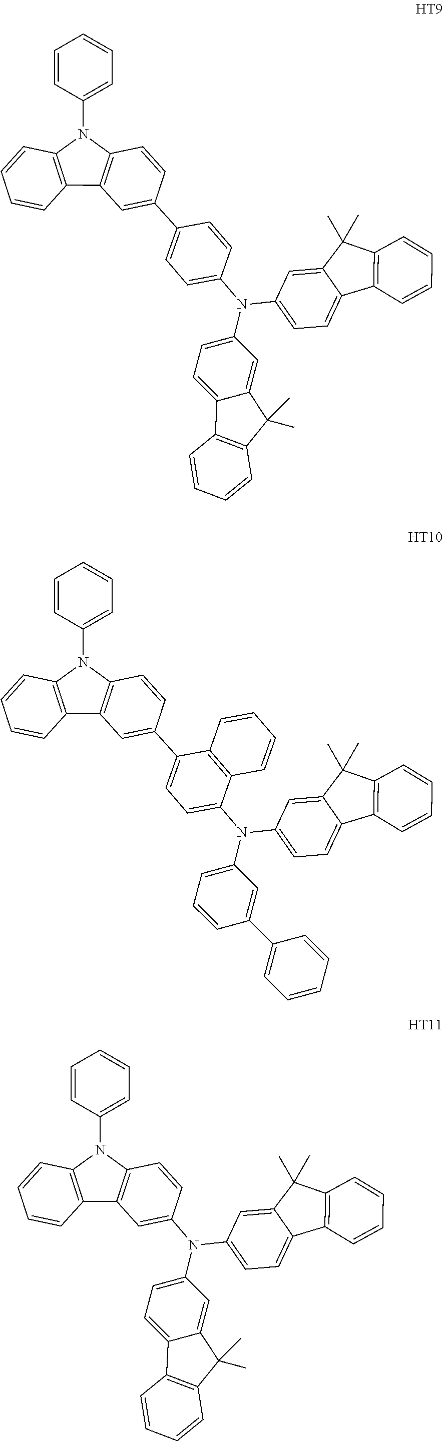 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

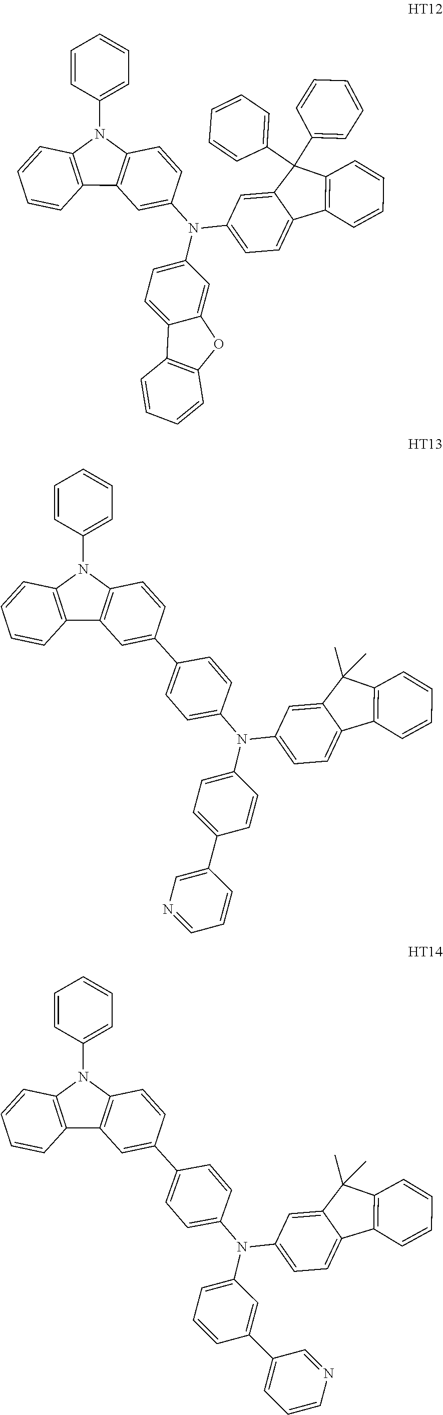 [SMILES: c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

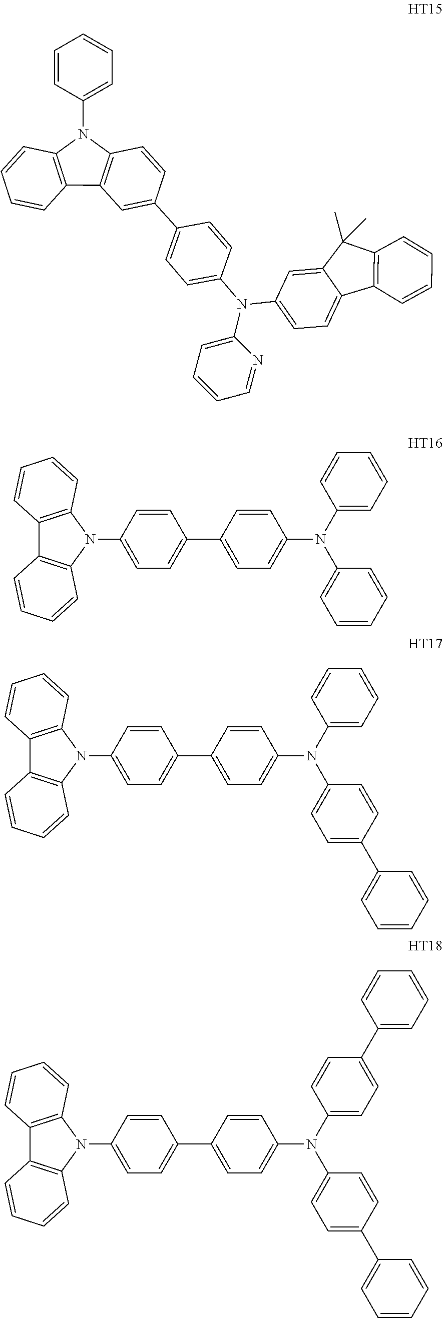

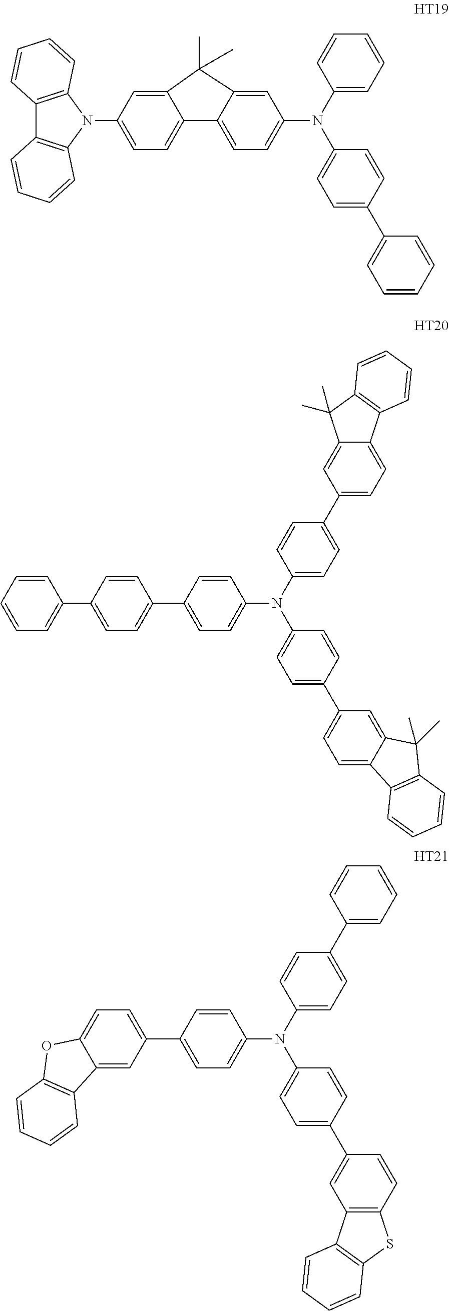

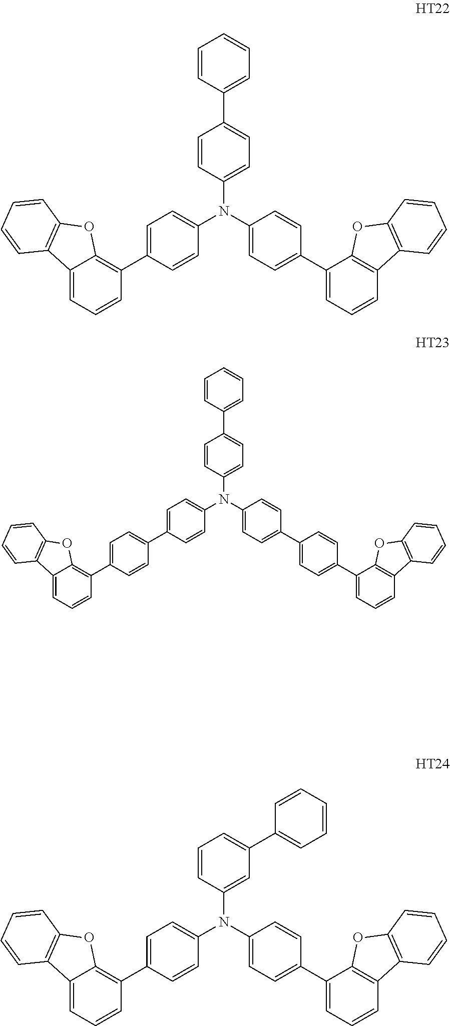 [SMILES: c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1]

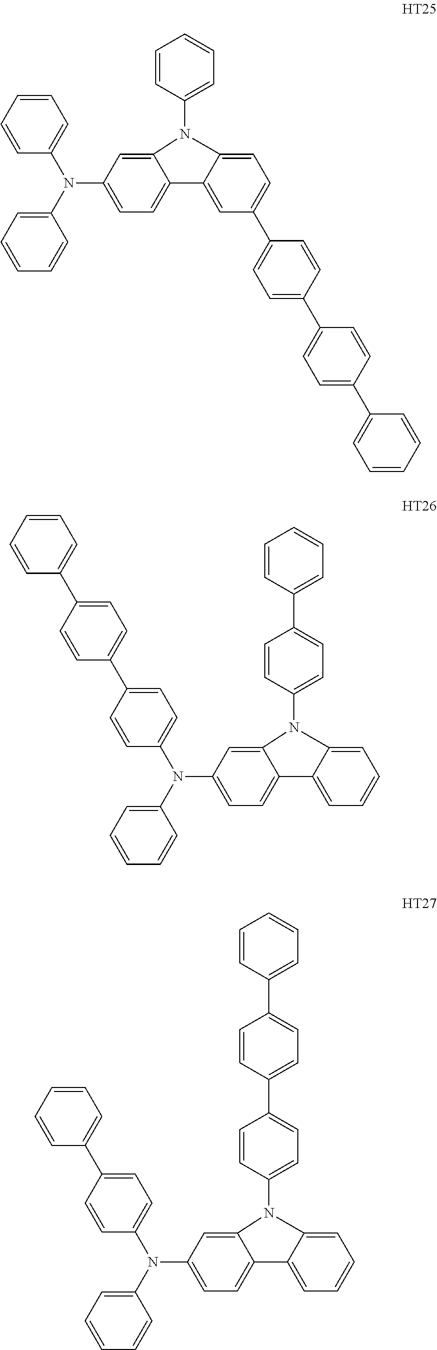 [SMILES: c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

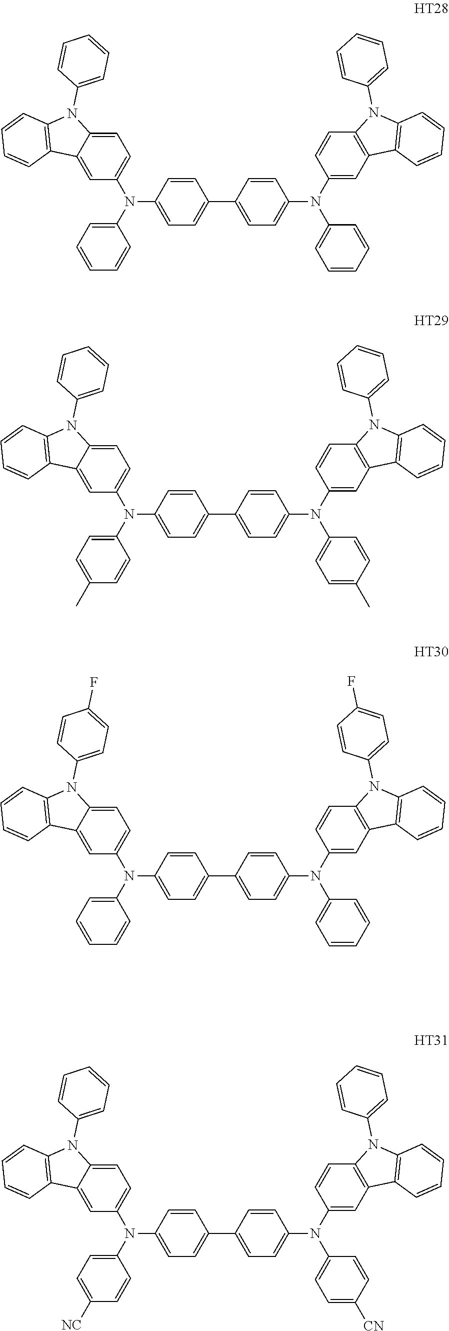 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

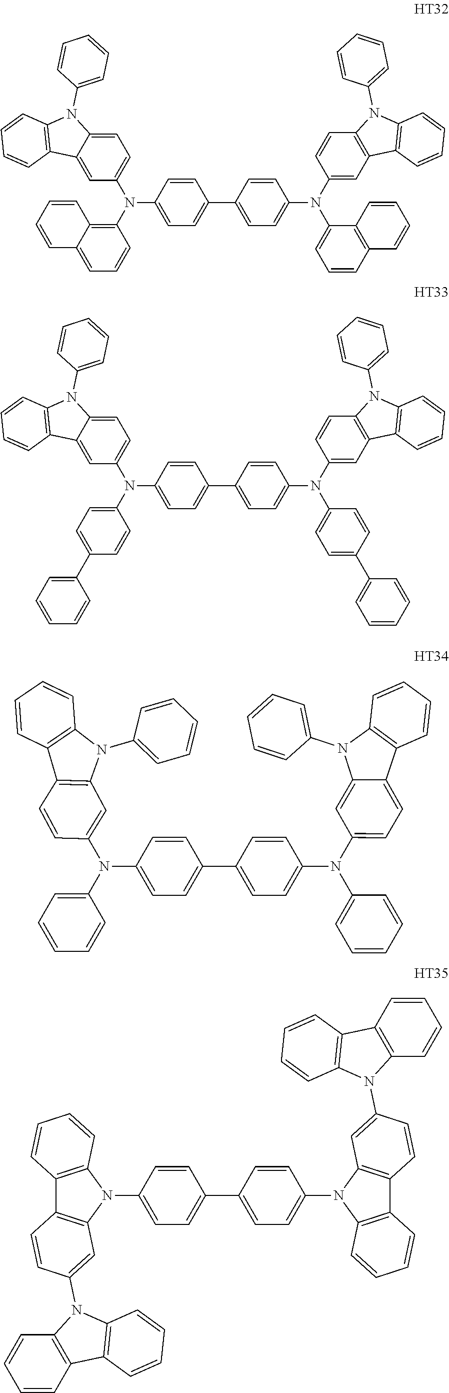 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1 ; c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1]

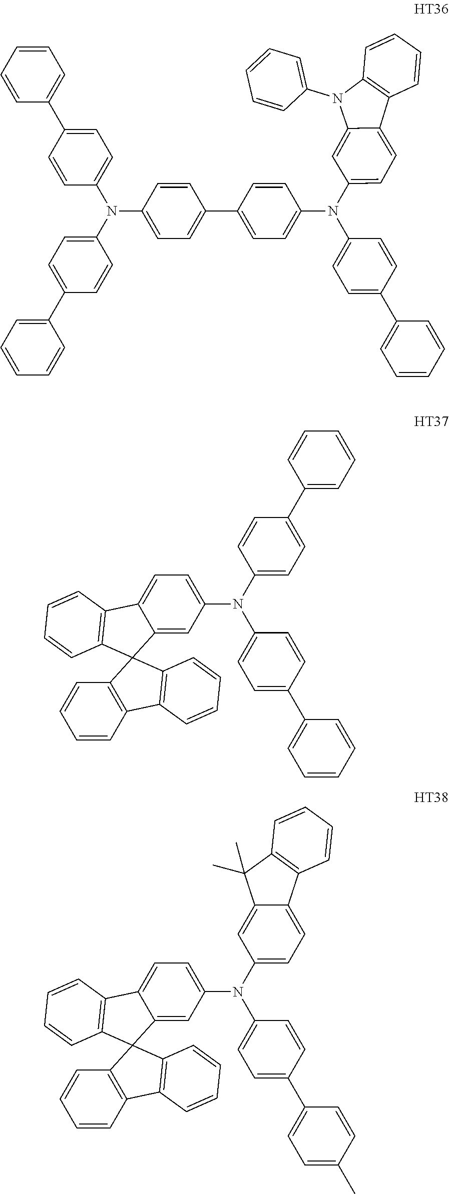

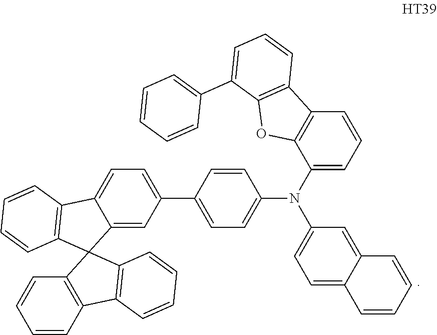 [SMILES: c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

Meanwhile, the hole transport region 13 of the organic light-emitting device 10 may further include a p-dopant. When the hole transport region 13 further includes a p-dopant, the hole transport region 13 may have a matrix (for example, at least one of compounds represented by Formulae 201 to 205) and a p-dopant included in the matrix. The p-dopant may be uniformly or non-uniformly doped into the hole transport region 13.

In one or more embodiments, the LUMO energy level of the p-dopant may be less than or equal to about −3.5 eV.

The p-dopant may include a quinone derivative, a metal oxide, a cyano group-containing compound, or a combination thereof.

The p-dopant may include:
a quinone derivative, such as tetracyanoquinodimethane (TCNQ),2,3,5,6-tetrafluoro-7,7,8,8-tetracyanoquinodimethane (F4-TCNQ), or F6-TCNNQ;
a metal oxide, such as tungsten oxide or molybdenum oxide;
1,4,5,8,9,12-hexaazatriphenylene-hexacarbonitrile (HAT-CN);
a compound represented by Formula 221; or
a combination thereof, but embodiments are not limited thereto:

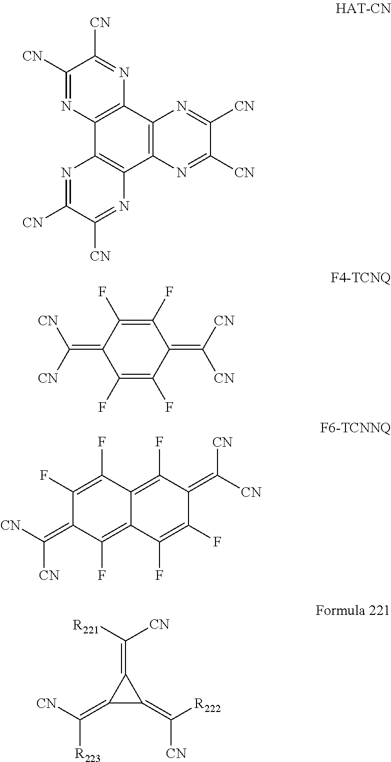

In Formula 221,
R₂₂₁ to R₂₂₃ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group, wherein at least one substituent of R₂₂₁ to R₂₂₃ may each independently be a cyano group; —F; —Cl; —Br; —I; a C₁-C₂₀ alkyl group substituted with —F; a C₁-C₂₀ alkyl group substituted with —Cl; a C₁-C₂₀ alkyl group substituted with —Br; a C₁-C₂₀ alkyl group substituted with —I; or a combination thereof.

The compound represented by Formula 221 may include, for example, Compound HT-D2:

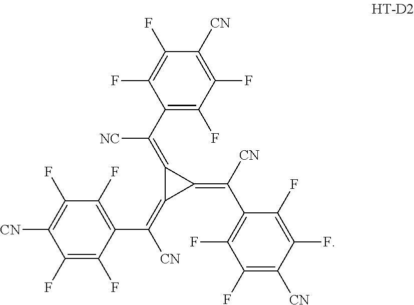

The hole transport region 13 may have a thickness of about 100 Å to about 10,000 Å, or about 400 Å to about 2,000 Å, and the emission layer 15 may have a thickness of about 100 Å to about 3,000 Å, or about 300 Å to about 1,000 Å. When the thickness of each of the hole transport region 13 and the emission layer 15 is within these ranges, satisfactory hole transportation characteristics and/or luminescence characteristics may be obtained without a substantial increase in driving voltage. For example, the thickness of the hole injection layer in the hole transport region may be about 50 Å to about 1000 Å, or about 100 Å to about 800 Å, and the thickness of the hole transport layer may be about 50 Å to about 2000 Å, or about 100 Å to about 1500 Å.

The hole transport region 13 may further include a buffer layer.

The buffer layer may compensate for an optical resonance distance according to a wavelength of light emitted from the emission layer 15, and thus, efficiency of a formed organic light-emitting device may be improved.

The hole transport region 13 may further include an electron-blocking layer. The electron-blocking layer may include a known material, such as mCP or DBFPO:

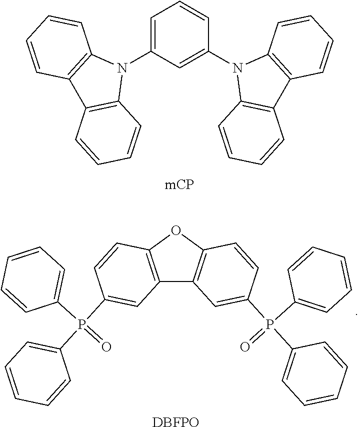

The thickness of the electron-blocking layer may be about 50 Å to about 1000 Å, or about 100 Å to about 800 Å.

### Electron Transport Region 17

The electron transport region 17 is arranged between the emission layer 15 and the second electrode 19 of the organic light-emitting device 10.

The electron transport region 17 may have a single-layer structure or a multi-layer structure.

The electron transport region 17 may have an electron transport layer, an electron transport layer/electron injection layer structure, a buffer layer/electron transport layer structure, hole-blocking layer/electron transport layer structure, a buffer layer/electron transport layer/electron injection layer structure, or a hole-blocking layer/electron transport layer/electron injection layer structure. The electron transport region 17 may further include an electron control layer.

The electron transport region 17 may include known electron-transporting materials.

The electron transport region 17 (such as, a buffer layer, a hole-blocking layer, an electron control layer, or an electron transport layer in the electron transport region) may include a metal-free compound containing at least one π electron-deficient nitrogen-containing C₁-C₆₀ cyclic group. The π electron-deficient nitrogen-containing C₁-C₆₀ cyclic group is the same as described herein.

The electron transport region 17 may include a compound represented by Formula 601.

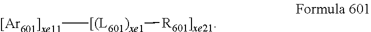

In Formula 601,
Ar₆₀₁ and L₆₀₁ may each independently be a C₅-C₆₀ carbocyclic group unsubstituted or substituted with at least one R₆₀₁ₐ or a C₁-C₆₀ heterocyclic group unsubstituted or substituted with at least one R₆₀₁ₐ,
xe11 may be 1, 2, or 3,
xe1 may be an integer from 0 to 5,
R₆₀₁ₐ and R₆₀₁ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryl alkyl group, a substituted or unsubstituted C₆-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₁-C₆₀ alkyl heteroaryl group, a substituted or unsubstituted C₁-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be a C₁-C₁₀ alkyl group, a C₁-C₁₀ alkoxy group, a C₁-C₁₀ alkylthio group, a phenyl group, a biphenyl group, a terphenyl group, or a naphthyl group, and
xe21 may be an integer from 1 to 5.

In one or more embodiments, at least one of Ar₆₀₁(s) in the number of xe11 and R₆₀₁(s) in the number of xe21 may include the π electron-deficient nitrogen-containing C₁-C₆₀ cyclic group.

In one or more embodiments, Ar₆₀₁ and L₆₀₁ in Formula 601 may each independently be a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, or an azacarbazole group, each unsubstituted or substituted with deuterium, —F, —C₁, —Br, —I, —SF₅, a hydroxyl group, a cyano group, a nitro group, an amino group, an amidino group, a hydrazino group, a hydrazono group, a C₁-C₂₀ alkyl group, a C₁-C₂₀ alkoxy group, a C₁-C₂₀ alkylthio group, a phenyl group, a biphenyl group, a terphenyl group, a naphthyl group, —Si(Q₃₁)(Q₃₂)(Q₃₃), —S(═O)₂(Q₃₁), —P(═O)(Q₃₁)(Q₃₂), or a combination thereof, and
Q₃₁ to Q₃₃ may each independently be a C₁-C₁₀ alkyl group, a C₁-C₁₀ alkoxy group, a C₁-C₁₀ alkylthio group, a phenyl group, a biphenyl group, a terphenyl group, or a naphthyl group.

When xe11 in Formula 601 is 2 or more, two or more of Ar₆₀₁ may be linked to each other via a single bond.

In one or more embodiments, Ar₆₀₁ in Formula 601 may be an anthracene group.

In one or more embodiments, the compound represented by Formula 601 may be represented by Formula 601-1:

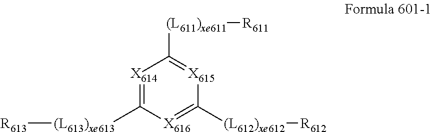

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ are each independently the same as described in connection with L₆₀₁,
xe611 to xe613 are each independently the same as described in connection with xe1,
R₆₁₁ to R₆₁₃ are each independently the same as described in connection with R₆₀₁, and
R₆₁₄ to R₆₁₆ may each independently be hydrogen, deuterium, —F, —Cl, —Br, —I, —SF₅, a hydroxyl group, a cyano group, a nitro group, an amino group, an amidino group, a hydrazino group, a hydrazono group, a C₁-C₂₀ alkyl group, a C₁-C₂₀ alkoxy group, a C₁-C₂₀ alkylthio group, a phenyl group, a biphenyl group, a terphenyl group, or a naphthyl group.

In one or more embodiments, xe1 and xe611 to xe613 in Formulae 601 and 601-1 may each independently be 0, 1, or 2.

In some embodiments, R₆₀₁ and R₆₁₁ to R₆₁₃ in Formulae 601 and 601-1 may each independently be a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzoisothiazolyl group, a benzoxazolyl group, a benzoisoxazolyl group, a triazolyl group, a tetrazolyl group, an imidazopyridinyl group, an imidazopyrimidinyl group, or an azacarbazolyl group, each unsubstituted or substituted with deuterium, —F, —Cl, —Br, —I, —SF₅, a hydroxyl group, a cyano group, a nitro group, an amino group, an amidino group, a hydrazino group, a hydrazono group, a C₁-C₂₀ alkyl group, a C₁-C₂₀ alkoxy group, a C₁-C₂₀ alkylthio group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzoisothiazolyl group, a benzoxazolyl group, a benzoisoxazolyl group, a triazolyl group, a tetrazolyl group, an imidazopyridinyl group, an imidazopyrimidinyl group, an azacarbazolyl group, or a combination thereof; or —S(═O)₂(Q₆₀₁), or —P(═O)(Q₆₀₁)(Q₆₀₂), and
Q₆₀₁ and Q₆₀₂ are the same as described herein.

The electron transport region 17 may include one of Compounds ET1 to ET36 or a combination thereof, but embodiments are not limited thereto:

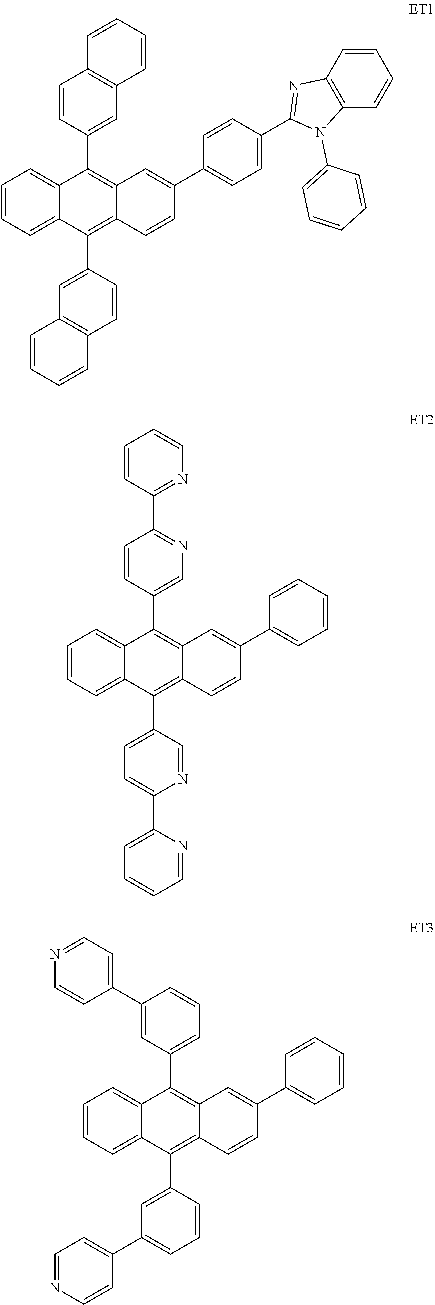 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

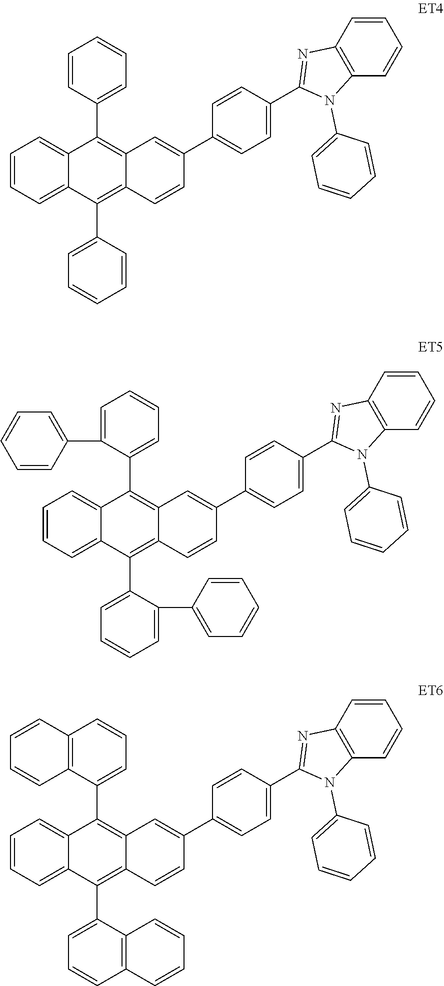 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

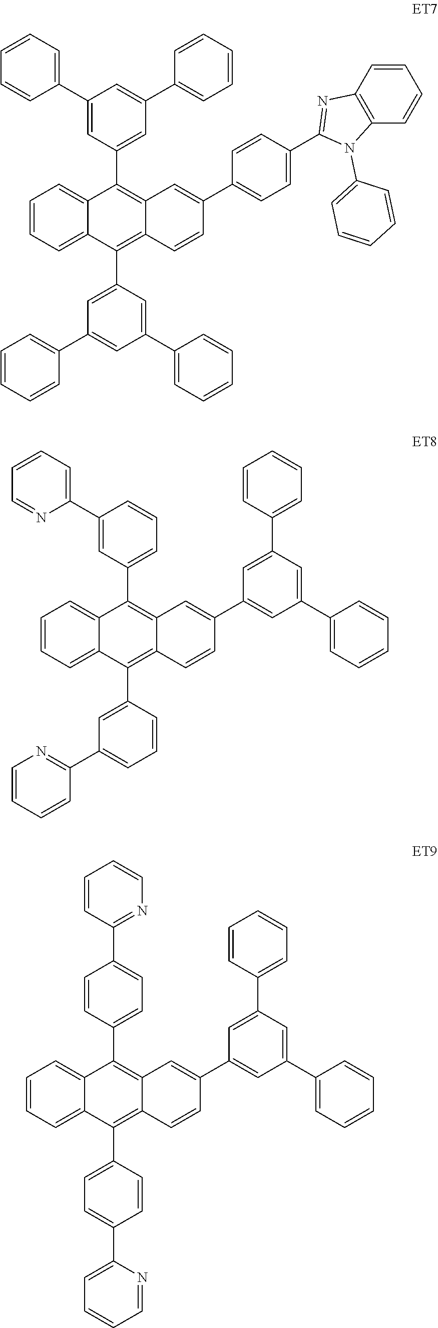 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

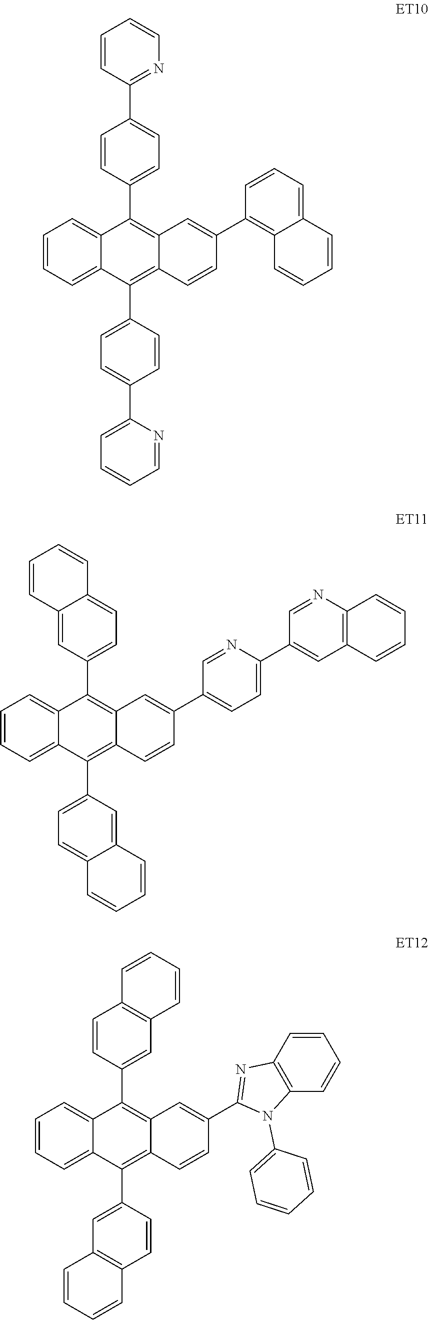 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

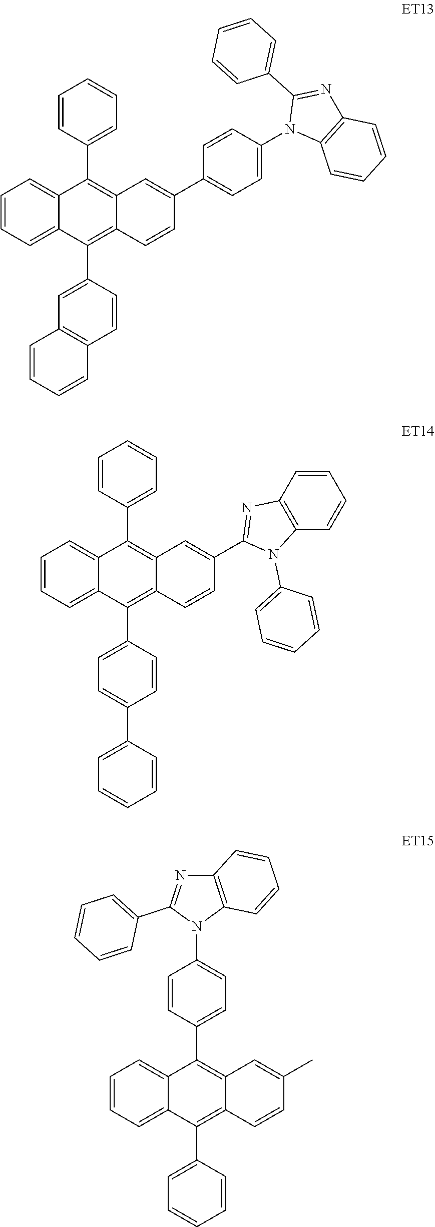 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

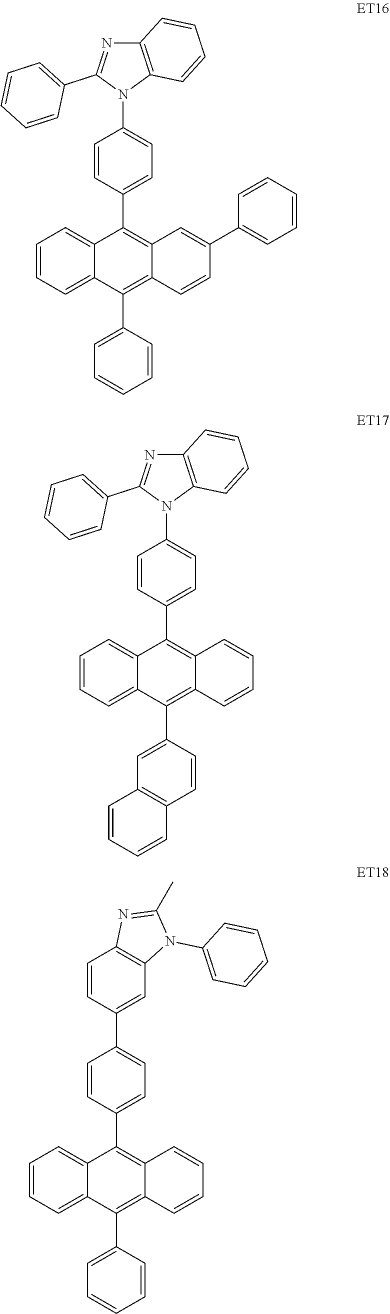

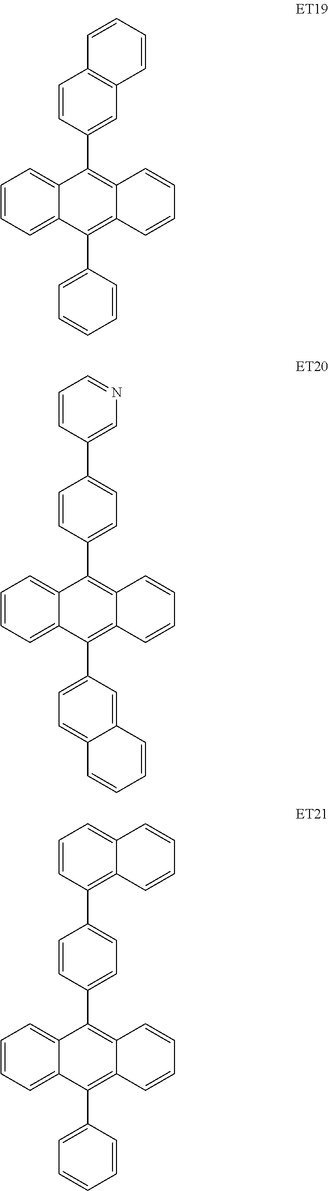

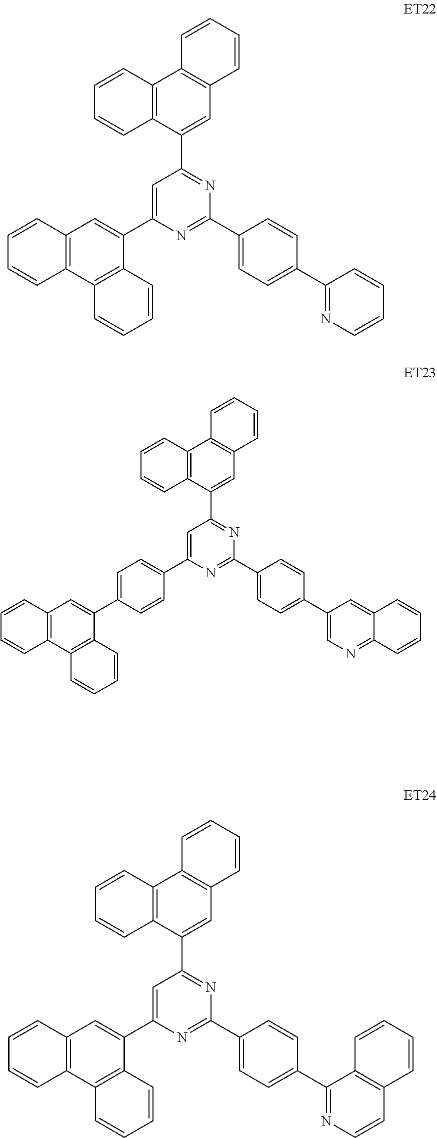 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

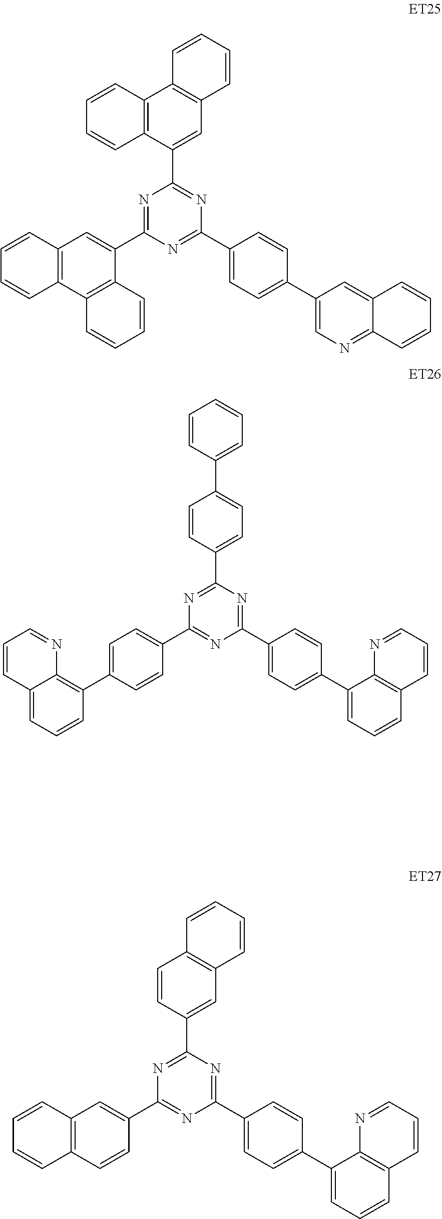 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

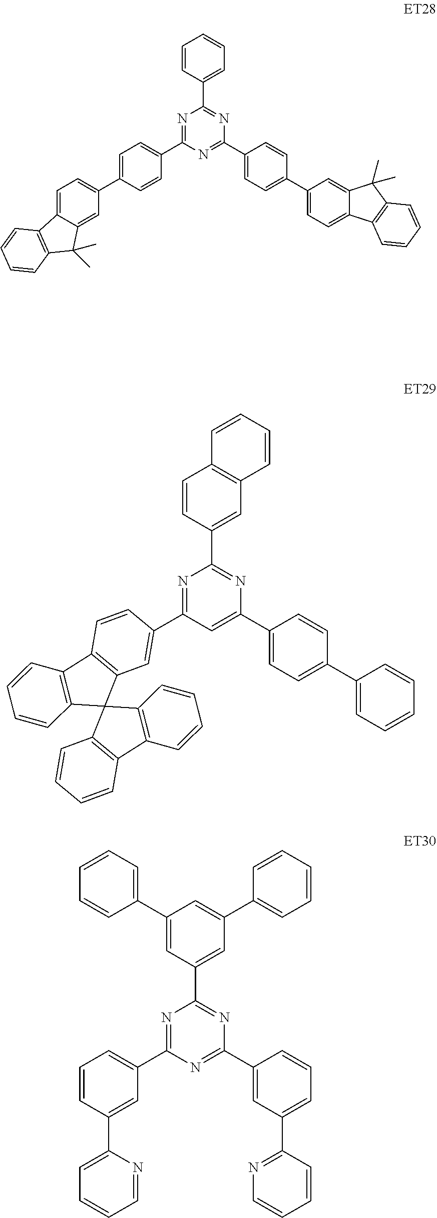 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

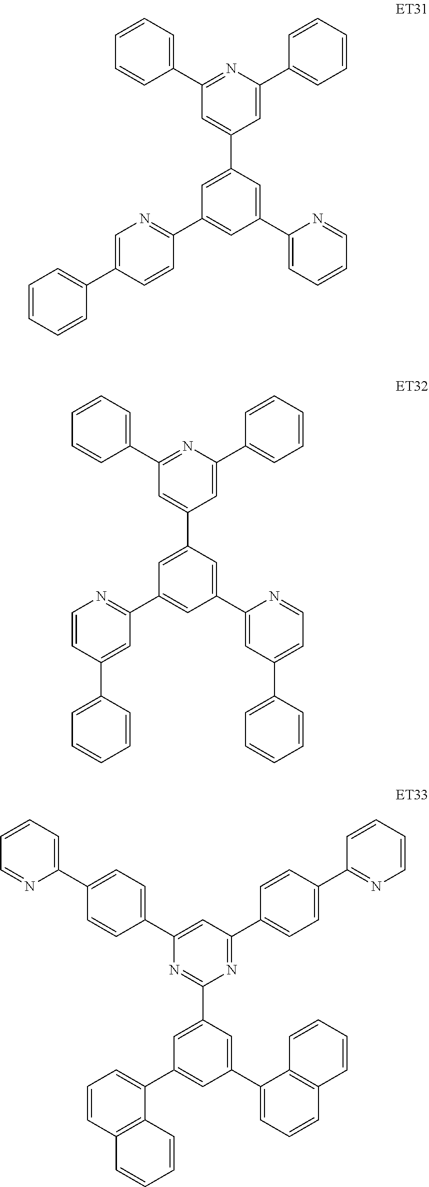 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

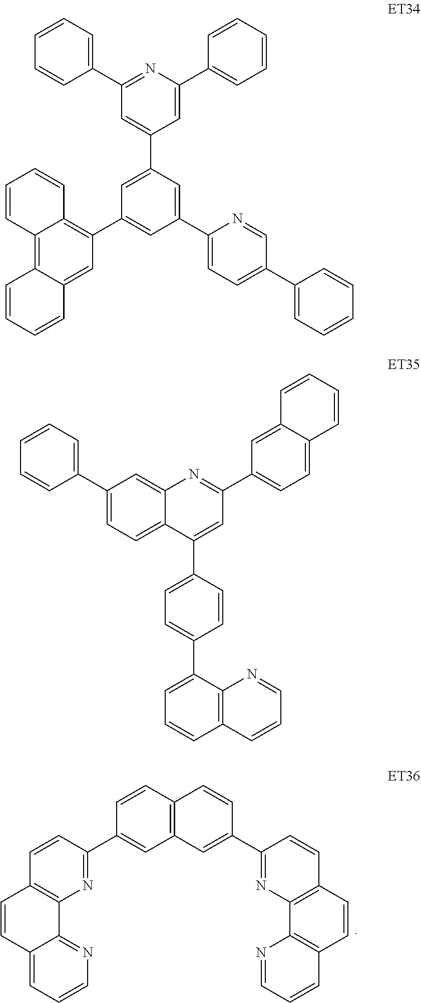

In one or more embodiments, the electron transport region 17 may include at least one of 2,9-dimethyl-4,7-diphenyl-1,10-phenanthroline (BCP), 4,7-diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), 4-(naphthalen-1-yl)-3,5-diphenyl-4H-1,2,4-triazole (NTAZ), DBFPO, or a combination thereof, but embodiments are not limited thereto. For example, when the electron transport region 17 includes a hole-blocking layer, the hole-blocking layer may include BCP or Bphen:

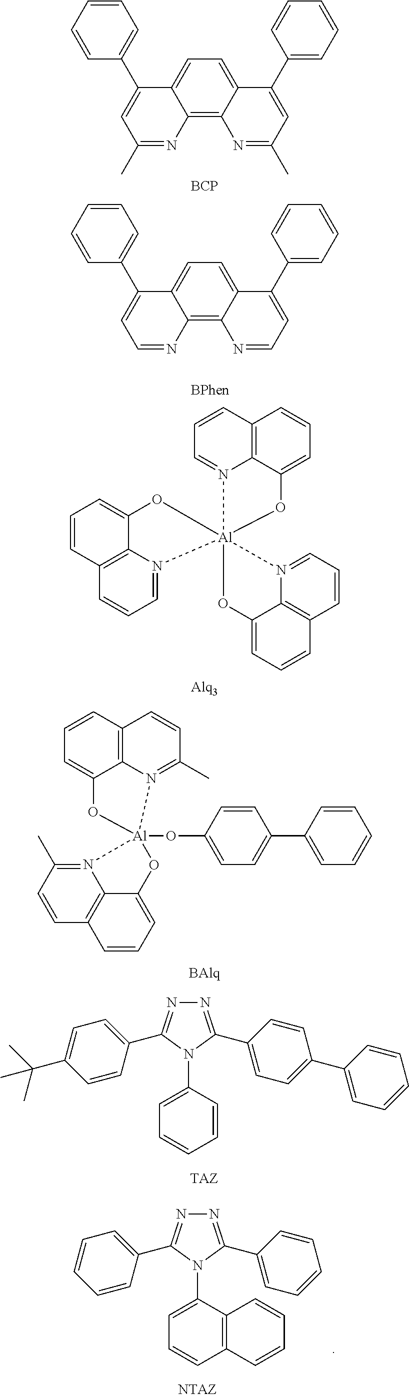

Thicknesses of the buffer layer, the hole-blocking layer, and the electron control layer may each independently be about 20 Å to about 1,000 Å, or about 30 Å to about 300 Å. When the thicknesses of the buffer layer, the hole-blocking layer, and the electron control layer are within these ranges, excellent hole-blocking characteristics and/or excellent electron control characteristics may be obtained without a substantial increase in driving voltage.

The thickness of the electron transport layer may be about 100 Å to about 1,000 Å, or about 150 Å to about 500 Å. When the thickness of the electron transport layer is within these ranges, satisfactory electron transporting characteristics may be obtained without a substantial increase in driving voltage.

The electron transport region 17 (for example, the electron transport layer in the electron transport region 17) may further include, in addition to the aforementioned materials, a metal-containing material.

The metal-containing material may include an alkali metal complex, an alkaline earth metal complex, or a combination thereof. A metal ion of the alkali metal complex may include a Li ion, a Na ion, a K ion, a Rb ion, a Cs ion, or a combination thereof, and a metal ion of the alkaline earth metal complex may include a Be ion, a Mg ion, a Ca ion, a Sr ion, a Ba ion, or a combination thereof. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxydiphenyloxadiazole, a hydroxydiphenylthiadiazole, a hydroxyphenylpyridine, a hydroxyphenylbenzimidazole, a hydroxyphenylbenzothiazole, a bipyridine, a phenanthroline, a cyclopentadiene, or a combination thereof.

In one or more embodiments, the metal-containing material may include a Li complex. The Li complex may include Compound ET-D1 (LiQ) or ET-D2:

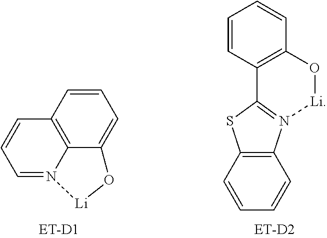

The electron transport region 17 may include an electron injection layer that facilitates the injection of electrons from the second electrode 19. A thickness of the electron injection layer may be about 1 Å to about 100 Å, or about 3 Å to about 90 Å. The electron injection layer may directly contact the second electrode 19.

The electron injection layer may have i) a single-layer structure consisting of a single layer including a single material, ii) a single-layer structure consisting of a single layer including multiple materials that are different from each other, or iii) a multi-layer structure consisting of multiple layers including multiple materials that are different from each other.

The electron injection layer may include an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or a combination thereof.

The alkali metal may include Li, Na, K, Rb, Cs, or a combination thereof. In one or more embodiments, the alkali metal may be Li, Na, or Cs. In one or more embodiments, the alkali metal may be Li or Cs.

The alkaline earth metal may include Mg, Ca, Sr, Ba, or a combination thereof.

The rare earth metal may include Sc, Y, Ce, Tb, Yb, Gd, or a combination thereof.

The alkali metal compound, the alkaline earth metal compound, and the rare earth metal compound may include oxides and halides (fluorides, chlorides, bromides, or iodides) of the alkali metal, the alkaline earth metal, the rare earth metal, or a combination thereof.

The alkali metal compound may include one of alkali metal oxides such as Li₂O, Cs₂O, K₂O, or the like; one of alkali metal halides such as LiF, NaF, CsF, KF, LiI, NaI, CsI, KI, or the like; or a combination thereof. In one or more embodiments, the alkali metal compound may include LiF, Li₂O, NaF, LiI, NaI, CsI, KI, or a combination thereof.

The alkaline earth-metal compound may include one of alkaline earth-metal compounds, such as BaO, SrO, CaO, BaₓSr₁₋ₓO (wherein 0<x<1), BaₓCa₁₋ₓO (wherein 0<x<1), or a combination thereof. In one or more embodiments, the alkaline earth metal compound may include BaO, SrO, CaO, or a combination thereof.

The rare earth metal compound may include YbF₃, ScF₃, Sc₂O₃, Y₂O₃, Ce₂O₃, GdF₃, TbF₃, or a combination thereof. In one or more embodiments, the rare earth metal compound may include YbF₃, ScF₃, TbF₃, YbI₃, ScI₃, TbI₃, or a combination thereof.

The alkali metal complex, the alkaline earth metal complex, and the rare earth metal complex may include an ion of alkali metal, alkaline earth metal, and rare earth metal as described above, and a ligand coordinated with a metal ion of the alkali metal complex, the alkaline earth metal complex, or the rare earth metal complex may include hydroxy quinoline, hydroxy isoquinoline, hydroxy benzoquinoline, hydroxy acridine, hydroxy phenanthridine, hydroxy phenyloxazole, hydroxy phenylthiazole, hydroxy diphenyloxadiazole, hydroxy diphenylthiadiazole, hydroxy phenylpyridine, hydroxy phenylbenzimidazole, hydroxy phenylbenzothiazole, bipyridine, phenanthroline, cyclopentadiene, or a combination thereof.

The electron injection layer may consist of an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or a combination thereof, as described herein. In one or more embodiments, the electron injection layer may further include an organic material. When the electron injection layer further includes an organic material, an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or a combination thereof may be homogeneously or non-homogeneously dispersed in a matrix including the organic material.

The thickness of the electron injection layer may be about 1 Å to about 100 Å, or about 3 Å to about 90 Å. When the thickness of the electron injection layer is within the range as described above, satisfactory electron injection characteristics may be obtained without a substantial increase in driving voltage.

### Second Electrode 19

The second electrode 19 may be positioned on the interlayer 10A. The second electrode 19 may be a cathode which is an electron injection electrode, and in this regard, a material for forming the second electrode 19 may be a metal, an alloy, an electrically conductive compound, or a combination thereof, which have a relatively low work function.

The second electrode 19 may include Li, Ag, Mg, A1, A1-Li, Ca, Mg—In, Mg—Ag, ITO, IZO, or a combination thereof. The second electrode 19 may be a transmissive electrode, a semi-transmissive electrode, or a reflective electrode.

The second electrode 19 may have a single-layer structure having a single layer or a multi-layer structure including two or more layers.

### Electronic Apparatus

According to another aspect, the light-emitting device may be included in various electronic apparatuses. Thus, an electronic apparatus including the light-emitting device is provided.

The electronic apparatus may further include, in addition to the light-emitting device, i) a color filter, ii) a color conversion layer, or iii) a color filter and a color conversion layer. The color filter and/or the color conversion layer may be arranged in at least one traveling direction of light emitted from the light-emitting device. Light emitted from the light-emitting device may be blue light, green light, or white light. A detailed description of the light-emitting device is provided above. In one or more embodiments, the color conversion layer may include quantum dots.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The electronic apparatus may further include a thin-film transistor, in addition to the light-emitting device as described above. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, or the like.

The active layer may include crystalline silicon, amorphous silicon, an organic semiconductor, an oxide semiconductor, or the like.

The electronic apparatus may further include a sealing portion for sealing the light-emitting device. The sealing portion may be arranged between the color filter and/or the color conversion layer and the light-emitting device. The sealing portion allows light from the light-emitting device to be extracted to the outside, and simultaneously prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin film encapsulation layer, the electronic apparatus may be flexible.

Various functional layers may be additionally arranged on the sealing portion, in addition to the color filter and/or the color conversion layer, according to the use of the electronic apparatus. Examples of the functional layers may include a touch screen layer and a polarizing layer. The touch screen layer may be a pressure-sensitive touch screen layer, a capacitive touch screen layer, or an infrared touch screen layer.

According to one or more embodiments, the electronic apparatus may include the light-emitting device and a sealing portion that seals the light-emitting device.

In some embodiments, a method of manufacturing an electronic apparatus including the light-emitting device and a sealing portion sealing the light-emitting device includes manufacturing the light-emitting device, and manufacturing a sealing portion for protecting the light-emitting device from external air and moisture.

In some embodiments, the electronic apparatus may be applied as or be one of a flat panel display, a curved display, a computer monitor, a medical monitor, a television, a billboard, indoor or outdoor lighting and/or signaling light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device (e.g., a wrist watch), a laptop computer, a personal computer, a digital camera, a camcorder, a viewfinder, a micro display, a three-dimensional (3D) display, a virtual reality or augmented reality display, a vehicle, a video wall including multiple displays tiled together, a theater screen, a stadium screen, a phototherapy device, a signage, an electronic organizer, an electronic dictionary, or an electronic game machine.

Since the light-emitting device has excellent driving voltage and external quantum efficiency characteristics, the electronic apparatus including the light-emitting device may have high-quality characteristics such as high brightness, high resolution, and/or low power consumption.

### Method of Evaluating % Vbur for the Center of HONTO of Condensed Cyclic Compound

According to another aspect, provided is a method of evaluating % Vbur for the center of HONTO of a condensed cyclic compound including first boron, second boron, ring A1, ring A2, ring A3, ring A4 and ring A5, wherein
each of ring A1 and ring A2 may be a monocyclic 6-membered ring including the first boron, four carbons and one nitrogen located at a para-position to the first boron as ring-forming atoms,
ring A1 and ring A2 are condensed with each other while sharing the first boron and one carbon among the carbon atoms,
each of ring A3 and ring A4 may be a monocyclic 5-membered ring including the second boron as a ring-forming atom, or a monocyclic 6-membered ring including the second boron as a ring-forming atom,
ring A3 and ring A4 may be condensed with each other while sharing the second boron,
ring A5 may be a C₅-C₆₀ carbocyclic group or a C₃-C₆₀ heterocyclic group, and
i) at least one of ring A1 or ring A2 and ii) at least one of ring A3 or ring A4 may each be condensed to ring A5, the method including
(a) calculating the center of HONTO of the condensed cyclic compound from the NTO contribution by each atom of the condensed cyclic compound in the T₁ state of the condensed cyclic compound, which is obtained using TD-DFT calculation at the B3LYP/6-31G(d,p) level, after obtaining the optimized structure of the condensed cyclic compound in the singlet state using DFT calculation at the B3LYP/6-31G(d,p) level, and
(b) calculating V2/V1 to obtain % Vbur,
wherein
V1 may be the volume of a virtual sphere S1, the center of the virtual sphere S1 is the center of HONTO of the condensed cyclic compound, and the radius of the virtual sphere S1 is 5 Å,
V2 is the total volume of atoms occupying the interior of the virtual sphere S1 among the atoms of the condensed cyclic compound arranged together with the virtual sphere S1 such that the center of HONTO of the condensed cyclic compound coincides with the center of the virtual sphere S1, and
V2 may be evaluated based on the geometric structure obtained through DFT calculations.

The % Vbur evaluation method for the center of HONTO as described is a value obtained by quantifying the degree to which the “center of HONTO”, which is electrically unstable in the excited state of the condensed cyclic compound, is protected by the remaining atoms, and may be usefully for the evaluation of the stability, robustness, etc. of the condensed cyclic compound as described above.

### Explanation of Terms

The term “C₁-C₆₀ alkyl group” as used herein refers to a linear or branched saturated aliphatic hydrocarbon monovalent group having 1 to 60 carbon atoms, and the term “C₁-C₆₀ alkylene group” as used here refers to a divalent group having the same structure as the C₁-C₆₀ alkyl group.

Non-limiting examples of the C₁-C₆₀ alkyl group, the C₁-C₂₀ alkyl group, and/or the C₁-C₁₀ alkyl group include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or the like, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, a propoxy group, a butoxy group, a pentoxy group, or the like.

The term “C₂-C₆₀ alkenyl group” as used herein refers to a structure containing at least one carbon-carbon double bond in the middle or at the end of the C₂-C₆₀ alkyl group, and non-limiting examples thereof include an ethenyl group, a propenyl group, a butenyl group, or the like. The term “C₂-C₆₀ alkenylene group” as used herein refers to a divalent group having the same structure as the C₂-C₆₀ alkenyl group.

The term “C₁-C₆₀ alkylthio group” as used herein refers to a monovalent group represented by —SA₁₀₁ (wherein A₁₀₁ is the C₁-C₆₀ alkyl group).

The term “C₂-C₆₀ alkynyl group” as used herein refers to a hydrocarbon group formed by substituting at least one carbon-carbon triple bond in the middle or at the terminus of the C₂-C₆₀ alkyl group, and non-limiting examples thereof include an ethynyl group, a propynyl group, or the like. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms as ring-forming atoms, and the term “C₃-C₁₀ cycloalkylene group” as used herein refers to a divalent group having the same structure as the C₃-C₁₀ cycloalkyl group.

Non-limiting examples of the C₃-C₁₀ cycloalkyl group include a cyclopropyl group, a cyclobutyl group, a cyclopentyl group, a cyclohexyl group, a cycloheptyl group, a cyclooctyl group, an adamantanyl group, a norbornanyl group (a bicyclo[2.2.1]heptyl group), a bicyclo[1.1.1]pentyl group, a bicyclo[2.1.1]hexyl group, a bicyclo[2.2.2]octyl group, or the like.

The term “C₁-C₁₀ heterocycloalkyl group” as used herein refers to a monovalent saturated ring group that includes at least one heteroatom selected from N, O, P, Si, S, Se, Ge, and B as a ring-forming atom and 1 to 10 carbon atoms as ring-forming atom(s), and the term “the C₁-C₁₀ heterocycloalkylene group” as used herein refers to a divalent group having the same structure as the C₁-C₁₀ heterocycloalkyl group.

Non-limiting examples of the C₁-C₁₀ heterocycloalkyl group include a silolanyl group, a silinanyl group, tetrahydrofuranyl group, a tetrahydro-2H-pyranyl group, a tetrahydrothiophenyl group, or the like.

The term “C₃-C₁₀ cycloalkenyl group” as used herein refers to a monovalent hydrocarbon cyclic group that has 3 to 10 carbon atoms as ring-forming atoms, and at least one carbon-carbon double bond in the ring thereof and has no aromaticity, and non-limiting examples thereof include a cyclopentenyl group, a cyclohexenyl group, a cycloheptenyl group, or the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent ring group that has at least one heteroatom selected from N, O, P, Si, S, Se, Ge, and B as a ring-forming atom, 1 to 10 carbon atoms as ring-forming atom(s), and at least one double bond in the ring thereof and has no aromaticity. Non-limiting examples of the C₁-C₁₀ heterocycloalkenyl group include a 2,3-dihydrofuranyl group, a 2,3-dihydrothiophenyl group, or the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms as ring-forming atoms, and the term “C₆-C₆₀ arylene group” as used herein refers to a divalent group having a carbocyclic aromatic system having 6 to 60 carbon atoms as ring-forming atoms. Non-limiting examples of the C₆-C₆₀ aryl group include a phenyl group, a naphthyl group, an anthracenyl group, a phenanthrenyl group, a pyrenyl group, a chrysenyl group, or the like. When the C₆-C₆₀ aryl group and the C₆-C₆₀ arylene group each include two or more rings, the rings may be fused with each other.

The term “C₁-C₆₀ heteroaryl group” as used herein refers to a monovalent group that includes a heterocyclic aromatic system having at least one heteroatom selected from N, O, P, Si, S, Se, Ge, and B as a ring-forming atom and 1 to 60 carbon atoms as ring-forming atom(s), and the term “C₁-C₆₀ heteroarylene group” as used herein refers to a divalent group that includes a heterocyclic aromatic system having at least one heteroatom selected from N, O, P, Si, S, Se, Ge, and B as a ring-forming atom and 1 to 60 carbon atoms as ring-forming atom(s). Non-limiting examples of the C₁-C₆₀ heteroaryl group include a pyridinyl group, a pyrimidinyl group, a pyrazinyl group, a pyridazinyl group, a triazinyl group, a quinolinyl group, an isoquinolinyl group, or the like. When the C₁-C₆₀ heteroaryl group and the C₁-C₆₀ heteroarylene group each include two or more rings, the rings may be fused with each other.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “monovalent non-aromatic condensed polycyclic group” as used herein refers to a monovalent group in which two or more rings are condensed with each other, only carbon is used as a ring-forming atom (for example, the number of carbon atoms may be 8 to 60), and the whole molecule has no aromaticity. An example of the monovalent non-aromatic condensed polycyclic group is a fluorenyl group or the like. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed with each other, a heteroatom selected from N, O, P, Si, S, Se, Ge, and B, other than carbon atoms (for example, having 1 to 60 carbon atoms), as a ring-forming atom, and no aromaticity in the entire molecular structure thereof. Non-limiting examples of the monovalent non-aromatic condensed heteropolycyclic group include a carbazolyl group, or the like. The term “divalent non-aromatic condensed heteropolycyclic group” as used herein refers to a divalent group having the same structure as the monovalent non-aromatic condensed heteropolycyclic group.

The term “π electron-deficient nitrogen-containing C₁-C₆₀ cyclic group” as used herein refers to a cyclic group having 1 to 60 carbon atoms and including at least one *—N═*′ (wherein * and *′ each indicate a binding site to a neighboring atom) as a ring-forming moiety. The π electron-deficient nitrogen-containing C₁-C₆₀ cyclic group may be a) a first ring, b) a condensed ring group in which at least two first rings are condensed, or c) a condensed ring group in which at least one first ring and at least one second ring are condensed.

The term “π electron-rich C₃-C₆₀ cyclic group” as used herein refers to a cyclic group having 3 to 60 carbon atoms and not including at least one *—N═*′ (wherein * and *′ each indicate a binding site to an adjacent atom) as a ring-forming moiety. The π electron-rich C₃-C₆₀ cyclic group may be a) a second ring or b) a condensed ring group in which at least two second rings are condensed.

The term “C₅-C₆₀ cyclic group” as used herein refers to a monocyclic or polycyclic group having 5 to 60 carbon atoms, and may be, for example, a) a third ring or b) a condensed ring group in which two or more third rings are condensed with each other.

The term “C₁-C₆₀ heterocyclic group” as used herein refers to a monocyclic or polycyclic group that has 1 to 60 carbon atoms and includes at least one heteroatom, and may be, for example, a) a fourth ring, b) a condensed ring group in which two or more fourth rings are condensed with each other, or c) a condensed ring group in which at least one third ring is condensed with at least one fourth ring.

The “first ring” as used herein may be an imidazole group, a pyrazole group, a thiazole group, an isothiazole group, an oxazole group, an isoxazole group, a pyridine group, a pyrazine group, a pyridazine group, a pyrimidine group, a triazole group, a tetrazole group, an oxadiazole group, a triazine group, or a thiadiazole group.

The “second ring” as used herein may be a benzene group, a cyclopentadiene group, a pyrrole group, a furan group, a thiophene group, or a silole group.

The “third ring” as used herein may be a cyclopentane group, a cyclopentadiene group, an indene group, an adamantane group, a norbornene group, a bicyclo[1.1.1]pentane group, a bicyclo[2.1.1]hexane group, a bicyclo[2.2.1]heptane group (a norbornane group), a bicyclo[2.2.2]octane group, a cyclohexane group, a cyclohexene group, or a benzene group.

The “fourth ring” as used herein may be a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, a triazasilole group, a pyridine group, a pyrimidine group, a pyrazine group, a pyridazine group, or a triazine group.

The π electron-deficient nitrogen-containing C₁-C₆₀ cyclic group may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline group, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, a benzoisothiazole group, a benzoxazole group, a benzoisoxazole group, a triazole group, a tetrazole group, an oxadiazole group, a triazine group, a thiadiazole group, an imidazopyridine group, an imidazopyrimidine group, an azacarbazole group, an azadibenzofuran group, an azadibenzothiophene group, an azadibenzosilole group, an acridine group, or a pyridopyrazine group.

The π electron rich C₃-C₆₀ cyclic group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, a furan group, a thiophene group, an isoindole group, an indole group, an indene group, a benzofuran group, a benzothiophene group, a benzosilole group, a naphthopyrrole group, a naphthofuran group, a naphthothiophene group, a naphthosilole group, a benzocarbazole group, a dibenzocarbazole group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, a triindolobenzene group, a pyrrolophenanthrene group, a furanophenanthrene group, a thienophenanthrene group, a benzonaphthofuran group, a benzonaphthothiophene group, an indolophenanthrene group, a benzofuranophenanthrene group, or a benzothienophenanthrene group.

The C₅-C₆₀ carbocyclic group may be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, an indene group, a fluorene group, a 5,6,7,8-tetrahydroisoquinoline group, a 5,6,7,8-tetrahydroquinoline group, an adamantane group, a norbornane group, or a norbornene group.

The C₁-C₆₀ heterocyclic group may be a thiophene group, a furan group, a pyrrole group, a cyclopentadiene group, a silole group, a borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group.

The terms “a π electron-deficient nitrogen-containing C₁-C₆₀ cyclic group”, “a π electron-rich C₃-C₆₀ cyclic group”, “a C₅-C₆₀ cyclic group”, and “a C₁-C₆₀ heterocyclic group” as used herein each refer to a part of a condensed cyclic or a monovalent, a divalent, a trivalent, a tetravalent, a pentavalent, or a hexavalent group, depending on the formula structure.

Substituents of the substituted π electron-deficient nitrogen-containing C₁-C₆₀ cyclic group, the substituted π electron-rich C₃-C₆₀ cyclic group, the substituted C₅-C₆₀ cyclic group, the substituted C₁-C₆₀ heterocyclic group, the substituted C₁-C₆₀ alkylene group, the substituted C₂-C₆₀ alkenylene group, the substituted C₂-C₆₀ alkynylene group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryl alkyl group, the substituted C₆-C₆₀ alkyl aryl group, the substituted C₆-C₆₀ aryloxy group, the substituted C₆-C₆₀ arylthio group, the substituted C₁-C₆₀ heteroaryl group, the substituted C₁-C₆₀ alkyl heteroaryl group, the substituted C₁-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may each independently be:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl alkyl group, a C₆-C₆₀ alkyl aryl group, a C₆-C₆₀ aryloxy group, a C₆-C₆₀ arylthio group, a C₁-C₆₀ heteroaryl group, a C₁-C₆₀ alkyl heteroaryl group, a C₁-C₆₀ heteroaryl alkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl alkyl group, a C₆-C₆₀ alkyl aryl group, a C₆-C₆₀ aryloxy group, a C₆-C₆₀ arylthio group, a C₁-C₆₀ heteroaryl group, a C₆-C₆₀ alkyl heteroaryl group, a C₁-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl alkyl group, a C₆-C₆₀ alkyl aryl group, a C₆-C₆₀ aryloxy group, a C₆-C₆₀ arylthio group, a C₁-C₆₀ heteroaryl group, a C₆-C₆₀ alkyl heteroaryl group, a C₁-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof.

Q₁ to Q₉, Q₁₁ to Q₁₉, Q₂₁ to Q₂₉ and Q₃₁ to Q₃₉ may each independently be hydrogen, deuterium, —F, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl alkyl group, a C₆-C₆₀ alkyl aryl group, a C₆-C₆₀ aryloxy group, a C₆-C₆₀ arylthio group, a C₁-C₆₀ heteroaryl group, a C₆-C₆₀ alkyl heteroaryl group, a C₁-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, a cyano group, a C₁-C₆₀ alkyl group, a C₆-C₆₀ aryl group, a C₆-C₆₀ aryl alkyl group, a C₆-C₆₀ alkyl aryl group, or a combination thereof.

For example, Q₁ to Q₉, Q₁₁ to Q₁₉, Q₂₁ to Q₂₉, and Q₃₁ to Q₃₉ described herein may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

The term “room temperature” as used herein refers to a temperature of about 25° C.

The terms “a biphenyl group, a terphenyl group, and a tetraphenyl group” used herein respectively refer to monovalent groups in which two, three, or four phenyl groups which are linked together via a single bond.

Hereinafter, a compound and an organic light-emitting device according to embodiments are described in detail with reference to Synthesis Examples and Examples. However, the organic light-emitting device is not limited thereto. The wording “‘B’ was used instead of ‘A’” used in describing Synthesis Examples means that an amount of ‘A’ used was identical to an amount of ‘B’ used, in terms of a molar equivalent.

### EXAMPLES

### Synthesis Example 1 (Compound 2)

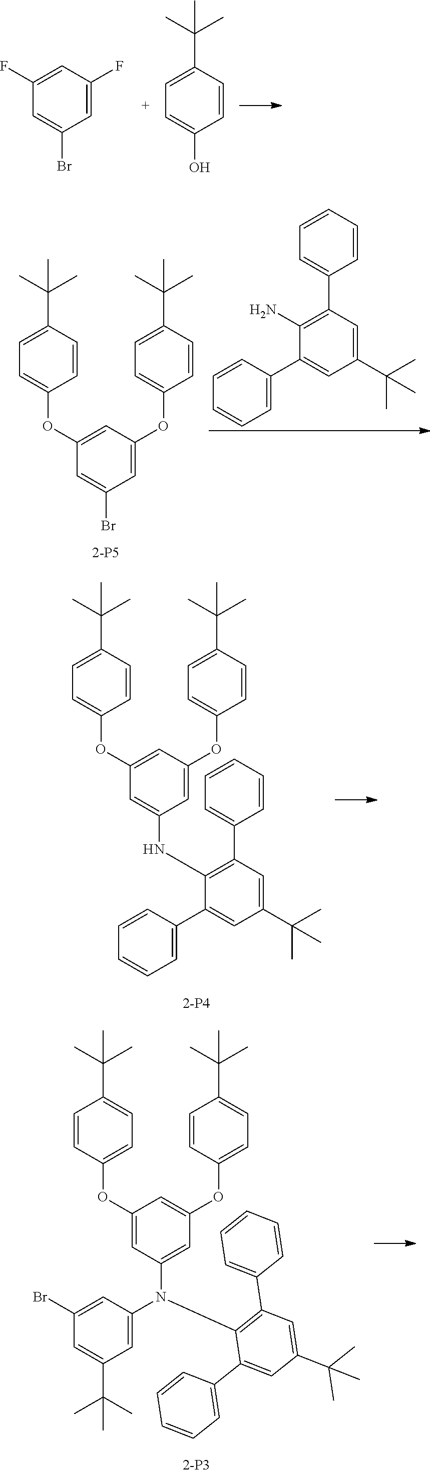

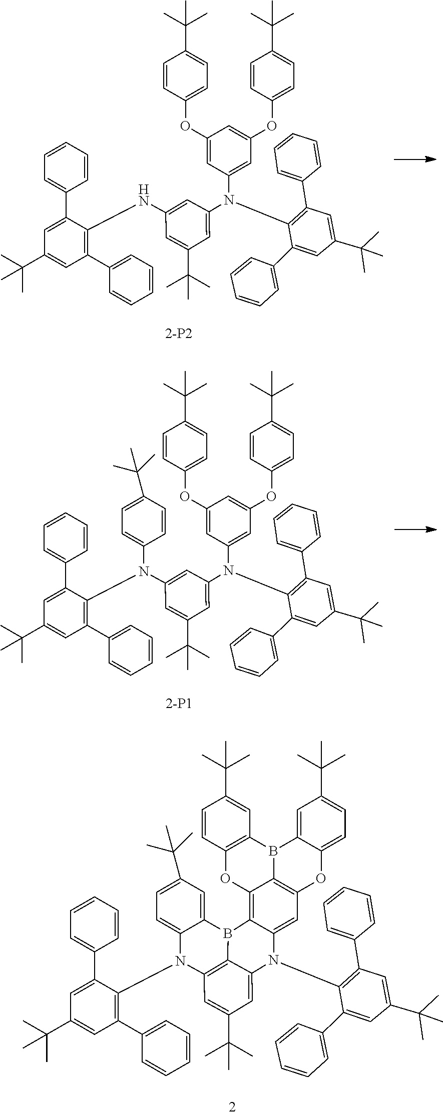

### Synthesis of Compound 2-P5

Under a nitrogen atmosphere, 1-bromo-3,5-difluorobenzene (10 grams (g), 51.93 millimoles (mmol)), 4-(tert-butyl)phenol (8.58 g, 57.13 mmol), and potassium carbonate (21.53 g, 155.79 mmol) were added to 300 mL of 1-methyl-2-pyrrolidinone (NMP), and the mixture was heated to 150° C. After 12 hours, the mixture was cooled to room temperature and the reaction was quenched with an ammonium chloride solution. Following extraction using methylene chloride (MC) and drying over MgSO₄, the solvent was removed and the obtained product was purified by column chromatography using MC and hexane at a volume ratio of 1:3 to obtain compound 2-P5 as a white solid (18 g, yield: 80%).

### Synthesis of Compound 2-P4

Under a nitrogen atmosphere, compound 2-P5 (5 g, 11.03 mmol), 5′-(tert-butyl)-[1,1′:3′,1″-terphenyl]-2′-amine (3.32 g, 11.03 mmol), tris(dibenzylideneacetone)dipalladium(0) (Pd₂(dba)₃) (0.50 g, 0.55 mmol), 2-dicyclohexylphosphino-2′,6′-dimethoxybiphenyl (SPhos) (0.45 g, 1.1 mmol), and sodium t-butoxide (1.59 g, 16.55 mmol) were added to 110 mL of toluene, and the mixture was heated under reflux at 110° C. After 2 hours, the mixture was cooled to room temperature, and the reaction was quenched with an ammonium chloride solution. Following extraction using ethyl acetate and drying over MgSO₄, the solvent was removed under reduced pressure and the obtained product was purified by column chromatography using MC and hexane at a volume ratio of 1:3 to obtain compound 2-P4 as a white solid (6.5 g, yield: 88%).

### Synthesis of Compound 2-P3

Under a nitrogen atmosphere, compound 2-P4 (6.5 g, 9.64 mmol), 1-bromo-3-(tert-butyl)-5-iodobenzene (6.53 g, 19.28 mmol), Pd₂(dba)₃ (0.88 g, 0.96 mmol), tri-tert-butylphosphine (TTBP) (0.39 g, 1.92 mmol), and sodium t-butoxide (2.04 g, 21.2 mmol) were added to 100 mL of xylene, and the mixture was heated under reflux at 140° C. After 1 hour, the mixture was cooled to room temperature, and the reaction was quenched with an ammonium chloride solution. Following extraction using ethyl acetate and drying over MgSO₄, the solvent was removed and the obtained product was purified by column chromatography using MC and hexane at a volume ratio of 1:3 to obtain compound 2-P3 as a white solid (5.1 g, yield: 60%).

### Synthesis of Compound 2-P2

Under a nitrogen atmosphere, compound 2-P3 (5.1 g, 5.76 mmol), 5′-(tert-butyl)-[1,1′:3′,1″-terphenyl]-2′-amine (2.08 g, 6.91 mmol), Pd₂(dba)₃ (0.53 g, 0.58 mmol), SPhos (0.48 g, 1.16 mmol), and sodium t-butoxide (0.83 g, 8.64 mmol) were added to 110 mL of toluene, and the mixture was heated under reflux at 110° C. After 2 hours, the mixture was cooled to room temperature, and the reaction was quenched with an ammonium chloride solution. Following extraction using ethyl acetate and drying over MgSO₄, the solvent was removed under reduced pressure and the obtained product was purified by column chromatography using MC and hexane at a volume ratio of 1:2 to obtain compound 2-P2 as a white solid (5.4 g, yield: 85%).

### Synthesis of Compound 2-P1

Under a nitrogen atmosphere, compound 2-P2 (5.4 g, 4.88 mmol), 1-(tert-butyl)-4-iodobenzene (3.81 g, 14.65 mmol), CuI (1.86 g, 9.76 mmol), and cesium carbonate (3.18 g, 9.76 mmol) were added to 50 mL of t-butylbenzene, and the mixture was heated with stirring at 165° C. After 24 hours, the mixture was cooled to room temperature, and following filtration using a celite filter and removal of the solvent, the obtained product was purified by column chromatography using MC and hexane at a volume ratio of 1:2 to obtain compound 2-P1 as a white solid (5.01 g, yield: 83%).

### Synthesis of Compound 2

Under a nitrogen atmosphere, compound 2-P1 (5 g, 4.05 mmol) was added to 50 mL of 1,2-dichlorobenzene and B13 (4.76 g, 12.15 mmol), the mixture was heated to 120° C., and stirred for 4 hours. After cooling to room temperature, the reaction was quenched with a sodium bicarbonate solution. The resulting organic layer was extracted with MC, dried over MgSO₄, and the solvent was removed under reduced pressure. The product was purified by column chromatography using MC and hexane at a volume ratio of 1:4 to obtain compound 2 (2.1 g, yield: 42%).

Liquid chromatography mass spectrometry (LCMS) (m/z) calculated: 1252.719 g/mol, found: [M+]1253.864 g/mol.

### Synthesis Example 2 (Compound 4)

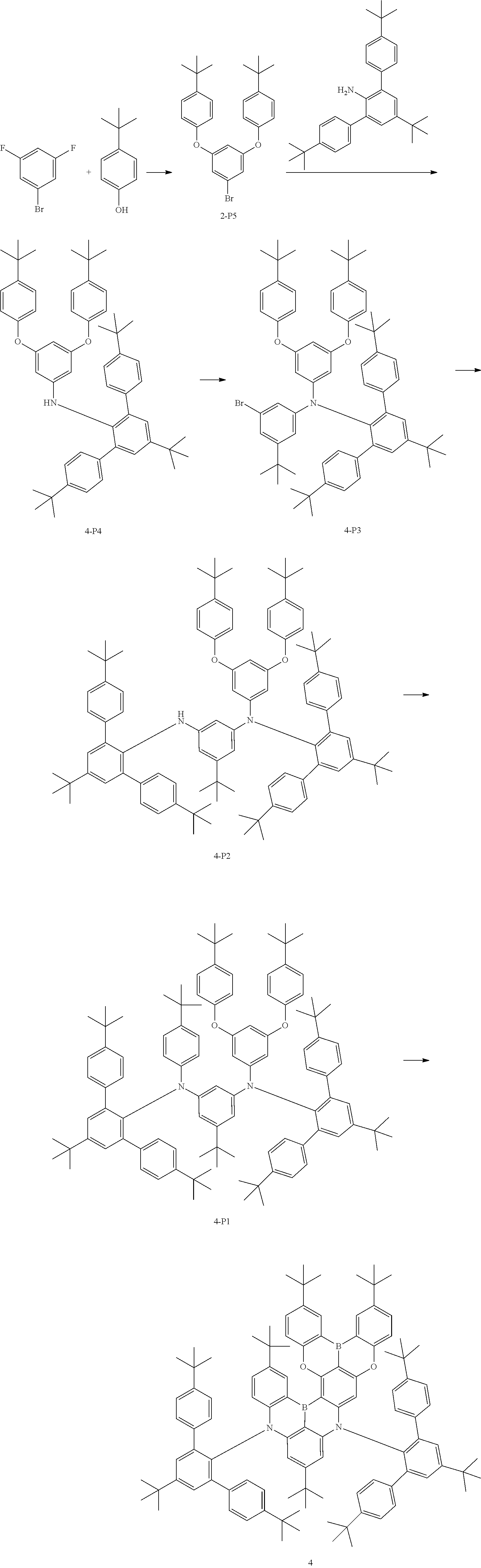

### Synthesis of Compound 4-P4

Compound 4-P4 was synthesized using the same method as used to prepare compound 2-P4 of Synthesis Example 1, except that 4,4″,5′-tri-tert-butyl-[1,1′:3′,1″-terphenyl]-2′-amine was used instead of 5′-(tert-butyl)-[1,1′:3′,1″-terphenyl]-2′-amine.

### Synthesis of Compound 4-P3

Compound 4-P3 was synthesized using the same method as used to prepare compound 2-P3 in Synthesis Example 1, except that compound 4-P4 was used instead of compound 2-P4.

### Synthesis of Compound 4-P2

Compound 4-P2 was synthesized using the same method as used to prepare compound 2-P2 in Synthesis Example 1, except that compound 4-P3 was used instead of compound 2-P3.

### Synthesis of Compound 4-P1

Compound 4-P1 was synthesized using the same method as that for synthesizing compound 2-P1 of Synthesis Example 1, except that compound 4-P2 was used instead of compound 2-P2.

### Synthesis of Compound 4

Compound 4 (2.5 g, yield: 50%) as a yellow solid was obtained using the same method as used to prepare compound 2 in Synthesis Example 1, except that compound 4-P1 was used instead of compound 2-P1.

LCMS (m/z) calculated: 1476.97 g/mol, found: [M+]1478.01 g/mol.

### Synthesis Example 3 (Compound 7)

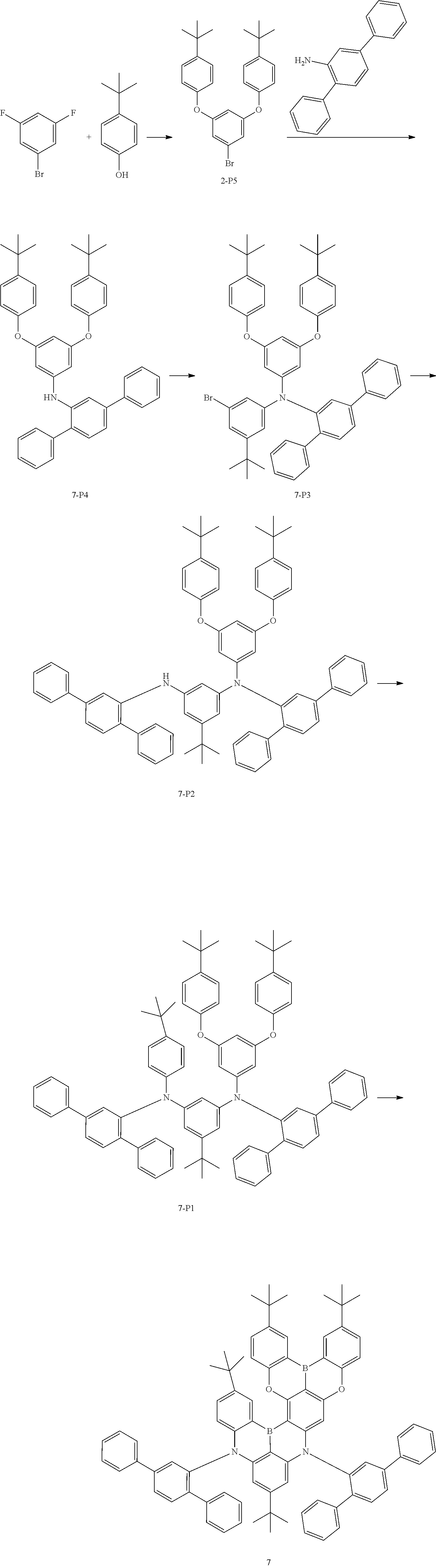

### Synthesis of Compound 7-P4

Compound 7-P4 was synthesized using the same method as used to prepare compound 2-P4 of Synthesis Example 1, except that [1,1′:4′,1″-terphenyl]-2′-amine was used instead of 5′-(tert-butyl)-[1,1′:3′,1″-terphenyl]-2′-amine.

### Synthesis of Compound 7-P3

Compound 7-P3 was synthesized using the same method as used to prepare compound 2-P3 in Synthesis Example 1, except that compound 7-P4 was used instead of compound 2-P4.

### Synthesis of Compound 7-P2

Compound 7-P2 was synthesized using the same method as used to prepare compound 2-P2 of Synthesis Example 1, except that compound 7-P3 was used instead of compound 2-P3.

### Synthesis of Compound 7-P1

Compound 7-P1 was synthesized using the same method as used to prepare compound 2-P1 of Synthesis Example 1, except that compound 7-P2 was used instead of compound 2-P2.

### Synthesis of Compound 7

Compound 7 (2.1 g, yield: 46%) as a yellow solid was obtained using the same method as used to prepare compound 2 in Synthesis Example 1, except that compound 7-P1 was used instead of compound 2-P1.

LCMS (m/z) calculated: 1141.13 g/mol, found: [M+]1142.62 g/mol.

### Evaluation Example 1

The center of HONTO of compound 2 was obtained from the NTO contribution by each atom of compound 2 in the T₁ state of compound 2, which is obtained using TD-DFT calculation at the B3LYP/6-31G(d,p) level, after obtaining the optimized structure of compound 2 in the singlet state using DFT calculation at the B3LYP/6-31G(d,p) level.

Afterwards, % Vbur for the center of HONTO of compound 2 was evaluated using SambVca calculations based on the geometric structure of compound 2 obtained through DFT calculations at the B3LYP/6-31G(d,p) level. Results thereof are shown in TABLE 1. % Vbur with respect to the center of HONTO of compound 2 is defined as “V2/V1” of compound 2. V1 is a volume of a virtual sphere S1, the center of the virtual sphere S1 is the center of HONTO of compound 2, the radius of the virtual sphere S1 is 5 Å, and V2 is a total volume of atoms occupying the interior of the virtual sphere S1 among the atoms of compound 2 arranged together with the virtual sphere S1 such that the center of HONTO of compound 2 coincides with the center of the virtual sphere S1, which may be more clearly understood with reference to FIG. 1.

This experiment was repeated for compounds 4, 7, C1, and C2. Results thereof are summarized in Table 1.

TABLE 1

| Compound No. | %Vbur for the center of HONTO |
|---|---|
| 2 | 75.7 |
| 4 | 75.3 |
| 7 | 66.6 |
| C1 | 52.7 |
| C2 | 56.7 |

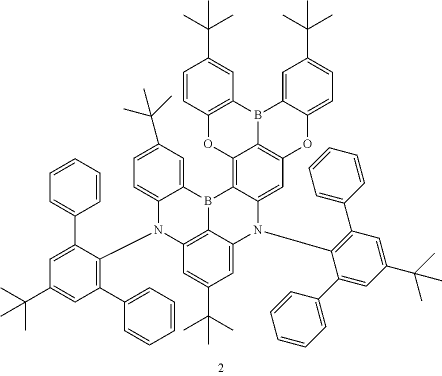 [SMILES: CC(C)(C)c1ccc2c(c1)B1c3cc(C(C)(C)C)ccc3Oc3c1c(cc1c3B3c4cc(C(C)(C)C)ccc4N(c4c(-c5ccccc5)cc(C(C)(C)C)cc4-c4ccccc4)c4cc(C(C)(C)C)cc(c43)N1c1c(-c3ccccc3)cc(C(C)(C)C)cc1-c1ccccc1)O2]

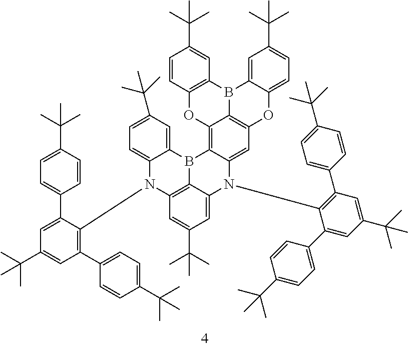 [SMILES: CC(C)(C)c1ccc(-c2cc(C(C)(C)C)cc(-c3ccc(C(C)(C)C)cc3)c2N2c3ccc(C(C)(C)C)cc3B3c4c2cc(C(C)(C)C)cc4N(c2c(-c4ccc(C(C)(C)C)cc4)cc(C(C)(C)C)cc2-c2ccc(C(C)(C)C)cc2)c2cc4c5c(c23)Oc2ccc(C(C)(C)C)cc2B5c2cc(C(C)(C)C)ccc2O4)cc1]

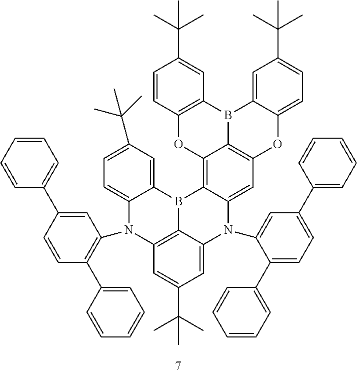 [SMILES: CC(C)(C)c1ccc2c(c1)B1c3cc(C(C)(C)C)ccc3Oc3c1c(cc1c3B3c4cc(C(C)(C)C)ccc4N(c4cc(-c5ccccc5)ccc4-c4ccccc4)c4cc(C(C)(C)C)cc(c43)N1c1cc(-c3ccccc3)ccc1-c1ccccc1)O2]

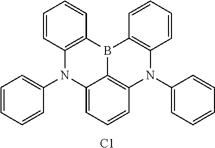

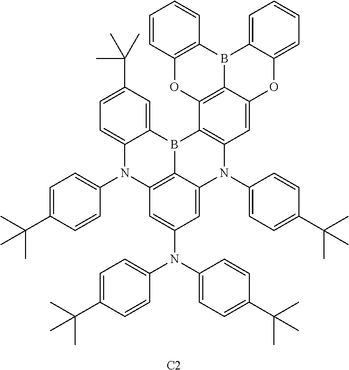 [SMILES: CC(C)(C)c1ccc(N(c2ccc(C(C)(C)C)cc2)c2cc3c4c(c2)N(c2ccc(C(C)(C)C)cc2)c2cc5c6c(c2B4c2cc(C(C)(C)C)ccc2N3c2ccc(C(C)(C)C)cc2)Oc2ccccc2B6c2ccccc2O5)cc1 ; "C2"]

From Table 1, it was confirmed that % Vbur for the center of HONTO of each of compounds 2, 4, and 7 is greater than % Vbur for the center of HONTO of compounds C1 and C2.

### Manufacture of OLED 1 to OLED 3 and OLED C1 and OLED C2

A glass substrate with a 1500 Å-thick ITO (indium tin oxide) electrode (first electrode, anode) was ultrasonically cleaned with deionized (DI) water. After cleaning with DI water, the substrate was ultrasonically cleaned with isopropyl alcohol, acetone, and methanol, dried, transferred to a plasma cleaner, cleaned for 5 minutes using oxygen plasma, and then transferred to a vacuum deposition apparatus.

On the ITO electrode of the glass substrate, compounds HT1 and HT-D2 were co-deposited at a weight ratio of 98:2 to form a hole injection layer having the thickness of 100 Å, then compound HT1 was deposited on the hole injection layer to form a hole transport layer having the thickness of 1300 Å, and mCP was deposited on the hole transport layer to form an electron-blocking layer having the thickness of 100 Å, thereby forming a hole transport region.

On the hole transport region, HTH7 (first host), ETH8 (second host), P31 (sensitizer), and each of the emitters listed in Table 2 (weight ratio of first host:second host:sensitizer:emitter was 56:30:13:1) were co-deposited to form an emission layer having the thickness of 400 Å.

BCP was vacuum-deposited on the emission layer to form a hole-blocking layer having the thickness of 100 Å, compound ET27 and Liq were co-deposited at a volume ratio of 50:50 on the hole-blocking layer to form an electron transport layer having the thickness of 300 Å, then Liq was deposited on the electron transport layer to form an electron injection layer having the thickness of 10 Å, and an A1 second electrode (cathode) having the thickness of 1200 Å was formed on the electron injection layer, thereby completing manufacture of an organic light-emitting device.

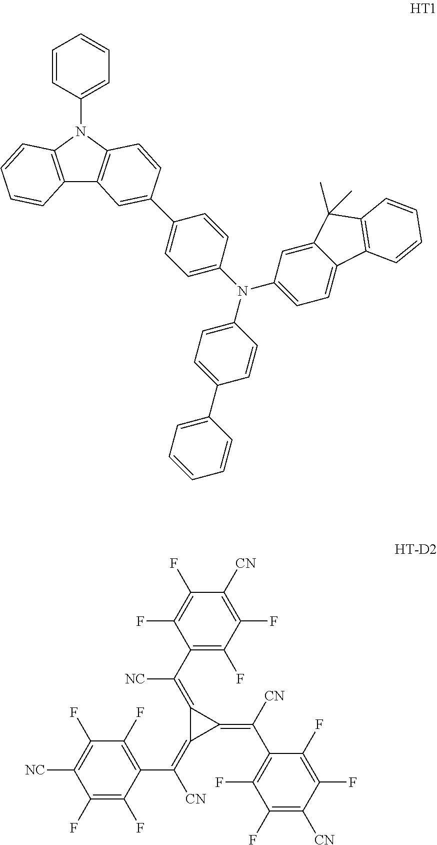 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

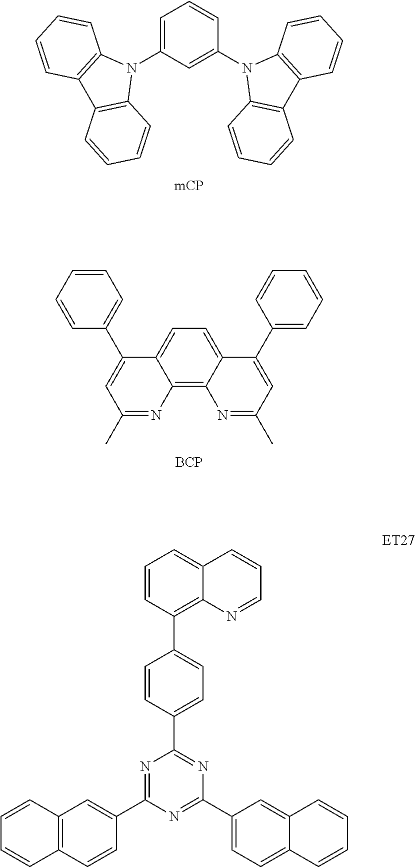

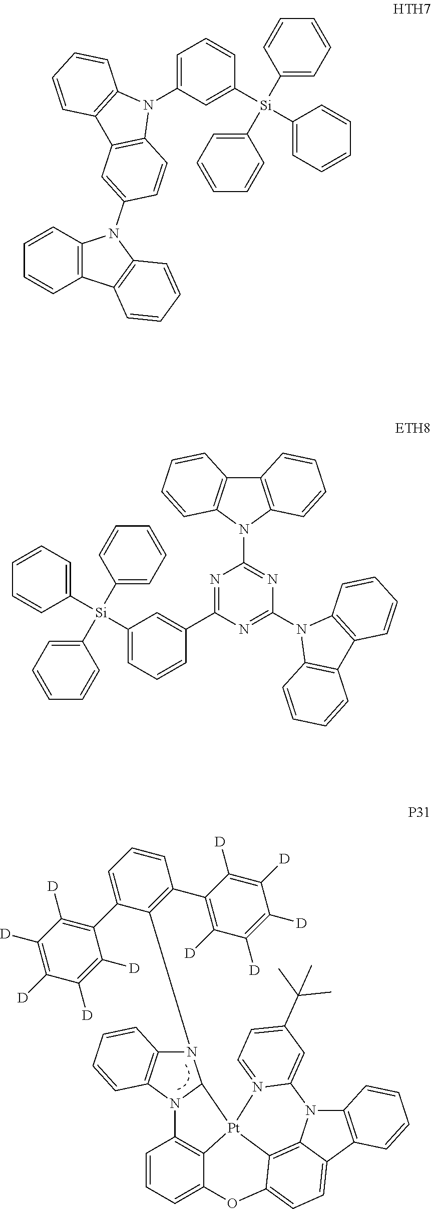

### Evaluation Example 2

Emission peak wavelength (maximum emission peak wavelength, nm) and FWHM (nm) of electroluminescent (EL) spectra, driving voltage (V), external quantum efficiency at 1000 cd/m2 (EQE at 1000 nit), and lifetime (LT₉₅ at 1000 nit) of OLED 1 to OLED 3 and OLED C1 to OLED C2 were evaluated. Results are recorded in Table 2.

Emission peak wavelength and FWHM of EL spectra were evaluated from EL spectra (at 1000 cd/m2) measured using a luminance meter (Minolta Cs-1000A). Driving voltage and external quantum efficiency were evaluated using a current-voltage meter (Keithley 2400) and a luminance meter (Minolta Cs-1000A). Lifetime (LT₉₅ at 1000 nit) was evaluated as the time (hr) taken for the luminance to reach 95% of the initial luminance of 100%, and was converted to a relative value (%). External quantum efficiency was also expressed as a relative value (%).

TABLE 2

| | | % Vbur for | Emission | | | EQE at | LT₉₅ at |
|---|---|---|---|---|---|---|---|
| | Emitter | the center of | peak | | Driving | 1000 nit | 1000 nit |
| | compound | the emitter's | wavelength | FWHM | voltage | (relative | (relative |
| | No. | HONTO | (nm) | (nm) | (V) | value, %) | value, %) |
| OLED 1 | 2 | 75.7 | 452 | 26 | 4.5 | 111 | 780 |
| OLED 2 | 4 | 75.3 | 452 | 27 | 4.5 | 100 | 750 |
| OLED 3 | 7 | 66.6 | 456 | 26 | 4.5 | 108 | 910 |
| OLED C1 | C1 | 52.7 | 453 | 27 | 4.4 | 86 | 62 |
| OLED C2 | C2 | 56.7 | 451 | 27 | 4.4 | 100 | 100 |

From Table 2, it was confirmed that OLED 1 to OLED 3 have superior external quantum efficiency and excellent lifespan characteristics compared to OLED C1 and OLED C2 while emitting blue light.

The condensed cyclic compound can have excellent electrical stability. Therefore, a light-emitting device including at least one of the condensed cyclic compounds can have excellent luminescence efficiency and excellent lifespan characteristics, and thus a high-quality electronic apparatus may be manufactured using the light-emitting device.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A condensed cyclic compound comprising a first boron, a second boron, ring A1, ring A2, ring A3, ring A4, and ring A5, wherein
each of ring A1 and ring A2 is a monocyclic 6-membered ring comprising, as ring-forming atoms, the first boron, four carbons, and one nitrogen, wherein the nitrogen is located at a para-position to the first boron,
ring A1 and ring A2 are condensed with each other while sharing one of the carbons and the first boron,
each of ring A3 and ring A4 is independently a monocyclic 5-membered ring comprising the second boron as a ring-forming atom, or a monocyclic 6-membered ring comprising the second boron as a ring-forming atom,
ring A3 and ring A4 are condensed with each other while sharing the second boron,
ring A5 is a C₅-C₆₀ carbocyclic group or a C₃-C₆₀ heterocyclic group,
i) at least one of ring A1 or ring A2, and ii) at least one of ring A3 or ring A4 are condensed to ring A5,
a percent volume buried (% Vbur) for a center of highest occupied natural transition orbital (HONTO) of the condensed cyclic compound is greater than or equal to about 65%,
the center of HONTO of the condensed cyclic compound is evaluated from natural transition orbital (NTO) contribution by each atom of the condensed cyclic compound in a T1 state of the condensed cyclic compound, which is obtained using a time dependent-density functional theory (TD-DFT) calculation at a B3LYP/6-31G(d,p) level, after obtaining an optimized structure of the condensed cyclic compound in a singlet state by using DFT calculation at the B3LYP/6-31 G(d,p) level,
% Vbur is V2/V1,
V1 is a volume of a virtual sphere S1, a center of the virtual sphere S1 is the center of HONTO of the condensed cyclic compound, and a radius of the virtual sphere S1 is 5 Å,
V2 is a total volume of atoms occupying an interior of the virtual sphere S1 among the atoms of the condensed cyclic compound arranged together with the virtual sphere S1 such that the center of HONTO of the condensed cyclic compound coincides with the center of the virtual sphere S1, and
V2 is evaluated based on a geometric structure obtained through DFT calculations.

2. The condensed cyclic compound of claim 1, wherein
each of ring A3 and ring A4 is a monocyclic 6-membered ring comprising the second boron as a ring-forming atom.

3. The condensed cyclic compound of claim 1, wherein
ring A5 is a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

4. The condensed cyclic compound of claim 1, wherein
each of ring A3 and ring A4 is a monocyclic 6-membered ring comprising oxygen (O), sulfur (S), nitrogen (N) or silicon (Si) as a ring-forming atom at a para-position with respect to the second boron.

5. The condensed cyclic compound of claim 1, wherein
at least one of nitrogen of ring A1 or nitrogen of ring A2 is each independently bonded to a terphenyl monovalent group, a quaterphenyl monovalent group, or a quinquephenyl monovalent group, and
at least one hydrogen of each of the terphenyl monovalent group, the quaterphenyl monovalent group, and the quinquephenyl monovalent group is optionally substituted with:
deuterium, —F, or a cyano group; or
a C₁-C₆₀ alkyl group unsubstituted or substituted with deuterium, —F, a cyano group, or a combination thereof.

6. The condensed cyclic compound of claim 1, wherein
nitrogen of ring A1, nitrogen of ring A2, or a combination thereof is each independently bonded to a group represented by Formula 2A, a group represented by Formula 2B, or a group represented by Formula 2C: 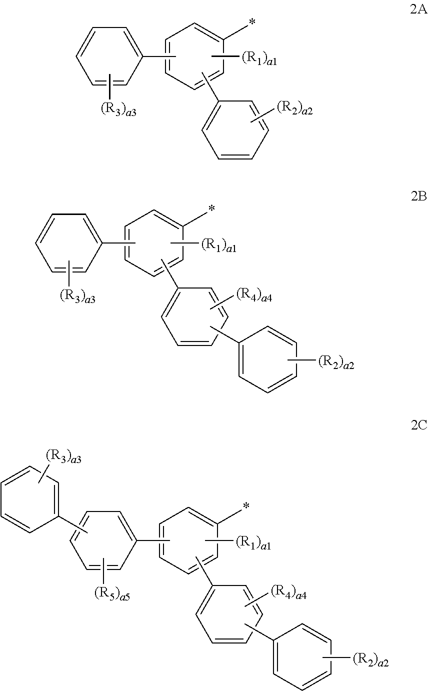
wherein, in Formulae 2A to 2C,
R₁ to R₅ are each independently:
hydrogen, deuterium, —F, or a cyano group; or
a C₁-C₆₀ alkyl group unsubstituted or substituted with deuterium, —F, a cyano group, or a combination thereof,
a1 is an integer from 0 to 3,
a4 and a5 are each independently an integer from 0 to 4,
a2 and a3 are each independently an integer from 0 to 5, and
* indicates a binding site with a neighboring nitrogen atom.

7. The condensed cyclic compound of claim 1, wherein
the % Vbur with respect to the center of HONTO is about 65% to about 90%.

8. The condensed cyclic compound of claim 1, wherein
the % Vbur with respect to the center of HONTO is about 66% to about 76%.

9. The condensed cyclic compound of claim 1, wherein
a distance between the center of HONTO and the first boron is smaller than a distance between the center of HONTO and the second boron.

10. The condensed cyclic compound of claim 1, comprising
a core represented by Formula 1: 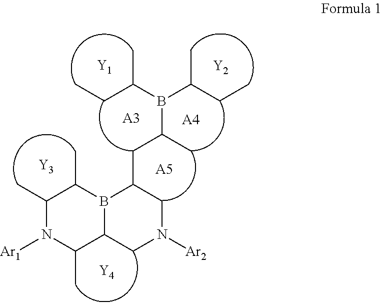
wherein, in Formula 1,
each of ring A3 and ring A4 is as described in claim 1,
ring Y₁, ring Y₂, ring Y₃, ring Y₄, and ring A5 are each independently a C₅-C₆a carbocyclic group or a C₃-C₆₀ heterocyclic group,
Ar₁ and Ar₂ are each independently a terphenyl monovalent group, a quaterphenyl monovalent group, or a quinquephenyl monovalent group,
at least one hydrogen of each of the terphenyl monovalent group, the quaterphenyl monovalent group, and the quinquephenyl monovalent group is optionally be substituted with:
deuterium, —F, or a cyano group; or
a C₁-C₆₀ alkyl group unsubstituted or substituted with deuterium, —F, a cyano group, or a combination thereof.

11. The condensed cyclic compound of claim 10, wherein
ring Y₁, ring Y₂, ring Y₃, ring Y₄, and ring A5 are each independently a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

12. The condensed cyclic compound of claim 10, wherein
each of ring A3 and ring A4 is a monocyclic 6-membered ring comprising oxygen (O), sulfur (S), nitrogen (N), or silicon (Si) as a ring-forming atom at a para-position with respect to boron.

13. The condensed cyclic compound of claim 10, wherein
at least one hydrogen of each of ring A3, ring A4, ring Y₁, ring Y₂, ring Y₃, ring Y₄, and ring A5 is optionally substituted with:
deuterium, —F, or a cyano group;
a C₁-C₆₀ alkyl group unsubstituted or substituted with deuterium, —F, a cyano group, or a combination thereof;
a C₆-C₆₀ aryl group, a C₁-C₆₀ heteroaryl group, a dibenzofuranyl group, a dibenzothiophenyl group, a carbazolyl group, a fluorenyl group, or a dibenzosilolyl group, each unsubstituted or substituted with a deuterium, —F, a cyano group, a C₁-C₆₀ alkyl group, a C₆-C₆₀ aryl group, a C₁-C₆₀ heteroaryl group, a dibenzofuranyl group, a dibenzothiophenyl group, a carbazolyl group, a fluorenyl group, a dibenzosilolyl group, —N(Q₃₁)(Q₃₂), —Si(Q₃₃)(Q₃₄)(Q₃₅), —Ge(Q₃₃)(Q₃₄)(Q₃₅), or a combination thereof; or
—N(Q₁)(Q₂), —Si(Q₃)(Q₄)(Q₅), or —Ge(Q₃)(Q₄)(Q₅), and Q₁ to Q₅ and Q₃₁ to Q₃₅ are each independently:
a C₁-C₆₀ alkyl group unsubstituted or substituted with deuterium, —F, a cyano group, or a combination thereof; or
a C₆-C₆₀ aryl group, a C₁-C₆₀ heteroaryl group, a dibenzofuranyl group, a dibenzothiophenyl group, a carbazolyl group, a fluorenyl group, or a dibenzosilolyl group, each unsubstituted or substituted with deuterium, —F, a cyano group, a C₁-C₆₀ alkyl group, a C₆-C₆₀ aryl group, a C₁-C₆₀ heteroaryl group, a dibenzofuranyl group, a dibenzothiophenyl group, a carbazolyl group, a fluorenyl group, a dibenzosilolyl group, or a combination thereof.

14. A light-emitting device, comprising:
a first electrode;
a second electrode facing the first electrode; and
an interlayer positioned between the first electrode and the second electrode,
wherein the interlayer comprises an emission layer, and
wherein the interlayer further comprises at least one condensed cyclic compound of claim 1.

15. The light-emitting device of claim 14, wherein
the emission layer comprises the at least one condensed cyclic compound.

16. The light-emitting device of claim 15, wherein
the at least one condensed cyclic compound in the emission layer is an emitter.

17. The light-emitting device of claim 16, wherein
the emission layer further comprises a sensitizer and a host, wherein
excitation energy in the emission layer is transferred from at least one of the sensitizer or the host to the at least one condensed cyclic compound, and the at least one condensed cyclic compound performs a radiative transition of the excitation energy absorbed from at least one of the sensitizer or the host to a ground state, and emits the excitation energy as fluorescence, thereby emitting light.

18. The light-emitting device of claim 16, wherein
fluorescence is emitted from the emission layer, and
a peak emission wavelength of the fluorescence is about 400 nanometers to about 500 nanometers.

19. The light-emitting device of claim 17, wherein
the sensitizer is an organometallic compound,
the organometallic compound comprises a transition metal and a tetradentate ligand bonded to the transition metal,
the transition metal is platinum or palladium, and
the tetradentate ligand comprises a carbene moiety bonded to the transition metal.

20. An electronic apparatus, comprising the light-emitting device of claim 14.
